(19) United States
(12) Patent Application Publication
(10) Pub. No.: US 2024/0218003 A1
(43) Pub. Date: Jul. 4, 2024

(54) ORGANOMETALLIC COMPOUND, ORGANIC LIGHT EMITTING DIODE AND ORGANIC LIGHT EMITTING DEVICE HAVING THE COMPOUND

(71) Applicant: LG DISPLAY CO., LTD., Seoul (KR)

(72) Inventor: Tae-Ryang HONG, Paju-si (KR)

(73) Assignee: LG DISPLAY CO., LTD., Seoul (KR)

(21) Appl. No.: 18/221,372

(22) Filed: Jul. 12, 2023

(30) Foreign Application Priority Data
Nov. 7, 2022 (KR) 10-2022-0146908

(51) Int. Cl. C07F 15/00; H10K 50/12; H10K 85/30

(52) U.S. Cl. CPC C07F 15/0033; H10K 50/12; H10K 85/342

(57) ABSTRACT

The present disclosure relates to an organometallic compound having the following structure of Chemical Formula 1, Ir(L_{A})ₘ(L_{B})ₙ, an organic light emitting diode (OLED) where the organometallic compound is applied to an emitting material layer and an organic light emitting diode. The luminous efficiency, color purity and luminous lifespan of the OLED and the organic light emitting device can be improved.

### CROSS-REFERENCE TO RELATED APPLICATIONS

This application claims the benefit of and the priority of Korean Patent Application No. 10-2022-0146908, filed in the Republic of Korea on Nov. 7, 2022, which is expressly incorporated hereby in its entirety into the present application.

### BACKGROUND

### Technical Field

The present disclosure relates to an organometallic compound, and more particularly to, an organometallic compound with beneficial luminous efficiency and luminous lifespan and an organic light emitting diode and an organic light emitting device including the compound.

### Description of the Related Art

A flat display device including an organic light emitting diode (OLED) has attracted attention as a display device that can replace a liquid crystal display device (LCD). The electrode configurations in the OLED can implement unidirectional or bidirectional images. Also, the OLED can be formed even on a flexible transparent substrate such as a plastic substrate so that a flexible or a foldable display device can be realized with ease using the OLED. In addition, the OLED can be driven at a lower voltage and the OLED has advantageous high color purity compared to the LCD.

Since fluorescent material uses only singlet excitons in the luminous process, the related art fluorescent material shows low luminous efficiency. On the contrary, phosphorescent material can show high luminous efficiency since it uses triplet exciton as well as singlet excitons in the luminous process. However, examples of phosphorescent material include metal complexes, which have a short luminous lifespan for commercial use.

### SUMMARY

Accordingly, embodiments of the present disclosure are directed to an organometallic compound, an organic light emitting diode and an organic light emitting device that substantially obviate one or more of the problems due to the limitations and disadvantages of the related art.

An aspect of the present disclosure is to provide an organic light emitting diode that may have enhanced thermal stability and an organic light emitting device including the organic light emitting diode. Another aspect of the present disclosure is to provide an organic light emitting diode that may have improved luminous properties and an organic light emitting device including the organic light emitting diode.

Additional features and aspects will be set forth in the description that follows, and in part will be apparent from the description, or may be learned by practice of the disclosed concepts provided herein. Other features and aspects of the disclosed concept may be realized and attained by the structure particularly pointed out in the written description, or derivable therefrom, and the claims hereof as well as the appended drawings.

To achieve these and other advantages and in accordance with objects of the disclosure, as embodied and broadly described herein, in one aspect, the present disclosure provides an organometallic compound represented by a structure of Chemical Formula 1:

Ir(L_{A})ₘ(L_{B})ₙ [Chemical Formula 1]
wherein, in the Chemical Formula 1,
L_{A} has the following structure of Chemical Formula 2;
L_{B} is an auxiliary ligand;
m is 1, 2 or 3;
n is 0, 1 or 2; and
m+n is 3;

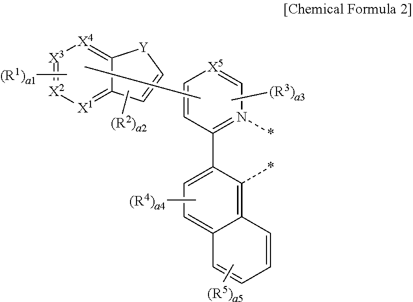

wherein, in the Chemical Formula 2,
each of X¹ to X⁴ is independently CR¹, N or a carbon atom linked to a hetero aromatic ring including X⁵, where at least one of X¹ to X⁴ is CR¹ or the carbon atom linked to the hetero aromatic ring including X⁵;
X⁵ is CR³, N or a carbon atom linked to a ring including X¹ to X⁴ and Y;
Y is CR⁶R⁷, NR⁶, O or S;
each of R¹ to R⁷ is independently hydrogen, halogen, a hydroxyl group, a cyano group, a nitro group, an amidino group, a hydrazine group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ alicyclic group, an unsubstituted or substituted C₃-C₃₀ hetero alicyclic group, an unsubstituted or substituted C₆-C₃₀ aromatic group or an unsubstituted or substituted C₃-C₃₀ hetero aromatic group, where each R¹ is identical to or different from each other when a1 is 2, 3 or 4, where each R² is identical to or different from each other when a2 is 2, where each R³ is identical to or different from each other when a3 is 2 or 3, where each R⁴ is identical to or different from each other when a4 is 2, and where each R⁵ is identical to or different from each other when a5 is 2, 3 or 4;
optionally,
two adjacent R¹ when a1 is 2, 3 or 4, and/or
two adjacent R² when a2 is 2, and/or
two adjacent R³ when a3 is 2 or 3, and/or
two adjacent R⁴ when a4 is 2, and/or
two adjacent R⁵ when a5 is 2, 3 or 4, and/or
R⁶ and R⁷
are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₃-C₂₀ hetero aromatic ring;
a1 is 1, 2, 3 or 4 when R¹ is hydrogen, and a1 is 0, 1, 2, 3 or 4 when R¹ is other than hydrogen;
a2 is 1 or 2 when R² is hydrogen, and a2 is 0, 1 or 2 when R² is other than hydrogen;
a3 is 2 or 3 when R³ is hydrogen, and a3 is 0, 1, 2 or 3 when R³ is other than hydrogen;
a4 is 2 when R⁴ is hydrogen, and a4 is 0, 1 or 2 when R⁴ is other than hydrogen; and
a5 is 4 when R⁵ is hydrogen, and a5 is 0, 1, 2, 3 or 4 when R⁵ is other than hydrogen.

In one example embodiment, the L_{A} in Chemical Formula 1 can have the following structure of Chemical Formula 3:

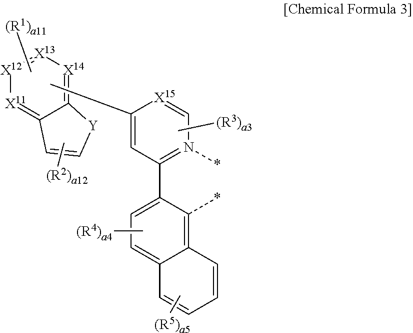

wherein, in the Chemical Formula 3,
each of Y, R¹ to R⁵ and a3 to a5 is a same as defined in Chemical Formula 2;
each of X¹¹ to X¹⁴ is independently CR¹, N or a carbon atom linked to a hetero aromatic ring including X¹⁵, where at least one of X¹¹ to X¹⁴ is CR¹ and another of X¹¹ to X¹⁴ is the carbon atom linked to the hetero aromatic ring including X¹⁵;
X¹⁵ is CR³ or N;
a11 is 1, 2 or 3 when R¹ is hydrogen, and a1 l is 0, 1, 2 or 3 when R¹ is other than hydrogen; and
a12 is 2 when R² is hydrogen, and a12 is 0, 1 or 2 when R² is other than hydrogen.

In another example embodiment, the L_{A} in Chemical Formula 1 can have the following structure of Chemical Formula 4:

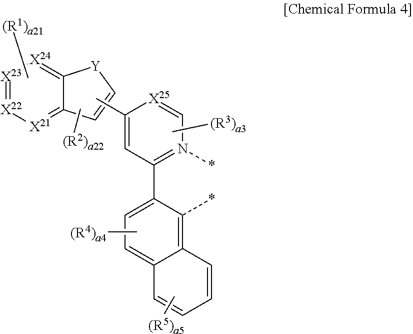

wherein, in the Chemical Formula 4,
each of Y, R¹ to R⁵ and a3 to a5 is a same as defined in Chemical Formula 2;
each of X²¹ to X²⁴ is independently CR¹ or N, where at least one of X²¹ to X²⁴ is CR¹;
X²⁵ is CR³ or N;
a21 is 1, 2, 3 or 4 when R¹ is hydrogen, and a21 is 0, 1, 2, 3 or 4 when R¹ is other than hydrogen; and
a22 is 1 when R² is hydrogen, and a22 is 0 or 1 when R² is other than hydrogen.

More particularly, the L_{A} in Chemical Formula 1 can have the following structure of Chemical Formula 5:

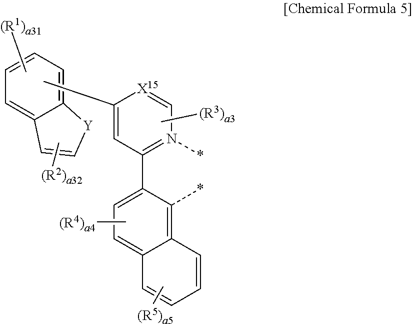

wherein, in the Chemical Formula 5,
each of Y, R¹ to R⁵ and a3 to a5 is a same as defined in Chemical Formula 2;
X¹⁵ is CR³ or N;
a31 is 3 when R¹ is hydrogen, and a31 is 0, 1, 2 or 3 when R¹ is other than hydrogen; and
a32 is 2 when R² is hydrogen, and a32 is 0, 1 or 2 when R² is other than hydrogen.

In another example embodiment, the L_{A} in Chemical Formula 1 can have the following structure of Chemical Formula 6:

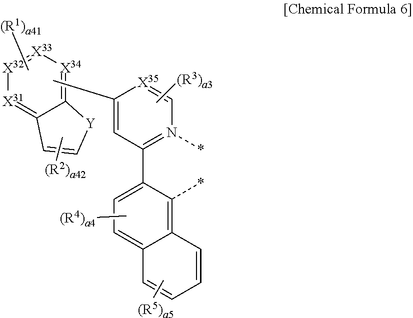

wherein, in the Chemical Formula 6,
each of Y, R³ to R⁵ and a3 to a5 is a same as defined in Chemical Formula 2;
each of X³¹ to X³⁴ is independently CR¹, N or a carbon atom linked to a hetero aromatic ring including X³⁵, where one of X³¹ to X³⁴ is N, the other of X³¹ to X³⁴ is the carbon atom linked to the hetero aromatic ring including X³⁵, and each of others of X³¹ to X³⁴ is independently CR¹;
X³⁵ is CR³ or N;
a41 is 2 when R³ is hydrogen, and a41 is 0, 1 or 2 when R³ is other than hydrogen; and
a42 is 1 when R² is hydrogen, and a42 is 0, 1 or 2 when R² is other than hydrogen.

In still another example embodiment, the L_{A} in Chemical Formula 1 can have the following structure of Chemical Formula 7:

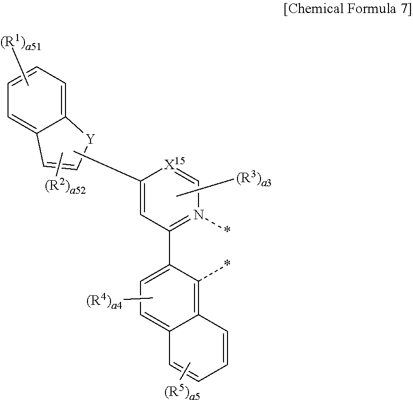

wherein, in the Chemical Formula 7,
each of Y, R¹ to R⁵ and a3 to a5 is a same as defined in Chemical Formula 2;
X¹⁵ is CR³ or N;
a51 is 4 when R¹ is hydrogen, and a51 is 0, 1, 2, 3 or 4 when R¹ is other than hydrogen; and
a52 is 1 when R² is hydrogen, and a52 is 0 or 1 when R² is other than hydrogen.

More particularly, the L_{A} in Chemical Formula 1 can have the following structure of Chemical Formula 8:

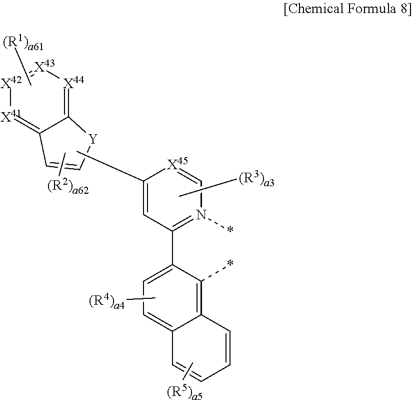

wherein, in the Chemical Formula 8,
each of Y, R¹ to R⁵ and a3 to a5 is a same as defined in Chemical Formula 2;
each of X⁴¹ to X⁴⁴ is independently CR¹ or N, where one of X⁴¹ to X⁴⁴ is N, and each of others of X⁴¹ to X⁴⁴ is independently CR¹; X⁴⁵ is CR³ or N;
a61 is 3 when R¹ is hydrogen, and a61 is 0, 1, 2 or 3 when R¹ is other than hydrogen; and
a62 is 1 when R² is hydrogen, and a62 is 0 or 1 when R² is other than hydrogen.

As an example, the L_{B} in Chemical Formula 1 can have the following structure of Chemical Formula 9A or Chemical Formula 9B:

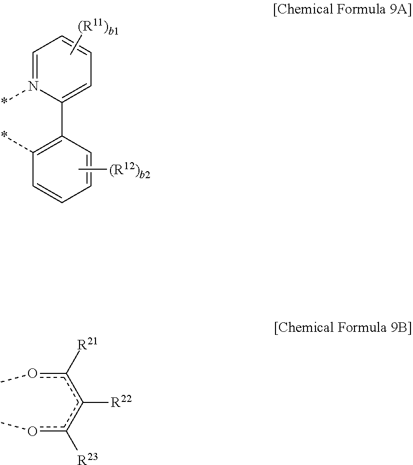

wherein, in the Chemical Formulae 9A and 9B,
each of R¹¹, R¹² and R²¹ to R²³ is independently hydrogen, halogen, a hydroxyl group, a cyano group, a nitro group, an amidino group, a hydrazine group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ alicyclic group, an unsubstituted or substituted C₃-C₃₀ hetero alicyclic group, an unsubstituted or substituted C₆-C₃₀ aromatic group or an unsubstituted or substituted C₃-C₃₀ hetero aromatic group, where each R¹¹ is identical to or different from each other when b1 is 2, 3 or 4, and where each R¹² is identical to or different from each other when b2 is 2, 3 or 4;
optionally,
two adjacent R¹¹ when b1 is 2, 3 or 4, and/or
two adjacent R¹² when b2 is 2, 3 or 4, and/or
R²¹ and R²² or R²² and R²³
are further linked together to form an unsubstituted or substituted C₄-C₂₀ alicyclic ring, an unsubstituted or substituted C₃-C₂₀ hetero alicyclic ring, an unsubstituted or substituted C₆-C₃₀ aromatic ring or an unsubstituted or substituted C₃-C₃₀ hetero aromatic ring; and
each of b1 and b2 is 4 when each of R¹¹ and R¹² is hydrogen and each of b1 and b2 is independently 0, 1, 2, 3 or 4 when each of R¹¹ and R¹² is other than hydrogen.

In another example embodiment, each of X¹ to X⁴ in Chemical Formula 2 is independently CR¹ or the carbon atom linked to the hetero aromatic ring including X⁵, Y in Chemical Formula 2 is O or S, and each of R¹ to R⁷ in Chemical Formula 2 is independently hydrogen or a C₁-C₂₀ alkyl group.

Alternatively, one of X¹ to X⁴ in Chemical Formula 2 is N and other three of X¹ to X⁴ can be independently CR¹ or the carbon atom linked to the hetero aromatic ring including X⁵, Y in Chemical Formula 2 is O or S, and each R¹ to R⁵ in Chemical Formula 2 is independently hydrogen or a C₁-C₂₀ alkyl group.

In another aspect, the present disclosure provides an organic light emitting diode includes a first electrode; a second electrode facing the first electrode; and an emissive layer disposed between the first and second electrodes and including at least one emitting material layer, wherein the at least emitting material layer includes the organometallic compound.

As an example, the organometallic compound can be a dopant in an emitting material layer.

The emissive layer can have a single emitting part, or multiple emitting parts to form a tandem structure.

In yet another aspect, the present disclosure provides an organic light emitting device, for example, an organic light emitting display device or an organic light emitting illumination device, includes a substrate and the organic light emitting diode over the substrate.

The organometallic compound includes a metal atom linked to multiple fused aromatic rings or fused hetero aromatic rings through a covalent bond or a coordination bond. The organometallic compound has very narrow full-width at half maximum, and thus shows beneficial color purity in emitting.

The organometallic compound can be a heteroleptic metal complex including two different bidentate ligands coordinated to the metal atom, so that the photoluminescence color purity and emission colors of the organometallic compound can be controlled with ease by combining two different bidentate ligands. The organometallic compound emitting red to green range light can be used as dopant of an emitting material layer so that the luminescent color purity, luminous efficiency and/or luminous lifetime of the organic light emitting diode and the organic light emitting device can be improved.

It is to be understood that both the foregoing general description and the following detailed description are merely by way of example, and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with the present disclosure.

FIG. 2 illustrates a cross-sectional view of an organic light emitting display device as an example of an organic light emitting device in accordance with an example embodiment of the present disclosure.

FIG. 3 illustrates a cross-sectional view of an organic light emitting diode having a single emitting part in accordance with an example embodiment of the present disclosure.

FIG. 4 illustrates a cross-sectional view of an organic light emitting display device in accordance with another example embodiment of the present disclosure.

FIG. 5 illustrates a cross-sectional view of an organic light emitting diode with two emitting parts forming a tandem structure in accordance with another example embodiment of the present disclosure.

FIG. 6 illustrates a cross-sectional view of an organic light emitting diode with three emitting parts forming a tandem structure in accordance with another example embodiment of the present disclosure.

### DETAILED DESCRIPTION

Reference will now be made in detail to aspects of the disclosure, examples of which are illustrated in the accompanying drawings. Wherever possible, the same reference numbers will be used throughout the drawings to refer to the same or like parts.

[Organometallic Compound]

The organometallic compound of the present disclosure has a rigid chemical conformation so as to improve the luminous efficiency and luminous lifespan of the organic light emitting diode and the organic light emitting device. The organometallic compound of the present disclosure can have the following structure of Chemical Formula 1:

Ir(L_{A})ₘ(L_{B})ₙ [Chemical Formula 1]
wherein, in the Chemical Formula 1,
L_{A} has the following structure of Chemical Formula 2;
L_{B} is an auxiliary ligand;
m is 1, 2 or 3;
n is 0, 1 or 2; and
m+n is 3;

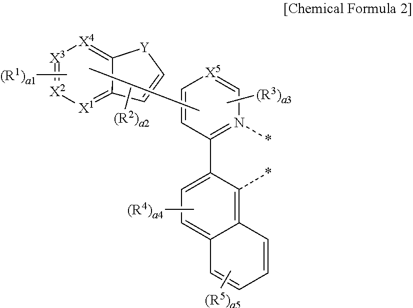

wherein, in the Chemical Formula 2,
each of X¹ to X⁴ is independently CR¹, N or a carbon atom linked to a hetero aromatic ring including X⁵, where at least one of X¹ to X⁴ is CR¹ or the carbon atom linked to the hetero aromatic ring including X⁵;
X⁵ is CR³, N or a carbon atom linked to a ring including X¹ to X⁴ and Y;
Y is CR⁶R⁷, NR⁶, O or S;
each of R¹ to R⁷ is independently hydrogen, halogen, a hydroxyl group, a cyano group, a nitro group, an amidino group, a hydrazine group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ alicyclic group, an unsubstituted or substituted C₃-C₃₀ hetero alicyclic group, an unsubstituted or substituted C₆-C₃₀ aromatic group or an unsubstituted or substituted C₃-C₃₀ hetero aromatic group, where each R¹ is identical to or different from each other when a1 is 2, 3 or 4, where each R² is identical to or different from each other when a2 is 2, where each R³ is identical to or different from each other when a3 is 2 or 3, where each R⁴ is identical to or different from each other when a4 is 2, and where each R⁵ is identical to or different from each other when a5 is 2, 3 or 4;
optionally,
two adjacent R¹ when a1 is 2, 3 or 4, and/or
two adjacent R² when a2 is 2, and/or
two adjacent R³ when a3 is 2 or 3, and/or
two adjacent R⁴ when a4 is 2, and/or
two adjacent R⁵ when a5 is 2, 3 or 4, and/or
R⁶ and R⁷
are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₃-C₂₀ hetero aromatic ring;
a1 is 1, 2, 3 or 4 when R¹ is hydrogen, and a1 is 0, 1, 2, 3 or 4 when R¹ is other than hydrogen;
a2 is 1 or 2 when R² is hydrogen, and a2 is 0, 1 or 2 when R² is other than hydrogen;
a3 is 2 or 3 when R³ is hydrogen, and a3 is 0, 1, 2 or 3 when R³ is other than hydrogen;
a4 is 2 when R⁴ is hydrogen, and a4 is 0, 1 or 2 when R⁴ is other than hydrogen; and
a5 is 4 when R⁵ is hydrogen, and a5 is 0, 1, 2, 3 or 4 when R⁵ is other than hydrogen.

As used herein, the term “unsubstituted” means that hydrogen is directly linked to a carbon atom. “Hydrogen”, as used herein, can refer to protium, deuterium and tritium.

As used herein, “substituted” means that the hydrogen is replaced with a substituent. The substituent can comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, an unsubstituted or halogen-substituted C₁-C₁₀ alkyl silyl group, an unsubstituted or halogen-substituted C₁-C₁₀ alkoxy silyl group, an unsubstituted or halogen-substituted C₃-C₂₀ cyclo alkyl silyl group, an unsubstituted or halogen-substituted C₆-C₃₀ aryl silyl group, a C₃-C₃₀ hetero aryl silyl group, an unsubstituted or substituted C₆-C₃₀ aryl group, an unsubstituted or substituted C₃-C₃₀ hetero aryl group.

As used herein, the term “hetero” in terms such as “a hetero aromatic group”, “a hetero cyclo alkylene group”, “a hetero arylene group”, “a hetero aryl alkylene group”, “a hetero aryl oxylene group”, “a hetero cyclo alkyl group”, “a hetero aryl group”, “a hetero aryl alkyl group”, “a hetero aryloxy group”, “a hetero aryl amino group” and the likes means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

As used herein, the C₆-C₃₀ aromatic group can comprise, but is not limited to, a C₆-C₃₀ aryl group, a C₇-C₃₀ aryl alkyl group, a C₆-C₃₀ aryloxy group and/or a C₆-C₃₀ aryl amino group, each of which can be independently unsubstituted or substituted. For example, the C₆-C₃₀ aryl group can include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

As used herein, the C₃-C₃₀ hetero aromatic group can comprise, but is not limited to, a C₃-C₃₀ hetero aryl group, a C₄-C₃₀ hetero aryl alkyl group, a C₃-C₃₀ hetero aryloxy group and/or a C₃-C₃₀ hetero aryl amino group, each of which can be independently unsubstituted or substituted. For example, the C₃-C₃₀ hetero aryl group can comprise, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

As an example, each of the aromatic group or the hetero aromatic group of R¹ to R⁷ in Chemical Formula 2 can consist of one to three aromatic and/or hetero aromatic rings. When the number of the aromatic and/or hetero aromatic rings of R¹ to R⁷ becomes more than four, conjugated structure among the within the whole molecule becomes too long, thus, the organometallic compound can have too narrow energy bandgap. For example, each of the aryl group or the hetero aryl group of R¹ to R⁷ can comprise independently, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

Alternatively, two adjacent R¹ when a1 is 2, 3 or 4, two adjacent R² when a2 is 2, two adjacent R³ when a3 is 2 or 3, two adjacent R⁴ when a4 is 2, two adjacent R⁵ when a5 is 2, 3 or 4, and/or R⁶ and R⁷ can further linked together to form an unsubstituted or substituted C₄-C₃₀ alicyclic ring (e.g., a C₅-C₁₀ alicyclic ring), an unsubstituted or substituted C₃-C₃₀ hetero alicyclic ring (e.g. a C₃-C₁₀ hetero alicyclic ring), an unsubstituted or substituted C₆-C₂₀ aromatic ring (e.g. a C₆-C₁₀ aromatic ring) and/or an unsubstituted or substituted C₃-C₂₀ hetero aromatic ring (e.g. a C₃-C₁₀ hetero aromatic ring). The alicyclic ring, the hetero alicyclic ring, the aromatic ring and the hetero aromatic ring formed by two adjacent R¹, two adjacent R², two adjacent R³, two adjacent R⁴, two adjacent R⁵, and/or R⁶ and R⁷ are not limited to specific rings. For example, the aromatic ring or the hetero aromatic ring formed by those groups can comprise, but is not limited to, a benzene ring, a pyridine ring, an indole ring, a pyran ring, or a fluorene ring, each can be unsubstituted or substituted with at least one C₁-C₁₀ alkyl group.

The organometallic compound having the structure of Chemical Formula 1 has at least one ligand of fused system with multiple aromatic and/or hetero aromatic rings so that the compound can have very narrow FWHM (Full-width at half maximum) in the luminescence spectrum. In addition, the organometallic compound has a very rigid chemical conformation, so that it is difficult to rotate its conformation in the luminous process, and therefore, the organometallic compound can maintain good luminous lifespan. The organometallic compound can have specific ranges of photoluminescence emissions, so that its color purity can be improved.

In one example embodiment, each of m (the number of the main ligand L_{A}) and n (the number of the auxiliary ligand L_{B}) in Chemical Formula 1 can be 1 or 2, respectively. In this case, the organometallic compound can be a heteroleptic metal complex including two different bidentate ligands coordinated to the central metal atom. The photoluminescence color purity and emission colors of the organometallic compound can be controlled with ease by combining two different bidentate ligands. In addition, it is possible to control the color purity and emission peaks of the organometallic compound by introducing various substituents to each of the ligands. As an example, the organometallic compound having the structure of Chemical Formula 1 can emit green to red color, for example, yellow green to red color and can improve luminous efficiency of an organic light emitting diode.

In one example embodiment, the hetero aromatic ring with X⁵ in Chemical Formula 2, which can be the L_{A} in Chemical Formula 1, can be linked the carbon atom of the aromatic or hetero aromatic ring including X¹ to X⁴. The main ligand L_{A} with such a linkage can have the following structure of Chemical Formula 3:

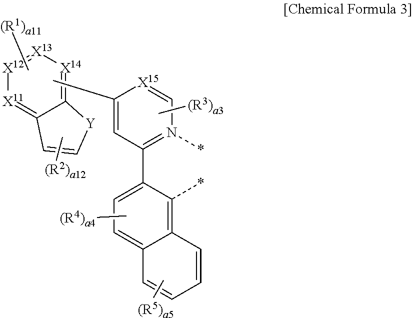

wherein, in the Chemical Formula 3,
each of Y, R¹ to R⁵ and a3 to a5 is a same as defined in Chemical Formula 2;
each of X¹¹ to X¹⁴ is independently CR¹, N or a carbon atom linked to a hetero aromatic ring including X¹⁵, where at least one of X¹¹ to X¹⁴ is CR¹ and another of X¹¹ to X¹⁴ is the carbon atom linked to the hetero aromatic ring including X¹⁵;
X¹⁵ is CR³ or N;
a11 is 1, 2 or 3 when R¹ is hydrogen, and a1 l is 0, 1, 2 or 3 when R¹ is other than hydrogen; and
a12 is 2 when R² is hydrogen, and a12 is 0, 1 or 2 when R² is other than hydrogen.

In another example embodiment, in the structure of Chemical Formula 2, which can be the L_{A} in Chemical Formula 1, the hetero aromatic ring with X⁵ can be linked to the carbon atom consisting of the 5-membering ring with Y. The main ligand L_{A} with such a linkage can have the following structure of Chemical Formula 4:

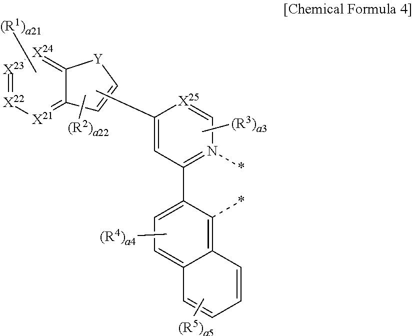

wherein, in the Chemical Formula 4,
each of Y, R¹ to R⁵ and a3 to a5 is a same as defined in Chemical Formula 2;
each of X²¹ to X²⁴ is independently CR¹ or N, where at least one of X²¹ to X²⁴ is CR¹;
X²⁵ is CR³ or N;
a21 is 1, 2, 3 or 4 when R¹ is hydrogen, and a21 is 0, 1, 2, 3 or 4 when R¹ is other than hydrogen; and
a22 is 1 when R² is hydrogen, and a22 is 0 or 1 when R² is other than hydrogen.

In still another example embodiment, three of X¹ to X⁴ in Chemical Formula 2 can be CR¹ and another of X¹ to X⁴ in Chemical Formula 2 can be the carbon atom linked to the hetero aromatic ring with X⁵. The main ligand L_{A} with such a linkage can have the following structure of Chemical Formula 5.

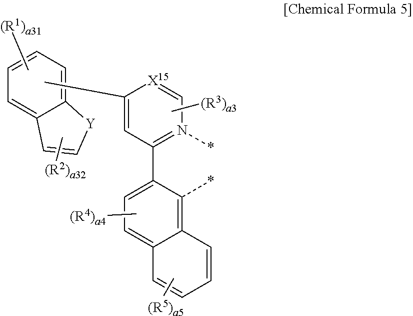

wherein, in the Chemical Formula 5,
each of Y, R¹ to R⁵ and a3 to a5 is a same as defined in Chemical Formula 2;
X¹⁵ is CR³ or N;
a31 is 3 when R¹ is hydrogen, and a31 is 0, 1, 2 or 3 when R¹ is other than hydrogen; and
a32 is 2 when R² is hydrogen, and a32 is 0, 1 or 2 when R² is other than hydrogen.

In still another example embodiment, one of X¹ to X⁴ in Chemical Formula 2 can be N, the other of X¹ to X⁴ in Chemical Formula 2 can be the carbon atom linked to the hetero aromatic ring with X⁵, and each of others of X¹ to X⁴ in Chemical Formula 2 can be CR¹, respectively. The main ligand L_{A} with such a linkage can have the following structure of Chemical Formula 6:

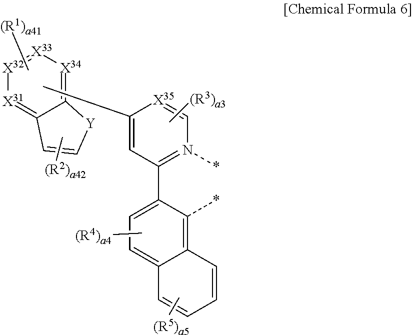

wherein, in the Chemical Formula 6,
each of Y, R³ to R⁵ and a3 to a5 is a same as defined in Chemical Formula 2;
each of X³¹ to X³⁴ is independently CR¹, N or a carbon atom linked to a hetero aromatic ring including X³⁵, where one of X³¹ to X³⁴ is N, the other of X³¹ to X³⁴ is the carbon atom linked to the hetero aromatic ring including X³⁵, and each of others of X³¹ to X³⁴ is independently CR¹;
X³⁵ is CR³ or N;
a41 is 2 when R³ is hydrogen, and a41 is 0, 1 or 2 when R³ is other than hydrogen; and
a42 is 1 when R² is hydrogen, and a42 is 0, 1 or 2 when R² is other than hydrogen.

In still another example embodiment, each of X³ to X⁴ in Chemical Formula 2 can be independently CR¹ and the hetero aromatic ring including X⁵ can be linked to the carbon atom consisting of the 5-membering ring including Y. The main ligand L_{A} with such a linkage can have the following structure of Chemical Formula 7:

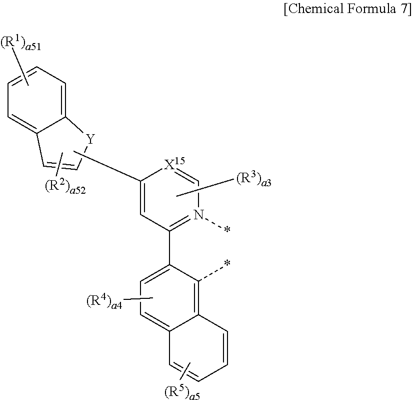

wherein, in the Chemical Formula 7,
each of Y, R¹ to R⁵ and a3 to a5 is a same as defined in Chemical Formula 2;
X¹⁵ is CR³ or N;
a51 is 4 when R¹ is hydrogen, and a51 is 0, 1, 2, 3 or 4 when R¹ is other than hydrogen; and
a52 is 1 when R² is hydrogen, and a52 is 0 or 1 when R² is other than hydrogen.

In still another example embodiment, one of X¹ to X⁴ in Chemical Formula 2 can be N and each of others of X¹ to X⁴ in Chemical Formula 2 can be independently CR¹, and the hetero aromatic ring including X⁵ can be linked to the carbon atom consisting of the 5-membering ring including Y. The main ligand L_{A} with such a linkage can have the following structure of Chemical Formula 8:

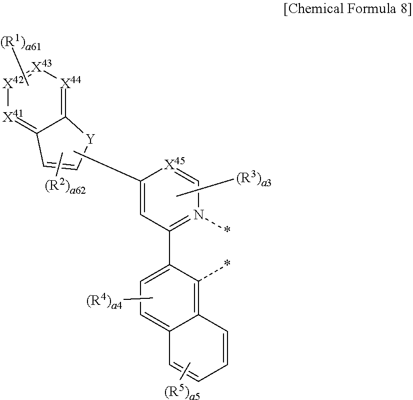

wherein, in the Chemical Formula 8,
each of Y, R¹ to R⁵ and a3 to a5 is a same as defined in Chemical Formula 2;
each of X⁴¹ to X⁴⁴ is independently CR¹ or N, where one of X⁴¹ to X⁴⁴ is N, and each of others of X⁴¹ to X⁴⁴ is independently CR¹; X⁴⁵ is CR³ or N;
a61 is 3 when R¹ is hydrogen, and a61 is 0, 1, 2 or 3 when R¹ is other than hydrogen; and
a62 is 1 when R² is hydrogen, and a62 is 0 or 1 when R² is other than hydrogen.

In still another example embodiment, each of X¹ to X⁴ in Chemical Formula 2 can be independently CR¹ or the carbon atom linked to the hetero aromatic ring including X⁵, Y in Chemical Formula 2 can be O or S, and each of R¹ to R⁷ in Chemical Formula 2 can be independently hydrogen or a C₁-C₂₀ alkyl group (e.g., C₁-C₁₀ alkyl group such as iso-butyl or tert-butyl). In still another example embodiment, one of X¹ to X⁴ in Chemical Formula 2 can be N and other three of X¹ to X⁴ can be independently CR¹ or the carbon atom linked to the hetero aromatic ring including X⁵, Y in Chemical Formula 2 can be O or S, and each R¹ to R⁵ in Chemical Formula 2 can be independently hydrogen or a C₁-C₂₀ alkyl group (e.g., C₁-C₁₀ alkyl group such as iso-butyl or tert-butyl).

The L_{B} in Chemical Formula 1 can be any auxiliary ligand. In one example embodiment, the L_{B} as the auxiliary ligand in Chemical Formula 1 can be a phenyl-pyridino-based ligand or an acetylacetonate-based ligand. The auxiliary ligand L_{B} with such a moiety can have the following structure of Chemical Formula 9A or Chemical Formula 9B:

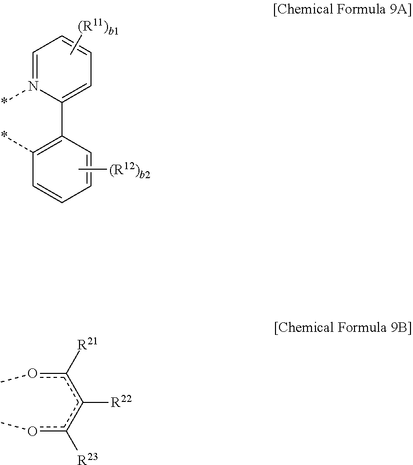

wherein, in the Chemical Formulae 9A and 9B,
each of R¹¹, R¹² and R²¹ to R²³ is independently hydrogen, halogen, a hydroxyl group, a cyano group, a nitro group, an amidino group, a hydrazine group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ alicyclic group, an unsubstituted or substituted C₃-C₃₀ hetero alicyclic group, an unsubstituted or substituted C₆-C₃₀ aromatic group or an unsubstituted or substituted C₃-C₃₀ hetero aromatic group, where each R¹¹ is identical to or different from each other when b1 is 2, 3 or 4, and where each R¹² is identical to or different from each other when b2 is 2, 3 or 4;
optionally,
two adjacent R¹¹ when b1 is 2, 3 or 4, and/or
two adjacent R¹² when b2 is 2, 3 or 4, and/or
R²¹ and R²² or R²² and R²³
are further linked together to form an unsubstituted or substituted C₄-C₂₀ alicyclic ring, an unsubstituted or substituted C₃-C₂₀ hetero alicyclic ring, an unsubstituted or substituted C₆-C₃₀ aromatic ring or an unsubstituted or substituted C₃-C₃₀ hetero aromatic ring; and each of b1 and b2 is 4 when each of R¹¹ and R¹² is hydrogen and each of b1 and b2 is independently 0, 1, 2, 3 or 4 when each of R¹¹ and R¹² is other than hydrogen.

The substituents of R¹¹ to R¹² and R²¹ to R²³ or the ring formed by R¹¹ to R²² R²¹ and R²² and/or R²³ can be identical to the substituents or the ring as described in Chemical Formulae 2 to 8. In one example embodiment, each of R¹¹, R¹² and R²¹ to R²³ in Chemical Formulae 9A and 9B can be, but is not limited to, hydrogen or a C₁-C₂₀ alkyl group (e.g. C₁-C₁₀ alkyl group).

In another example embodiment, the organometallic compound can have a structure where each of X¹ to X⁴ is independently CR¹, or three of X¹ to X⁴ is independently CR¹ and other of X¹ to X⁴ is the carbon atom linked to the hetero aromatic ring with X⁵, and X⁵ is CR³ in Chemical Formula 2 as the L_{A}, and the L_{B} in Chemical Formula 1 has the structure of Chemical Formula 9B. The organometallic compound with such a linkage can include at least one of, or selected from, but is not limited to, the following organometallic compounds represented by Chemical Formula 10:

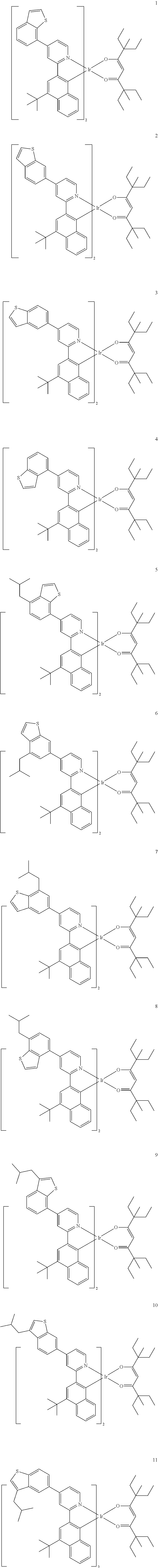

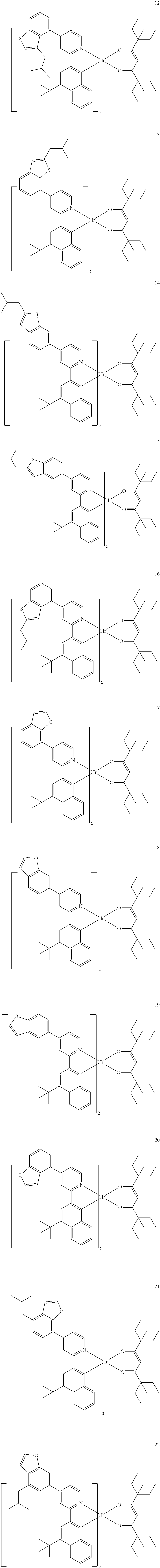

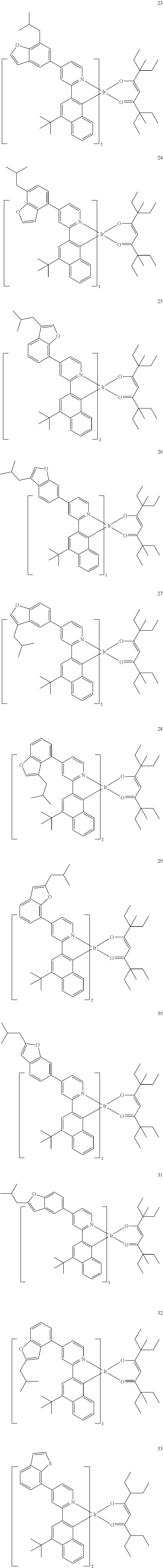

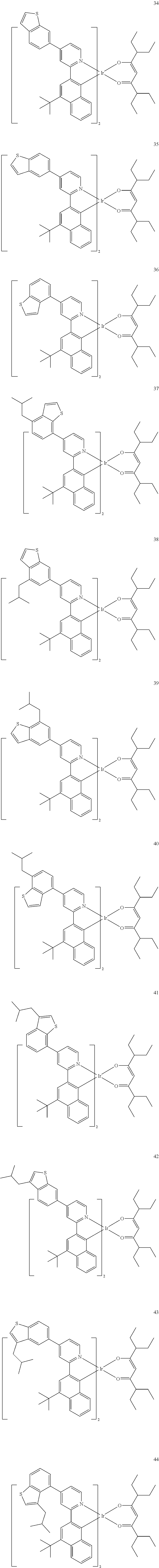

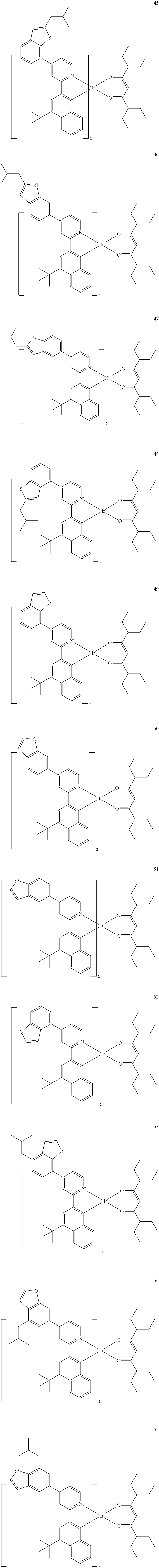

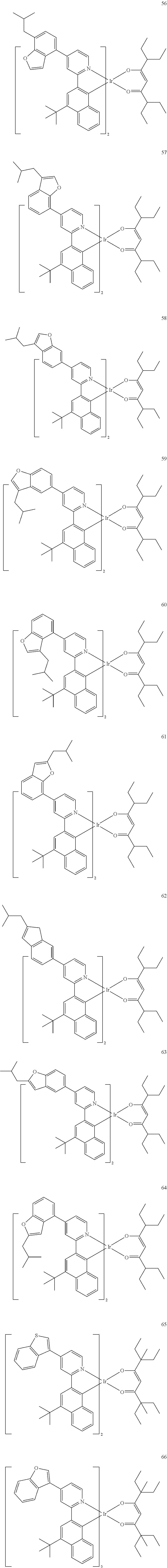

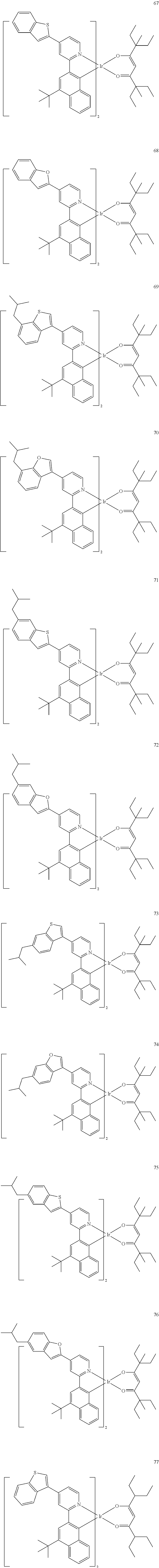

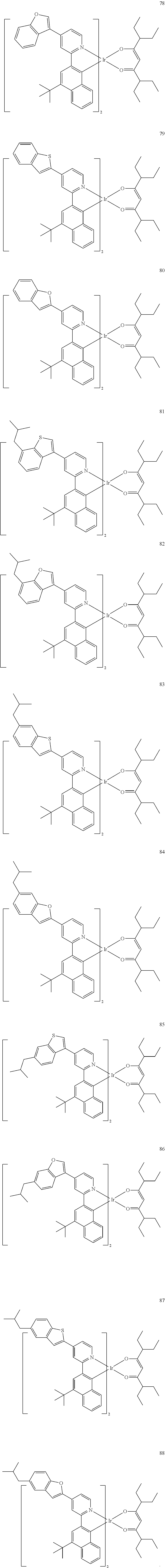

In another example embodiment, the organometallic compound can have a structure where each of X¹ to X⁴ is independently CR¹, or three of X¹ to X⁴ is independently CR¹ and other of X¹ to X⁴ is the carbon atom linked to the hetero aromatic ring with X⁵, and X⁵ is N in Chemical Formula 2 as the L_{A}, and the L_{B} in Chemical Formula 1 has the structure of Chemical Formula 9B. The organometallic compound with such a linkage can include at least one of, or selected from, but is not limited to, the following organometallic compounds represented by Chemical Formula 11:

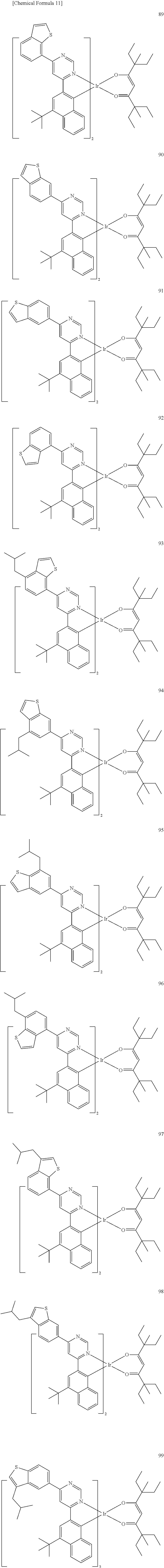

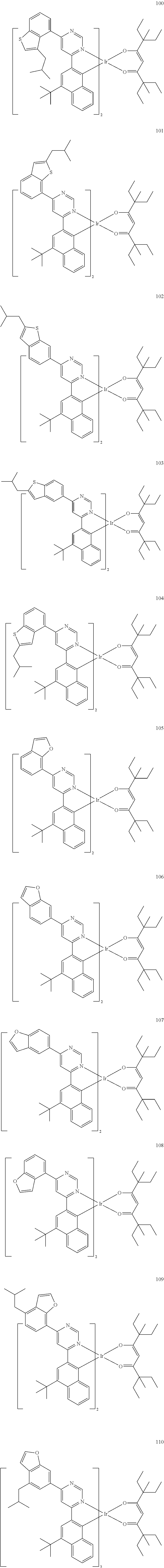

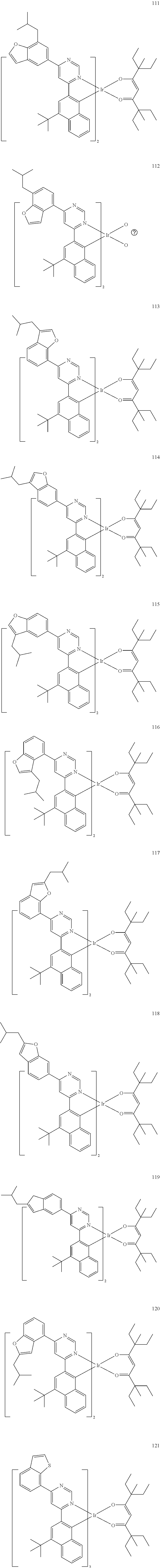

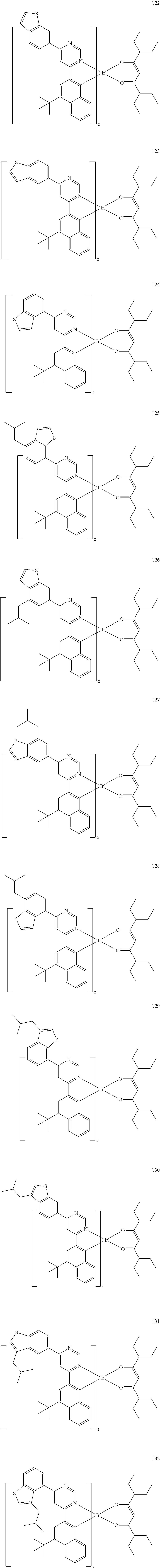

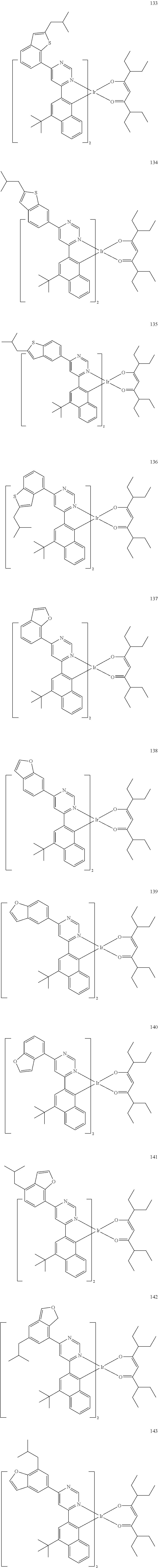

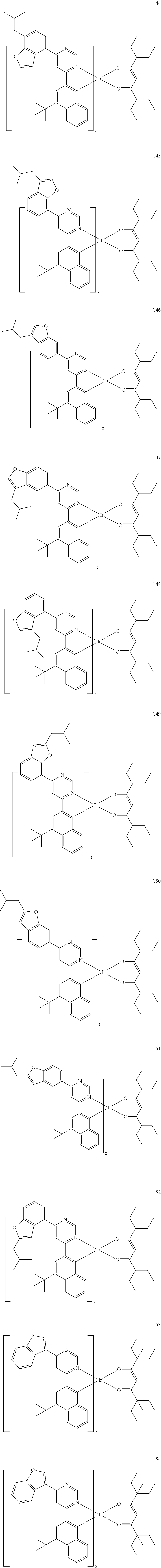

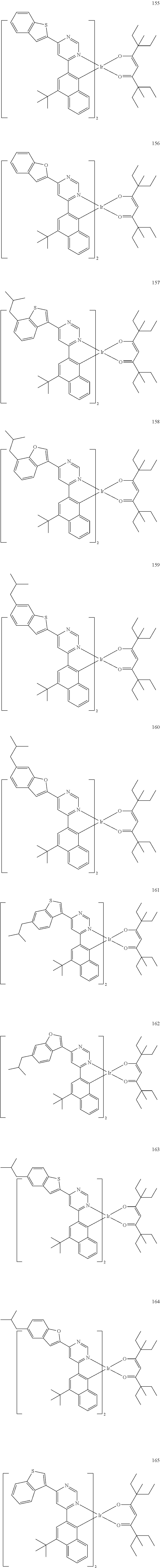

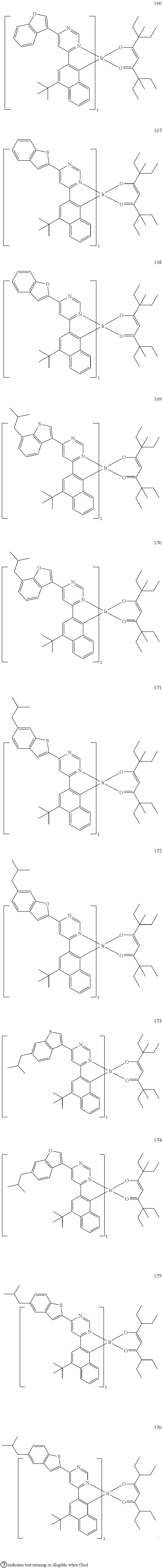

In another example embodiment, the organometallic compound can have a structure where one of X¹ to X⁴ is N and three of X¹ to X⁴ is independently CR¹, or one of X¹ to X⁴ is N, two of X¹ to X⁴ is independently CR¹ and other of X¹ to X⁴ is the carbon atom linked to the hetero aromatic ring with X⁵, and X⁵ is CR³ in Chemical Formula 2 as the L_{A}, and the L_{B} in Chemical Formula 1 has the structure of Chemical Formula 9B. The organometallic compound with such a linkage can include at least one of, or selected from, but is not limited to, the following organometallic compounds represented by Chemical Formula 12.

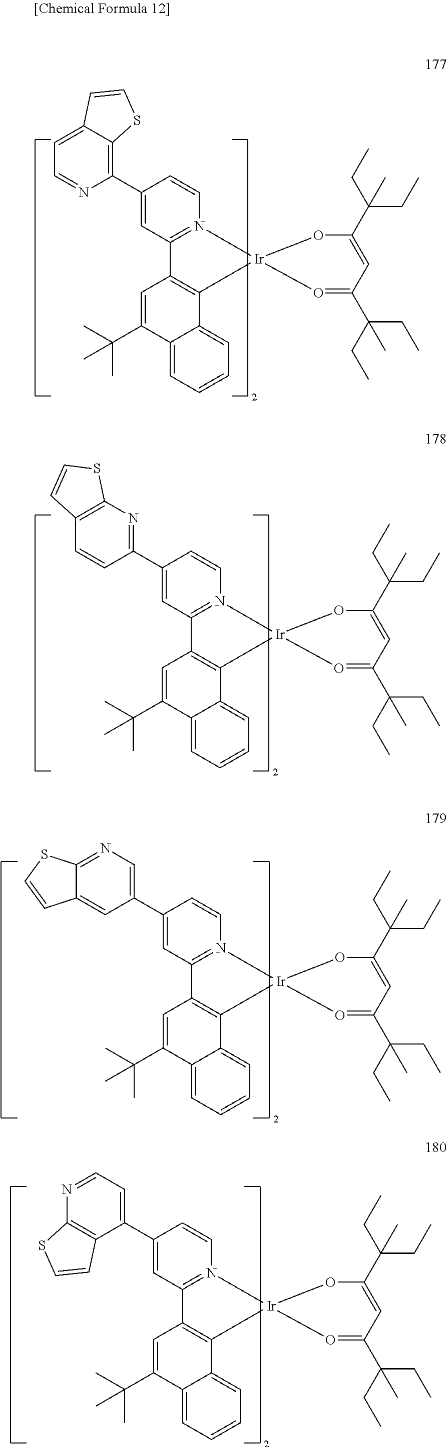

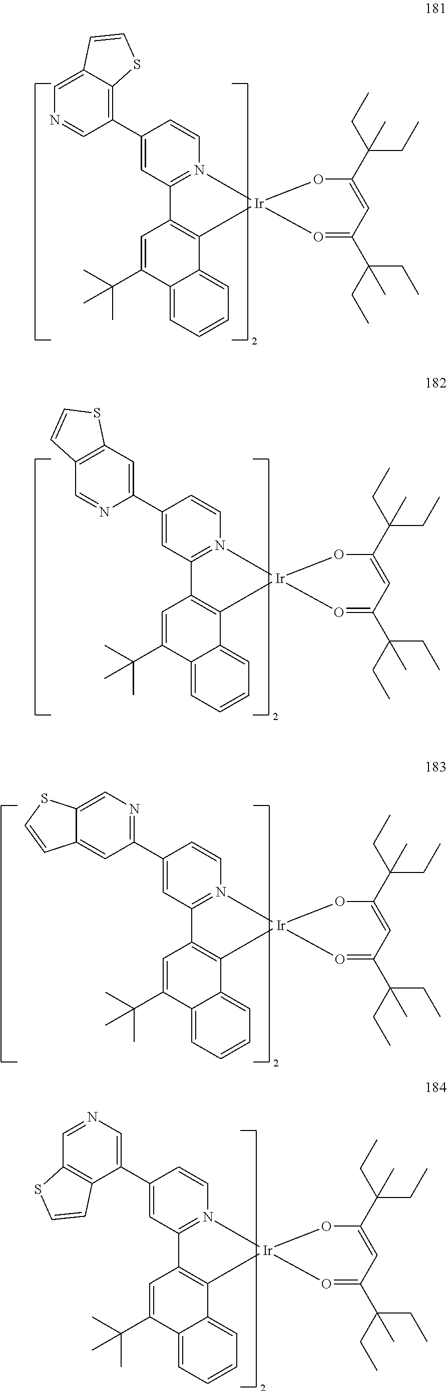

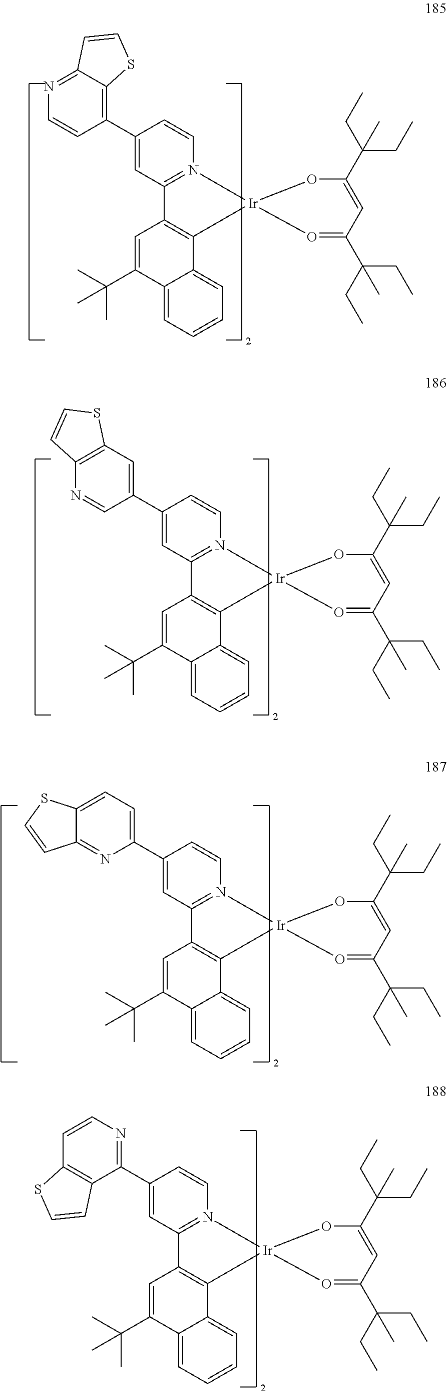

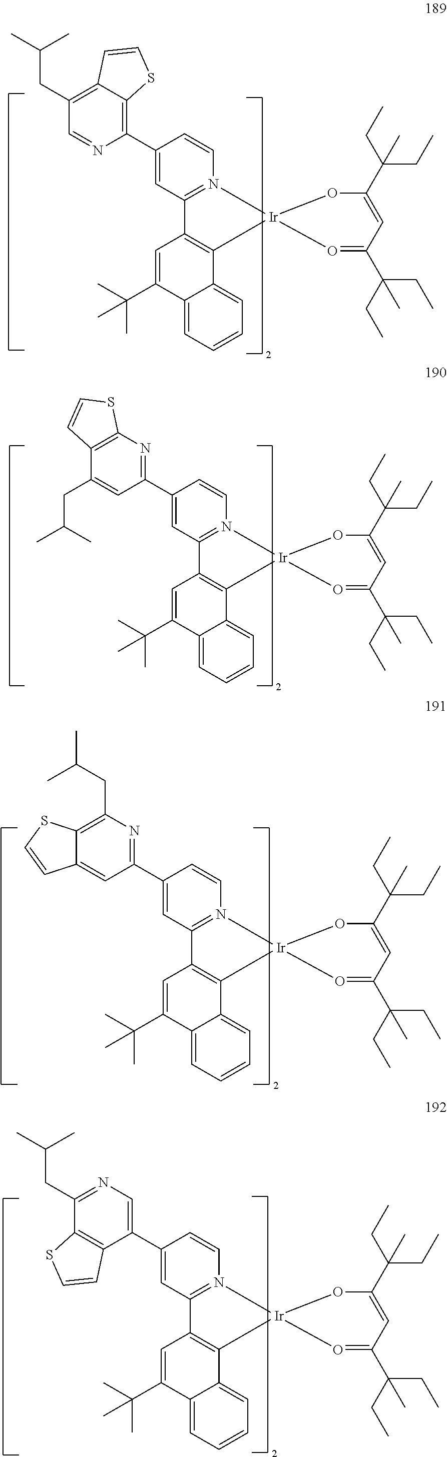

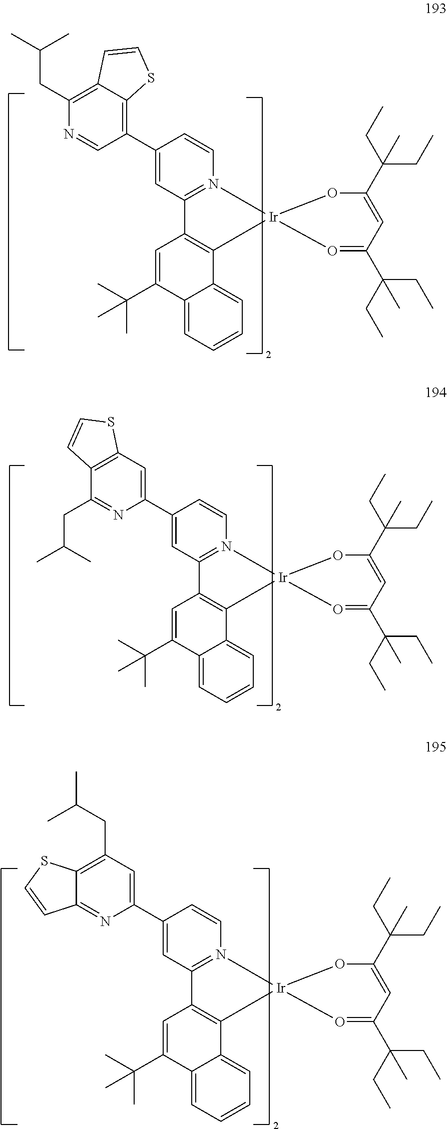

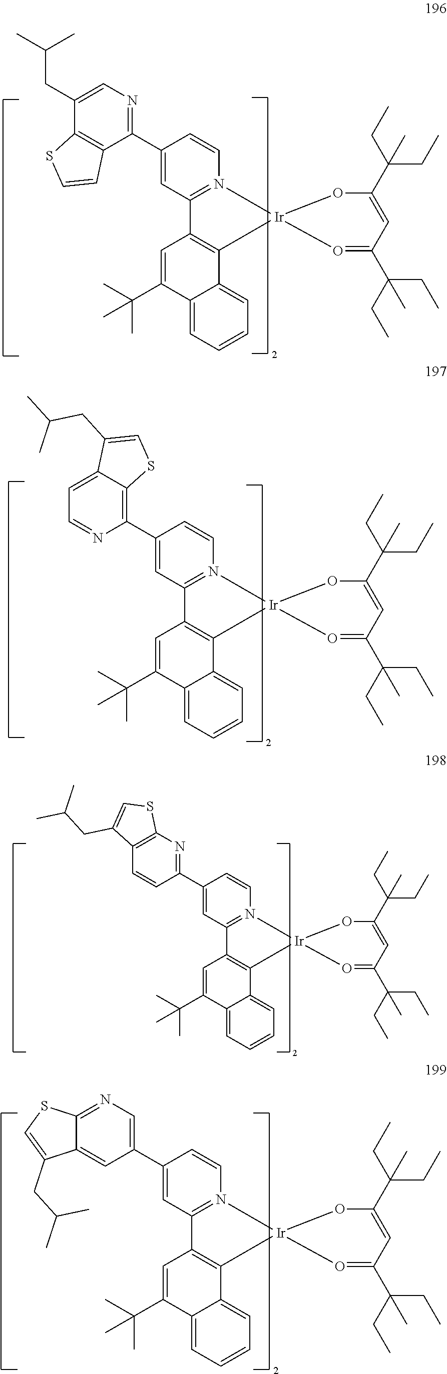

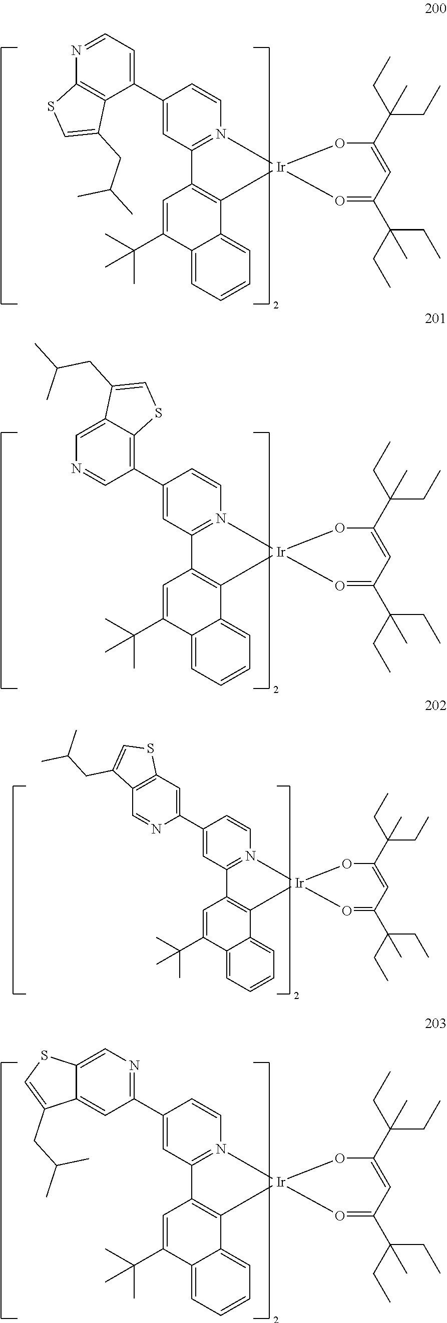

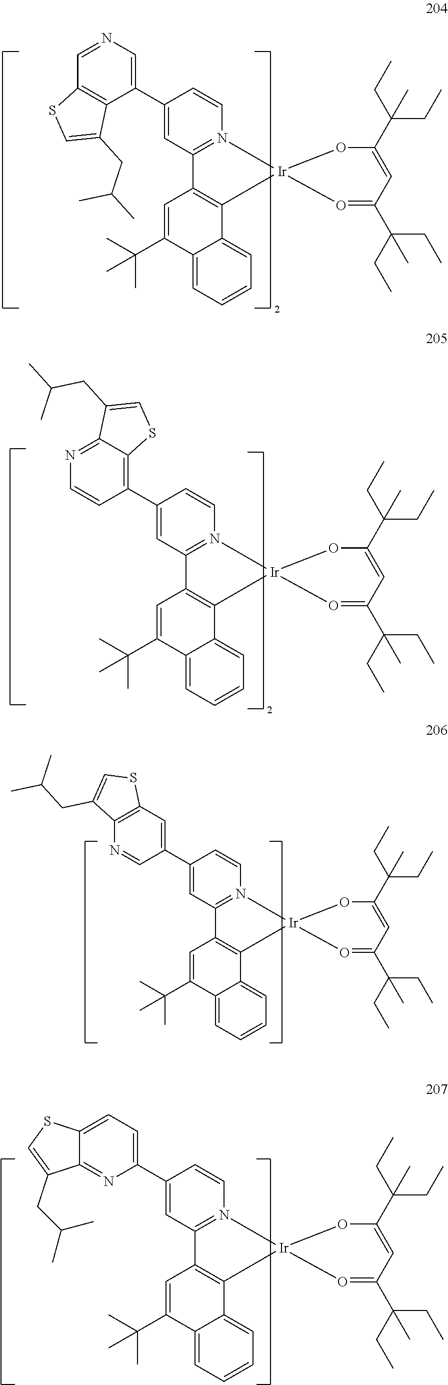

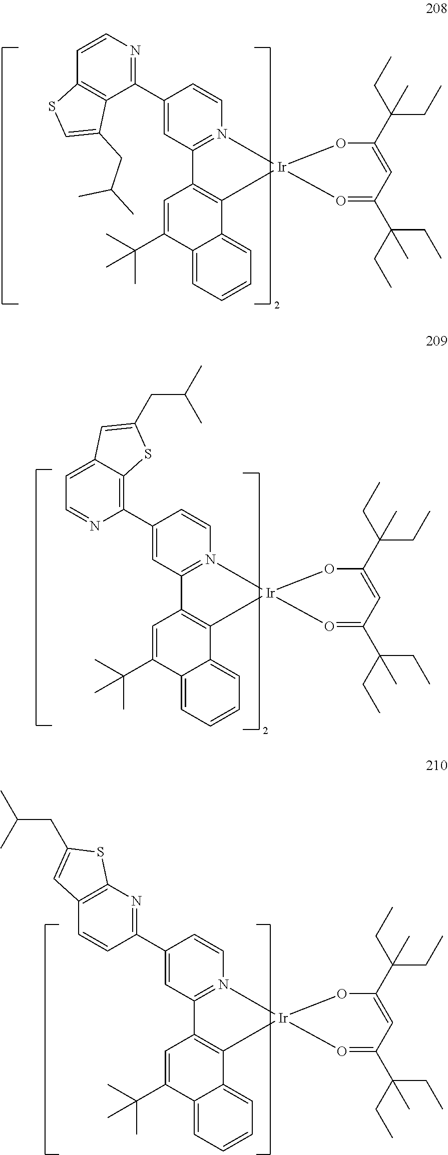

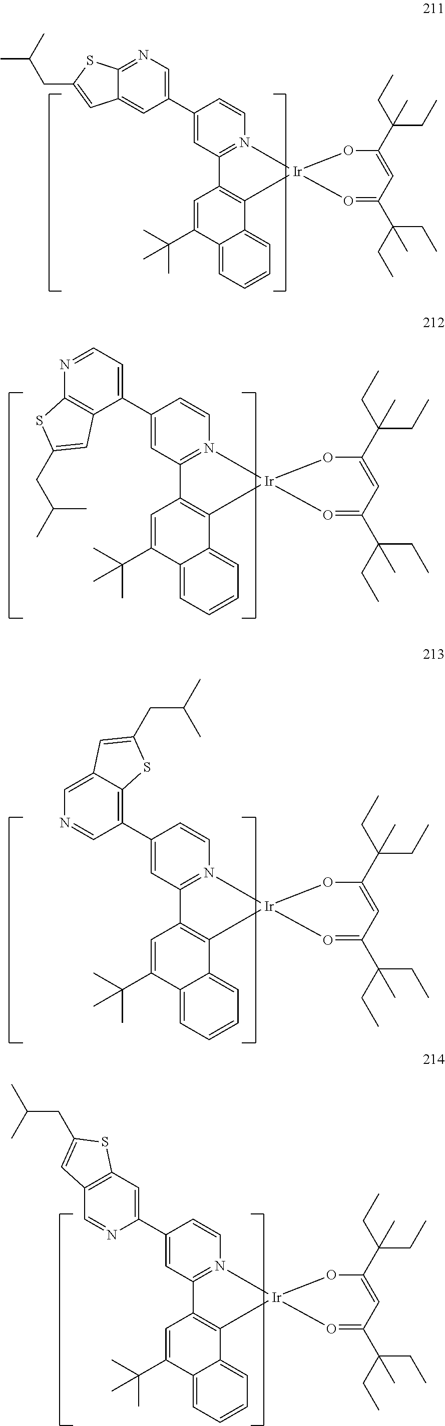

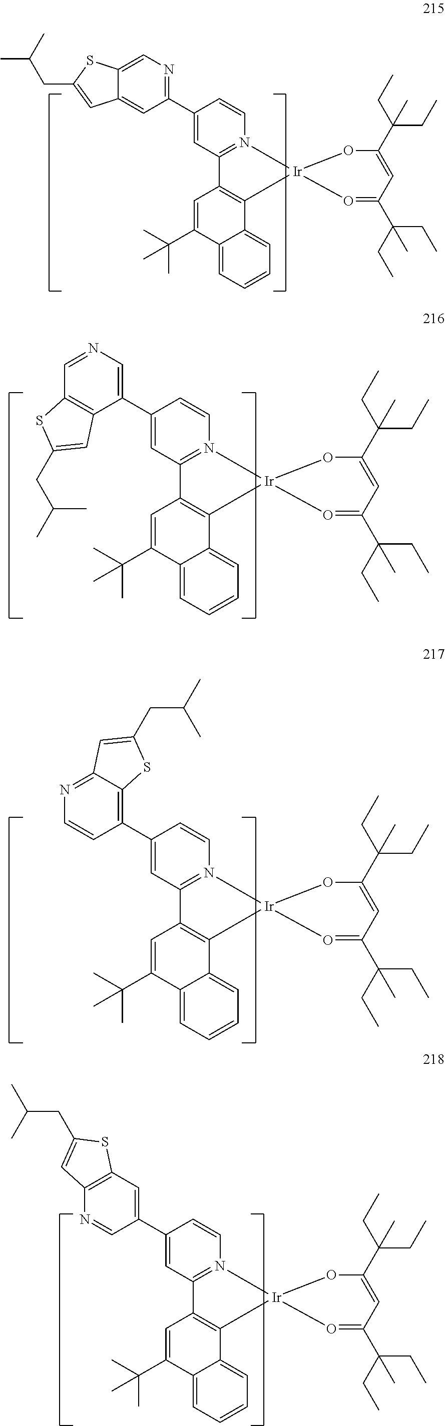

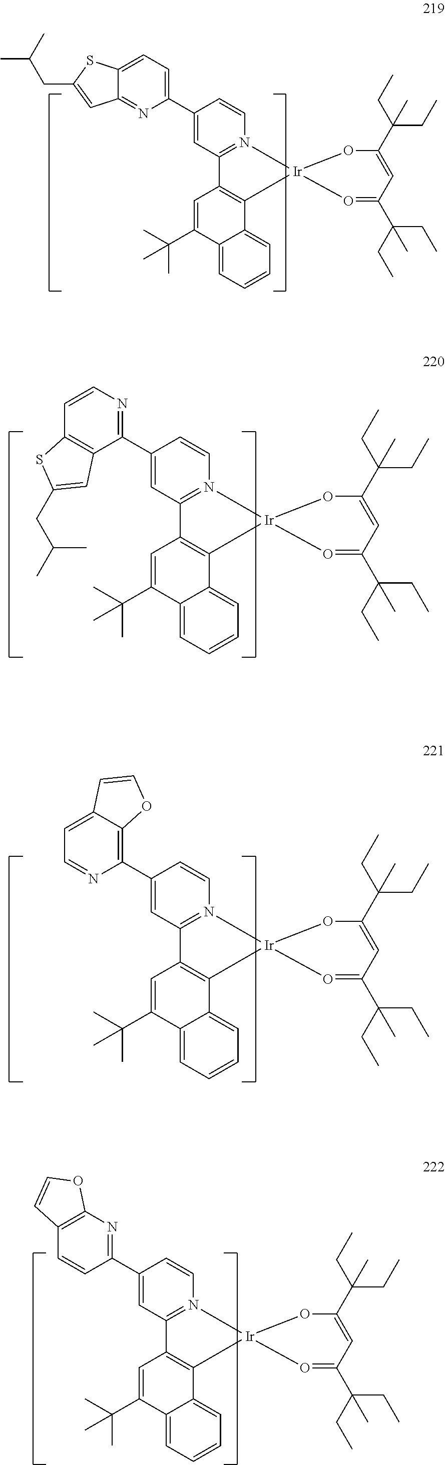

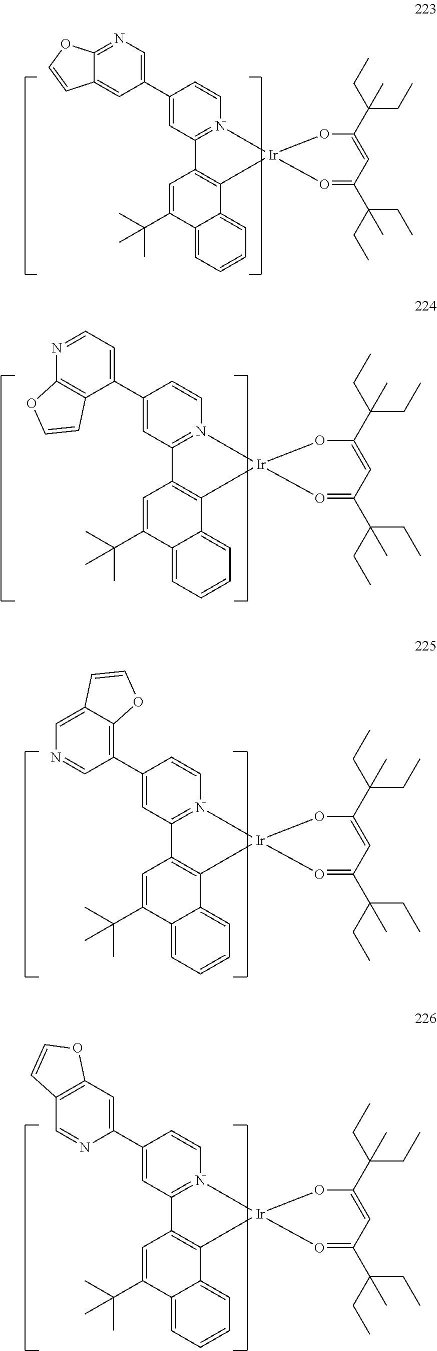

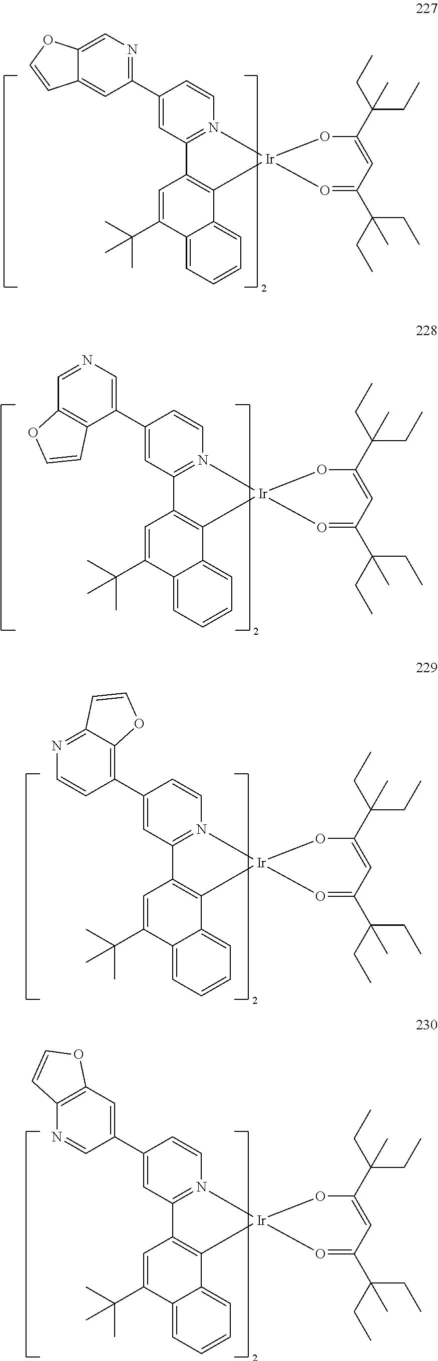

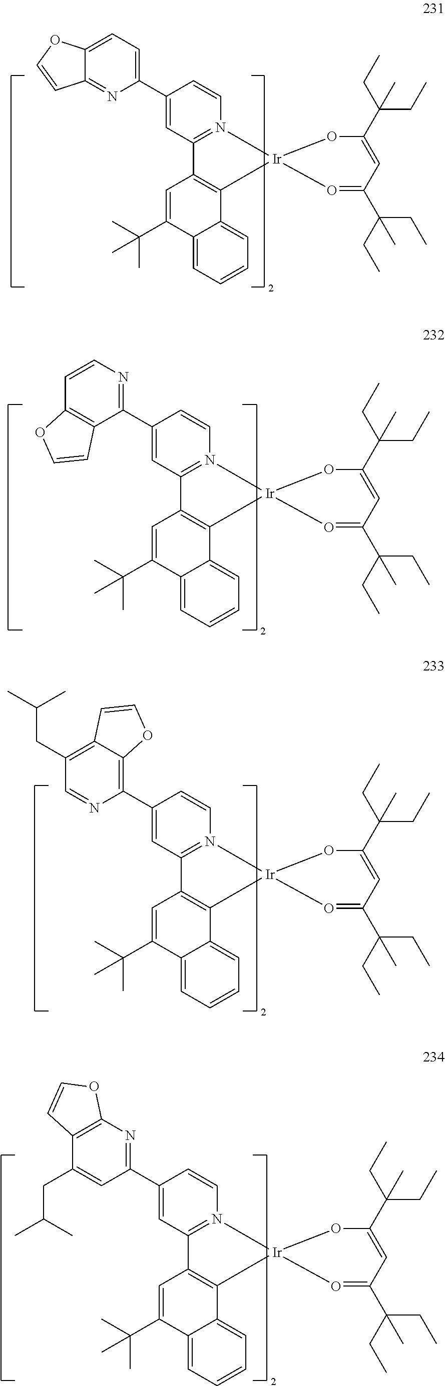

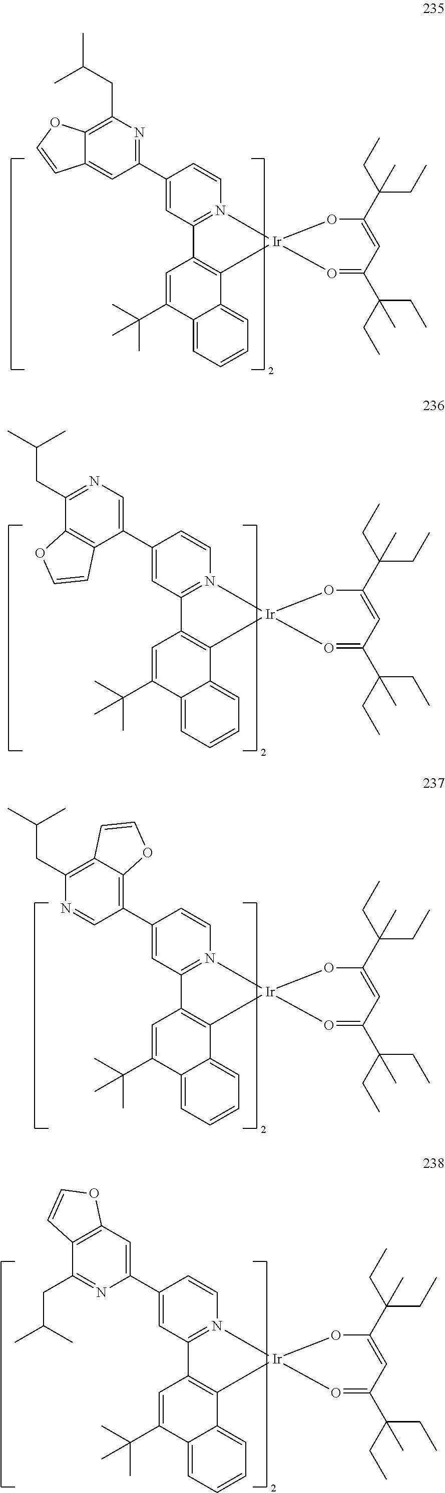

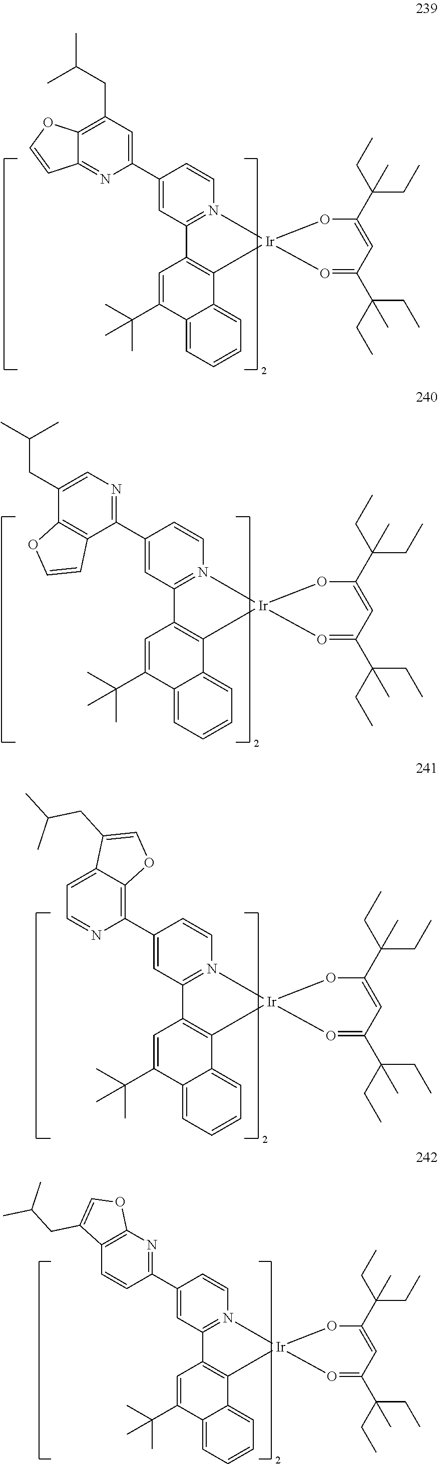

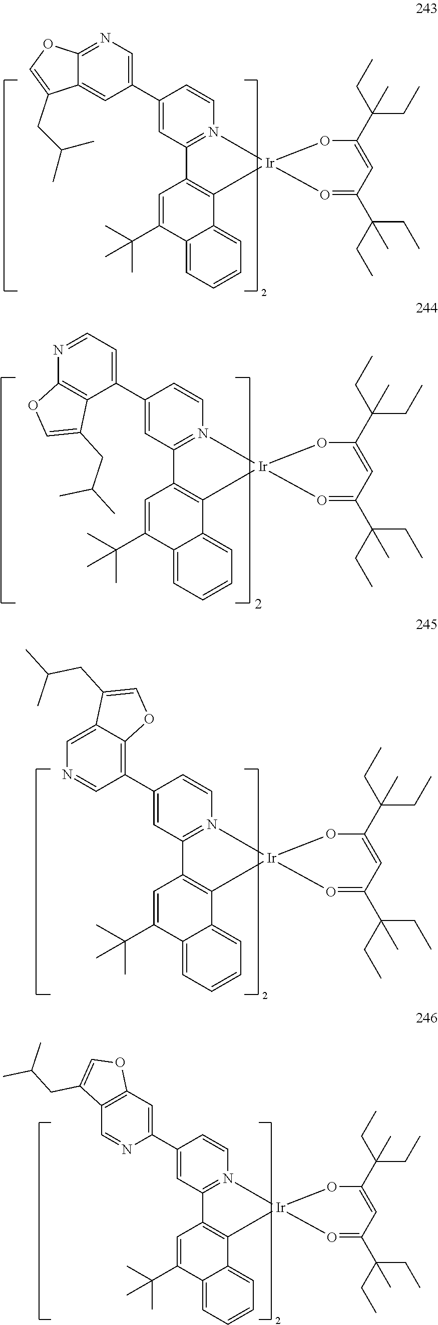

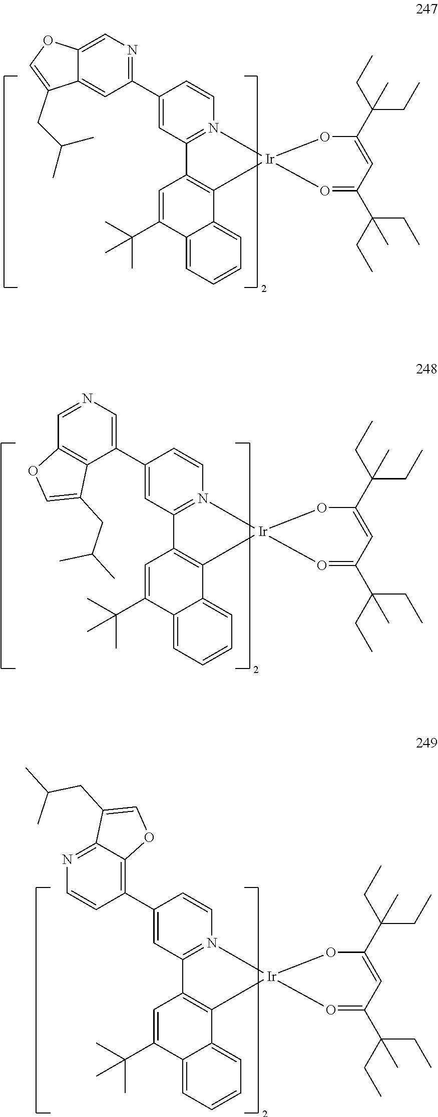

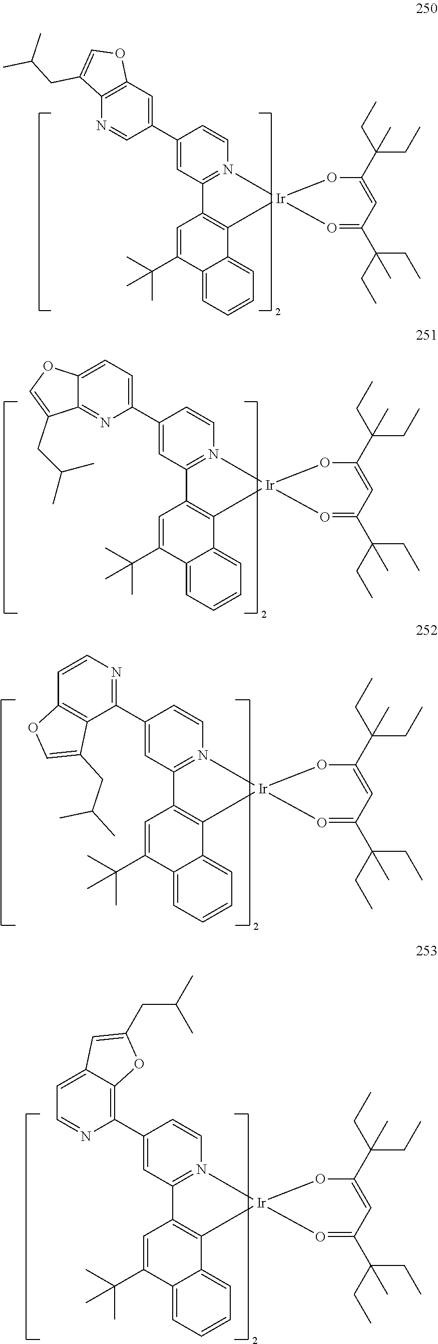

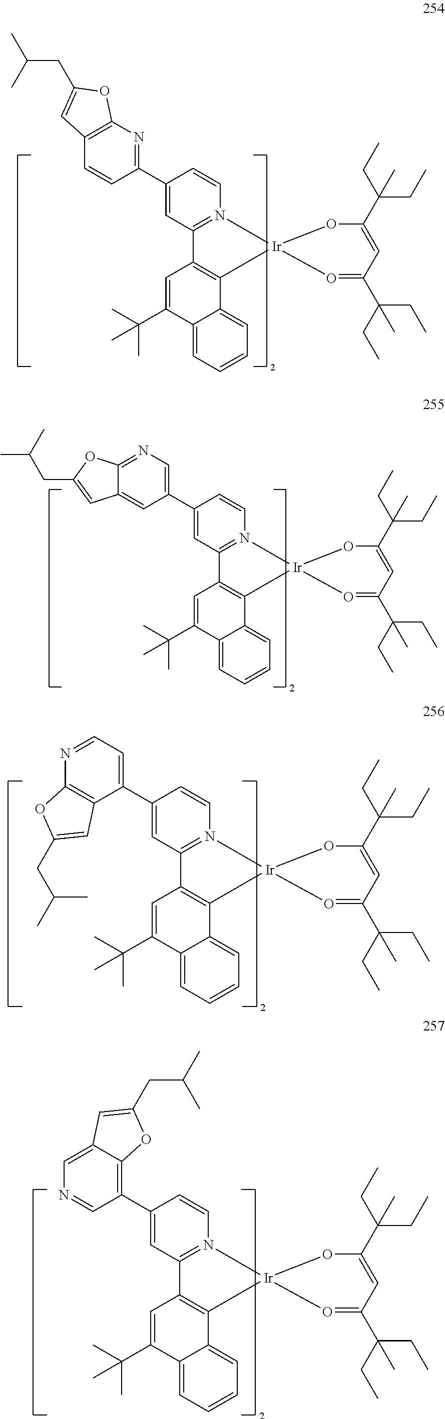

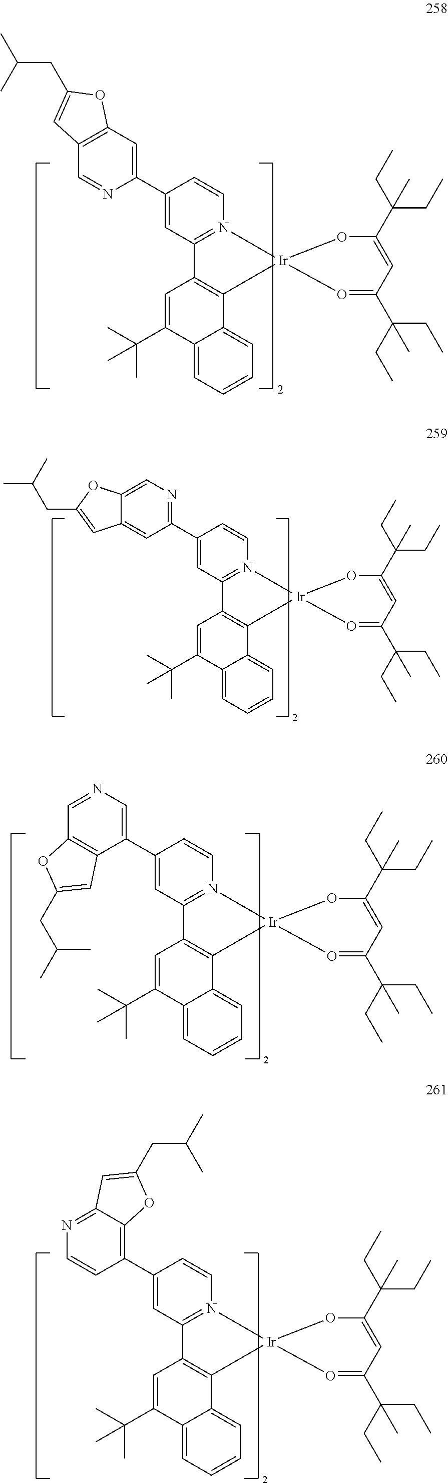

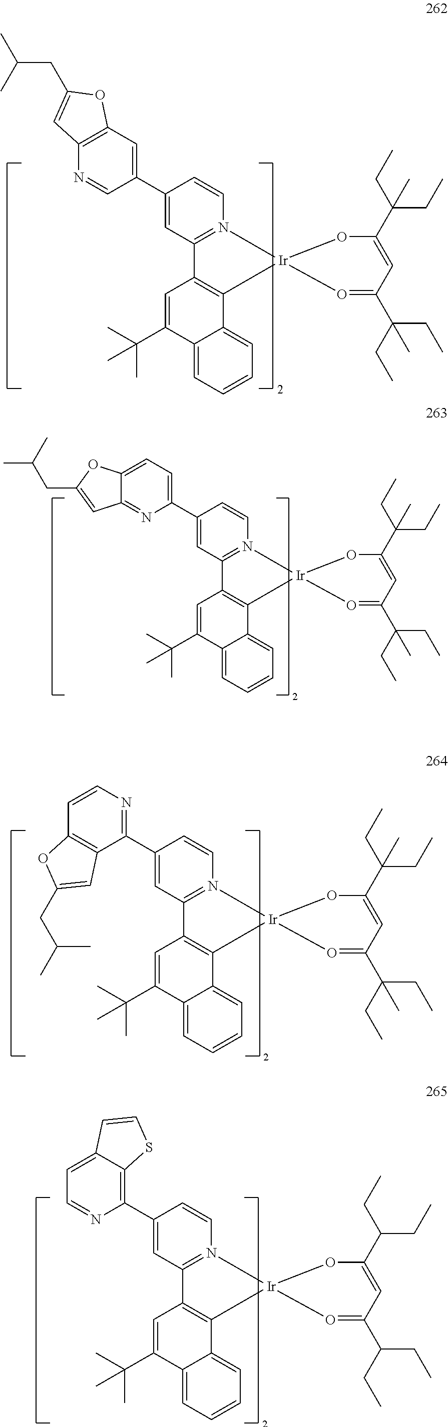

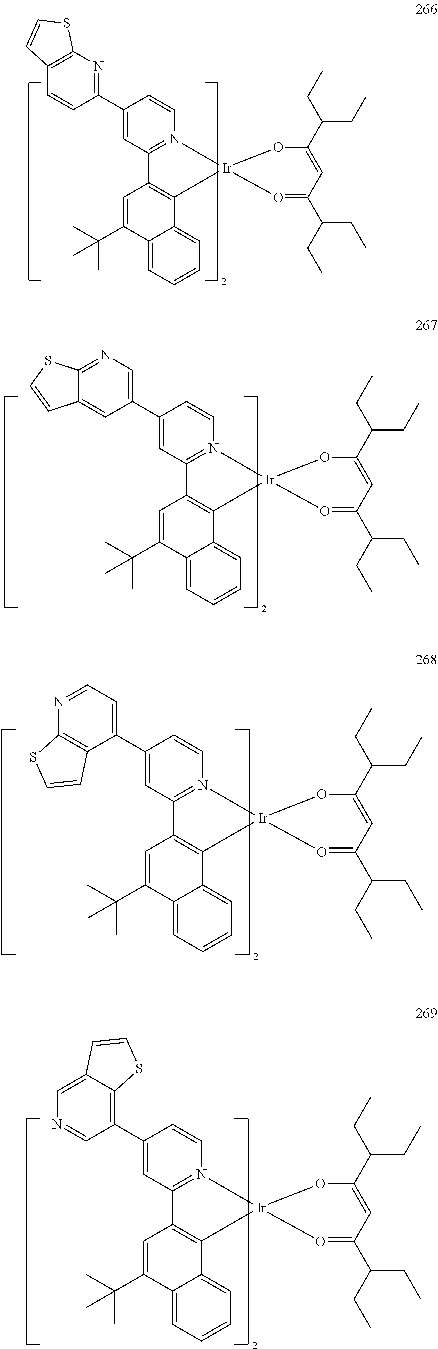

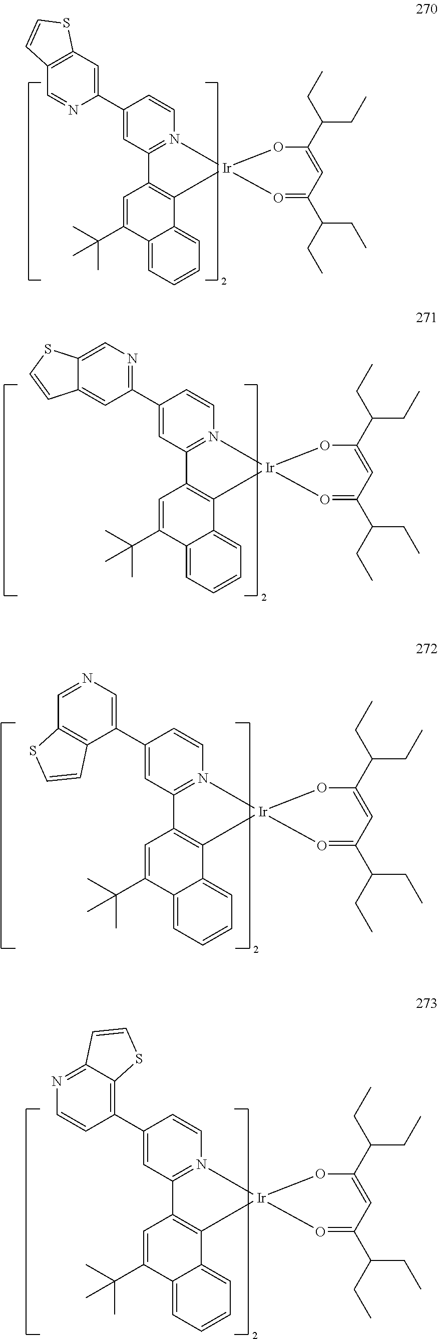

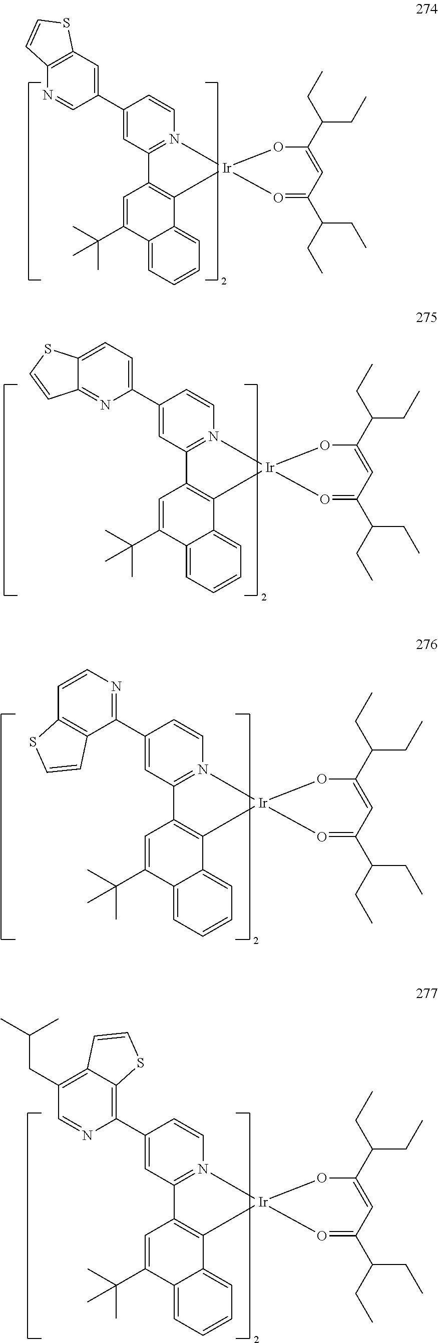

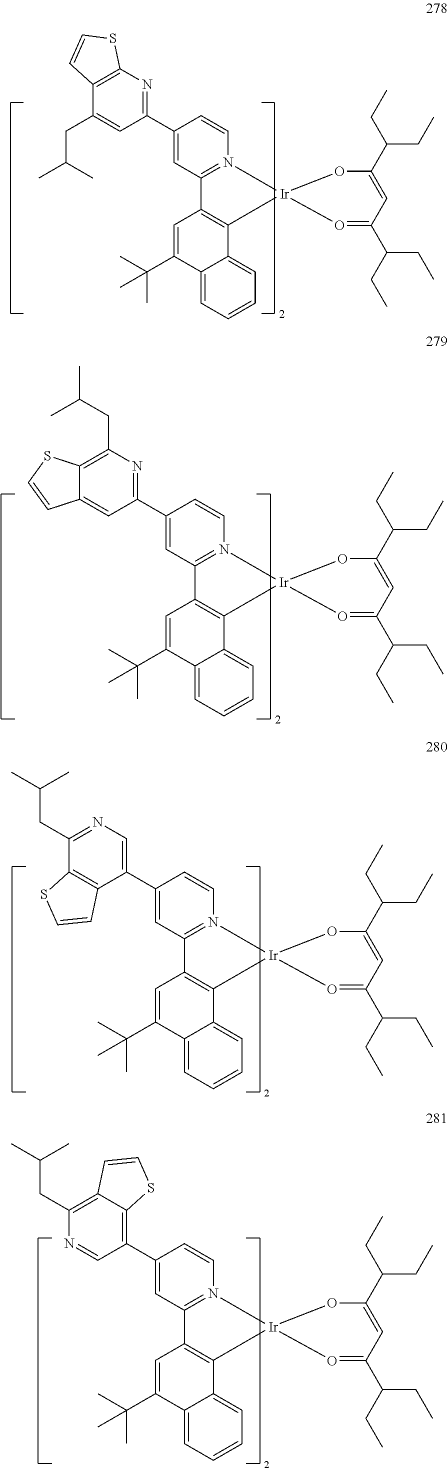

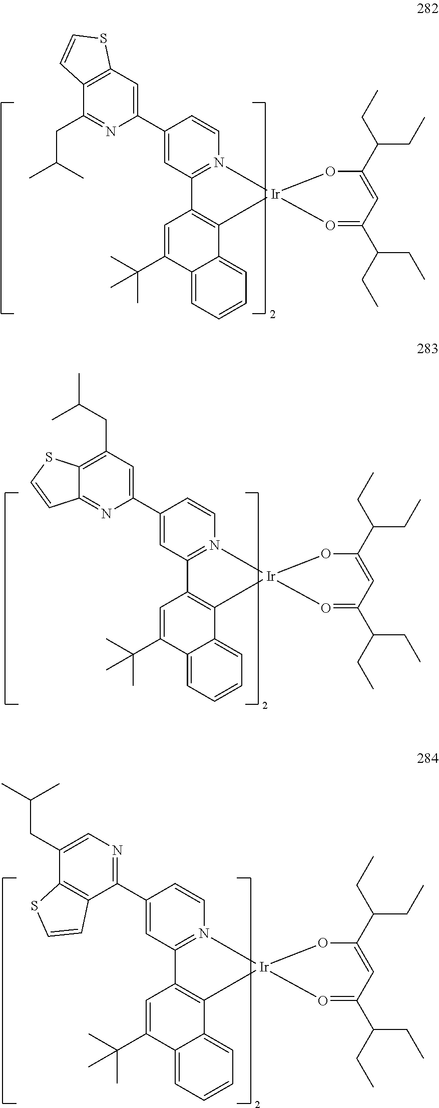

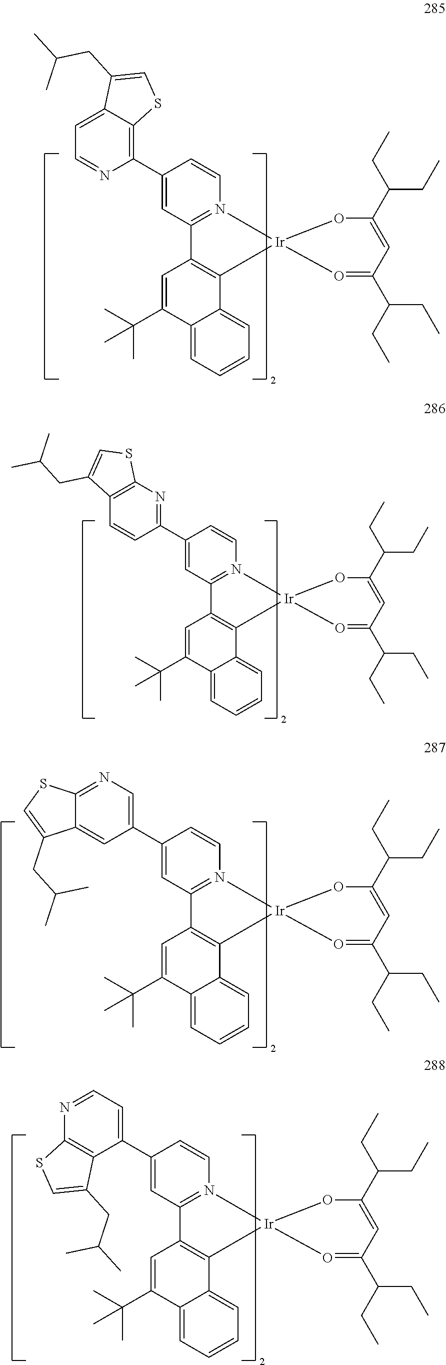

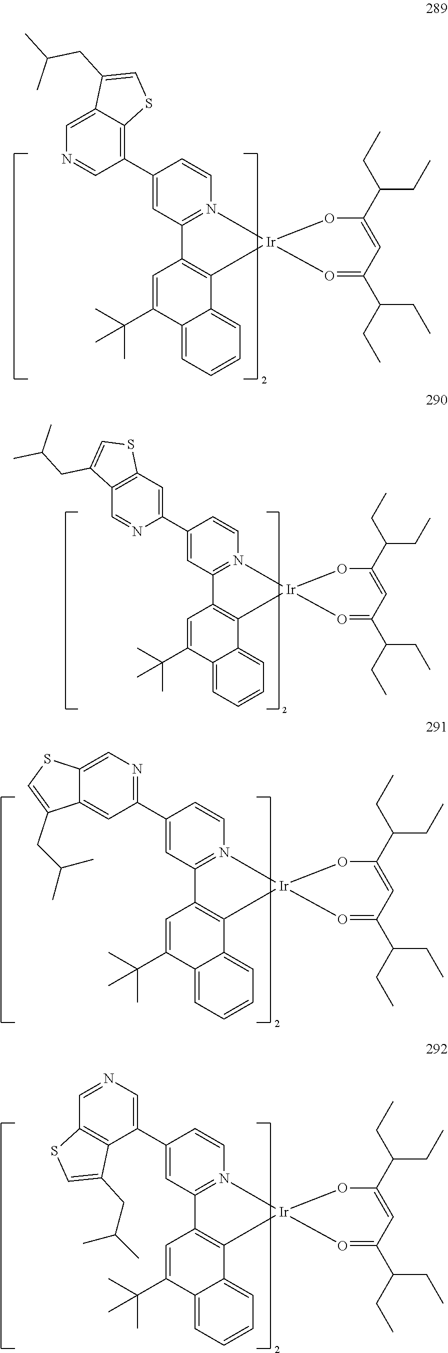

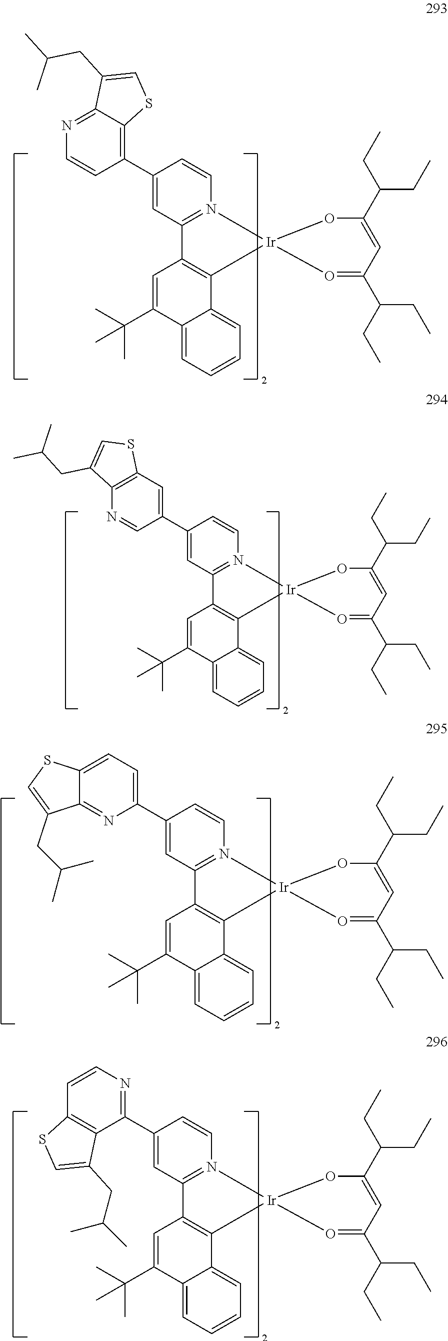

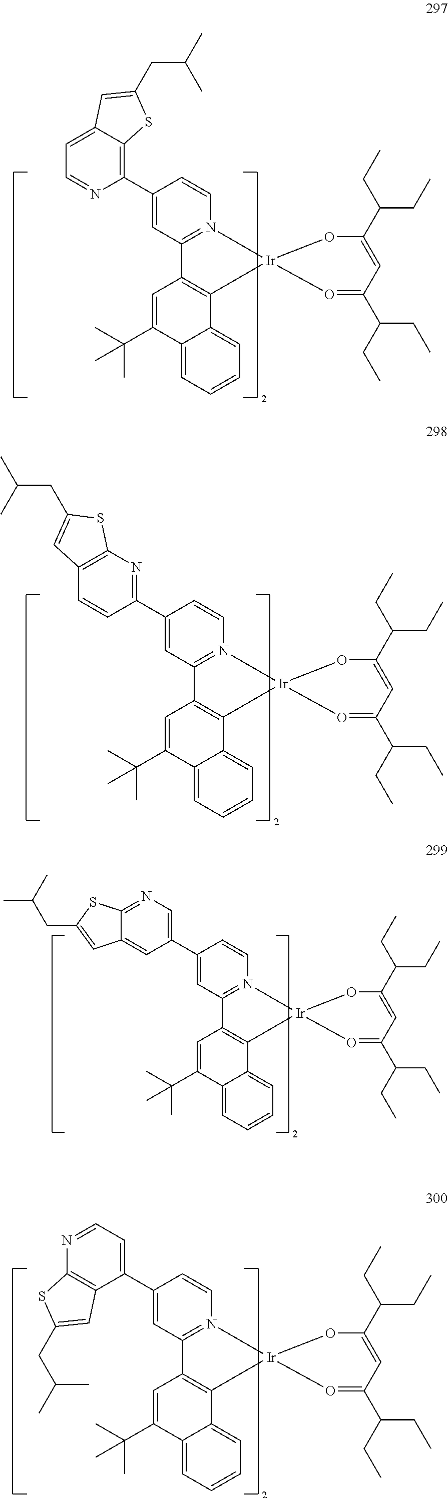

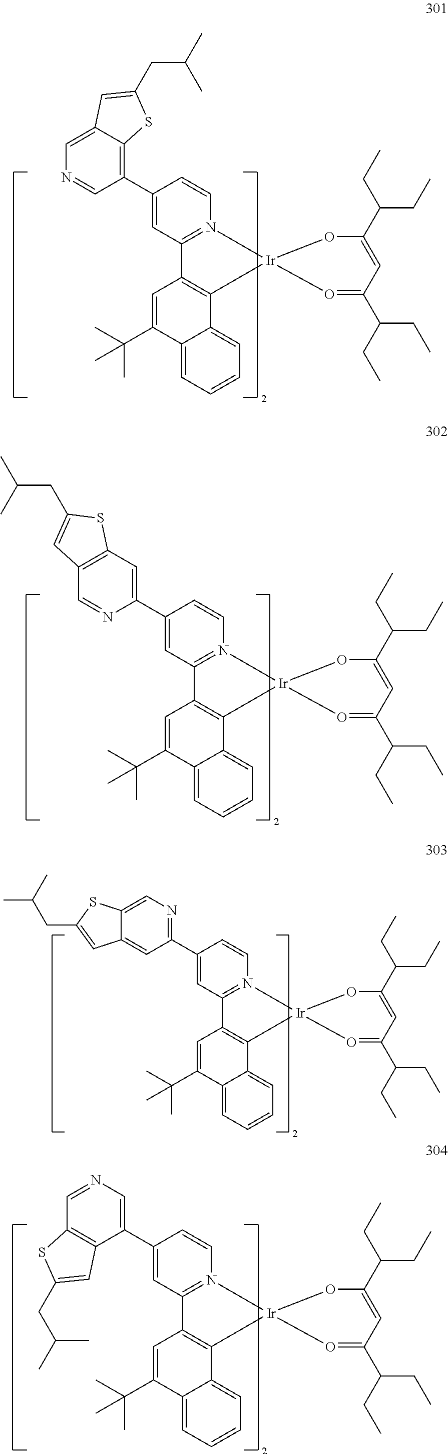

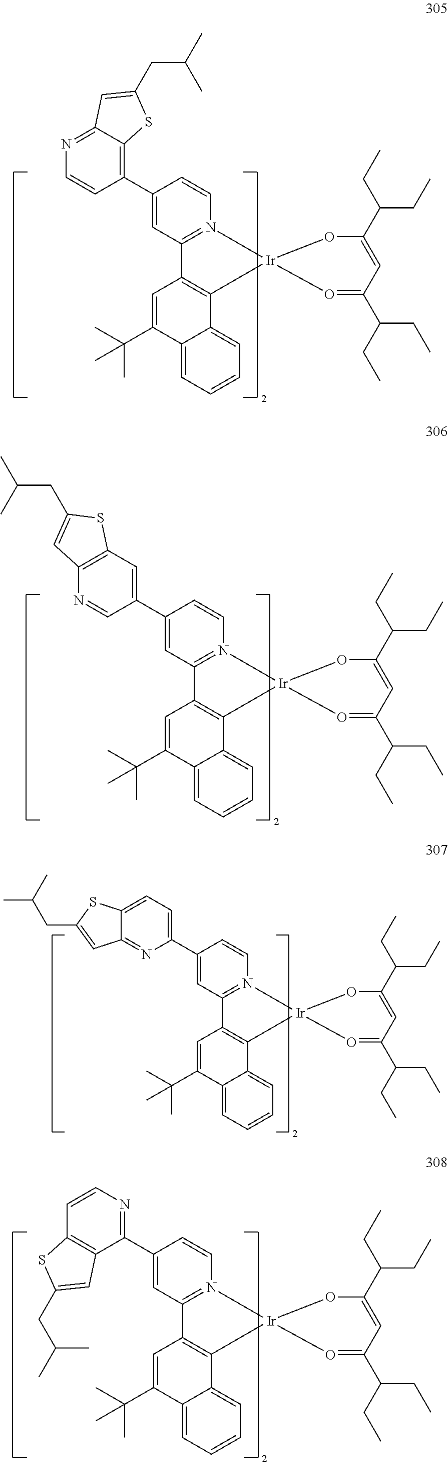

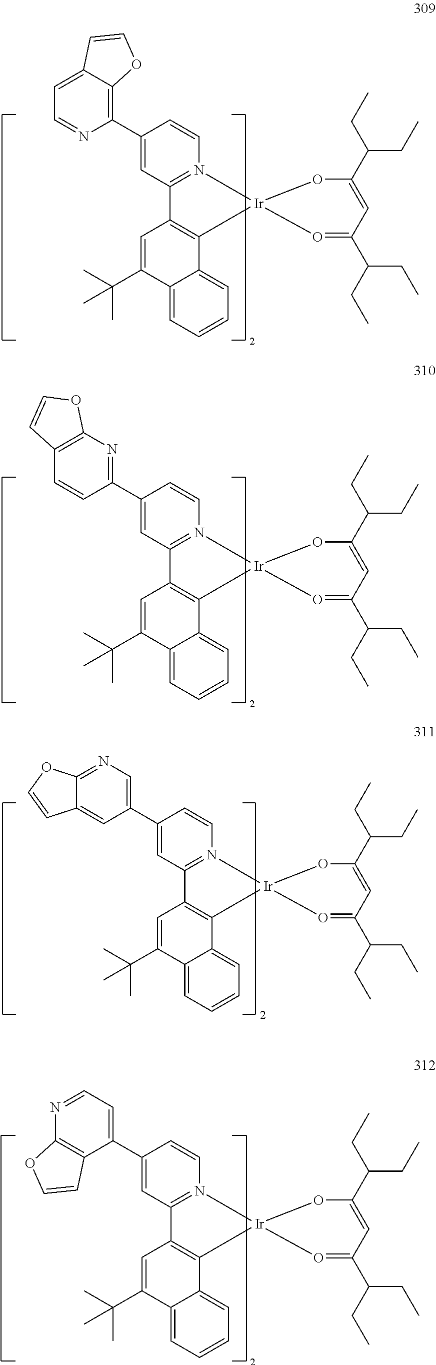

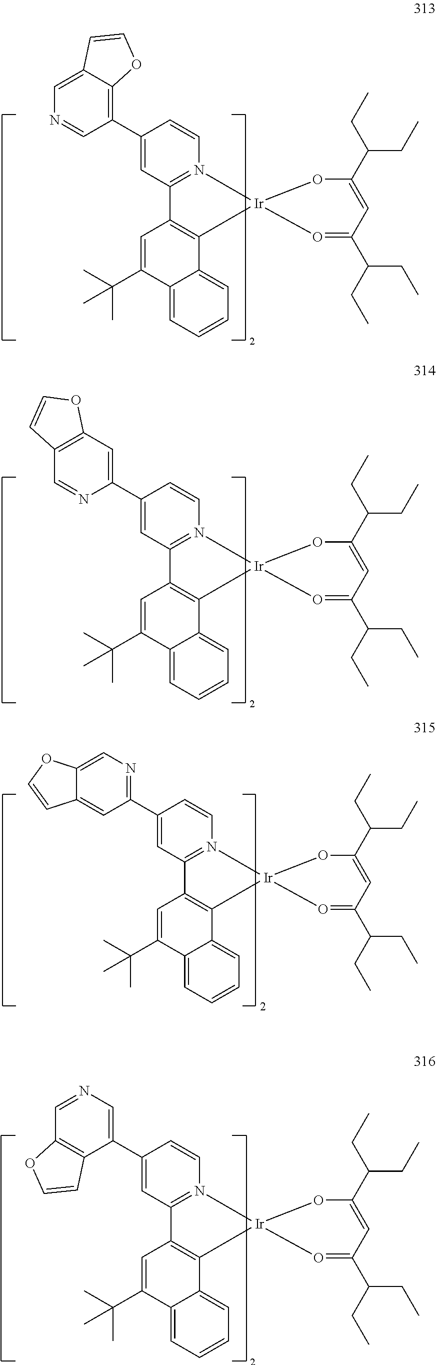

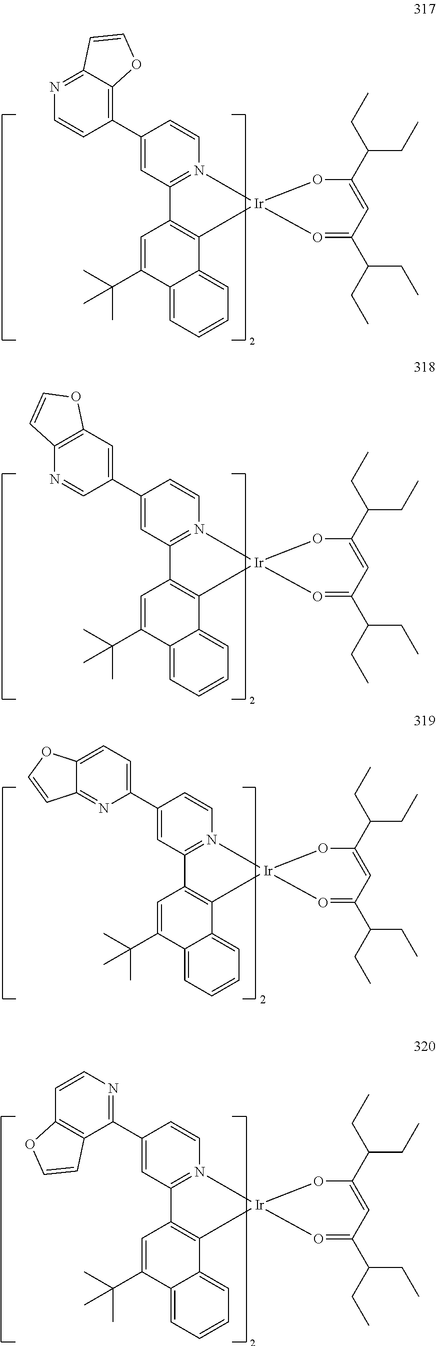

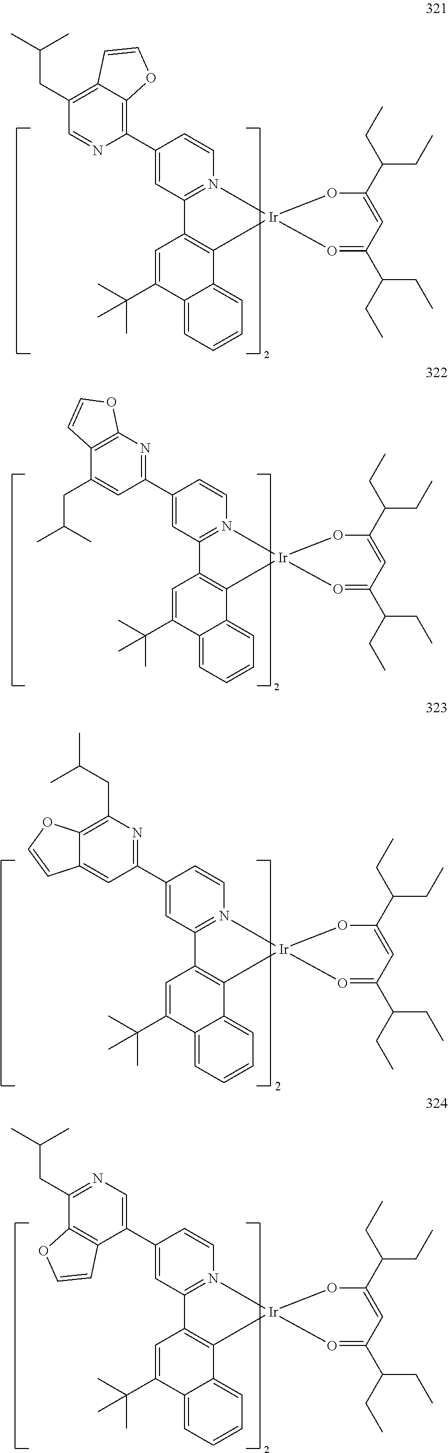

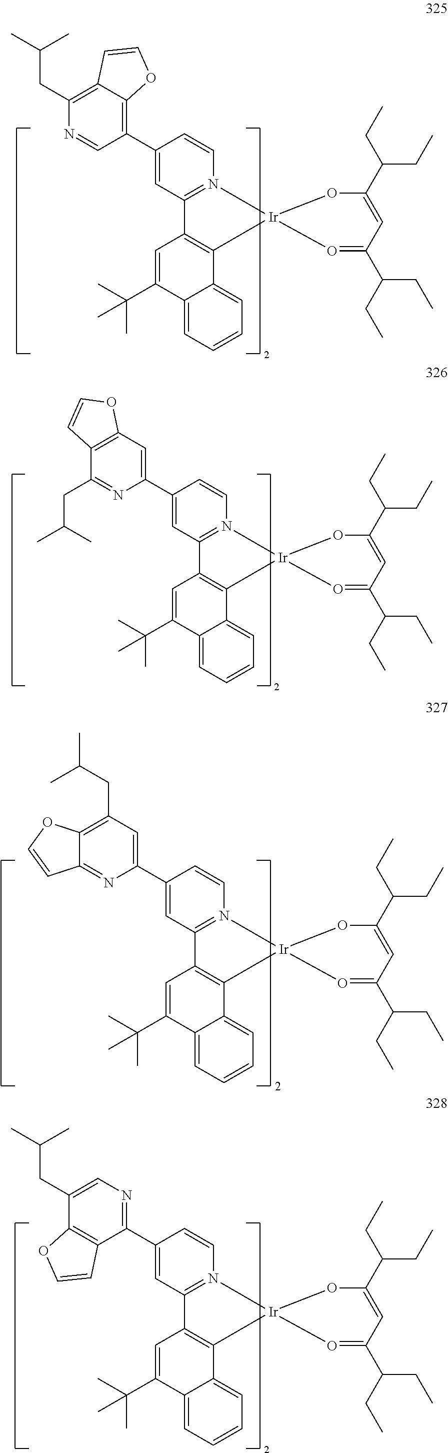

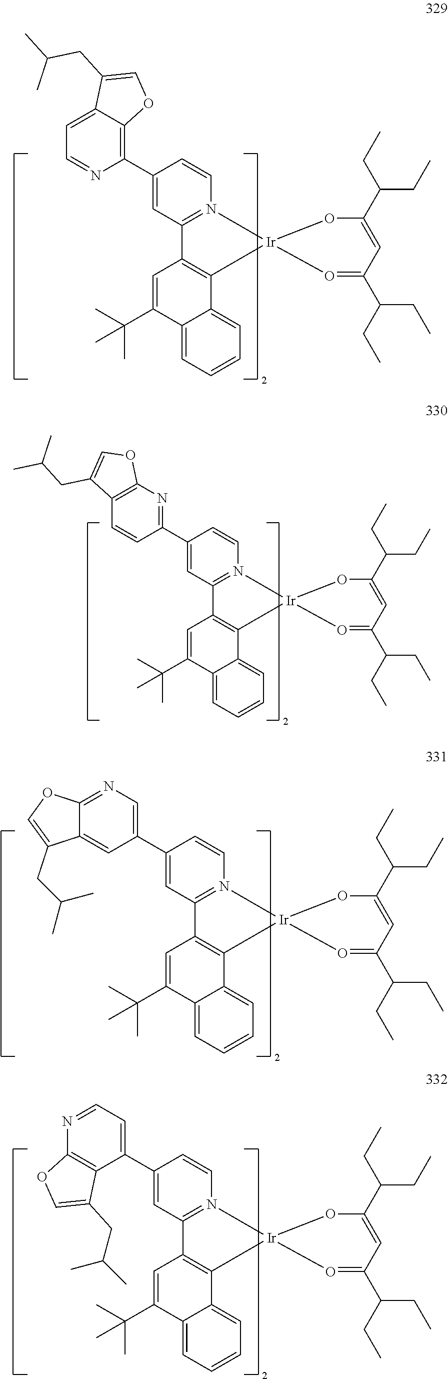

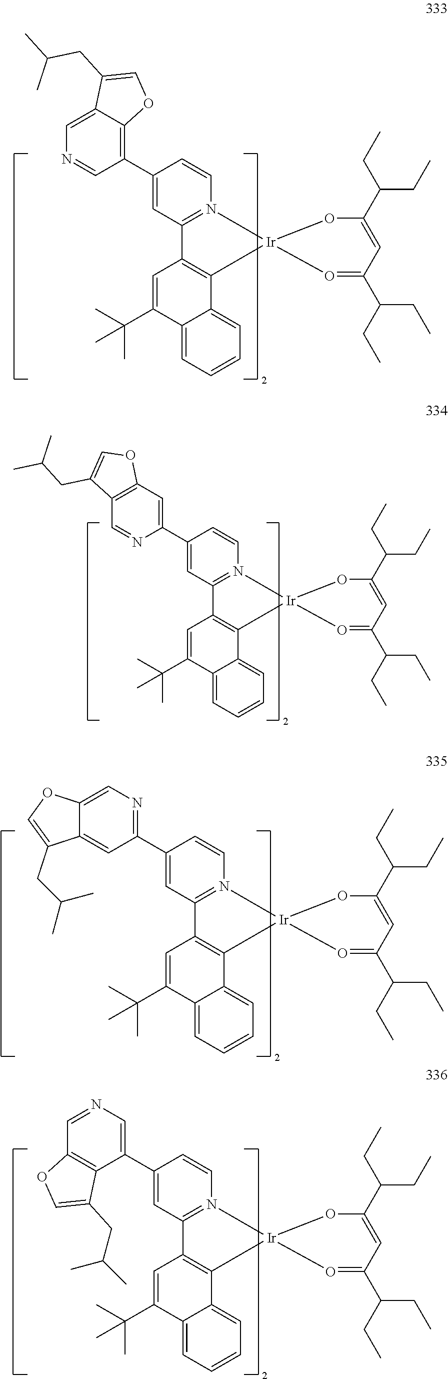

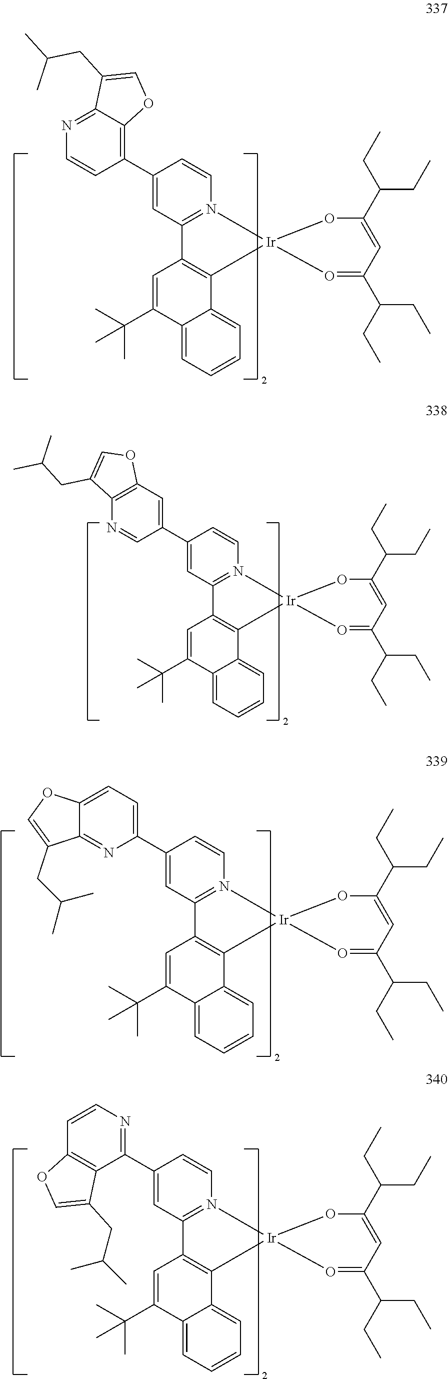

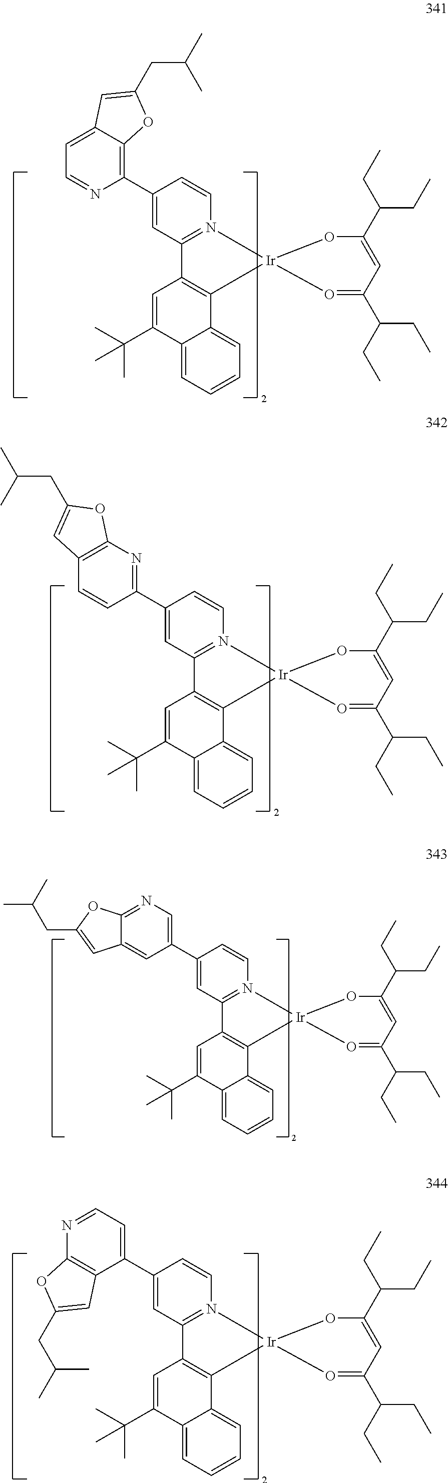

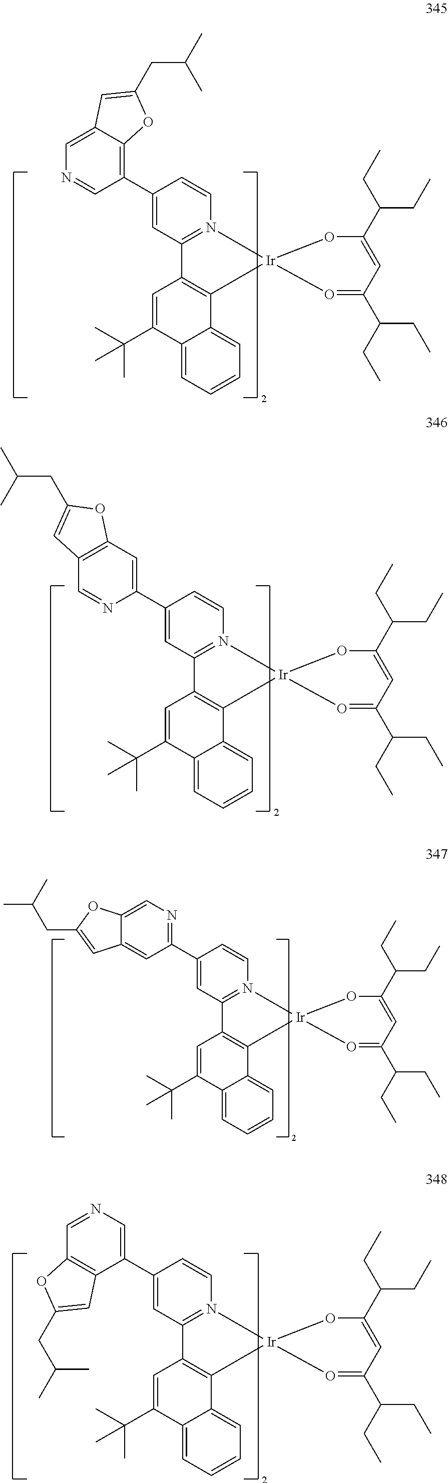

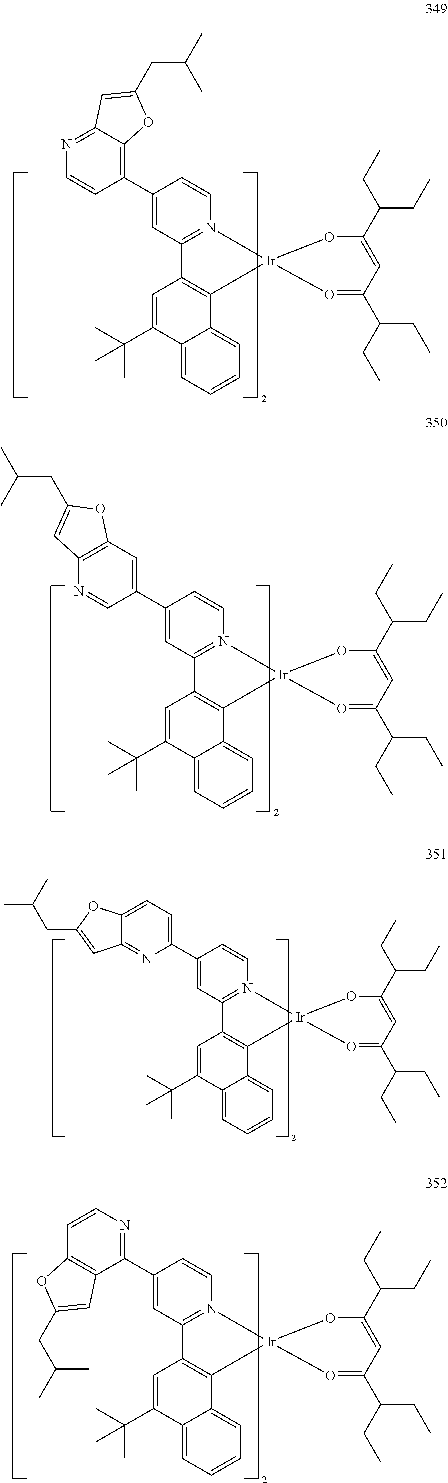

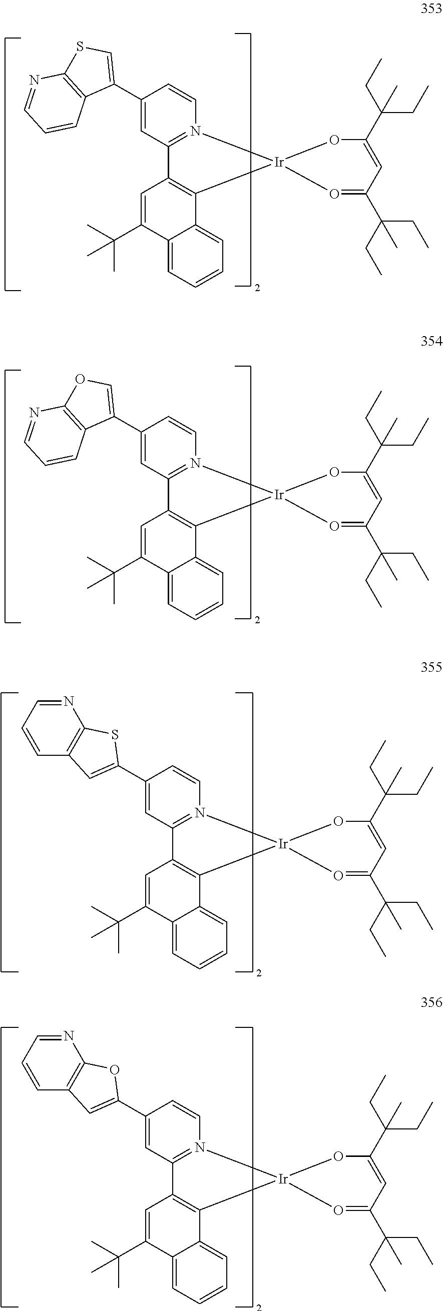

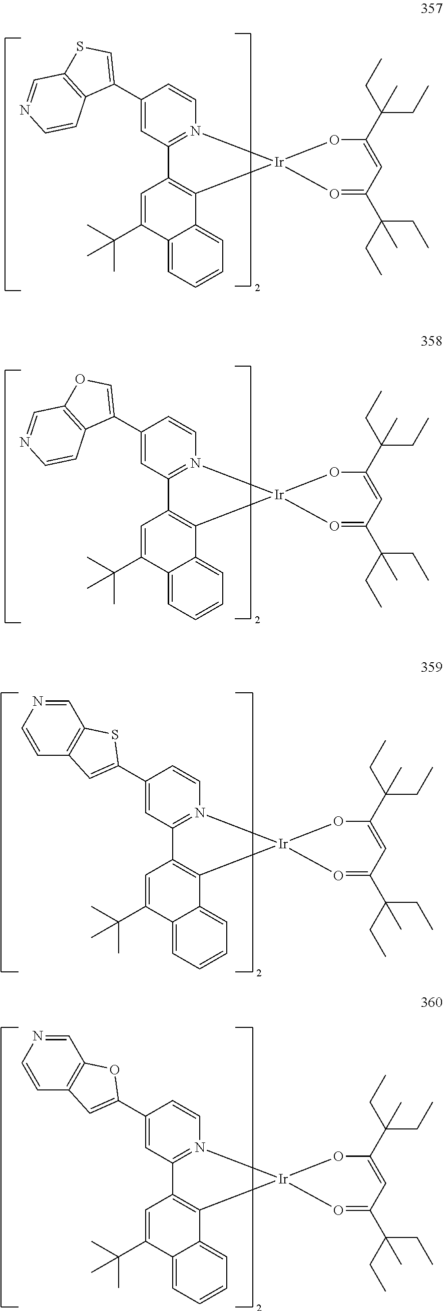

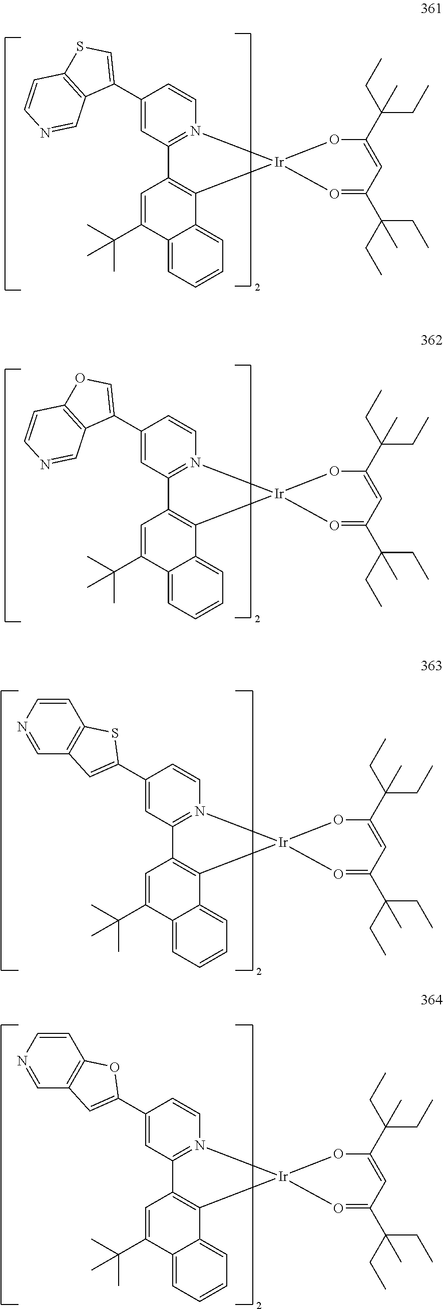

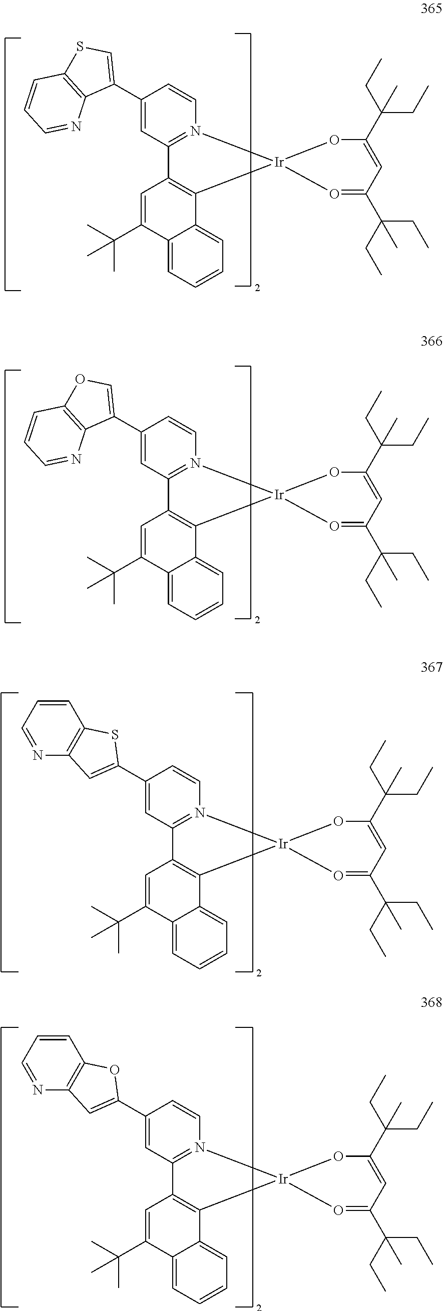

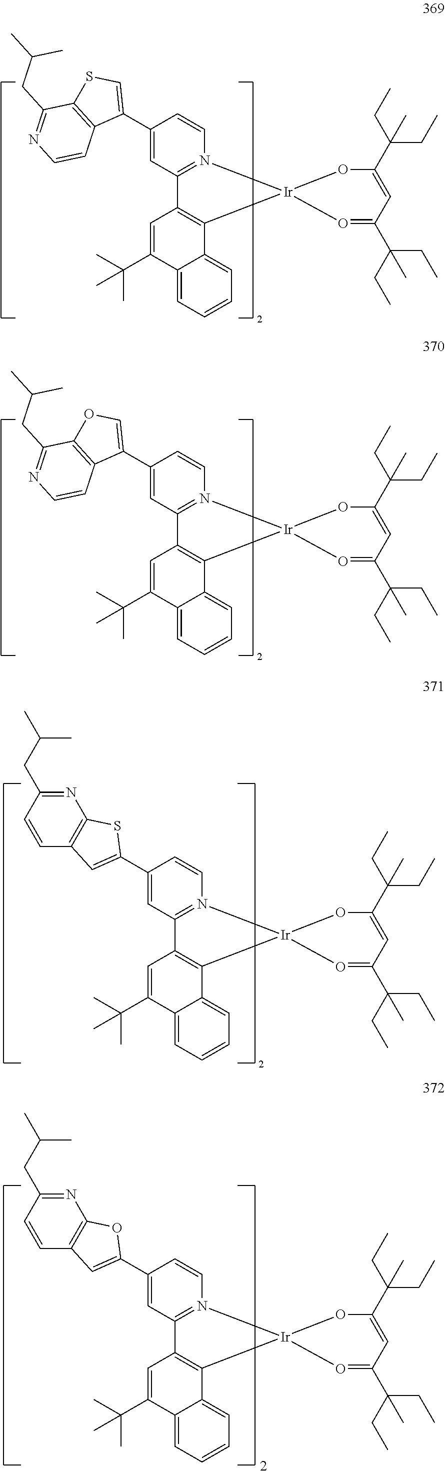

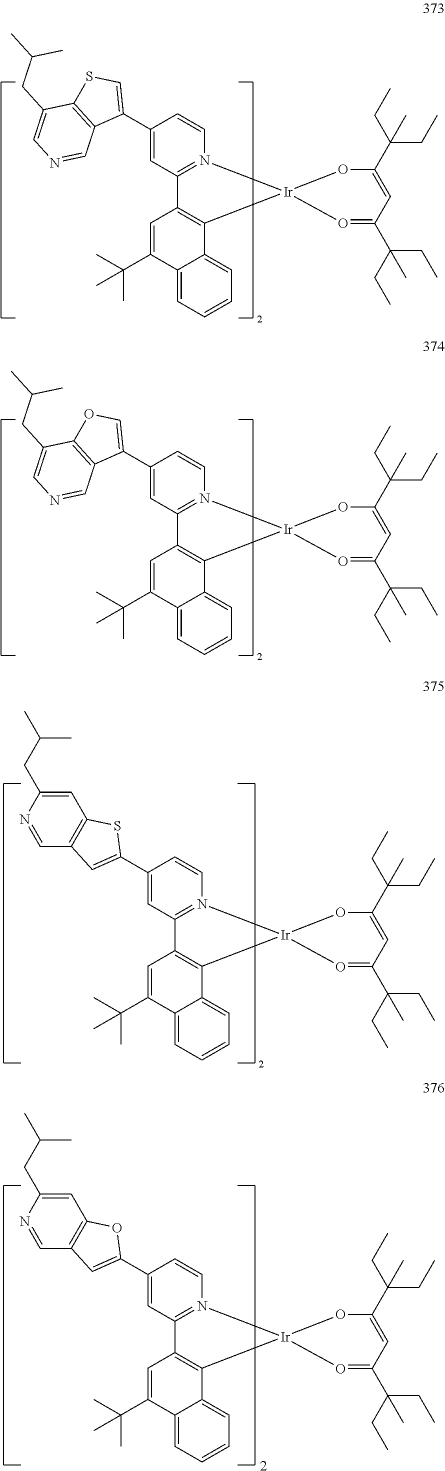

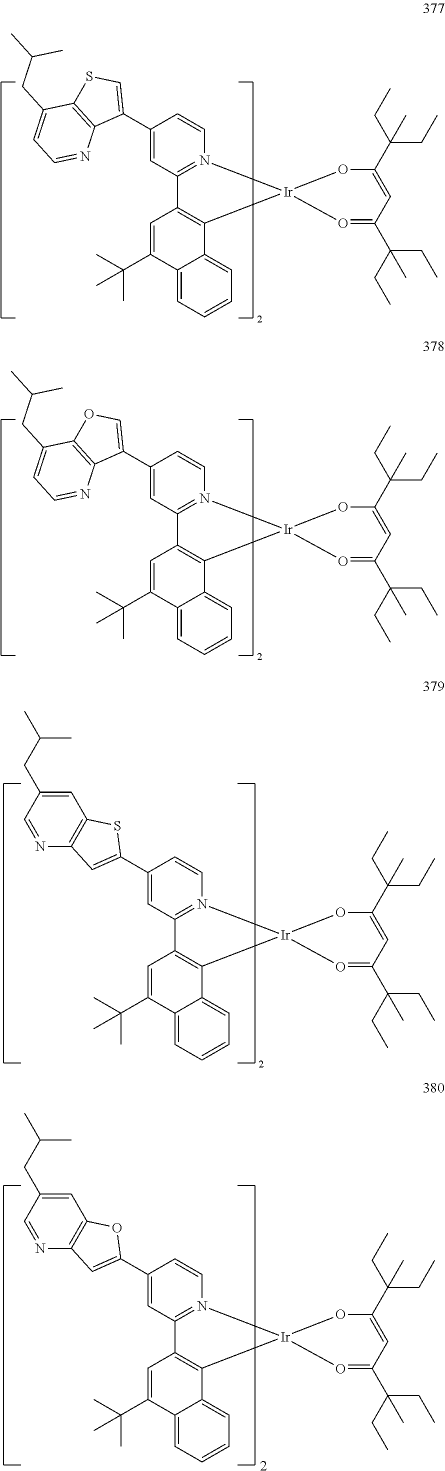

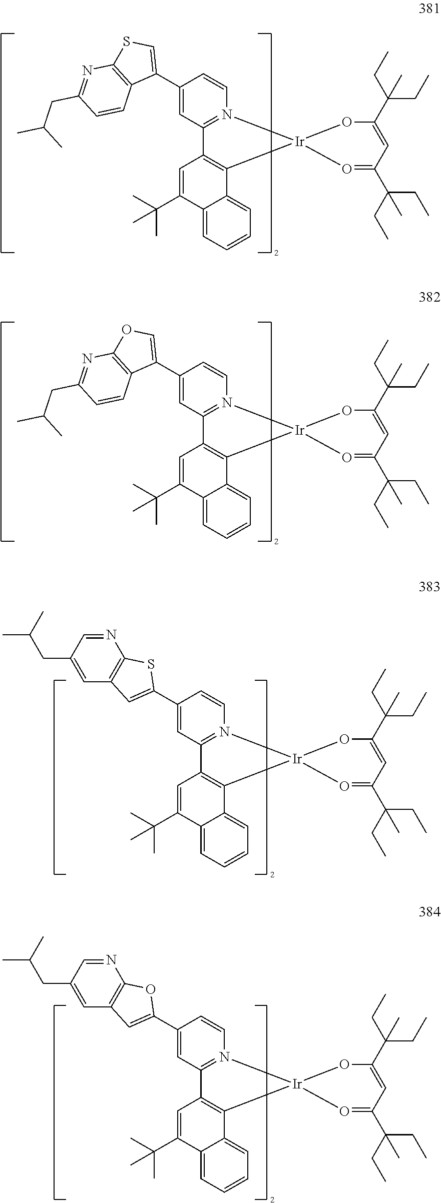

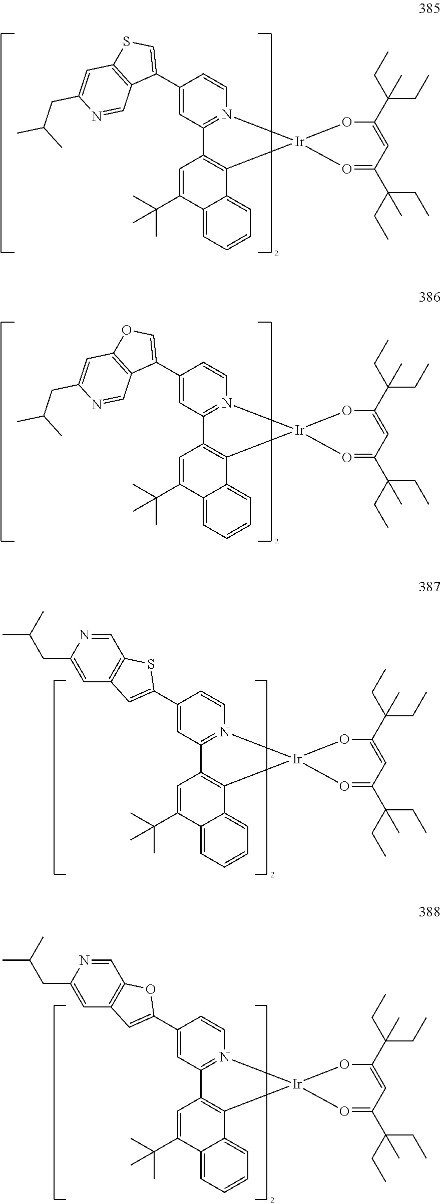

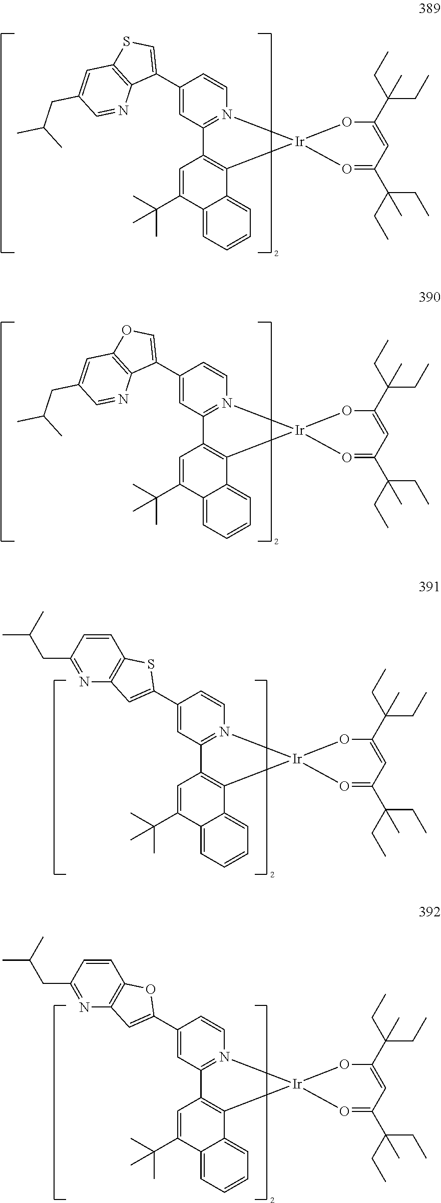

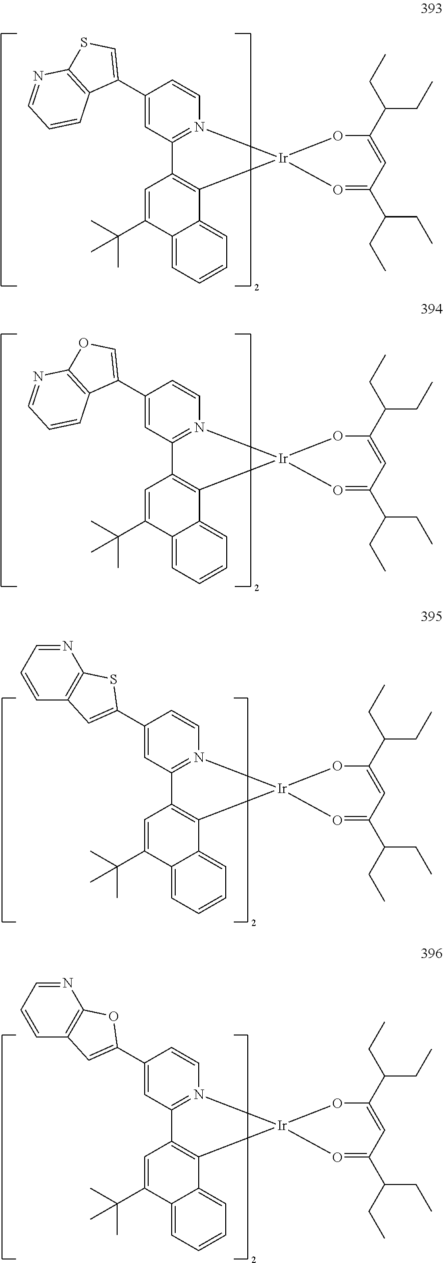

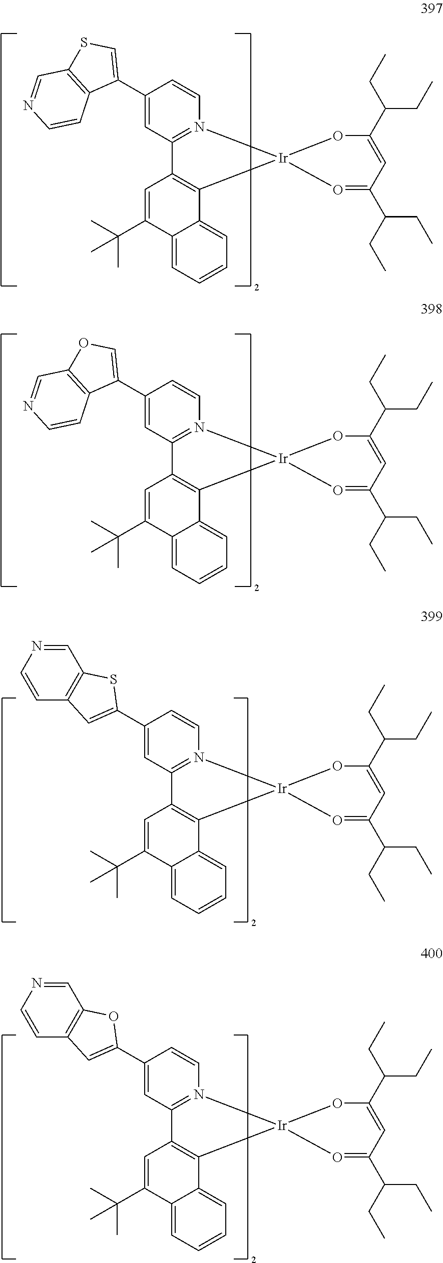

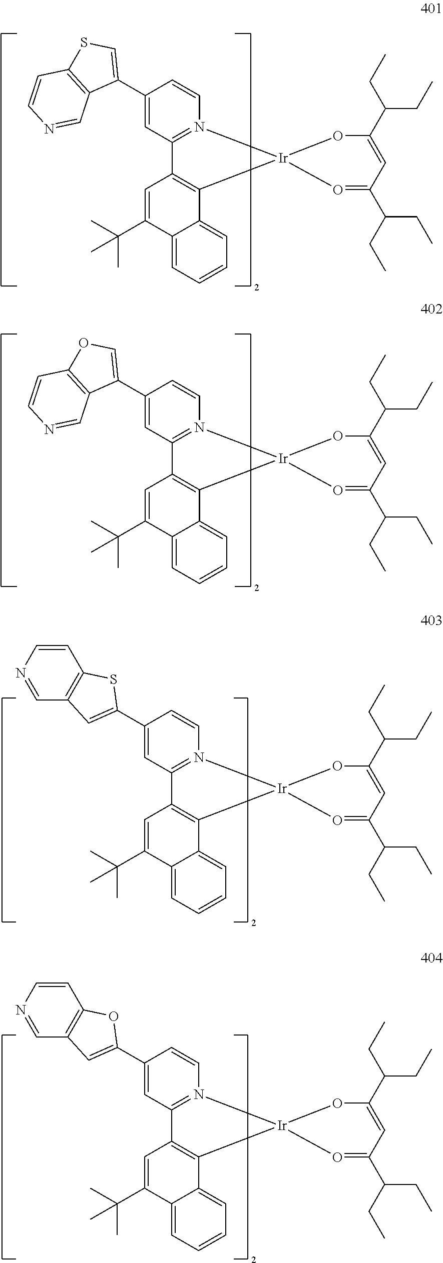

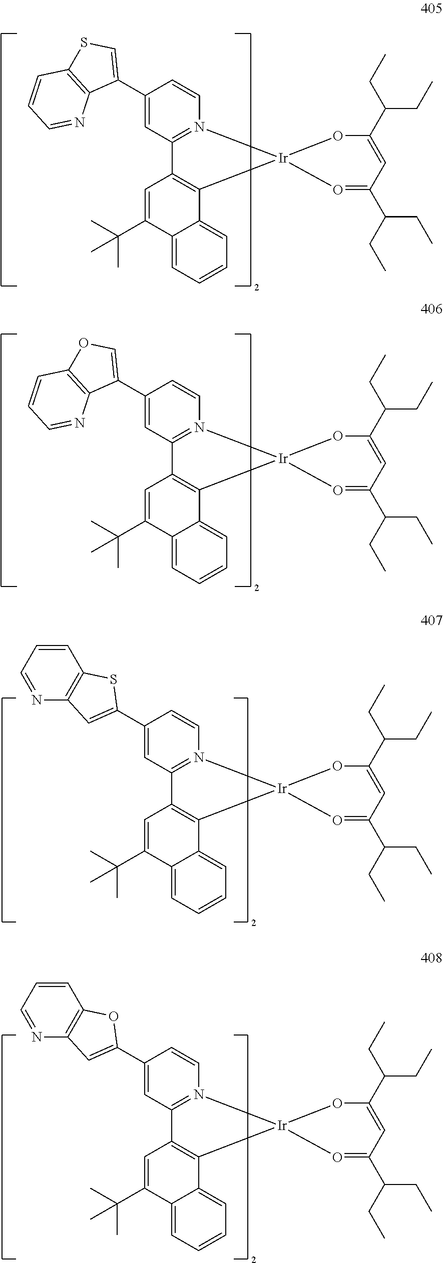

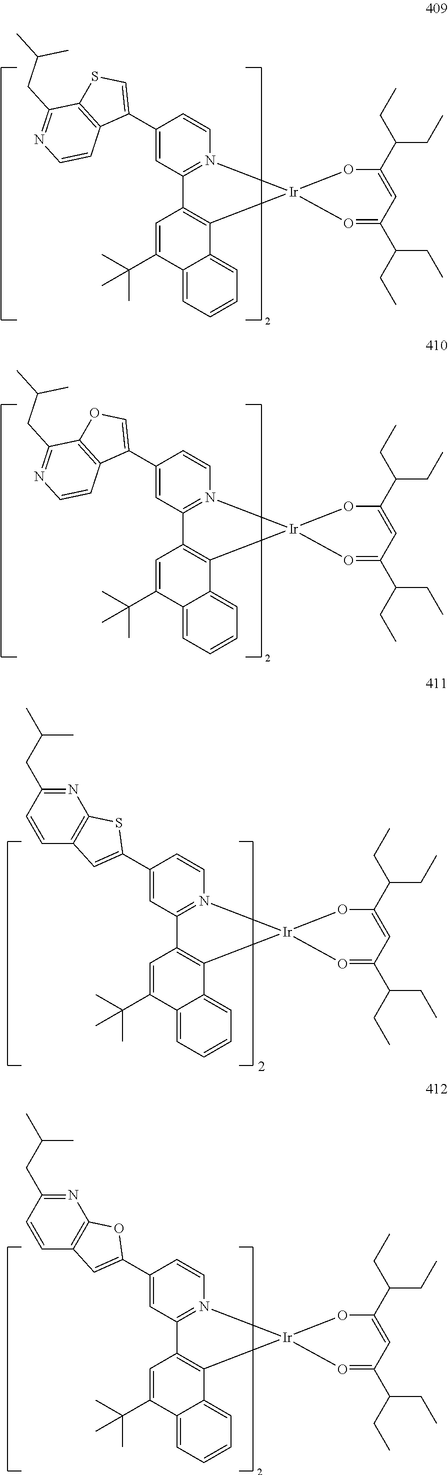

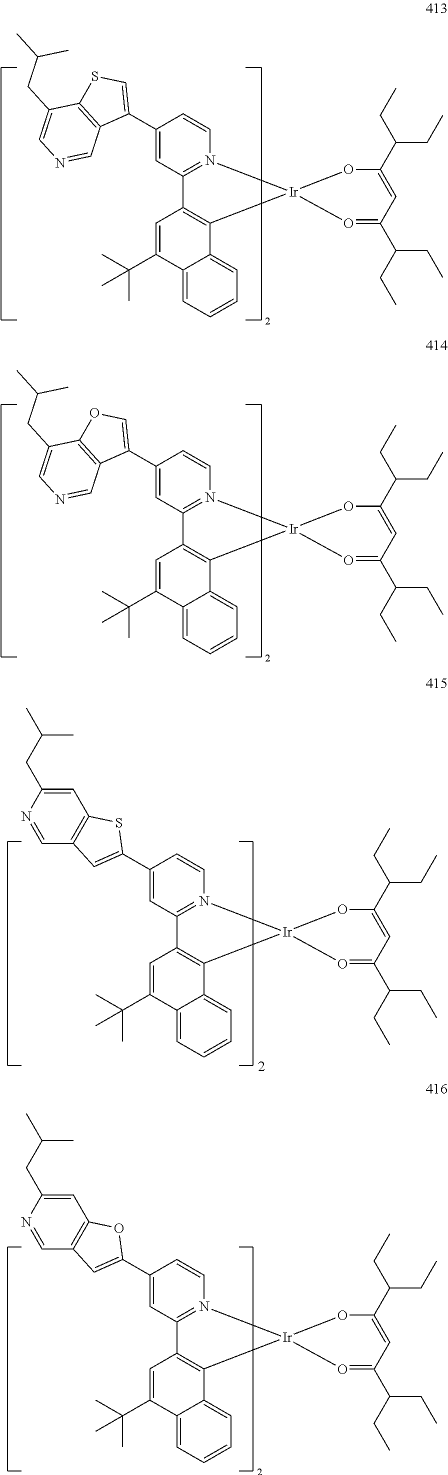

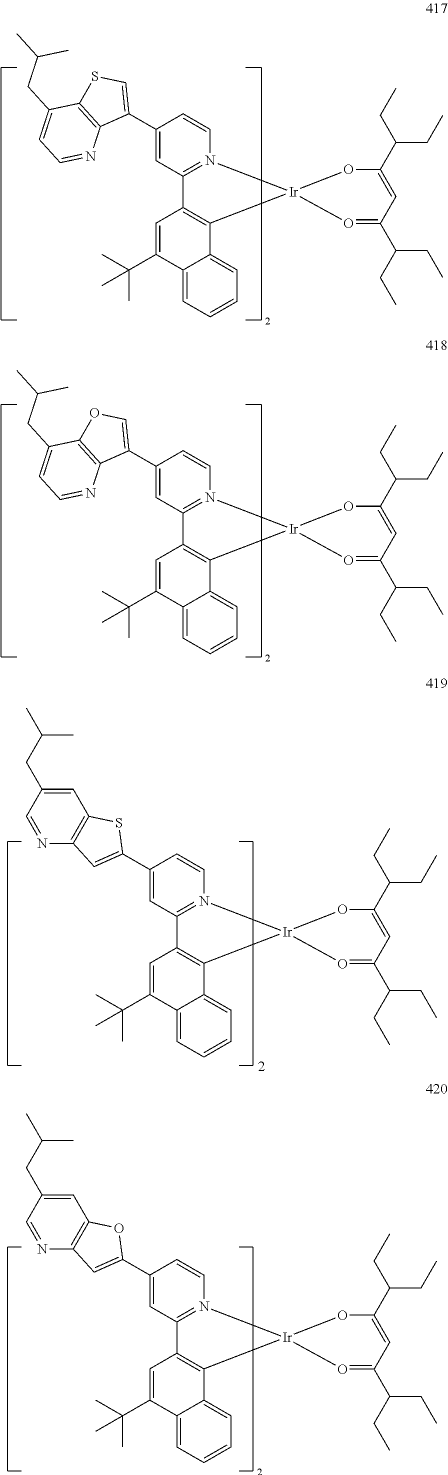

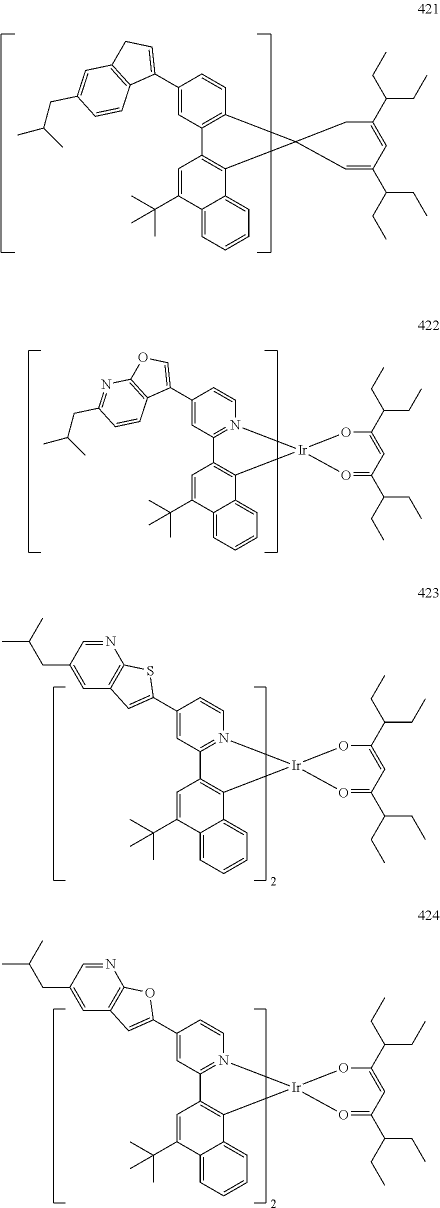

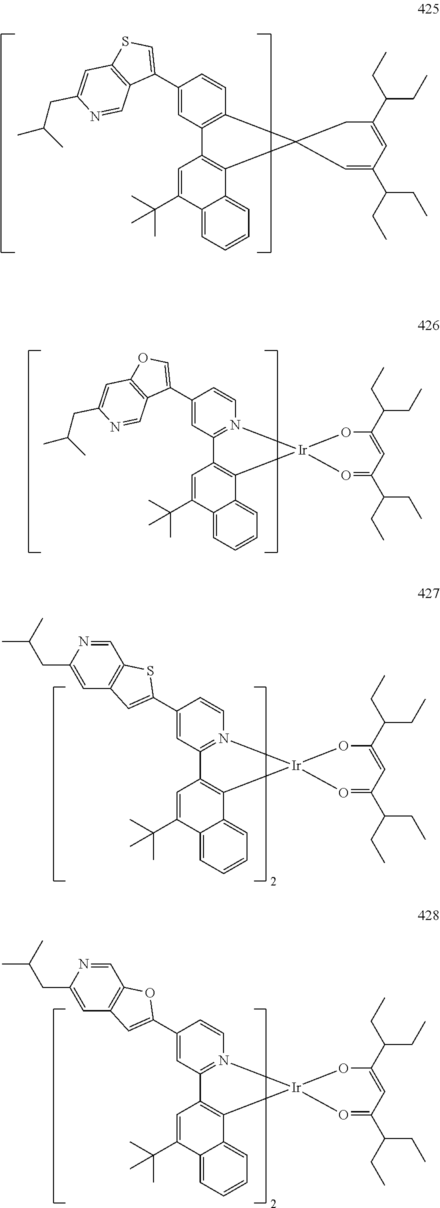

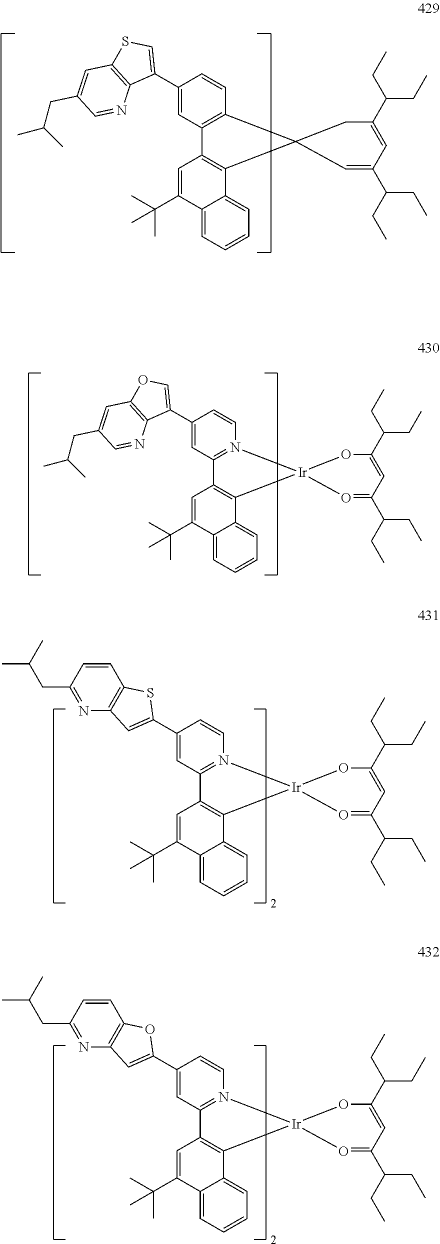

In another example embodiment, the organometallic compound can have a structure where one of X¹ to X⁴ is N and three of X¹ to X⁴ is independently CR¹, or one of X¹ to X⁴ is N, two of X¹ to X⁴ is independently CR¹ and other of X¹ to X⁴ is the carbon atom linked to the hetero aromatic ring with X⁵, and X⁵ is N in Chemical Formula 2 as the L_{A}, and the L_{B} in Chemical Formula 1 has the structure of Chemical Formula 9B. The organometallic compound with such a linkage can include at least one of, or selected from, but is not limited to, the following organometallic compounds represented by Chemical Formula 13:

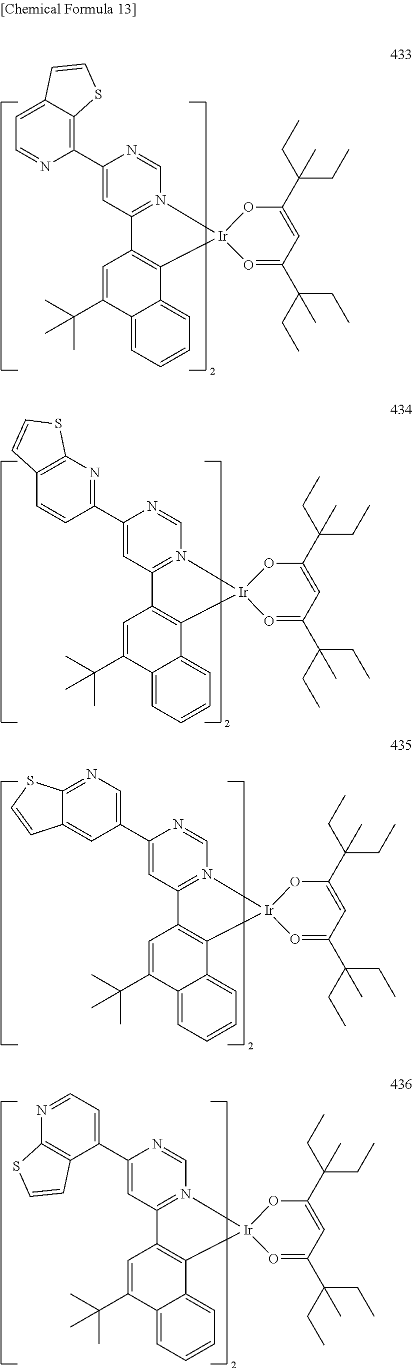

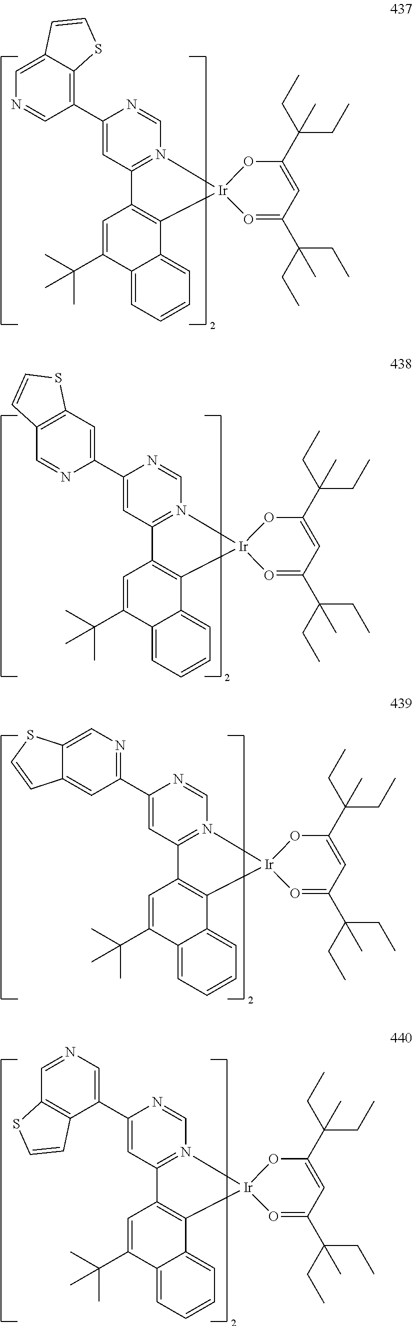

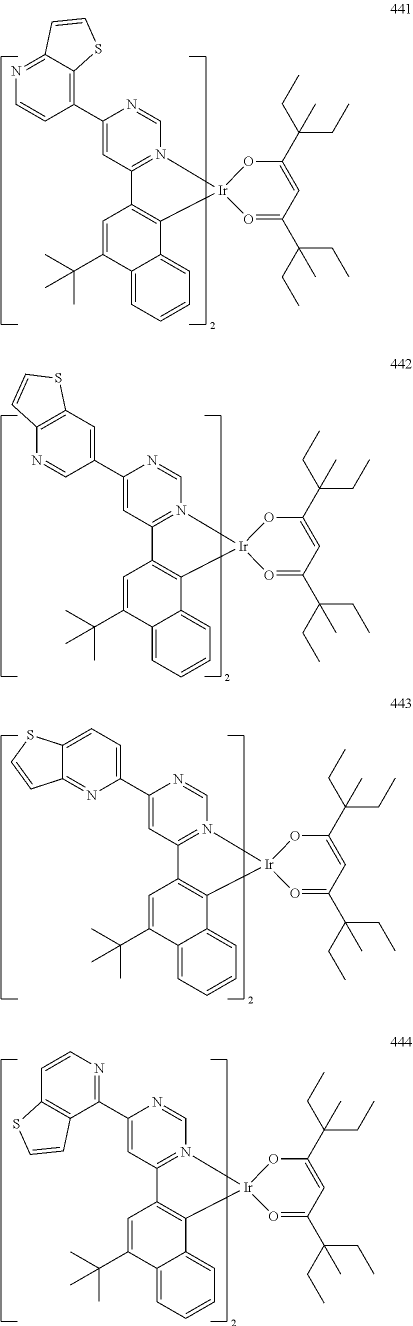

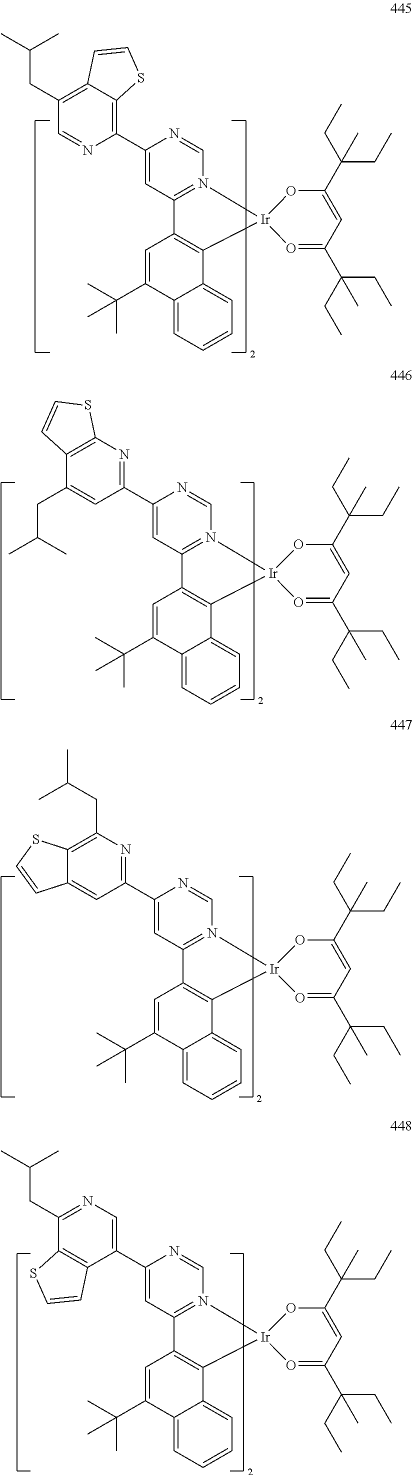

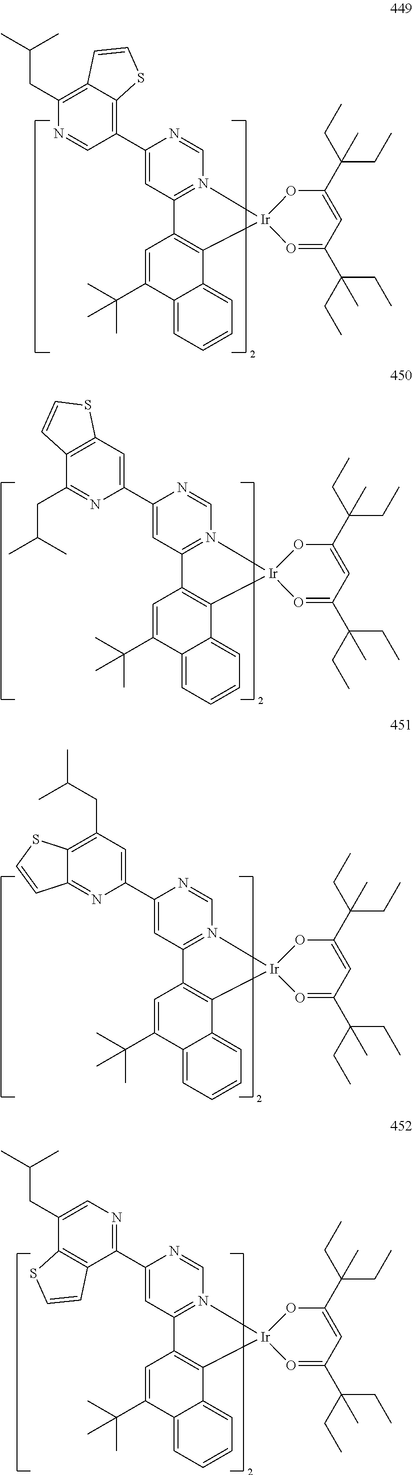

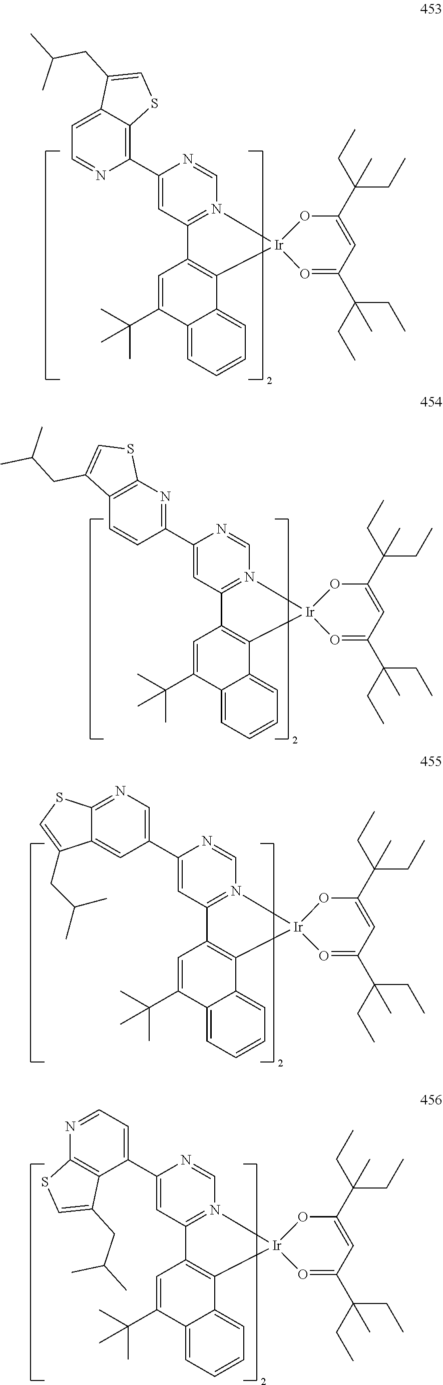

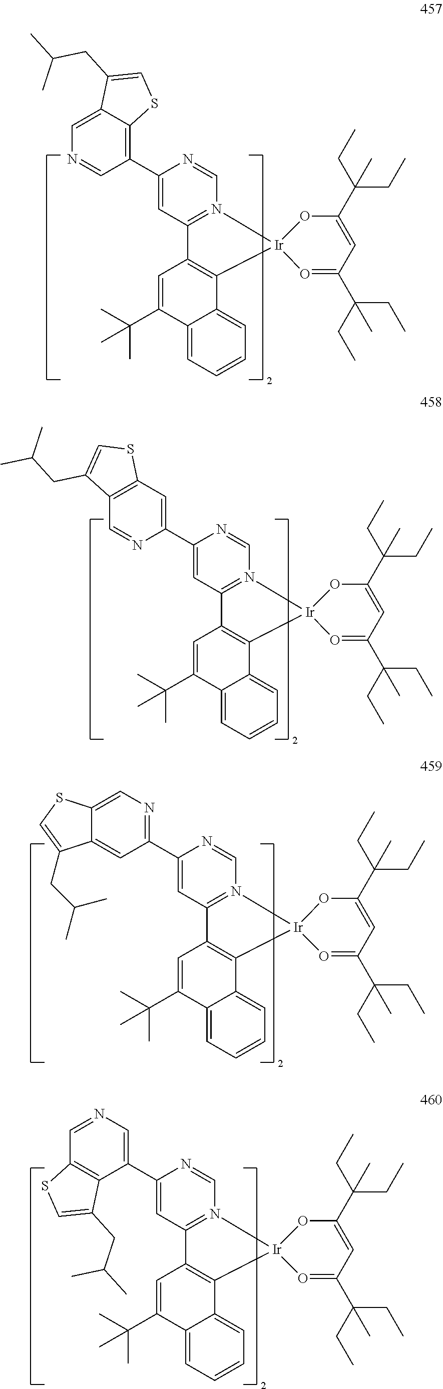

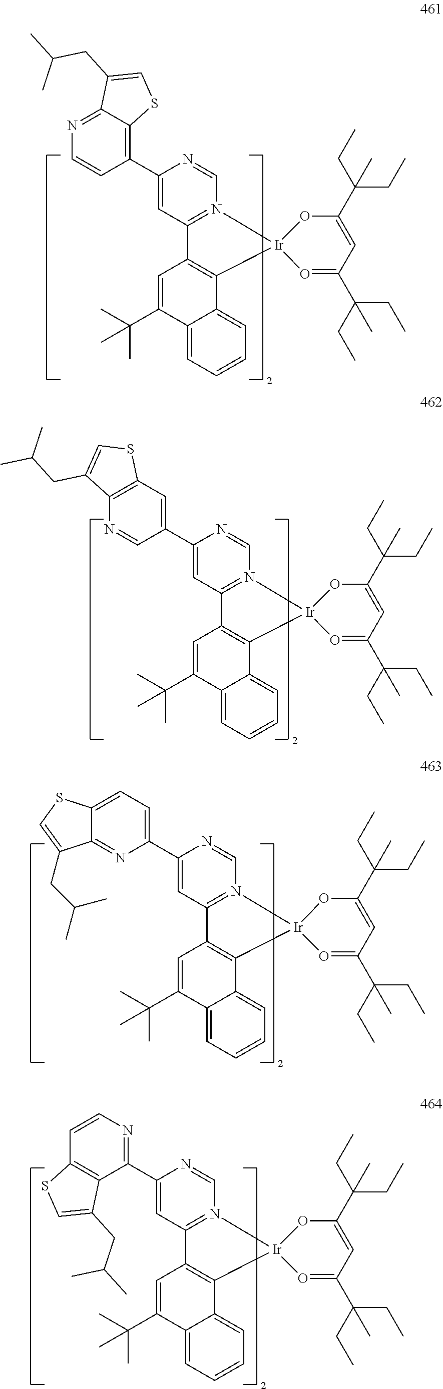

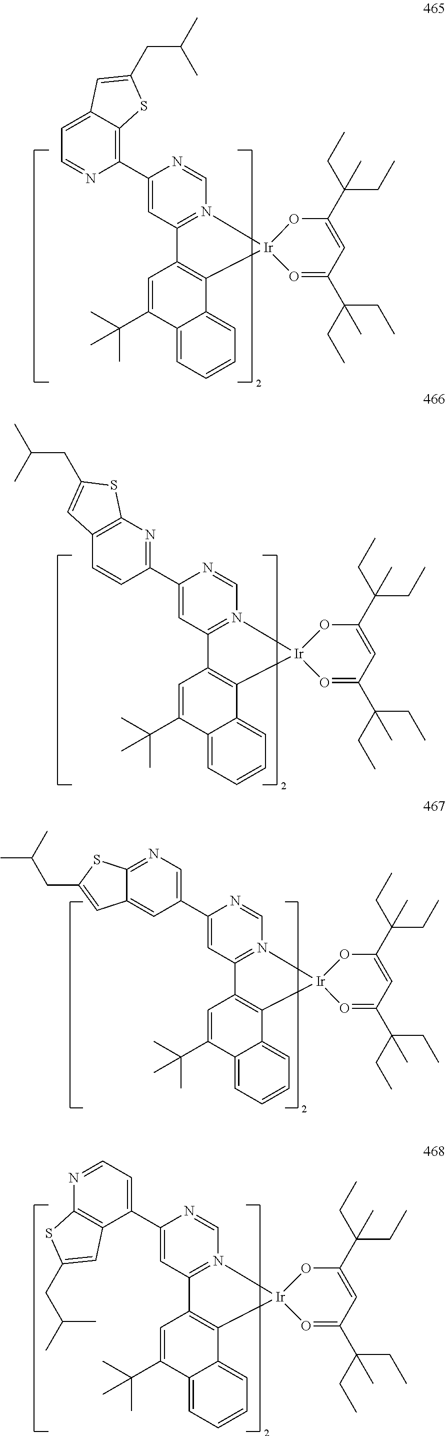

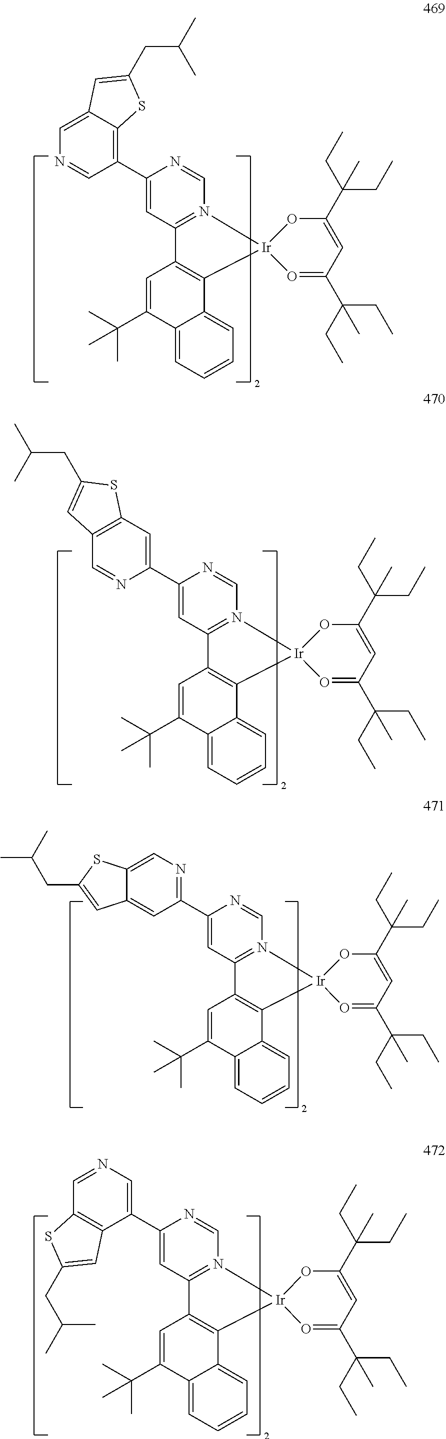

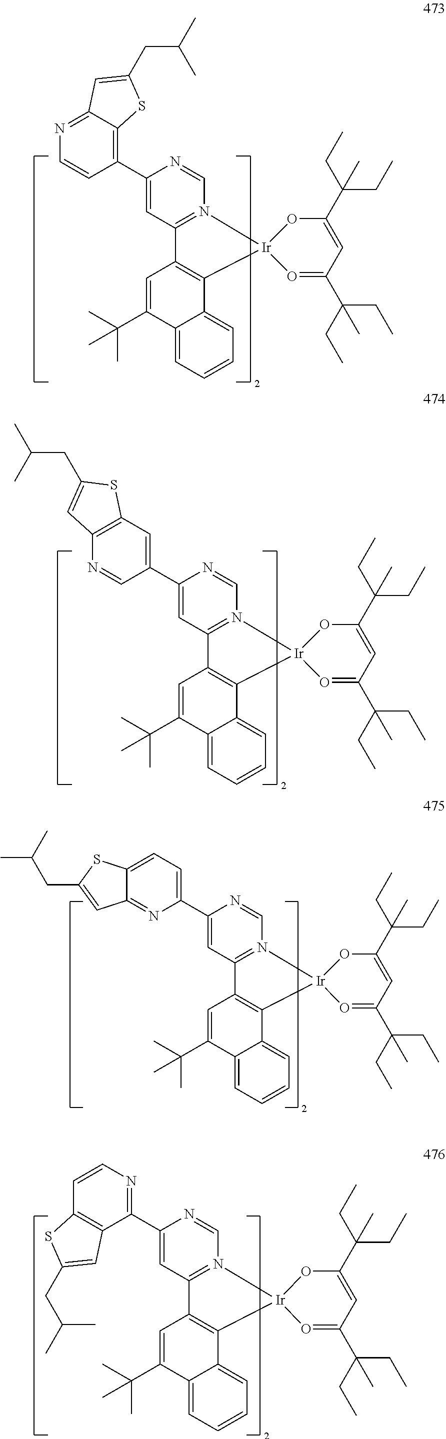

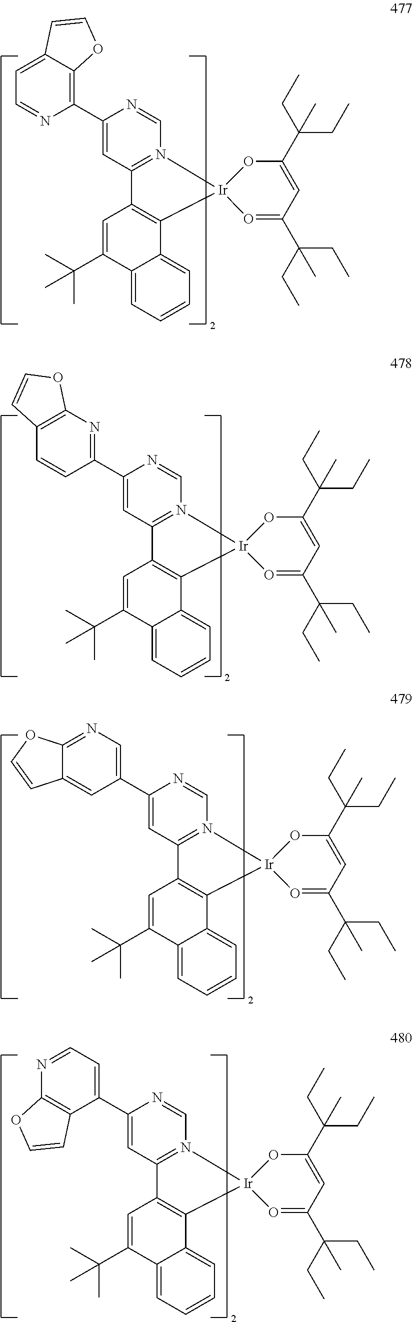

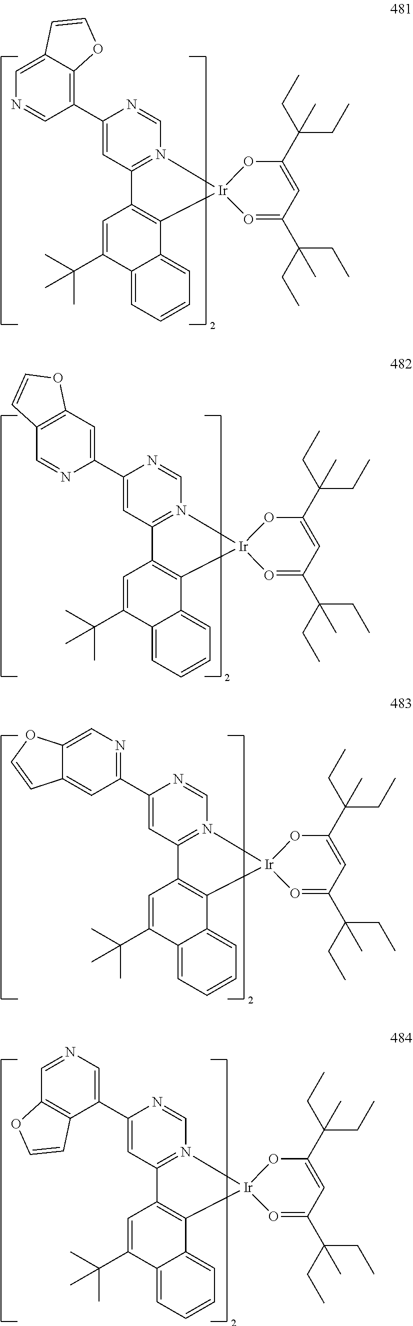

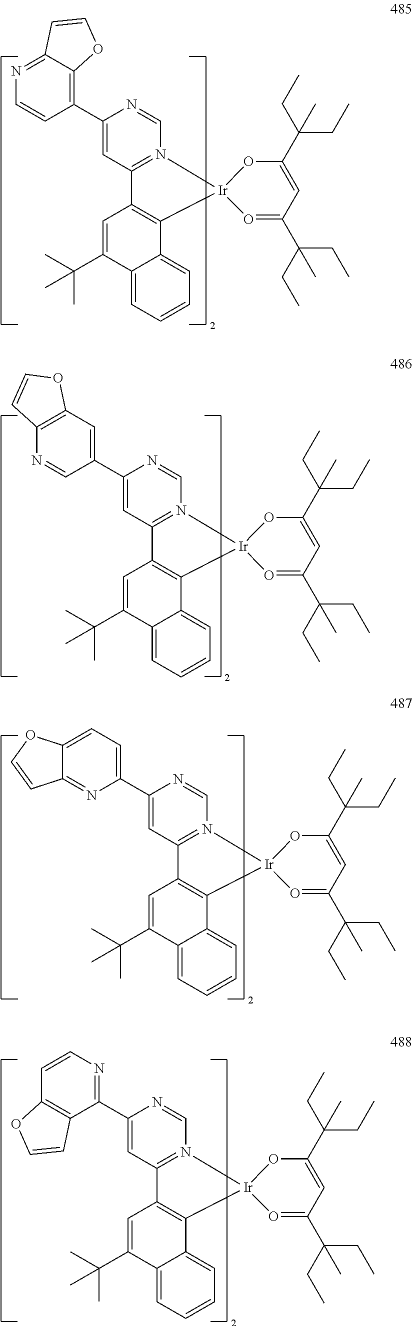

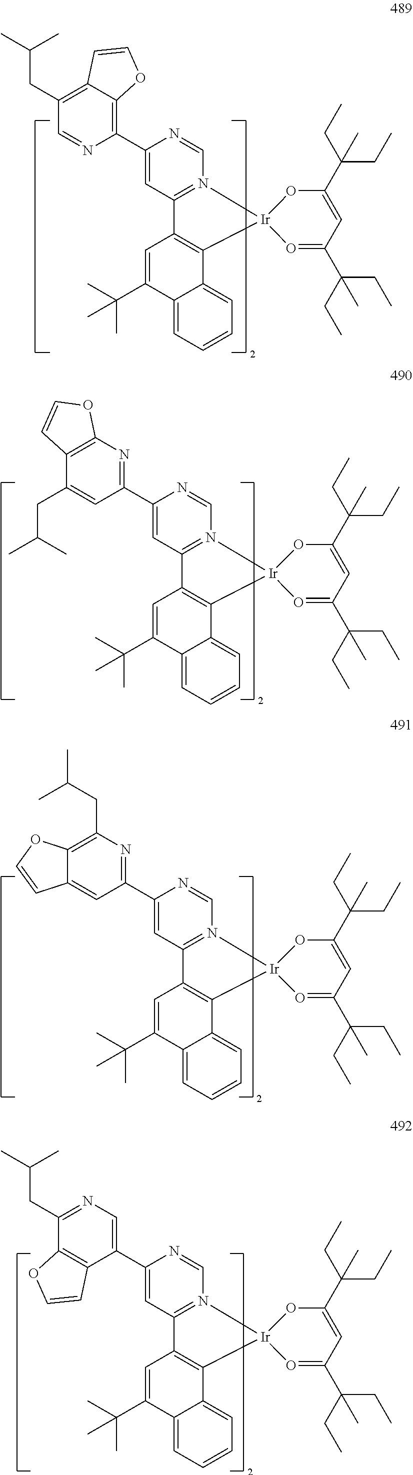

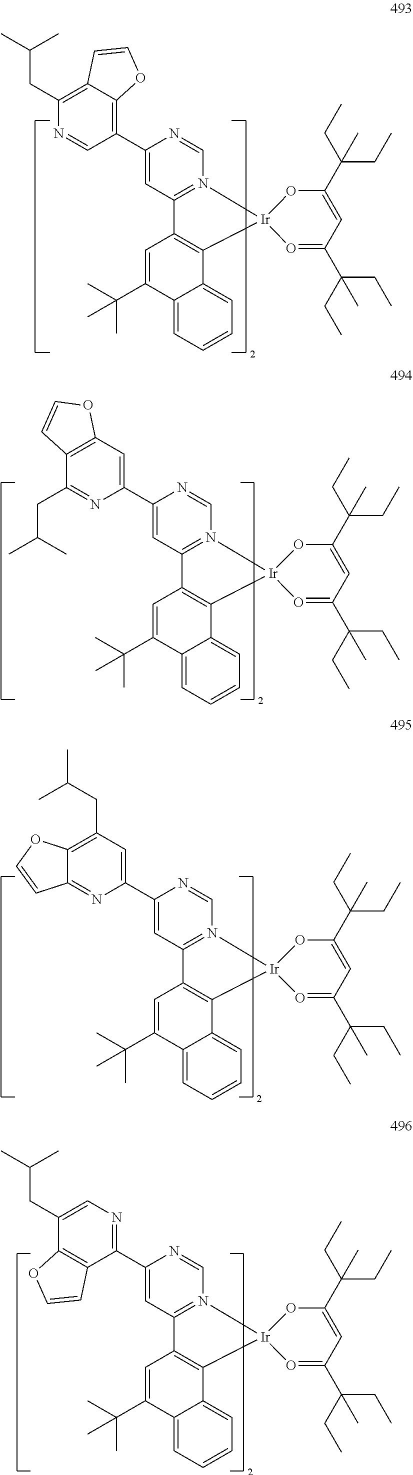

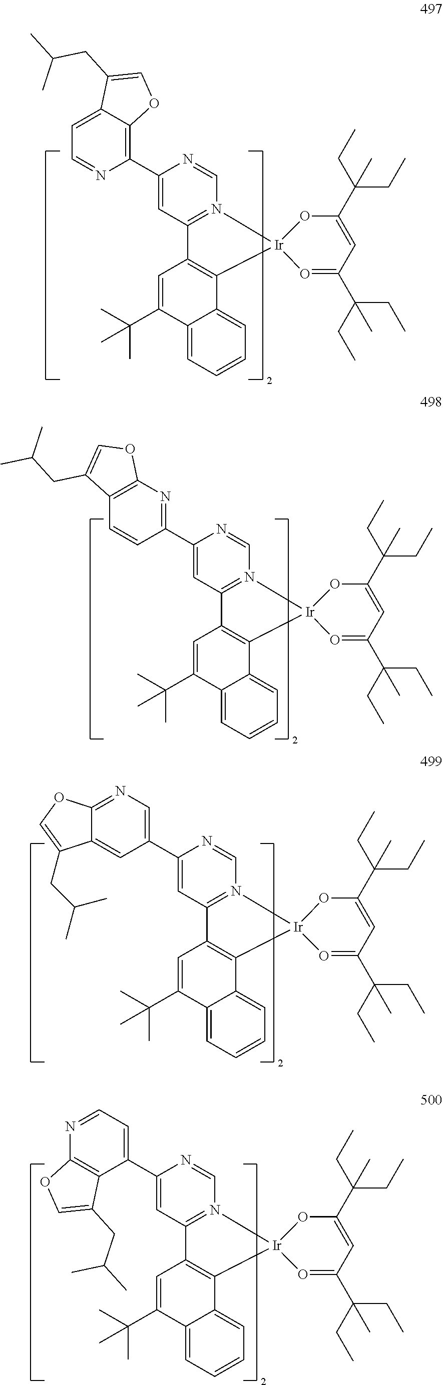

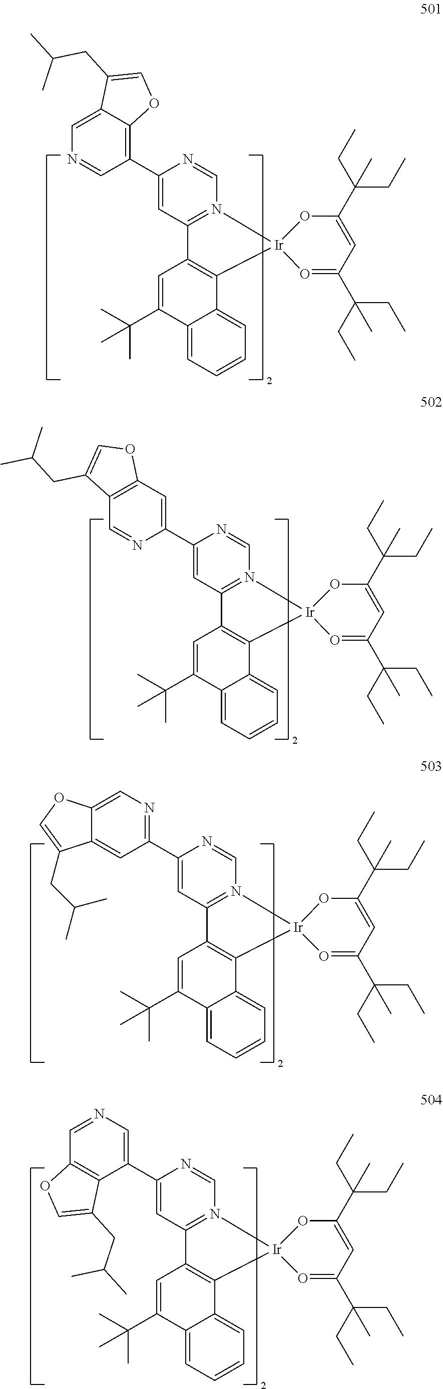

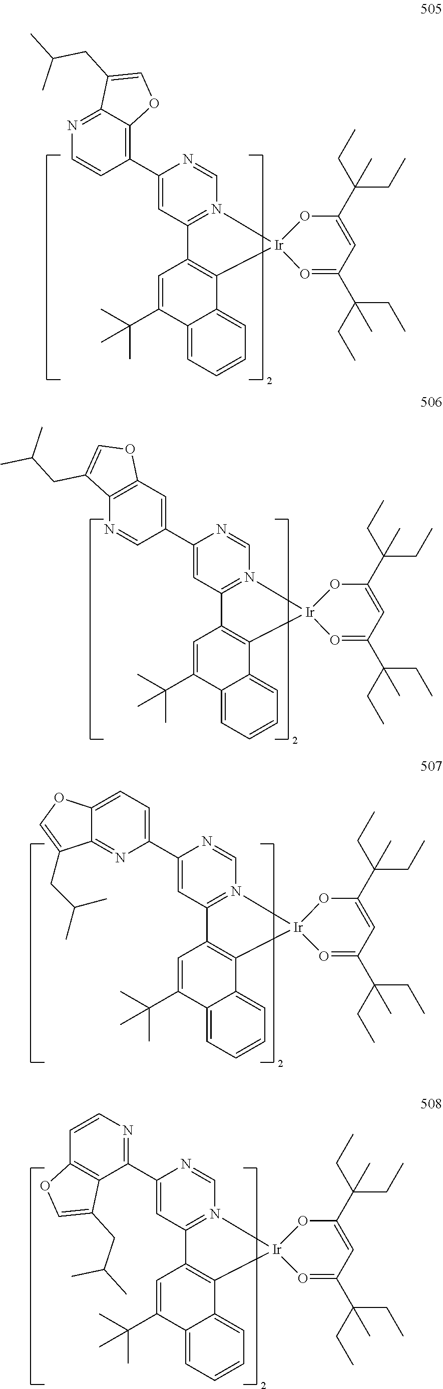

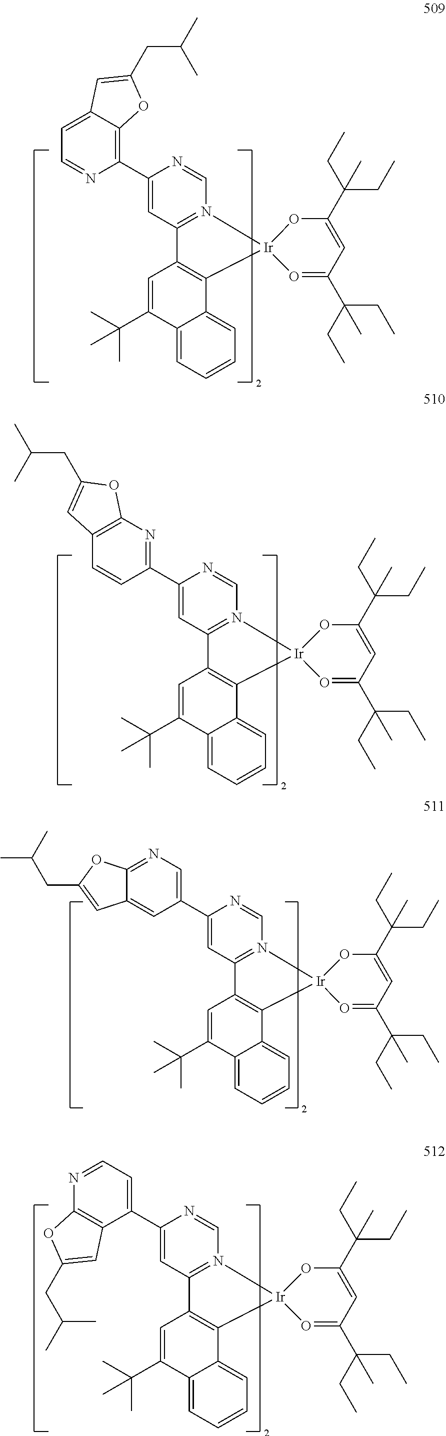

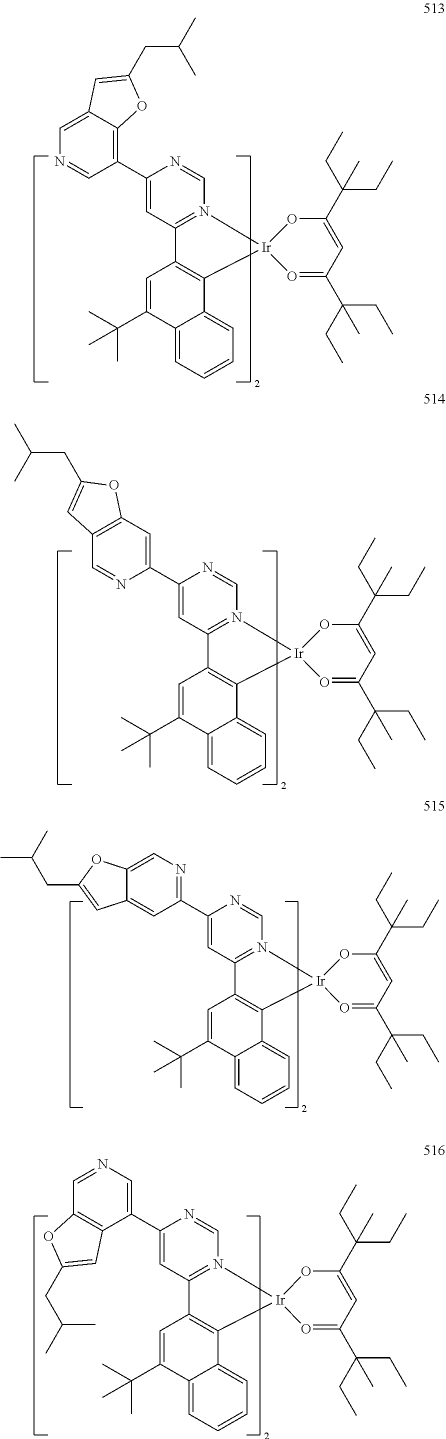

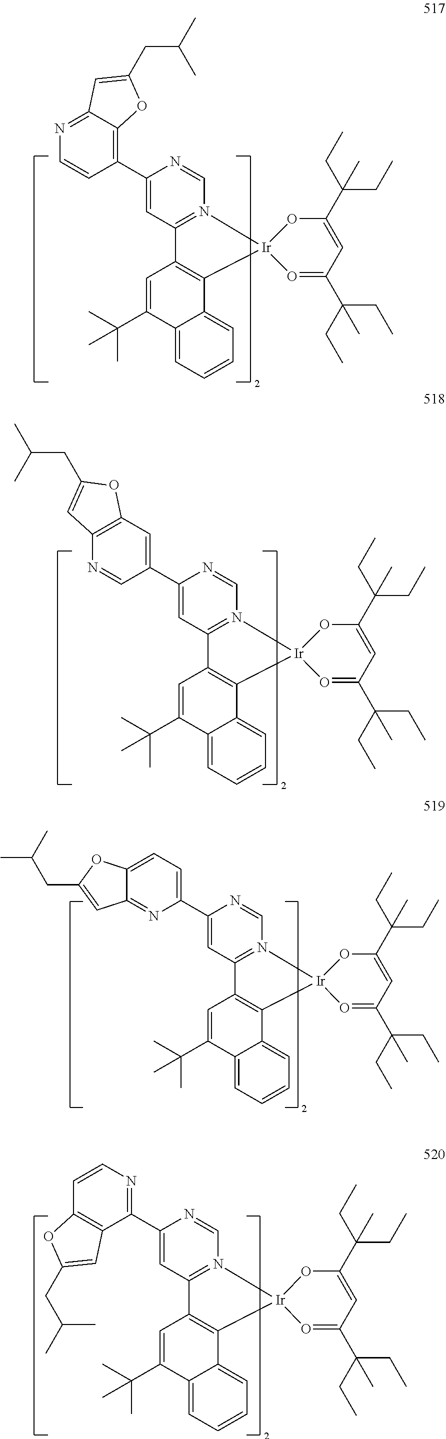

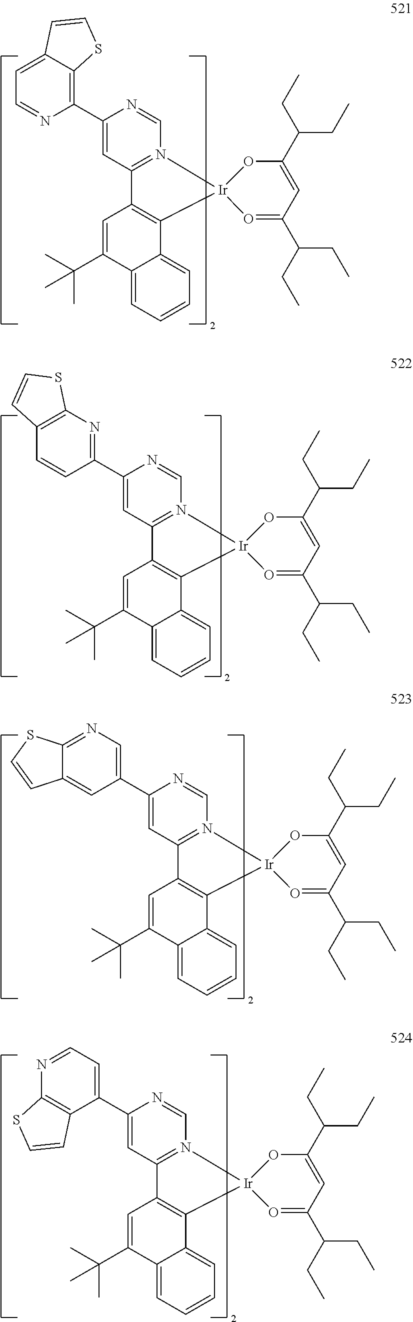

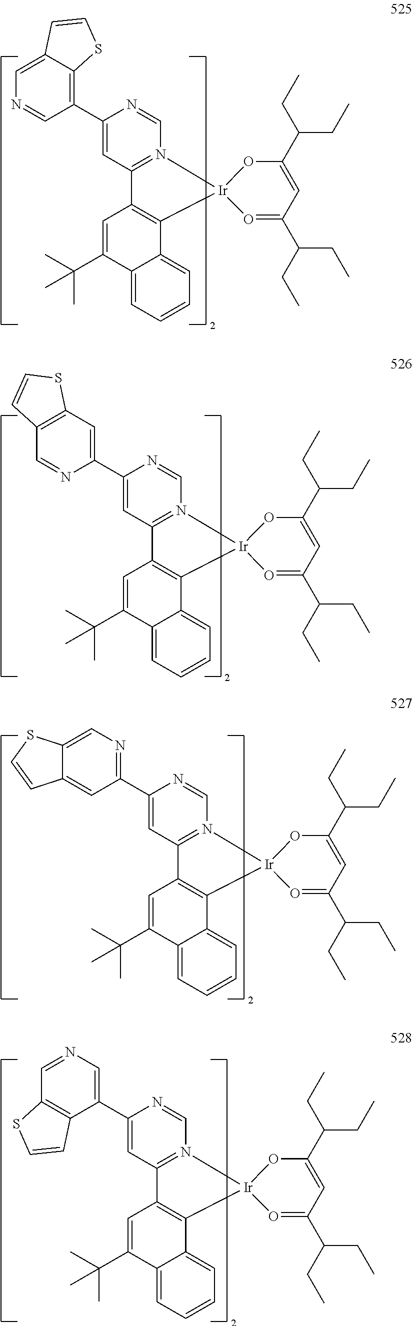

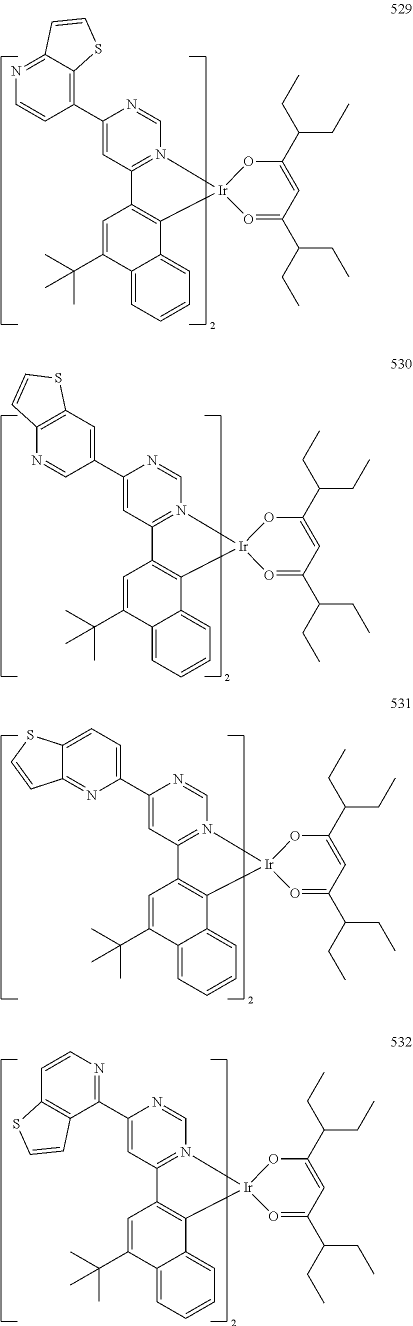

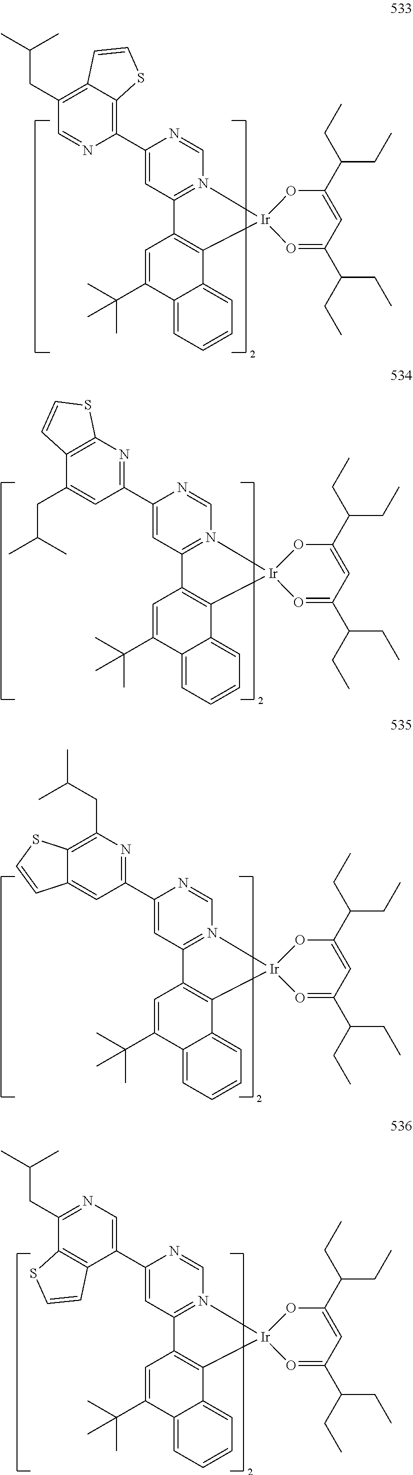

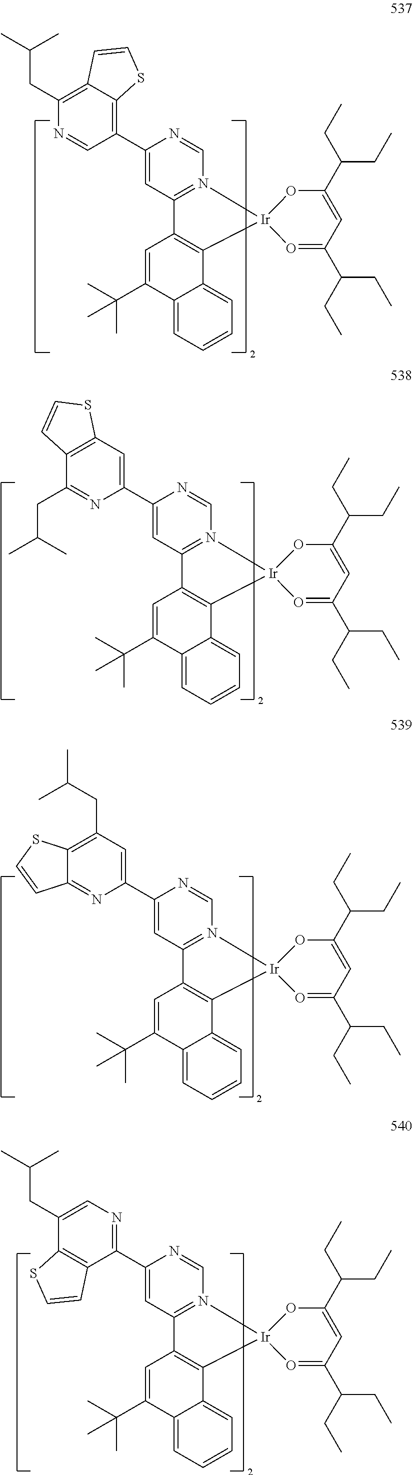

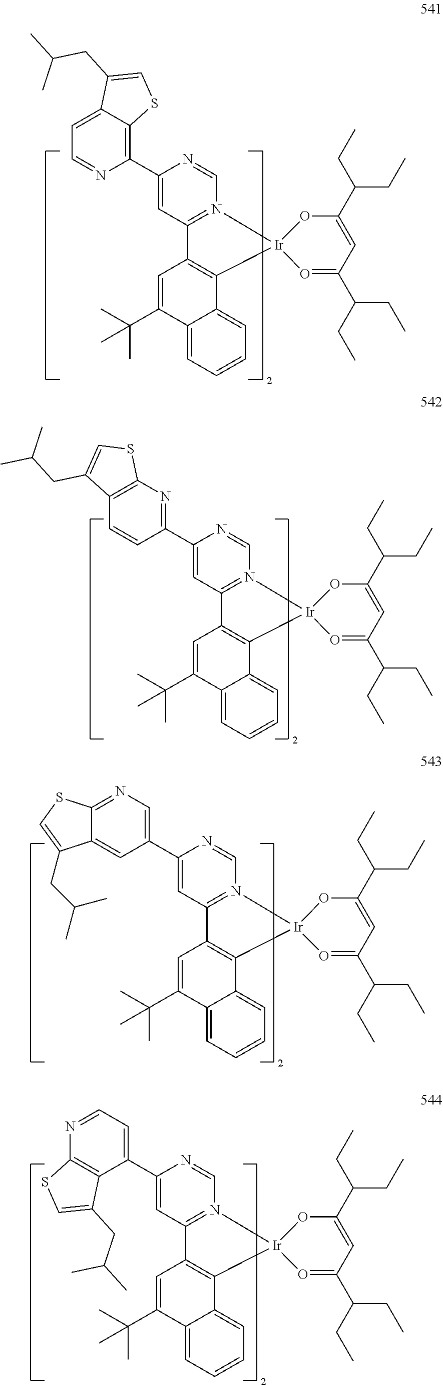

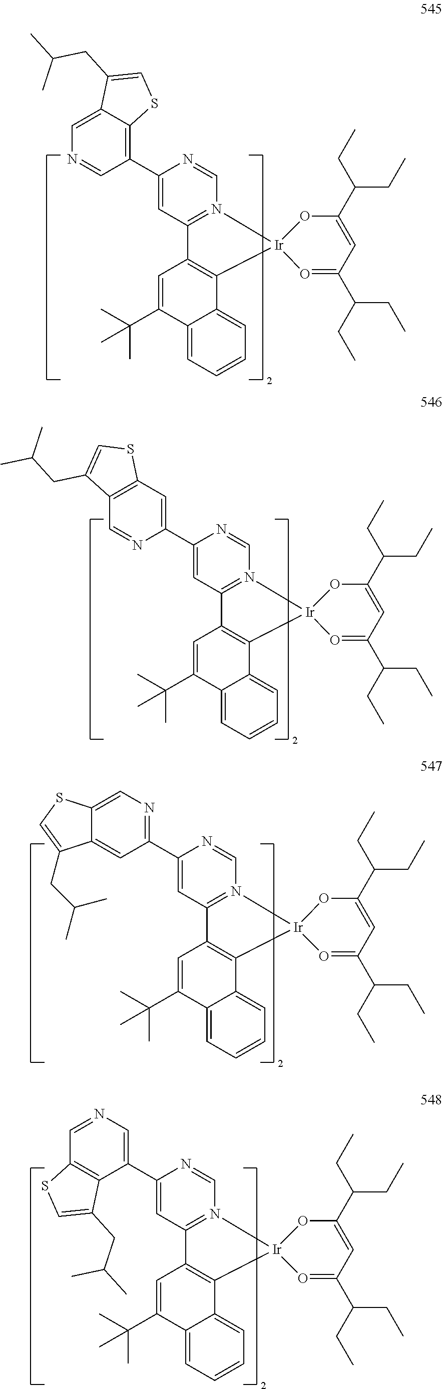

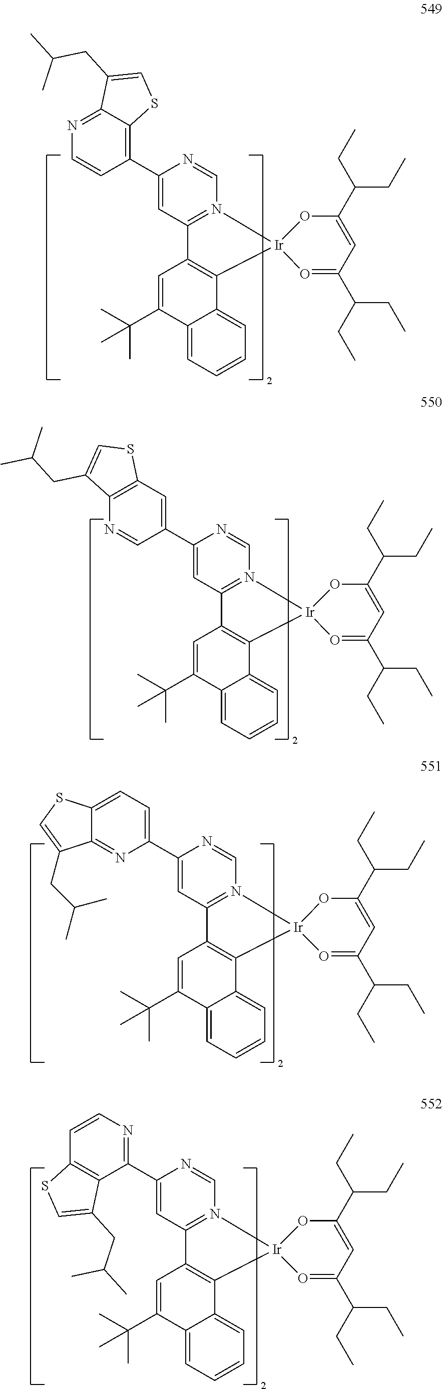

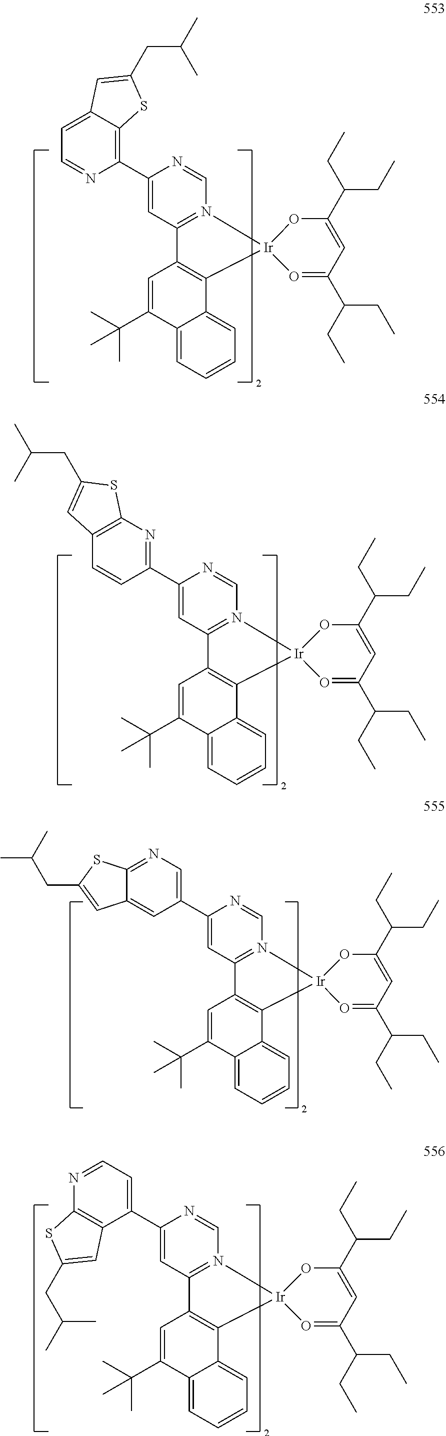

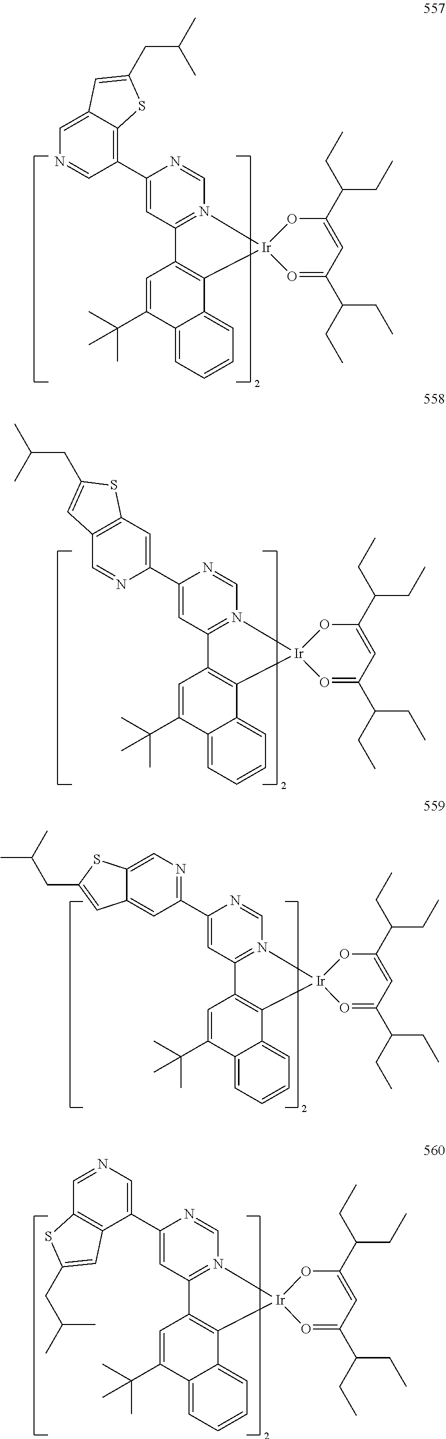

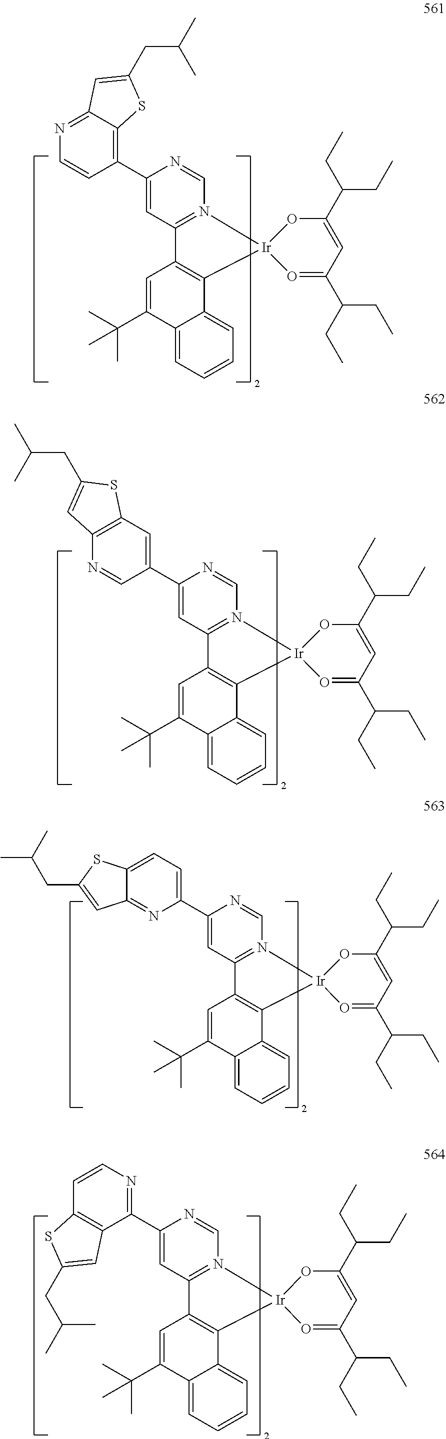

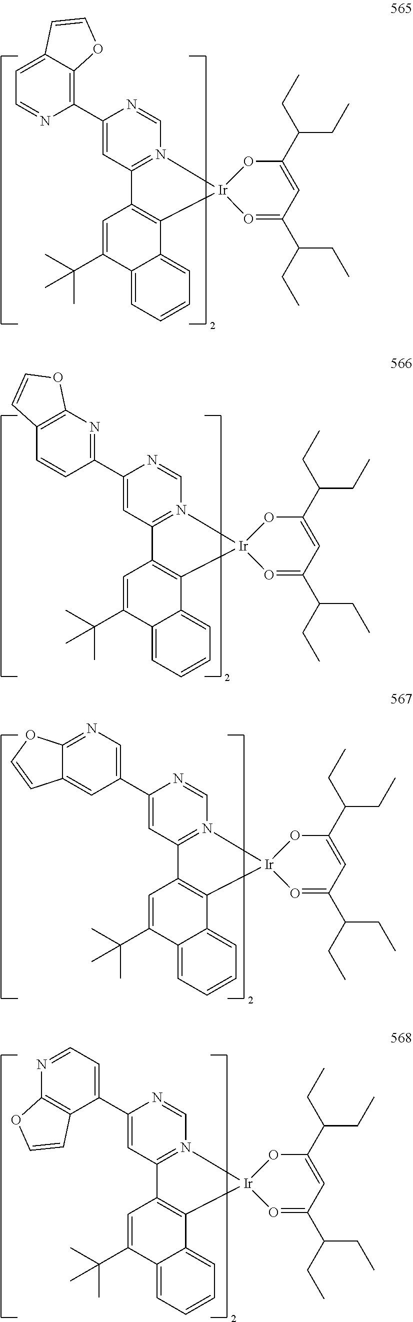

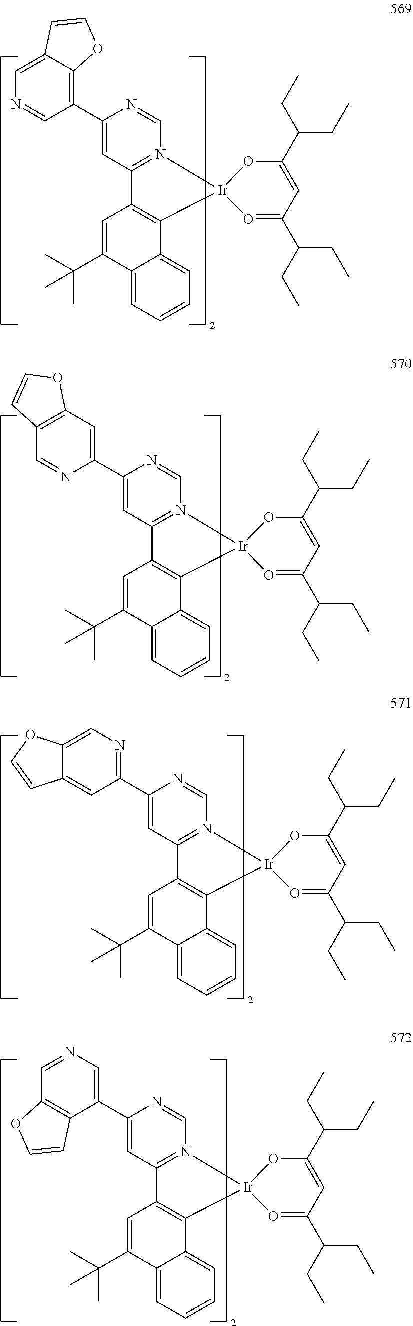

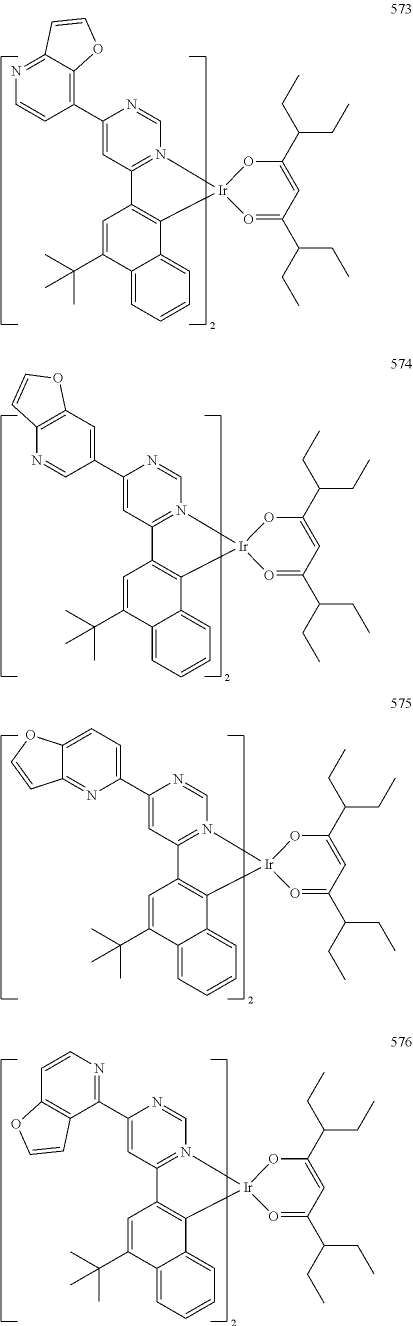

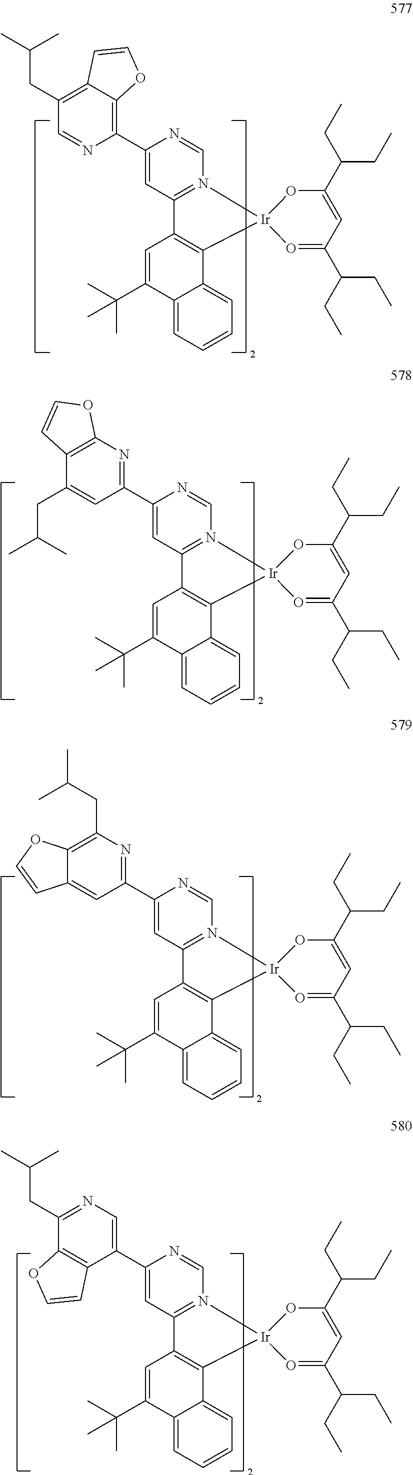

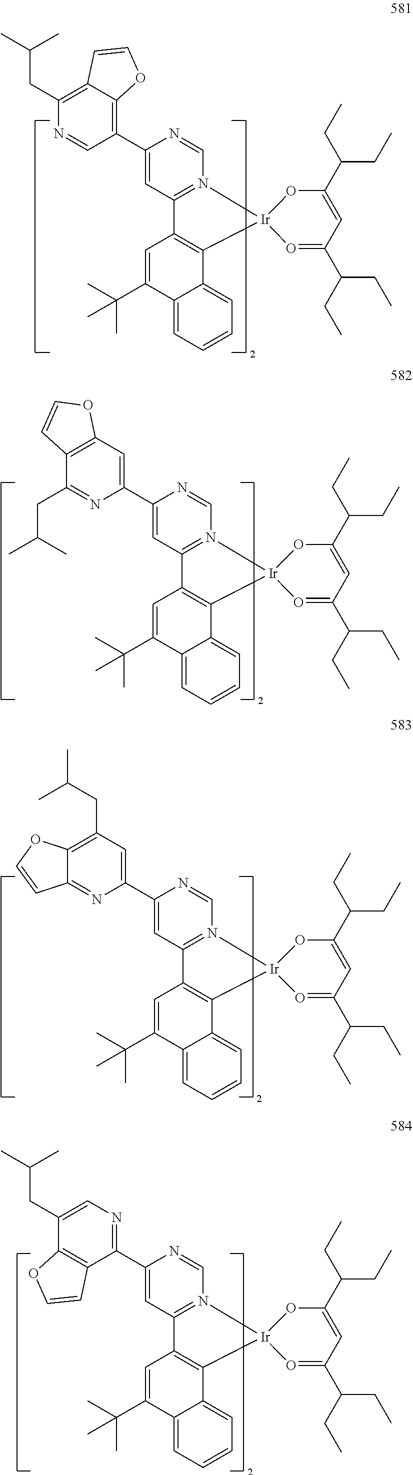

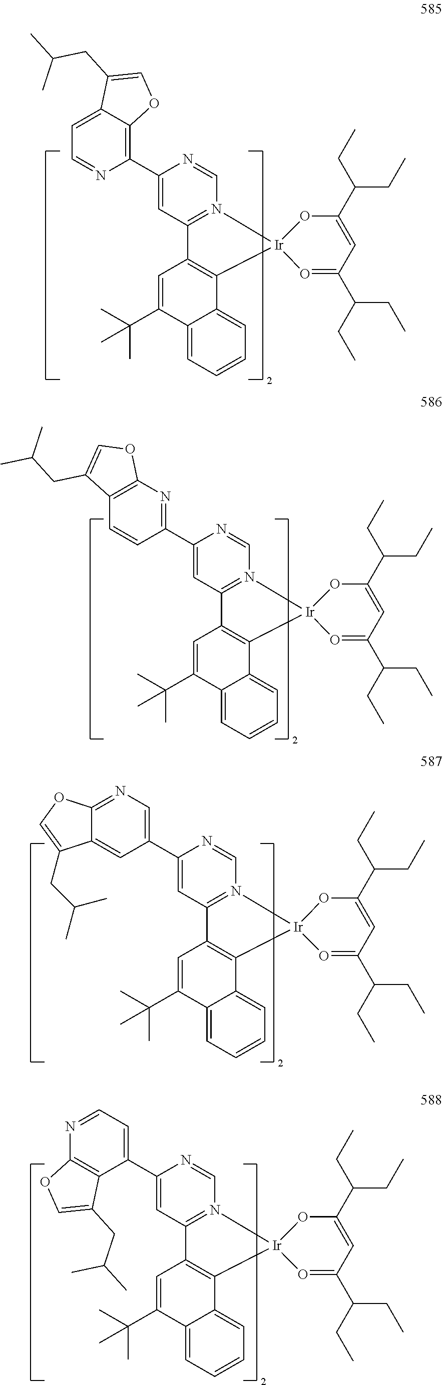

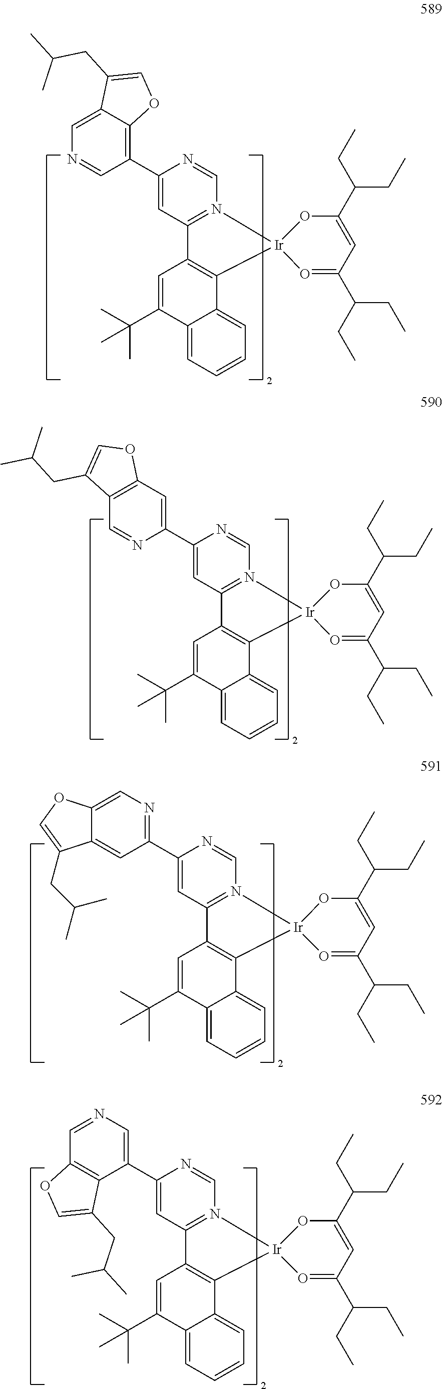

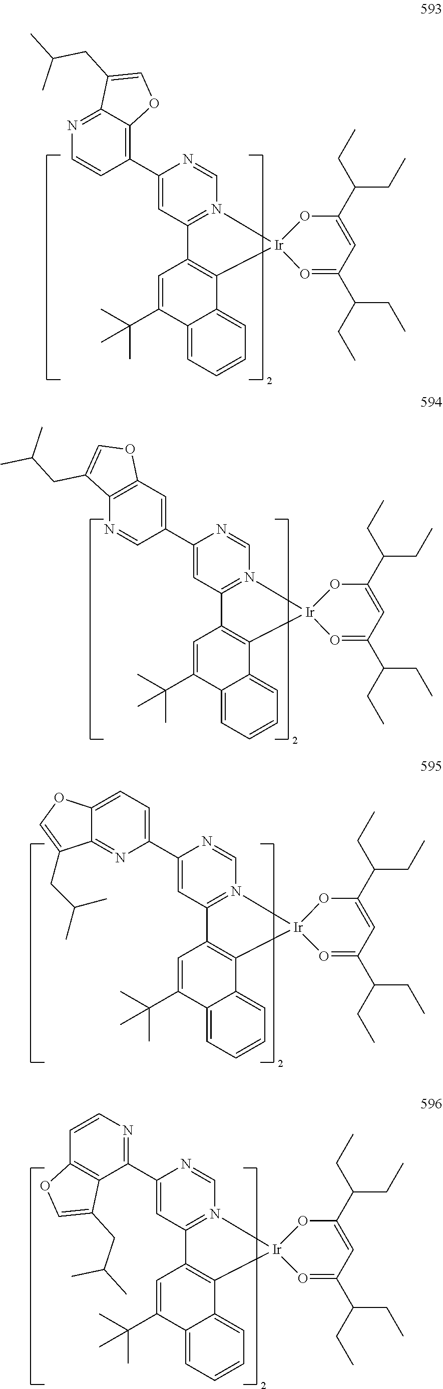

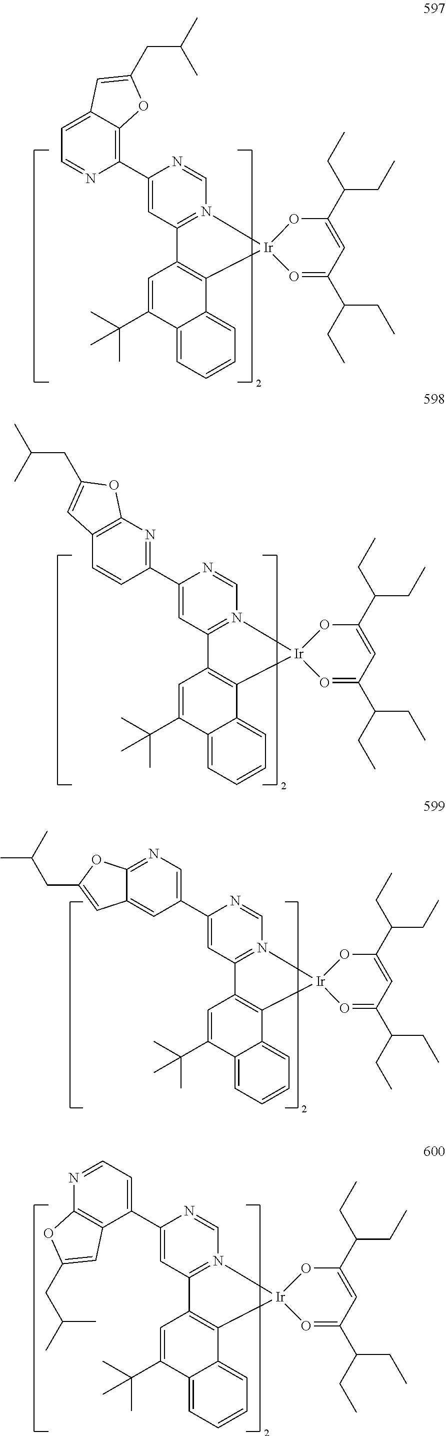

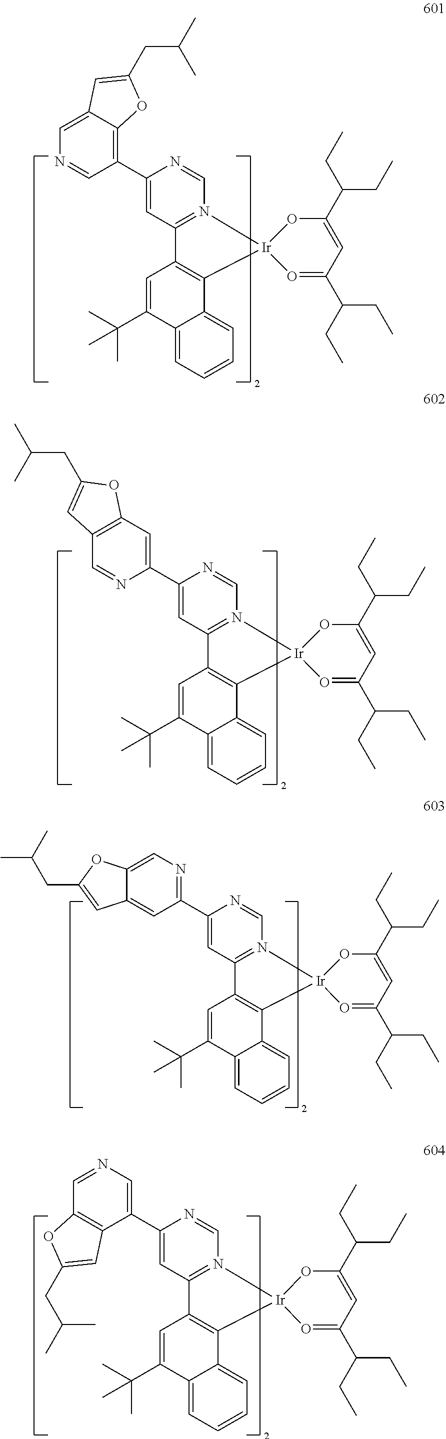

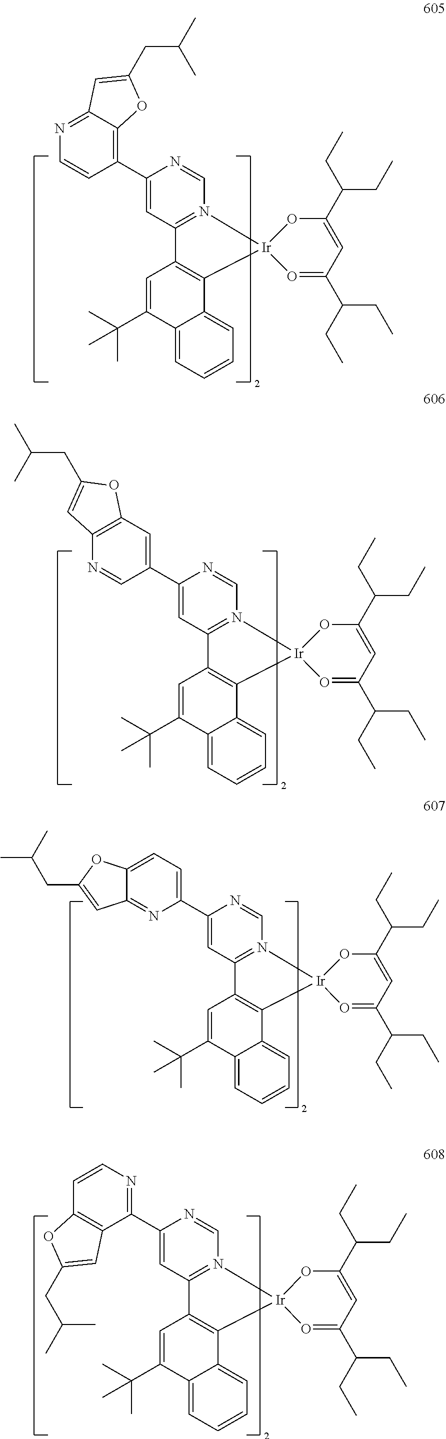

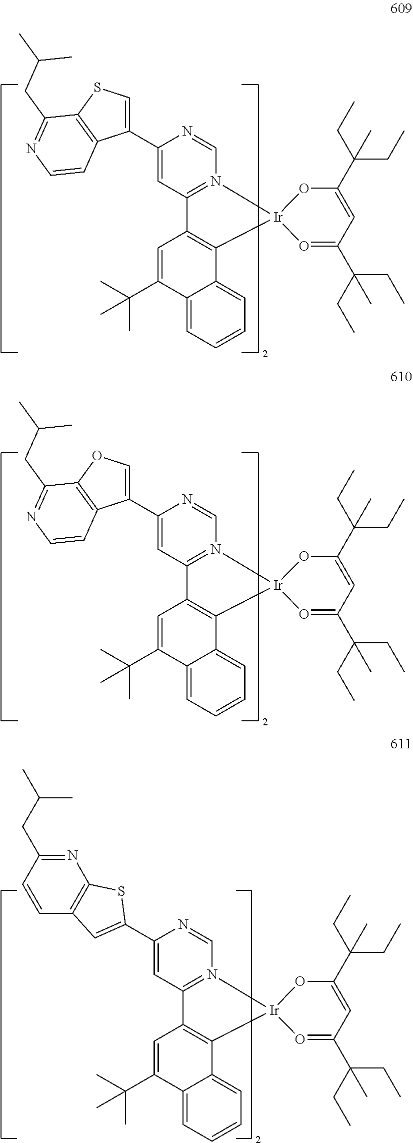

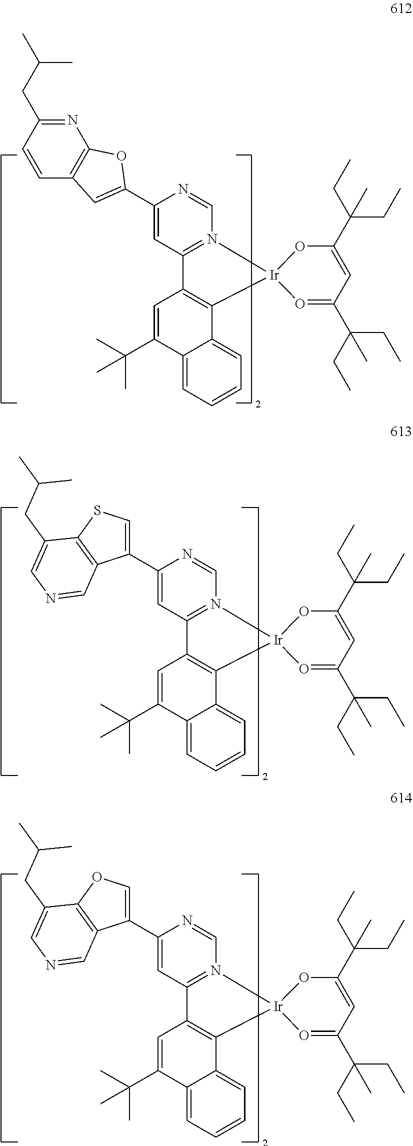

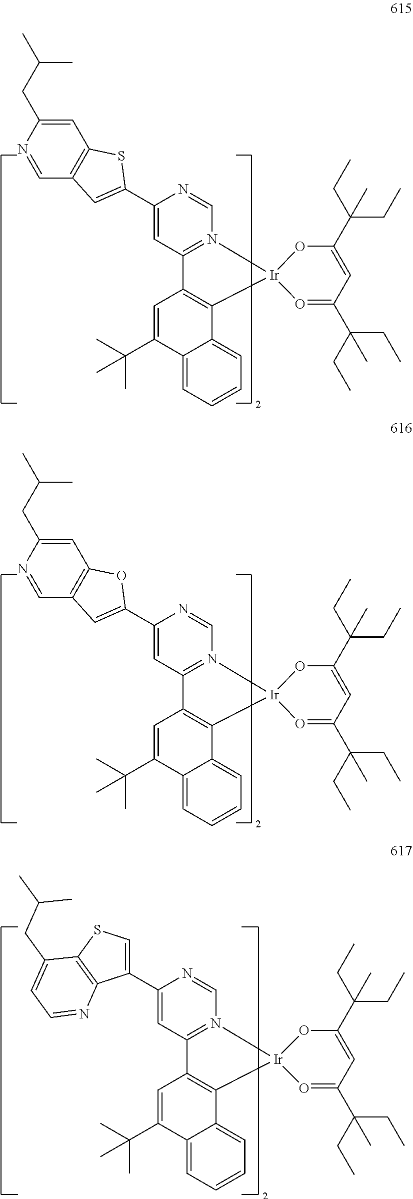

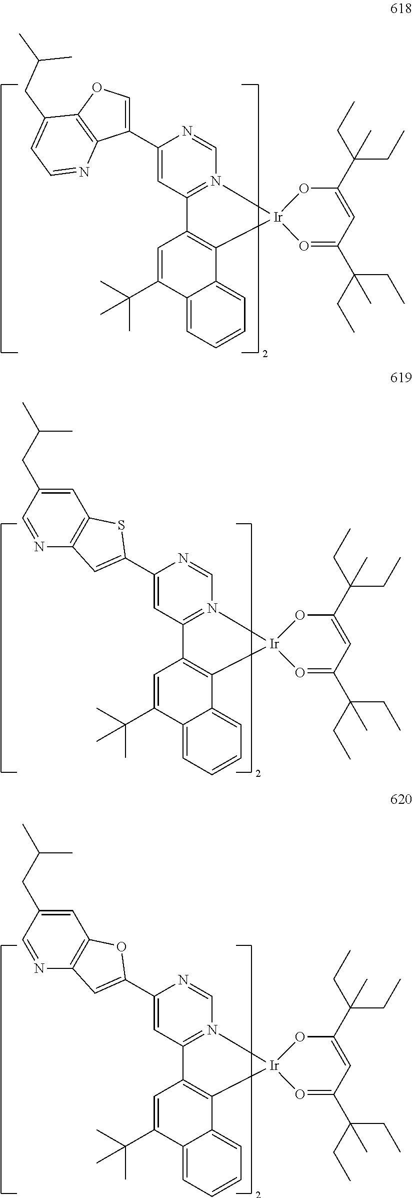

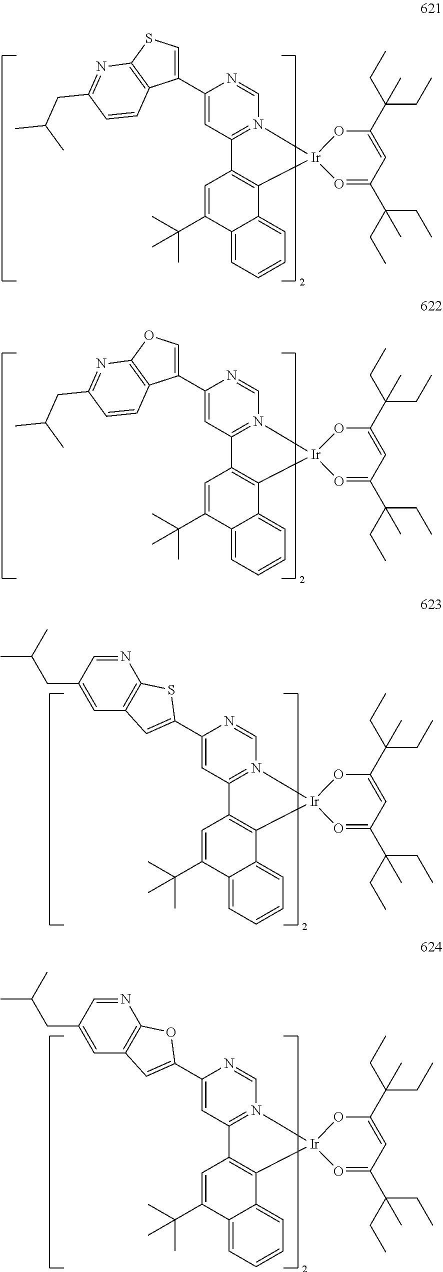

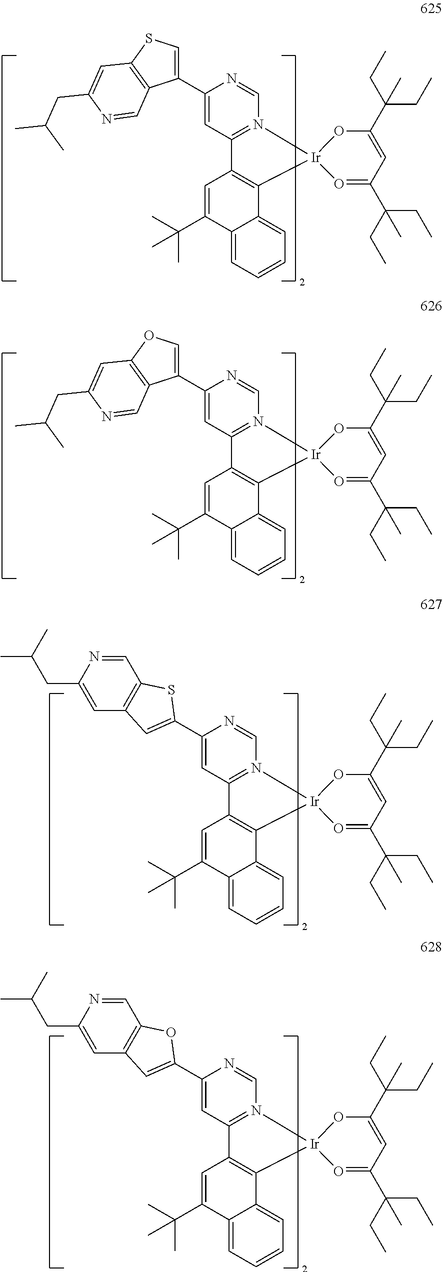

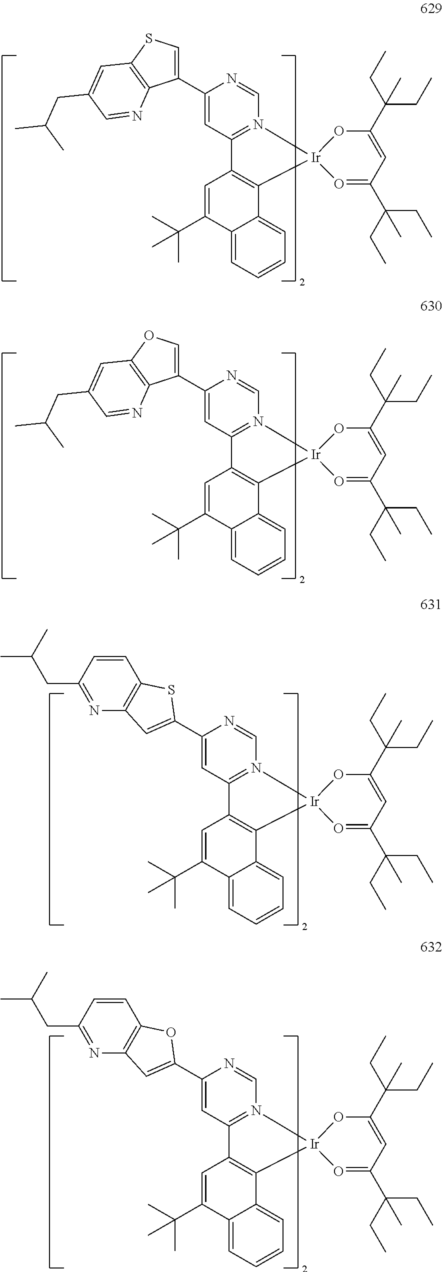

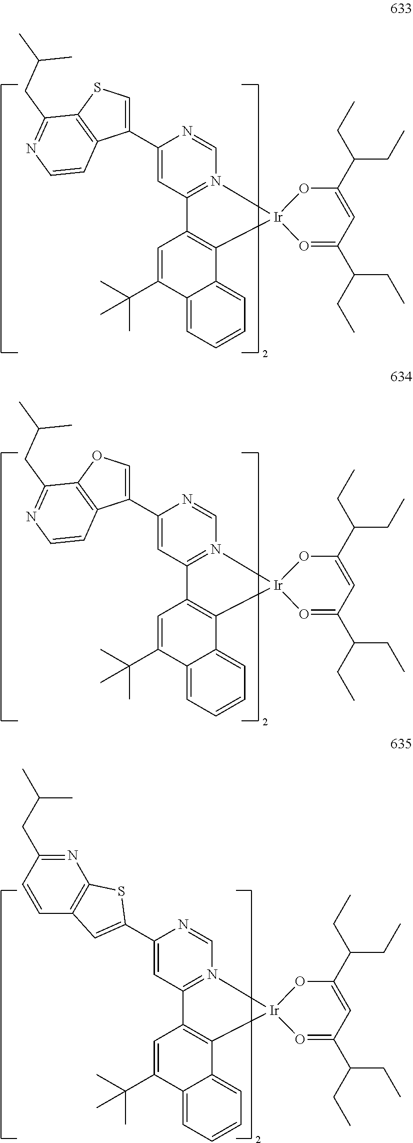

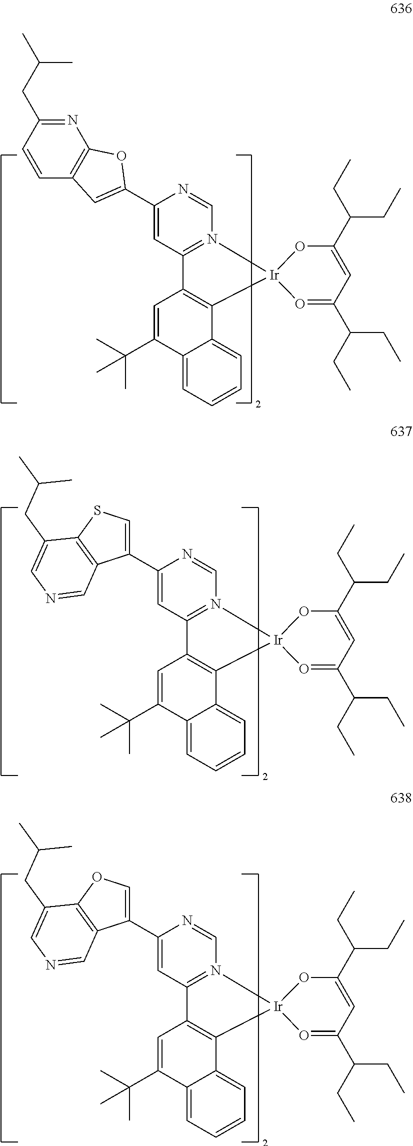

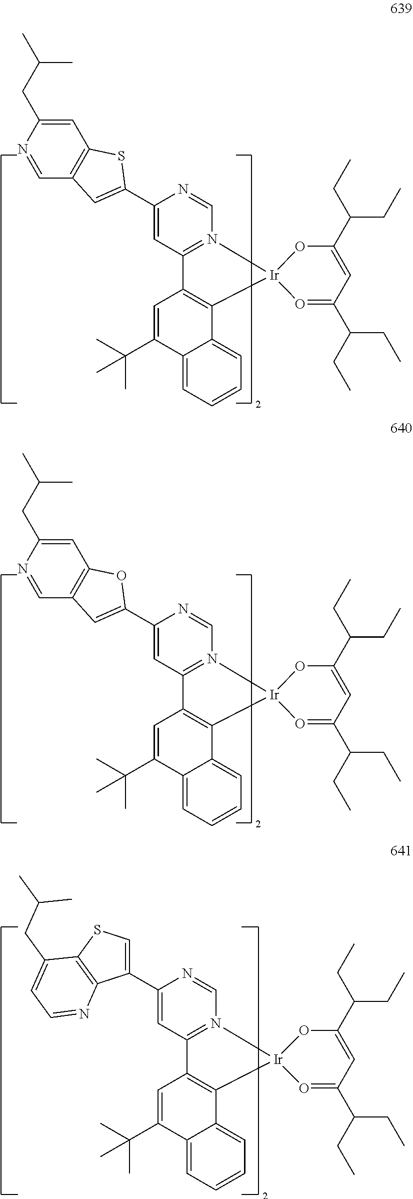

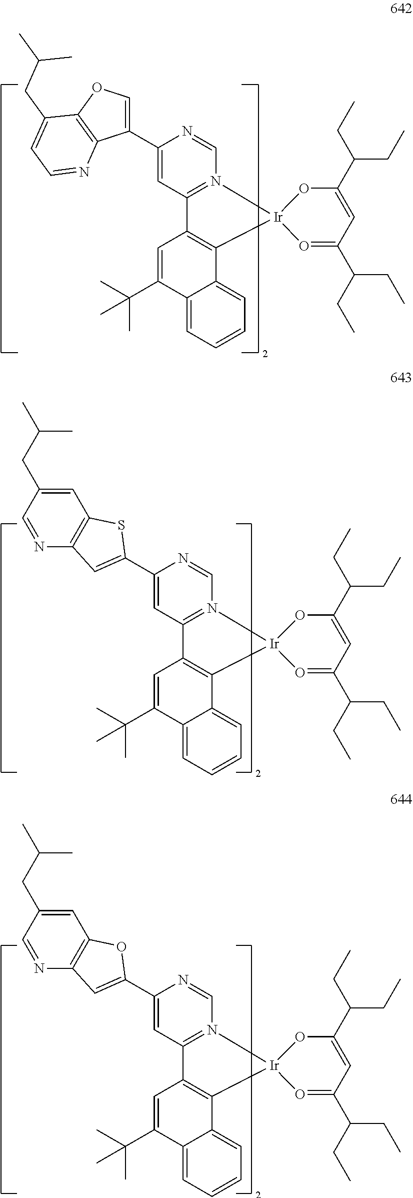

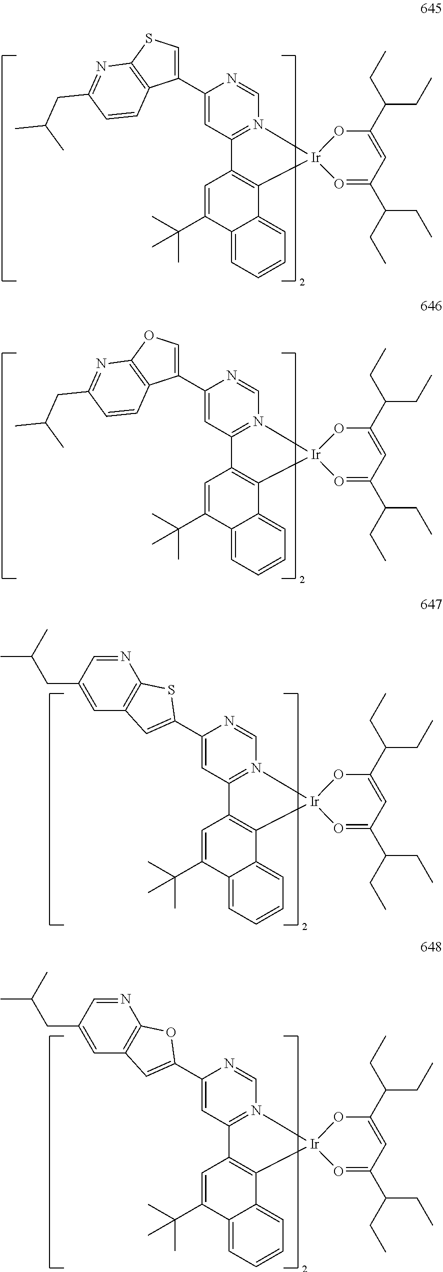

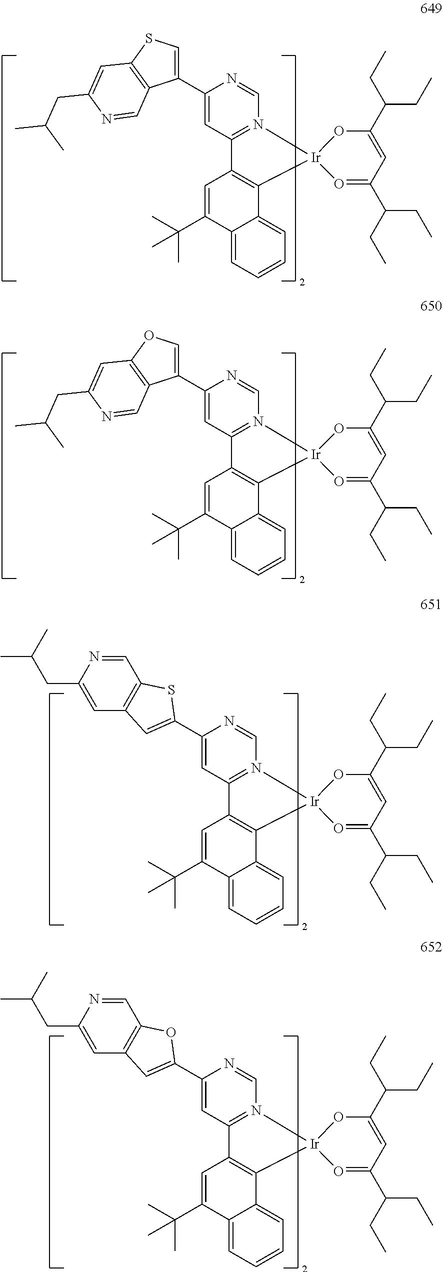

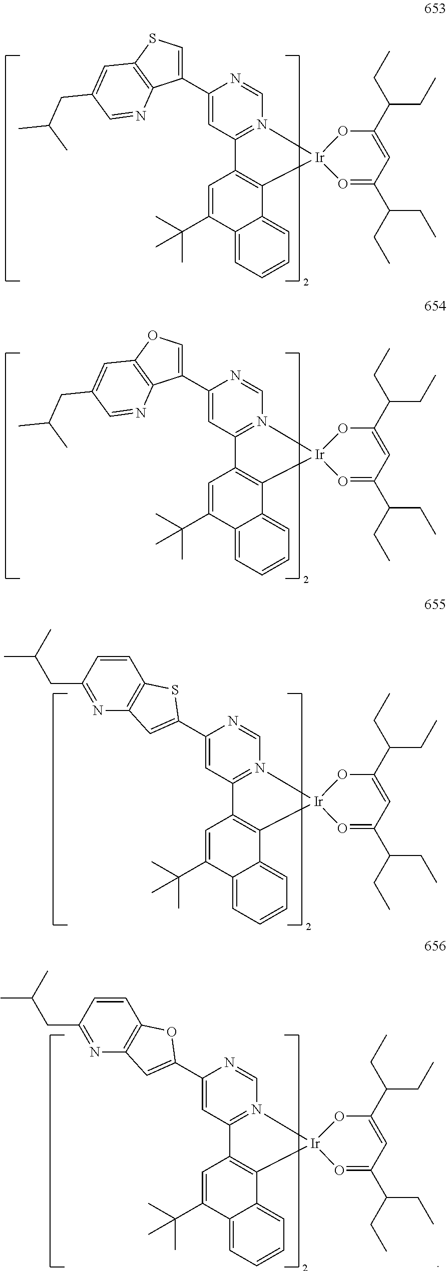

The organometallic compound having anyone of the structures of Chemical Formulae 1 to 13 includes at least one ligand with aromatic rings and/or fused hetero aromatic rings with fused ring system so that the compound has a rigid chemical conformation. The organometallic compound can improve its color purity and luminous lifespan because the compound has narrow FWHM and can maintain its stable chemical conformation in the emission process. In addition, since the organometallic compound can be a metal complex with bidentate ligands, it is possible to control the emission color purity and emission colors with ease. An organic light emitting diode has beneficial luminous efficiency by applying the organometallic compound having the structure of Chemical Formulae 1 to 13 into an emissive layer.

### [Organic Light Emitting Diode and Organic Light Emitting Device]

The luminous efficiency and/or the luminous lifespan of an organic light emitting diode where the organometallic compound having the structure of Chemical Formulae 1 to 13 is applied to an emissive layer can be improved. As an example, the emissive layer including the organometallic compound having the structure of Chemical Formulae 1 to 13 can be applied to an organic light emitting diode with a single emitting part in a red pixel region, a green pixel region and/or a blue pixel region. Alternatively, the emissive layer including the organometallic compound having the structure of Chemical Formulae 1 to 13 can be applied to an organic light emitting diode of having a tandem structure where at least two emitting parts are stacked.

The organic light emitting diode where an emissive layer includes the organometallic compound having the structure of Chemical Formulae 1 to 13 can be applied to an organic light emitting device such as an organic light emitting display device or an organic light emitting illumination device. As an example, an organic light emitting display device will be described.

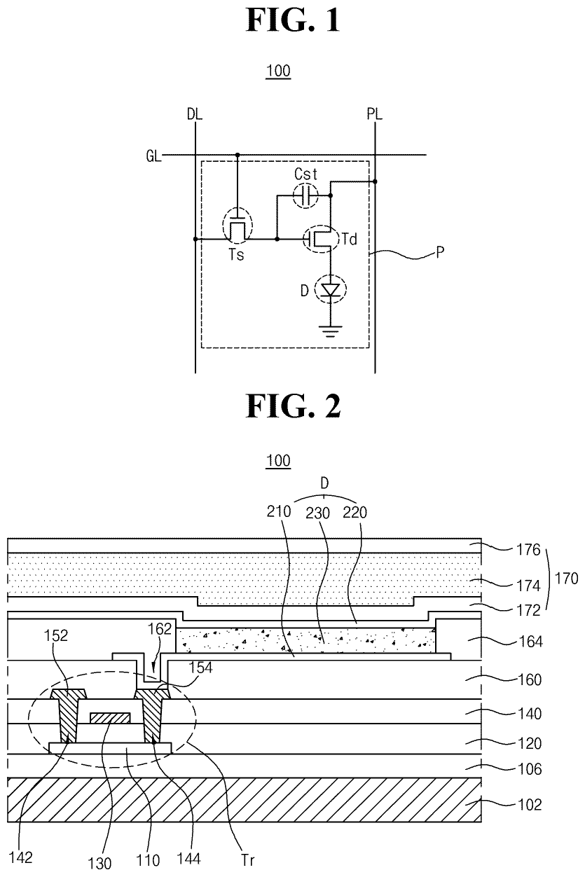

FIG. 1 illustrates a schematic circuit diagram of an organic light emitting display device in accordance with the present disclosure. As illustrated in FIG. 1, a gate line GL, a data line DL and power line PL, each of which crosses each other to define a pixel region P, in an organic light emitting display device 100. A switching thin film transistor Ts, a driving thin film transistor Td, a storage capacitor Cst and an organic light emitting diode D are disposed within the pixel region P. The pixel region P may include a red (R) pixel region, a green (G) pixel region and a blue (B) pixel region. However, embodiments of the present disclosure are not limited to such examples.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

The driving thin film transistor Td is turned on by the data signal applied to the gate electrode 130 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an example embodiment of the present disclosure. As illustrated in FIG. 2, the organic light emitting display device 100 includes a substrate 102, a thin-film transistor Tr on the substrate 102, and an organic light emitting diode D connected to the thin film transistor Tr.

As an example, the substrate 102 can include a red pixel region, a green pixel region and a blue pixel region and an organic light emitting diode D can be located in each pixel region. Each of the organic light emitting diodes D emitting red, green and blue light, respectively, is located correspondingly in the red pixel region, the green pixel region and the blue pixel region.

The substrate 102 can include, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 can be disposed on the substrate 102. The thin film transistor Tr can be disposed on the buffer layer 106. The buffer layer 106 can be omitted.

A semiconductor layer 110 is disposed on the buffer layer 106. In one example embodiment, the semiconductor layer 110 can include, but is not limited to, oxide semiconductor materials. In this case, a light-shield pattern may be disposed under the semiconductor layer 110, and the light-shield pattern can prevent light from being incident toward the semiconductor layer 110, and thereby, preventing or reducing the semiconductor layer 110 from being degraded by the light. Alternatively, the semiconductor layer 110 can include polycrystalline silicon. In this case, opposite edges of the semiconductor layer 110 can be doped with impurities.

A gate insulating layer 120 including an insulating material is disposed on the semiconductor layer 110. The gate insulating layer 120 can include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on a whole area of the substrate 102 as shown in FIG. 2, the gate insulating layer 120 may be patterned identically as the gate electrode 130.

An interlayer insulating layer 140 including an insulating material is disposed on the gate electrode 130 with and covers an entire surface of the substrate 102. The interlayer insulating layer 140 can include, but is not limited to, an inorganic insulating material such as silicon oxide (SiOₓ) or silicon nitride (SiNₓ), or an organic insulating material such as benzocyclobutene or photo-acryl.

The interlayer insulating layer 140 has first and second semiconductor layer contact holes 142 and 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 in FIG. 2. Alternatively, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can include amorphous silicon.

The gate line GL and the data line DL, which cross each other to define a pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr may further include a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the whole substrate 102. The passivation layer 160 has a flat top surface and a drain contact hole 162 that exposes or does not cover the drain electrode 154 of the thin film transistor Tr. While the drain contact hole 162 is disposed on the second semiconductor layer contact hole 144, it may be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

The first electrode 210 is disposed in each pixel region. The first electrode 210 can be an anode and include conductive material having relatively high work function value. For example, the first electrode 210 can include a transparent conductive oxide (TCO). More particularly, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or the like.

In one example embodiment, when the organic light emitting display device 100 is a bottom-emission type, the first electrode 210 can have a single-layered structure of the TCO. Alternatively, when the organic light emitting display device 100 is a top-emission type, a reflective electrode or a reflective layer may be disposed under the first electrode 210. For example, the reflective electrode or the reflective layer can include, but is not limited to, silver (Ag) or aluminum-palladium-copper (APC) alloy. In the OLED D of the top-emission type, the first electrode 210 can have a triple-layered structure of ITO/Ag/ITO or ITO/APC/ITO.

In addition, a bank layer 164 is disposed on the passivation layer 160 in order to cover edges of the first electrode 210. The bank layer 164 exposes or does not cover a center of the first electrode 210 corresponding to each pixel region. The bank layer 164 can be omitted.

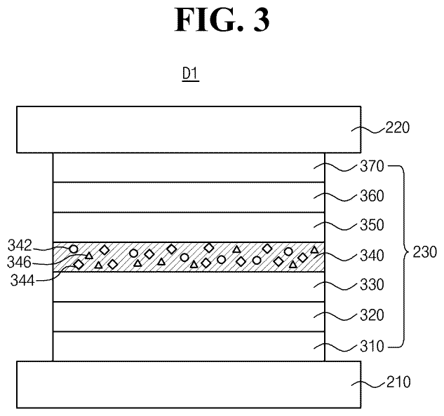

An emissive layer 230 is disposed on the first electrode 210. In one example embodiment, the emissive layer 230 can have a single-layered structure of an emitting material layer (EML). Alternatively, the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIG. 3). In one aspect, the emissive layer 230 can have a single emitting part. Alternatively, the emissive layer 230 can have multiple emitting parts to form a tandem structure. For example, the emissive layer 230 can be applied to an OLED with a single emitting part located each of the red pixel region, the green pixel region and the blue pixel region. Alternatively, the emissive layer 230 can be applied to a tandem-type OLED where at least two emitting parts are stacked.

The emissive layer 230 can include the organometallic compound having the structure of Chemical Formulae 1 to 13. The luminous efficiency and the luminous lifespan of the OLED D and the organic light emitting display device 100 can be improved by including the organometallic compound having the structure of Chemical Formulae 1 to 13.

The second electrode 220 is disposed on the substrate 102 above which the emissive layer 230 is disposed. The second electrode 220 can be disposed on a whole display area. The second electrode 220 can include a conductive material with a relatively low work function value compared to the first electrode 210. The second electrode 220 can be a cathode providing electrons. For example, the second electrode 220 can include at least one of, but is not limited to, aluminum (Al), magnesium (Mg), calcium (Ca), silver (Ag), alloy thereof and/or combinations thereof such as aluminum-magnesium alloy (Al—Mg). When the organic light emitting display device 100 is a top-emission type, the second electrode 220 is thin so as to have light-transmissive (semi-transmissive) property.

In addition, an encapsulation film 170 can be disposed on the second electrode 220 in order to prevent or reduce outer moisture from penetrating into the OLED D. The encapsulation film 170 can have, but is not limited to, a laminated structure of a first inorganic insulating film 172, an organic insulating film 174 and a second inorganic insulating film 176. The encapsulation film 170 can be omitted.

A polarizing plate can be attached onto the encapsulation film 170 to reduce reflection of external light. For example, the polarizing plate may be a circular polarizing plate. When the organic light emitting display device 100 is a bottom-emission type, the polarizing plate can be disposed under the substrate 102. Alternatively, when the organic light emitting display device 100 is a top-emission type, the polarizing plate can be disposed on the encapsulation film 170. In addition, a cover window can be attached to the encapsulation film 170 or the polarizing plate. In this case, the substrate 102 and the cover window may have a flexible property, thus the organic light emitting display device 100 may be a flexible display device.

The OLED D is described in more detail. FIG. 3 illustrates a schematic cross-sectional view of an organic light emitting diode having a single emitting part in accordance with an example embodiment of the present disclosure. As illustrated in FIG. 3, the organic light emitting diode (OLED) D1 in accordance with the present disclosure includes first and second electrodes 210 and 220 facing each other and an emissive layer 230 disposed between the first and second electrodes 210 and 220. The organic light emitting display device 100 includes a red pixel region, a green pixel region and a blue pixel region, and the OLED D1 can be disposed in the red pixel region and/or the green pixel region.

In an example embodiment, the emissive layer 230 includes an emitting material layer (EML) 340 disposed between the first and second electrodes 210 and 220. Also, the emissive layer 230 can include at least one of an HTL 320 disposed between the first electrode 210 and the EML 340 and an ETL 360 disposed between the second electrode 220 and the EML 340. In addition, the emissive layer 230 can further include at least one of an HIL 310 disposed between the first electrode 210 and the HTL 320 and an EIL 370 disposed between the second electrode 220 and the ETL 360. Alternatively, the emissive layer 230 can further comprise a first exciton blocking layer, i.e. an EBL 330 disposed between the HTL 320 and the EML 340 and/or a second exciton blocking layer, i.e. a HBL 350 disposed between the EML 340 and the ETL 360.

The first electrode 210 can be an anode that provides holes into the EML 340. The first electrode 210 can include a conductive material having a relatively high work function value, for example, a transparent conductive oxide (TCO). In an example embodiment, the first electrode 210 can include, but is not limited to, ITO, IZO, ITZO, SnO, ZnO, ICO, AZO, and the like.

The second electrode 220 can be a cathode that provides electrons into the EML 340. The second electrode 220 can include a conductive material having a relatively low work function values, i.e., a highly reflective material such as Al, Mg, Ca, Ag, and/or alloy thereof and/or combinations thereof such as Al—Mg.

The HIL 310 is disposed between the first electrode 210 and the HTL 320 and can improve an interface property between the inorganic first electrode 210 and the organic HTL 320. In one example embodiment, the HIL 310 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), N,N′-Bis{4-[bis(3-methylphenyl)amino]phenyl}-N,N′-diphenyl-4·4′-biphenyldiamine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB) and/or combinations thereof. The HIL 310 can be omitted in compliance of the OLED D1 property.

The HTL 320 is disposed adjacently to the EML 340 between the first electrode 210 and the EML 340. In one example embodiment, the HTL 320 can include, but is not limited to, N,N′-Diphenyl-N,N′-bis(3-methylphenyl)-1,1′-biphenyl-4,4′-diamine (TPD), NPB(NPD), DNTPD, 4,4′-bis(N-carbazolyl)-1,1′-biphenyl (CBP), Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), Di-[4-(N,N-di-p-tolyl-amino)-phenyl]cyclohexane (TAPC), 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine), N-([1,1′-Biphenyl]-4-yl)-9,9-dimethyl-N-(4-(9-phenyl-9H-carbazol-3-yl)phenyl)-9H-fluoren-2-amine and/or combinations thereof.

The EML 340 can include a dopant (emitter) 342 and a host 344 and/or 346. For example, the EML 340 can include the dopant 342 where ultimate light emission occurs, a first host 344 and a second host 346. The EML 340 can emit green to red color light, for example, yellow green to red color light. The dopant 342 can include the organometallic compound having the structure of Chemical Formulae 1 to 13.

The first host 344 can be a P-type host (hole-type host) with relatively beneficial hole affinity. As an example, the first host 344 can include, but is not limited to, a biscarbazole-based organic compound, an aryl amine- or a hetero aryl amine-based organic compound with at least one fused aromatic and/or fused hetero aromatic moiety, and/or an aryl amine- or a hetero aryl amine-based organic compound with a spirofluorene moiety.

The second host 346 can be an N-type host (electron-type host) with relatively beneficial electron affinity. As an example, the second host 346 can include, but is not limited to, an azine-based organic compound.

For example, the host 344 and/or 346 which can be used together with the dopant 344 can include, but is not limited to, 9-(3-(9H-carbazol-9-yl)phenyl)-9H-carbazole-3-carbonitrile (mCP-CN), CBP, 3,3′-bis(N-carbazolyl)-1,1′-biphenyl (mCBP), 1,3-Bis(carbazol-9-yl)benzene (mCP), Bis[2-(diphenylphosphino)phenyl]ether oxide (DPEPO), 2,8-bis(diphenylphosphoryl)dibenzothiophene (PPT), 1,3,5-Tri[(3-pyridyl)-phen-3-yl]benzene (TmPyPB), 2,6-Di(9H-carbazol-9-yl)pyridine (PYD-2Cz), 2,8-di(9H-carbazol-9-yl)dibenzothiophene (DCzDBT), 3′,5′-Di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), Diphenyl-4-triphenylsilyl-phenylphosphine oxide (TSPO1), 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-Diphenyl-9H,9′H-3,3′-bicarbazole (BCzPh), 1,3,5-Tris(carbazole-9-yl)benzene (TCP), TCTA, 4,4′-Bis(carbazole-9-yl)-2,2′-dimethylbiphenyl (CDBP), (2,7-Bis(carbazole-9-yl)-9,9-dimethylfluorene (DMFL-CBP), 2,2′,7,7′-Tetrakis(carbazole-9-yl)-9,9-spirofluorene (Spiro-CBP), 3,6-Bis(carbazole-9-yl)-9-(2-ethyl-hexyl)-9H-carbazole (TCzl) and/or combinations thereof.

The contents of the host 344 and/or 346 in the EML 340 can be about 50 wt % to about 99 wt %, for example, about 80 wt % to about 95 wt %, and the contents of the dopant 342 in the EML 340 can be about 1 wt % to about 50 wt %, for example, about 5 wt % to about 20 wt %, but is not limited thereto. When the EML 340 includes both the first host 344 and the second host 346, the first host 344 and the second host 346 can be admixed, but is not limited to, with a weight ratio of about 4:1 to about 1:4, for example about 3:1 to about 1:3. As an example, the EML 340 can have a thickness, but is not limited to, about 100 Å to about 500 Å.

The ETL 360 and the EIL 370 can be laminated sequentially between the EML 340 and the second electrode 220. An electron transporting material included in the ETL 360 has high electron mobility so as to provide electrons stably with the EML 340 by fast electron transportation.

The ETL 360 can include at least one of oxadiazole-based compounds, triazole-based compounds, phenanthroline-based compounds, benzoxazole-based compounds, benzothiazole-based compounds, benzimidazole-based compounds and triazine-based compounds.

More particularly, the ETL 360 can include, but is not limited to, tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-Tris(N-phenylbenzimidazol-2-yl)benzene (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), TSPO1, 2-[4-(9,10-Di-2-naphthalen2-yl-2-anthracen-2-yl)phenyl]-1-phenyl-1H-benzimidazole (ZADN) and/or combinations thereof.

The EIL 370 is disposed between the second electrode 220 and the ETL 360, and can improve physical properties of the second electrode 220 and therefore, can enhance the lifespan of the OLED D1. In one example embodiment, the EIL 370 can include, but is not limited to, an alkali metal halide or an alkaline earth metal halide such as LiF, CsF, NaF, BaF₂ and the like, and/or an organometallic compound such as Liq, lithium benzoate, sodium stearate, and the like. Alternatively, the EIL 370 can be omitted.

When holes are transferred to the second electrode 220 via the EML 340 and/or electrons are transferred to the first electrode 210 via the EML 340, the OLED D1 can have short lifespan and reduced luminous efficiency. In order to prevent those phenomena, the OLED D1 in accordance with this aspect of the present disclosure can have at least one exciton blocking layer adjacent to the EML 340.

As an example, the OLED D1 can include the EBL 330 between the HTL 320 and the EML 340 so as to control and prevent electron transfers. In one example embodiment, the EBL 330 can include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, 1,3-Bis(carbazol-9-yl)benzene (mCP), 3,3-Di(9H-carbazol-9-yl)biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, 2,8-bis(9-phenyl-9H-carbazol-3-yl)dibenzo[b,d]thiophene and/or combinations thereof.

In addition, the OLED D1 can further include the HBL 350 as a second exciton blocking layer between the EML 340 and the ETL 360 so that holes cannot be transferred from the EML 340 to the ETL 360. In one example embodiment, the HBL 350 can include, but is not limited to, at least one of oxadiazole-based compounds, triazole-based compounds, phenanthroline-based compounds, benzoxazole-based compounds, benzothiazole-based compounds, benzimidazole-based compounds, and triazine-based compounds.

For example, the HBL 350 can include material having a relatively low HOMO energy level compared to the luminescent materials in EML 340. The HBL 350 can include, but is not limited to, BCP, BAlq, Alq₃, PBD, spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole, TSPO1 and/or combinations thereof.

As described above, the EML 340 includes a host 346 and/or 344 and a dopant 342 that includes the organometallic compound having the structure of Chemical Formulae 1 to 13. The organometallic compound having the structure of Chemical Formulae 1 to 13 has very narrow FWHM. The organometallic compound has very rigid chemical conformation, so that its chemical conformation can be maintained in the luminous process, and therefore, its color purity and luminous lifespan can be improved. It is possible to adjust luminous colors by modifying the structure of the ligand and/or the groups substituted to the ligands. Accordingly, the OLED D1 including the organometallic compound can have beneficial luminous efficiency and luminous lifespan.

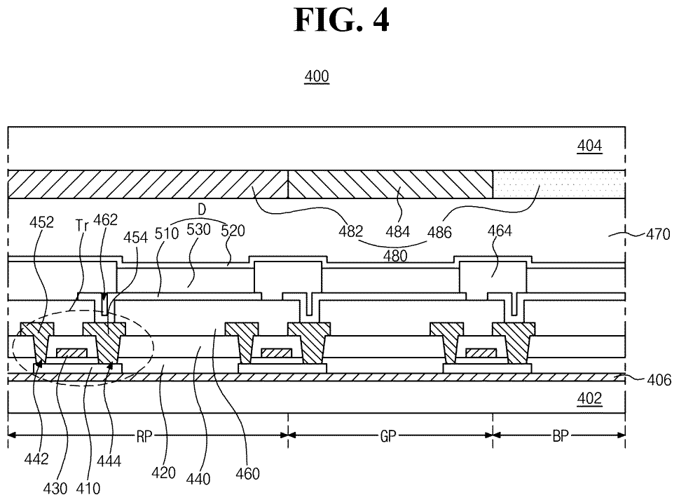

The organic light emitting device and the OLED D1 with a single emitting part and emitting red to green color light is shown in FIGS. 2 and 3. In another example embodiment, an organic light emitting display device can implement full-color including white color. FIG. 4 illustrates a schematic cross-sectional view of an organic light emitting display device in accordance with another example embodiment of the present disclosure.

As illustrated in FIG. 4, the organic light emitting display device 400 includes a first substrate 402 that defines each of a red pixel region RP, a green pixel region GP and a blue pixel region BP, a second substrate 404 facing the first substrate 402, a thin film transistor Tr on the first substrate 402, an OLED D disposed between the first and second substrates 402 and 404 and emitting white (W) light and a color filter layer 480 disposed between the OLED D and the second substrate 404.

Each of the first and second substrates 402 and 404 can include, but is not limited to, glass, flexible material and/or polymer plastics. For example, each of the first and second substrates 402 and 404 can be made of PI, PES, PEN, PET, PC and/or combinations thereof. The second substrate 404 can be omitted. The first substrate 402, on which a thin film transistor Tr and the OLED D are arranged, forms an array substrate.

A buffer layer 406 can be disposed on the first substrate 402. The thin film transistor Tr is disposed on the buffer layer 406 correspondingly to each of the red pixel region RP, the green pixel region GP and the blue pixel region BP. The buffer layer 406 can be omitted.

A semiconductor layer 410 is disposed on the buffer layer 406. The semiconductor layer 410 can be made of or include oxide semiconductor material or polycrystalline silicon.

A gate insulating layer 420 including an insulating material, for example, inorganic insulating material such as silicon oxide (SiOₓ, wherein 0<x≤2) or silicon nitride (SiNₓ, wherein 0<x≤2) is disposed on the semiconductor layer 410.

A gate electrode 430 made of a conductive material such as a metal is disposed over the gate insulating layer 420 so as to correspond to a center of the semiconductor layer 410. An interlayer insulating layer 440 including an insulating material, for example, inorganic insulating material such as SiOₓ or SiNₓ, or an organic insulating material such as benzocyclobutene or photo-acryl, is disposed on the gate electrode 430.

The interlayer insulating layer 440 has first and second semiconductor layer contact holes 442 and 444 that expose or do not cover a portion of the surface nearer to the opposing ends than to a center of the semiconductor layer 410. The first and second semiconductor layer contact holes 442 and 444 are disposed on opposite sides of the gate electrode 430 with spacing apart from the gate electrode 430.

A source electrode 452 and a drain electrode 454, which are made of or include a conductive material such as a metal, are disposed on the interlayer insulating layer 440. The source electrode 452 and the drain electrode 454 are spaced apart from each other with respect to the gate electrode 430. The source electrode 452 and the drain electrode 454 contact both sides of the semiconductor layer 410 through the first and second semiconductor layer contact holes 442 and 444, respectively.

The semiconductor layer 410, the gate electrode 430, the source electrode 452 and the drain electrode 454 constitute the thin film transistor Tr, which acts as a driving element.

Although not shown in FIG. 4, the gate line GL and the data line DL, which cross each other to define the pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL, and the thin film transistor Tr can further include the storage capacitor Cst configured to constantly keep a voltage of the gate electrode 430 for one frame.

A passivation layer 460 is disposed on the source electrode 452 and the drain electrode 454 and covers the thin film transistor Tr over the whole first substrate 402. The passivation layer 460 has a drain contact hole 462 that exposes or does not cover the drain electrode 454 of the thin film transistor Tr.

The OLED D is located on the passivation layer 460. The OLED D includes a first electrode 510 that is connected to the drain electrode 454 of the thin film transistor Tr, a second electrode 520 facing the first electrode 510 and an emissive layer 530 disposed between the first and second electrodes 510 and 520.

The first electrode 510 formed for each pixel region RP, GP or BP can be an anode and can include a conductive material having relatively high work function value. For example, the first electrode 510 can include, but is not limited to, ITO, IZO, ITZO, SnO, ZnO, ICO, AZO, and/or the like. Alternatively, a reflective electrode or a reflective layer can be disposed under the first electrode 510. For example, the reflective electrode or the reflective layer can include, but is not limited to, Ag or APC alloy.

A bank layer 464 is disposed on the passivation layer 460 in order to cover edges of the first electrode 510. The bank layer 464 exposes or does not cover a center of the first electrode 510 corresponding to each of the red pixel RP, the green pixel GP and the blue pixel BP. The bank layer 464 can be omitted.

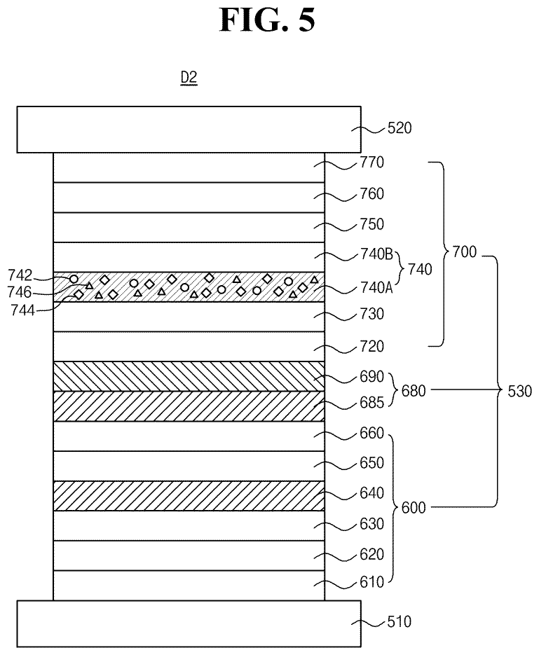

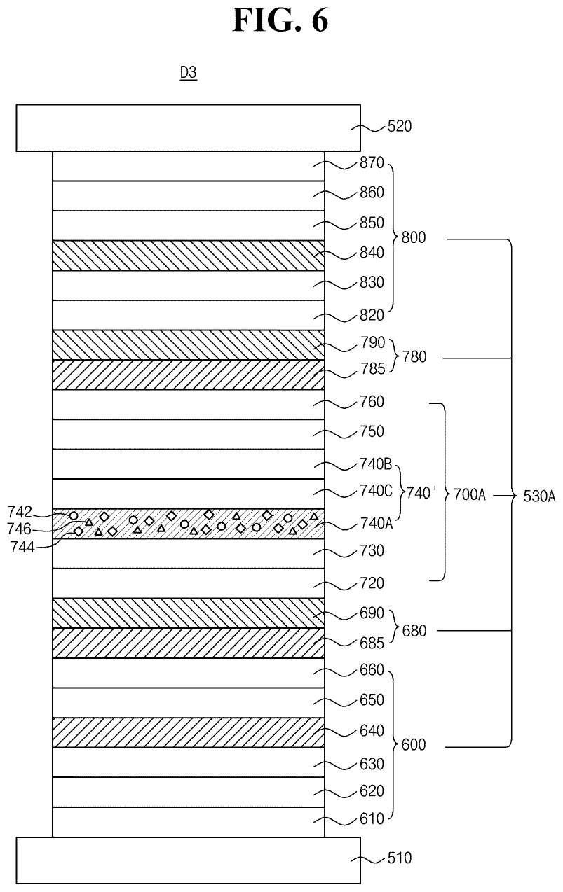

An emissive layer 530 that can include multiple emitting parts is disposed on the first electrode 510. As illustrated in FIGS. 5 and 6, the emissive layer 530 can include multiple emitting parts 600, 700, 700A, and 800 and at least one charge generation layer 680 and 780. Each of the emitting parts 600, 700, 700A and 800 includes at least one emitting material layer and can further include an HIL, an HTL, an EBL, an HBL, an ETL and/or an EIL.

The second electrode 520 can be disposed on the first substrate 402 above which the emissive layer 530 can be disposed. The second electrode 520 can be disposed over a whole display area, can include a conductive material with a relatively low work function value compared to the first electrode 510, and can be a cathode. For example, the second electrode 520 can include, but is not limited to, Al, Mg, Ca, Ag, alloy thereof, and/or combinations thereof such as Al—Mg.

Since the light emitted from the emissive layer 530 is incident to the color filter layer 480 through the second electrode 520 in the organic light emitting display device 400 in accordance with the second embodiment of the present disclosure, the second electrode 520 has a thin thickness so that the light can be transmitted.

The color filter layer 480 is disposed on the OLED D and includes a red color filter pattern 482, a green color filter pattern 484 and a blue color filter pattern 486 each of which is disposed correspondingly to the red pixel RP, the green pixel GP and the blue pixel BP, respectively. Although not shown in FIG. 4, the color filter layer 480 can be attached to the OLED D through an adhesive layer. Alternatively, the color filter layer 480 can be disposed directly on the OLED D.

In addition, an encapsulation film 470 can be disposed on the second electrode 520 in order to prevent or reduce outer moisture from penetrating into the OLED D. The encapsulation film 470 can have, but is not limited to, a laminated structure including a first inorganic insulating film, an organic insulating film and a second inorganic insulating film (170 in FIG. 2). In addition, a polarizing plate can be attached onto the second substrate 404 to reduce reflection of external light. For example, the polarizing plate can be a circular polarizing plate.

In FIG. 4, the light emitted from the OLED D is transmitted through the second electrode 520 and the color filter layer 480 is disposed on the OLED D. In this case, the organic light emitting display device 400 can be a top-emission type. Alternatively, when the organic light emitting display device 400 is a bottom-emission type, the light emitted from the OLED D is transmitted through the first electrode 510 and the color filter layer 480 can be disposed between the OLED D and the first substrate 402.

In addition, a color conversion layer may be formed or disposed between the OLED D and the color filter layer 480. The color conversion layer may include a red color conversion layer, a green color conversion layer and a blue color conversion layer each of which is disposed correspondingly to each pixel (RP, GP and BP), respectively, so as to convert the white (W) color light to each of a red, green and blue color lights, respectively. Alternatively, the organic light emitting display device 400 can comprise the color conversion layer instead of the color filter layer 480.

As described above, the white (W) color light emitted from the OLED D is transmitted through the red color filter pattern 482, the green color filter pattern 484 and the blue color filter pattern 486 each of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that can be applied into the organic light emitting display device will be described in more detail. FIG. 5 illustrates a schematic cross-sectional view of an organic light emitting diode having a tandem structure of two emitting parts.

As illustrated in FIG. 5, the OLED D2 in accordance with the example embodiment of the present disclosure includes first and second electrodes 510 and 520 and an emissive layer 530 disposed between the first and second electrodes 510 and 520. The emissive layer 530 includes a first emitting part 600 disposed between the first and second electrodes 510 and 520, a second emitting part 700 disposed between the first emitting part 600 and the second electrode 520 and a charge generation layer (CGL) 680 disposed between the first and second emitting parts 600 and 700.

The first electrode 510 can be an anode and can include a conductive material having relatively high work function value such as TCO. For example, the first electrode 510 can include, but is not limited to, ITO, IZO, ITZO, SnO, ZnO, ICO, AZO, and/or the like. The second electrode 520 can be a cathode and can include a conductive material with a relatively low work function value. For example, the second electrode 520 can include, but is not limited to, highly reflective material such as Al, Mg, Ca, Ag, alloy thereof and/or combination thereof such as Al—Mg.

The first emitting part 600 includes a first EML (EML1) 640. The first emitting part 600 can further include at least one of an HIL 610 disposed between the first electrode 510 and the EML1 640, a first HTL (HTL1) 620 disposed between the HIL 610 and the EML1 640, and a first ETL (ETL1) 660 disposed between the EML1 640 and the CGL 680. Alternatively, the first emitting part 600 can further include a first EBL (EBL1) 630 disposed between the HTL1 620 and the EML1 640 and/or a first HBL (HBL1) 650 disposed between the EML1 640 and the ETL1 660.

The second emitting part 700 includes a second EML (EML2) 740. The second emitting part 700 can further include at least one of a second HTL (HTL2) 720 disposed between the CGL 680 and the EML2 740, an second ETL (ETL2) 760 disposed between the second electrode 520 and the EML2 740 and an EIL 770 disposed between the second electrode 520 and the ETL2 760. Alternatively, the second emitting part 700 can further include a second EBL (EBL2) 730 disposed between the HTL2 720 and the EML2 740 and/or a second HBL (HBL2) 750 disposed between the EML2 740 and the ETL2 760.

One of the EML1 640 and the EML2 740 can include the organometallic compound having the structure of Chemical Formulae 1 to 13 so that it can emit red to green color light, and the other of the EML1 640 and the EM2 740 can emit blue color light, so that the OLED D2 can realize white (W) emission. Hereinafter, the OLED D2 where the EML2 740 includes the organometallic compound having the structure of Chemical Formulae 1 to 13 will be described in detail.

The HIL 610 is disposed between the first electrode 510 and the HTL1 620 and improves an interface property between the inorganic first electrode 510 and the organic HTL1 620. In one exemplary embodiment, the HIL 610 can include, but is not limited to, MTDATA, NATA, 1T-NATA, 2T-NATA, CuPc, TCTA, NPB (NPD), DNTPD, HAT-CN, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB and/or combinations thereof. The HIL 610 can be omitted in compliance of the OLED D2 property.

In one example embodiment, each of the HTL1 620 and the HTL2 720 can include, but is not limited to, TPD, NPB (NPD), DNTPD, CBP, poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combinations thereof.

Each of the ETL1 660 and the ETL2 760 facilitates electron transportation in each of the first emitting part 600 and the second emitting part 700, respectively. As an example, each of the ETL1 660 and the ETL2 760 can include at least one of oxadiazole-based compounds, triazole-based compounds, phenanthroline-based compounds, benzoxazole-based compounds, benzothiazole-based compounds, benzimidazole-based compound and triazine-based compounds. For example, each of the ETL1 660 and the ETL2 760 can include, but is not limited to, Alq₃, PBD, spiro-PBD, Liq, TPBi, BAlq, Bphen, NBphen, BCP, TAZ, NTAZ, TpPyPB, TmPPPyTz, PFNBr, TPQ, TSPO1, ZADN and/or combinations thereof.

The EL 770 is disposed between the second electrode 520 and the ETL2 760, and can improve physical properties of the second electrode 520 and therefore, can enhance the lifespan of the OLED D2. In one example embodiment, the EIL 770 can include, but is not limited to, an alkali metal halide or an alkaline earth metal halide such as LiF, CsF, NaF, BaF₂ and the like, and/or an organometallic Compound such as Liq, lithium benzoate, sodium stearate, and the like.

Each of the EBL1 630 and the EBL2 730 can independently include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively.

Each of the HBL 1 650 and the HBL2 750 can include, but is not limited to, at least one of oxadiazole-based compounds, triazole-based compounds, phenanthroline-based compounds, benzoxazole-based compounds, benzothiazole-based compounds, benzimidazole-based compounds, and triazine-based compounds. For example, each of the HBL1 650 and the HBL2 750 can independently include, but is not limited to, BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, TSPO1 and/or combinations thereof, respectively.

The CGL 680 is disposed between the first emitting part 600 and the second emitting part 700. The CGL 680 includes an N-type CGL (N-CGL) 685 disposed adjacently to the first emitting part 600 and a P-type CGL (P-CGL) 690 disposed adjacently to the second emitting part 700. The N-CGL 685 injects electrons to the EML1 640 of the first emitting part 600 and the P-CGL 690 injects holes to the EML2 740 of the second emitting part 700.

The N-CGL 685 can be an organic layer doped with an alkali metal such as Li, Na, K and Cs and/or an alkaline earth metal such as Mg, Sr, Ba and Ra. For example, the host in the N-CGL 685 can include, but is not limited to, Bphen and MTDATA. The contents of the alkali metal or the alkaline earth metal in the N-CGL 685 can be between about 0.01 wt % and about 30 wt %.

The P-CGL 690 can include, but is not limited to, inorganic material selected from the group consisting of tungsten oxide (WOₓ), molybdenum oxide (MoOₓ), beryllium oxide (Be₂O₃), vanadium oxide (V₂O₅) and/or combinations thereof and/or organic material selected from the group consisting of NPD, DNTPD, HAT-CN, F4-TCNQ, TPD, N,N,N′,N′-tetranaphthalenyl-benzidine (TNB), TCTA, N,N′-dioctyl-3,4,9,10-perylenedicarboximide (PTCDI-C8) and/or combinations thereof.

The EML1 640 can be a blue EML. In this case, the EML1 640 can be a blue EML, a sky-blue EML or a deep-blue EML. The EML1 640 can include a blue host and a blue dopant.

For example, the blue host can include, but is not limited to, mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spirobifluoren-2-yl-diphenyl-phosphine oxide (SPPO1), 9,9′-(5-(Triphenylsilyl)-1,3-phenylene)bis(9H-carbazole) (SimCP) and/or combinations thereof.

The blue dopant can include at least one of blue phosphorescent material, blue fluorescent material and blue delayed fluorescent material. As an example, the blue dopant can include, but is not limited to, perylene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl)-9,9-spirofluorene (spiro-DPVBi), [1,4-bis[2-[4-[N,N-di(p-tolyl)amino]phenyl]vinyl] benzene (DSB), 1-4-di-[4-(N,N-diphenyl)amino]styryl-benzene (DSA), 2,5,8,11-Tetra-tert-butylperylene (TBPe), Bis(2-hydroxylphenyl)-pyridine)beryllium (Bepp₂), 9-(9-Phenylcarbazole-3-yl)-10-(naphthalene-1-yl)anthracene (PCAN), mer-Tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C(2)′iridium(III) (fac-Ir(dpbic)₃), Bis(3,4,5-trifluoro-2-(2-pyridyl)phenyl-(2-carboxypyridyl)iridium(III) (Ir(tfpd)₂pic), tris(2-(4,6-difluorophenyl)pyridine))iridium(III) (Ir(Fppy)₃), Bis[2-(4,6-difluorophenyl)pyridinato-C²,N](picolinato)iridium(III) (FIrpic) and/or combinations thereof.

The EML2 740 can include a lower EML (first layer) 740A disposed between the EBL2 730 and the HBL2 750 and an upper EML (second layer) 740B disposed between the lower EML 740A and the HBL2 750. One of the first layer 740A and the second layer 740B can emit red to yellow color light and the other of the first layer 740A and the second layer 740B can emitting green color light. Hereinafter, the EML1 740 where the first layer 740A emits a red to yellow color light and the second layer 740B emits a green color light will be described in detail.

The first layer 740A can include a dopant 742 and a host 744 and/or 746. As an example, the first layer 740A can include a first host 744 of a P-type host and a second host 746 of an N-type host. For example, the dopant 742 can include the organometallic compound having the structure of Chemical Formulae 1 to 13 and can emit red to yellow light color.

As an example, the first host 744 can include, but is not limited to, a biscarbazole-based organic compound, an aryl amine- or a hetero aryl amine-based organic compound with at least one fused aromatic and/or fused hetero aromatic moiety, and/or an aryl amine- or a hetero aryl amine-based organic compound with a spirofluorene moiety. The second host 746 can include, but is not limited to, an azine-based organic compound.

For example, the host 744 and/or 746 can include, but is not limited to, mCP-CN, CBP, mCBP, mCP, DPEPO, PPT, TmPyPB, PYD-2Cz, DCzDBT, DCzTPA, pCzB-2CN, mCzB-2CN, TSPO1, CCP, 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, BCzPh, TCP, TCTA, CDBP, DMFL-CBP, Spiro-CBP, TCzl and/or combinations thereof.

As an example, the contents of the host 744 and/or 746 in the first layer 740A can be about 50 wt % to about 99 wt %, for example, about 80 wt % to about 95 wt %, and the contents of the dopant 742 in the first layer 740A can be about 1 wt % to about 50 wt %, for example, about 5 wt % to about 20 wt %, but is not limited thereto. When the first layer 740A includes both the first host 744 and the second host 746, the first host 744 and the second host 746 can be admixed, but is not limited to, with a weight ratio of about 4:1 to about 1:4, for example about 3:1 to about 1:3.

The second layer 740B can include a green host and a green dopant. For example, the second layer 740B can include one or two kinds of green hosts, and the green dopant. As an example, the green host can be identical to the first host 744 and/or the second host 746. The green dopant can include at least one of green phosphorescent material, green fluorescent material and green delayed fluorescent material. As an example, the green dopant can include, but is not limited to, [Bis(2-phenylpyridine)](pyridyl-2-benzofuro[2,3-b]pyridine)iridium, Tris[2-phenylpyridine]iridium(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tris[2-(p-tolyl)pyridine]iridium(III) (Ir(mppy)₃), Bis(2-(naphthalene-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium(III) (TEG) and/or combinations thereof. Alternatively, the green dopant can include the organometallic compound having the structure of Chemical Formulae 1 to 13.

Alternatively, the EML2 740 can further include a third layer (740C in FIG. 6) that can emit yellow-green color light disposed between the first layer 740A of the red EML and the second layer 740B of the green EML.

The OLED D2 in accordance with this example embodiment has a tandem structure and includes the organometallic compound having the structure of Chemical Formulae 1 to 13. The luminous efficiency and the luminous lifespan of the OLED, which includes the organometallic compound having excellent thermal resistant property and rigid chemical conformation and enabling its luminous color with ease, can be improved.

An OLED can have three or more emitting parts to form a tandem structure. FIG. 6 is a schematic cross-sectional view illustrating an organic light emitting diode in accordance with yet another example embodiment of the present disclosure.

As illustrated in FIG. 6, the OLED D3 includes first and second electrodes 510 and 520 facing each other and an emissive layer 530A disposed between the first and second electrodes 510 and 520. The emissive layer 530A includes a first emitting part 600 disposed between the first and second electrodes 510 and 520, a second emitting part 700A disposed between the first emitting part 600 and the second electrode 520, a third emitting part 800 disposed between the second emitting part 700A and the second electrode 520, a first charge generation layer (CGL1) 680 disposed between the first and second emitting parts 600 and 700A, and a second charge generation layer (CGL2) 780 disposed between the second and third emitting parts 700A and 800.

The first emitting part 600 includes a first EML (EML1) 640. The first emitting part 600 can further include at least one of an HIL 610 disposed between the first electrode 510 and the EML1 640, a first HTL (HTL1) 620 disposed between the HIL 610 and the EML1 640, a first ETL (ETL1) 660 disposed between the EML1 640 and the CGL1 680. Alternatively, the first emitting part 600 can further comprise a first EBL (EBL1) 630 disposed between the HTL1 620 and the EML1 640 and/or a first HBL (HBL1) 650 disposed between the EML1 640 and the ETL1 660.

The second emitting part 700A includes a second EML (EML2) 740′. The second emitting part 700A can further include at least one of a second HTL (HTL2) 720 disposed between the CGL1 680 and the EML2 740′ and a second ETL (ETL2) 760 disposed between the EML2 740′ and the CGL2 780. Alternatively, the second emitting part 700A can further include a second EBL (EBL2) 730 disposed between the HTL2 720 and the EML2 740′ and/or a second HBL (HBL2) 750 disposed between the EML2 740′ and the ETL2 760.

The third emitting part 800 includes a third EML (EML3) 840. The third emitting part 800 can further include at least one of a third HTL (HTL3) 820 disposed between the CGL2 780 and the EML3 840, a third ETL (ETL3) 860 disposed between the second electrode 520 and the EML3 840 and an EIL 870 disposed between the second electrode 520 and the ETL3 860. Alternatively, the third emitting part 800 can further comprise a third EBL (EBL3) 830 disposed between the HTL3 820 and the EML3 840 and/or a third HBL (HBL3) 850 disposed between the EML3 840 and the ETL3 860.

The CGL1 680 is disposed between the first emitting part 600 and the second emitting part 700A and the CGL2 780 is disposed between the second emitting part 700A and the third emitting part 800. The CGL1 680 includes a first N-type CGL (N-CGL1) 685 disposed adjacently to the first emitting part 600 and a first P-type CGL (P-CGL1) 690 disposed adjacently to the second emitting part 700A. The CGL2 780 includes a second N-type CGL (N-CGL2) 785 disposed adjacently to the second emitting part 700A and a second P-type CGL (P-CGL2) 790 disposed adjacently to the third emitting part 800. Each of the N-CGL1 685 and the N-CGL2 785 injects electrons to the EML1 640 of the first emitting part 600 and the EML2 740′ of the second emitting part 700A, respectively, and each of the P-CGL1 690 and the P-CGL2 790 injects holes to the EML2 740′ of the second emitting part 700A and the EML3 840 of the third emitting part 800, respectively.

The materials included in the HIL 610, the HTL1 to the HTL3 620, 720 and 820, the EBL1 to the EBL3 630, 730 and 830, the HBL1 to the HBL3 650, 750 and 850, the ETL1 to the ETL3 660, 760 and 860, the EIL 870, the CGL1 680, and the CGL2 780 can be identical to the materials with referring to FIGS. 3 and 5.

At least one of the EML1 640, the EML2 740′ and the EML3 840 can include the organometallic compound having the structure of Chemical Formulae 1 to 13. For example, one of the EML1 640, the E-L2 740′ and the EML3 840 can emit red to green color light, and the other of the EML1 640, the E-L2 740′ and the EML3 840 can emit blue color light so that the OLED D3 can realize white (W) emission. Hereinafter, the OLED where the EML2 740′ includes the organometallic compound having the structure of Chemical Formulae 1 to 13 and emits red to green color light, and each of the EML1 640 and the EML3 840 emits blue color light will be described in detail.

Each of the EML1 640 and the EML3 840 can be independently a blue EML. In this case, each of the EML1 640 and the EML3 840 can be independently a blue EML, a sky-blue EML or a deep-blue EML. Each of the EML1 640 and the EML3 840 can independently include a blue host and a blue dopant. Each of the blue host and the blue dopant can be identical to the blue host and the blue dopant with referring to FIG. 5. For example, the blue dopant can include at least one of blue phosphorescent material, blue fluorescent material and blue delayed fluorescent material. Alternatively, the blue dopant in the EML1 640 can be identical to or different from the blue dopant in the EML3 840 in terms of color and/or luminous efficiency.

The EML2 740′ can include a lower EML (first layer) 740A disposed between the EBL2 730 and the HBL2 750, an upper EML (second layer) 740B disposed between the first layer 740A and the HBL2 750, and a middle EML (third layer) 740C disposed between the first layer 740A and the second layer 740B. One of the first layer 740A and the second layer 740B can emit red color and the other of the first layer 740A and the second layer 740B can emit green color. Hereinafter, the EML2 740′ where the first layer 740A emits a red color and the second layer 740B emits a green color will be described in detail.

The first layer 740A can include a dopant 742 and a host 744 and/or 746. As an example, the first layer 740A can include a first host 744 of a P-type host and a second host 746 of an N-type host. As an example, the dopant 742 can include the organometallic compound having the structure of Chemical Formulae 1 to 13 and can emit red to yellow color light.

The second layer 740B can include a green host and a green dopant. As an example, the second layer 740B can include one or two kinds of green hosts and a green dopant. The green host can be identical to the first and/or second hosts 744 and 746, and the green dopant can include at least one of green phosphorescent material, green fluorescent material and green delayed fluorescent material. As an example, the green dopant can include the organometallic compound having the structure of Chemical Formulae 1 to 13.

The third layer 740C can be a yellow green EML. The third layer 740C can include a yellow green host and a yellow green dopant. For example, the third layer 740C can include one or two kinds of yellow green hosts and a yellow green dopant. As an example, the yellow green host can be identical to the first and/or second hosts 744 and 746. The yellow green dopant can include at least one of yellow green phosphorescent material, yellow green fluorescent material and yellow green delayed fluorescent material.

For example, the yellow green dopant can include, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)iridium(III) (Ir(BT)₂(acac)), Bis(2-(9,9-diethytl-fluoren-2-yl)-1-phenyl-1H-benzo[d]imdiazolato)(acetylacetonate)iridium(III) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline)(picolinate)iridium(III) (FPQIrpic), Bis(4-phenylthieno[3,2-c]pyridinato-N,C2′) (acetylacetonate) iridium(III) (PO-01) and/or combinations thereof. The third layer 740C can be omitted.

The OLED D3 in accordance with this example embodiment includes the organometallic compound having the structure of Chemical Formulae 1 to 13 in at least one EML. The organometallic compound has narrow luminous FWHM and can maintain its stable chemical conformation in emitting process. The OLED D3, which includes the organometallic compound and three or more emitting part, enables its luminous efficiency, color purity and luminous lifespan to be improved with white emission.

### Synthesis Example 1: Synthesis of Compound 5

### (1) Synthesis of Intermediate A-1

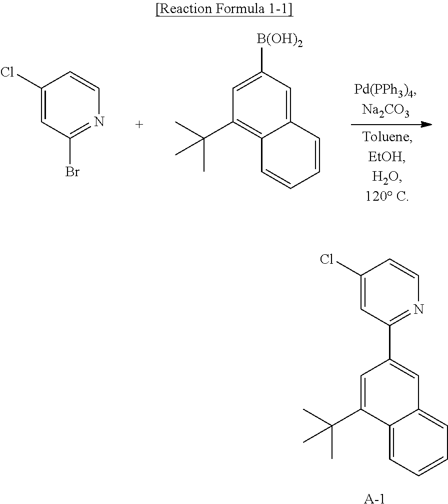

2-bromo-4-chloropyridine (19.2 g, 100.0 mmol), (4-(tert-butyl)naphthalen-2-yl)boronic acid (25.1 g, 110.0 mmol), Na₂CO₃ (21.2 g, 200.0 mmol), Tetrakis(triphenylenephosphine)palladium(0) (Pd(PPh₃)4, 5.8 g, 5.0 mmol) and a mixed solution (toluene 200 ml, EtOH 40 ml, H₂O 40 ml) were added into a reaction vessel under nitrogen atmosphere, and then the solution was stirred at 120° C. for 24 hours. After the reaction was complete, the solution was cooled to a room temperature. The organic layer was extracted with dichloromethane and washed sufficiently with H₂O. H₂O in the organic layer was removed with MgSO₄, and then the filtered solution was concentrated under reduced pressure. The obtained crude product was purified with a column chromatography (eluent: hexane and dichloromethane) to give Intermediate A-1 (21.3 g, yield: 72%).

### (2) Synthesis of Intermediate A-2

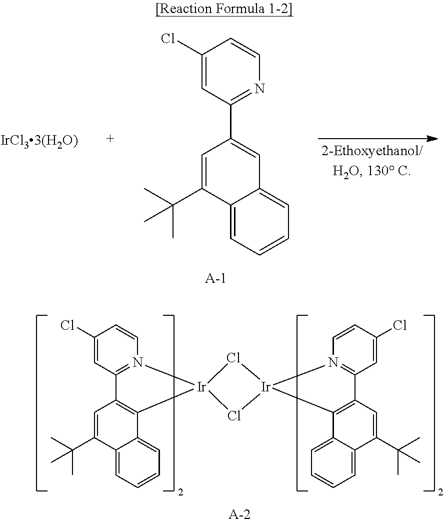

The Intermediate A-1 (14.8 g, 50.0 mmol), Iridium chloride hydrate (3.0 g, 10.0 mmol) and a mixed solution (2-Ethoxyethanol 100 ml, H₂O 50 ml) were added into a reaction vessel under nitrogen atmosphere, and then the solution was stirred at 130° C. for 24 hours. After the reaction was complete, the solution was cooled to a room temperature. MeOH was added into the solution to produce solid. The solid was filtered under reduced pressure to give Intermediate A-2 (5.9 g, yield: 72%).

### (3) Synthesis of Intermediate A-3

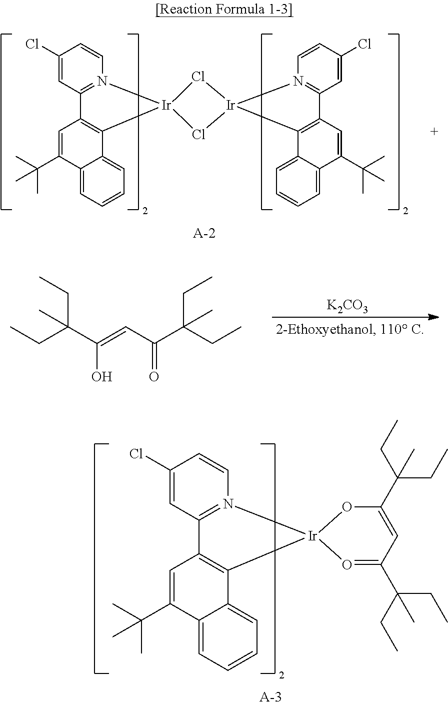

The Intermediate A-2 (4.1 g, 2.5 mmol), (Z)-3,7-diethyl-6-hydroxy-3,7-dimethylnon-5-en-4-one (6.0 g, 25.0 mmol), K₂CO₃ (6.9 g, 50.0 mmol) and 2-Ethoxyethanol (100 ml) were added into a reaction vessel under nitrogen atmosphere, and then the solution was stirred at 110° C. for 24 hours. After the reaction was complete, the solution was cooled to a room temperature. The organic layer was extracted with dichloromethane and washed sufficiently with H₂O. H₂O in the organic layer was removed with MgSO₄, and then the filtered solution was concentrated under reduced pressure. The obtained crude product was purified with a column chromatography (eluent: hexane and dichloromethane) to give Intermediate A-3 (2.7 g, yield: 52%).

### (4) Synthesis of Compound 5

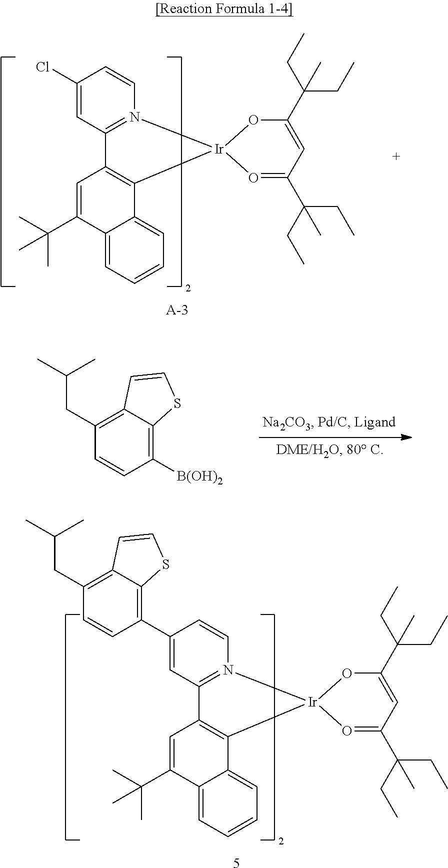

The Intermediate A-3 (2.6 g, 2.5 mmol), (4-isobutylbenzo[b]thiophen-7-yl)boronic acid (1.3 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 5 (2.8 g, yield: 83%).

### Synthesis Example 2: Synthesis of Compound 31

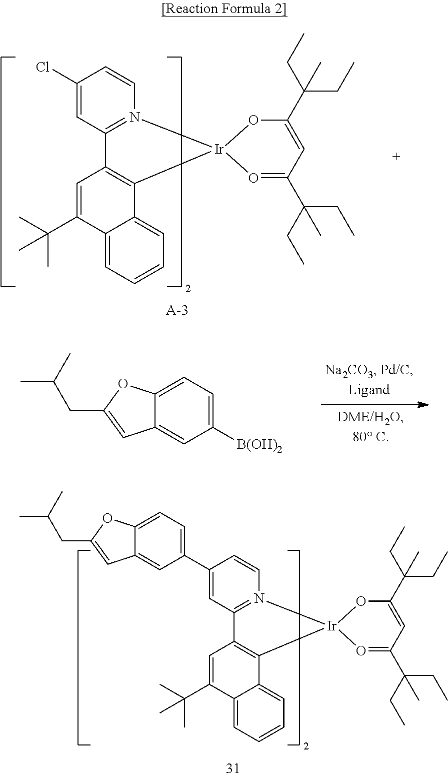

The Intermediate A-3 (2.6 g, 2.5 mmol), (2-isobutylbenzofuran-5-yl)boronic acid (1.2 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 31 (2.4 g, yield: 74%)

### Synthesis Example 3: Synthesis of Compound 90

### (1) Synthesis of Intermediate C-1

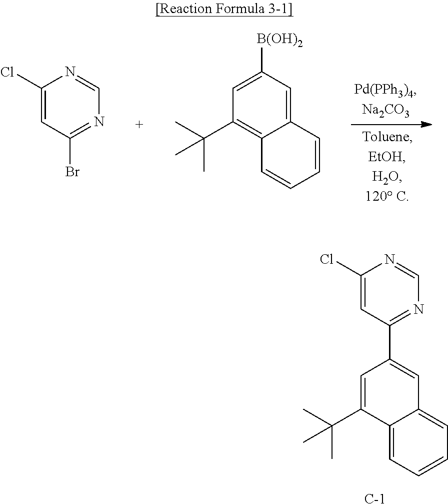

4-bromo-6-chloropyrimidine (19.3 g, 100.0 mmol), (4-(tert-butyl)naphthalen-2-yl)boronic acid (25.1 g, 110.0 mmol), Na₂CO₃ (21.2 g, 200.0 mmol), Pd(PPh₃)₄ (5.8 g, 5.0 mmol) and a mixed solution (toluene 200 ml, EtOH 40 ml, H₂O 40 ml) were added into a reaction vessel under nitrogen atmosphere, and then the solution was stirred at 120° C. for 24 hours. After the reaction was complete, the solution was cooled to a room temperature. The organic layer was extracted with dichloromethane and washed sufficiently with H₂O. H₂O in the organic layer was removed with MgSO₄, and then the filtered solution was concentrated under reduced pressure. The obtained crude product was purified with a column chromatography (eluent: hexane and dichloromethane) to give Intermediate C-1 (22.0 g, yield: 74%).

### (2) Synthesis of Intermediate C-2

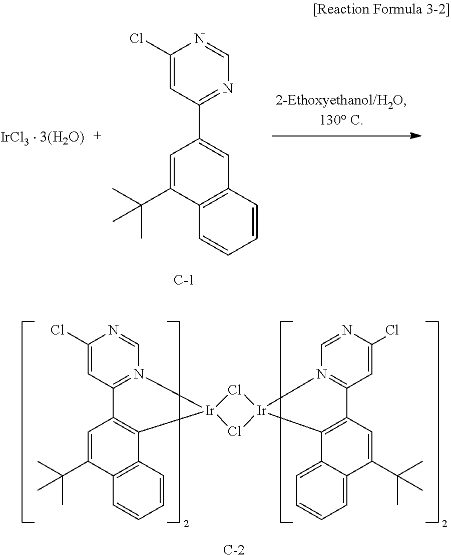

The Intermediate C-1 (14.8 g, 50.0 mmol), Iridium chloride hydrate (3.0 g, 10.0 mmol) and a mixed solution (2-Ethoxyethanol 100 ml, H₂O 50 ml) were added into a reaction vessel under nitrogen atmosphere, and then the solution was stirred at 130° C. for 24 hours. After the reaction was complete, the solution was cooled to a room temperature. MeOH was added into the solution to produce solid. The solid was filtered under reduced pressure to give Intermediate C-2 (5.7 g, yield: 69%).

### (3) Synthesis of Intermediate C-3

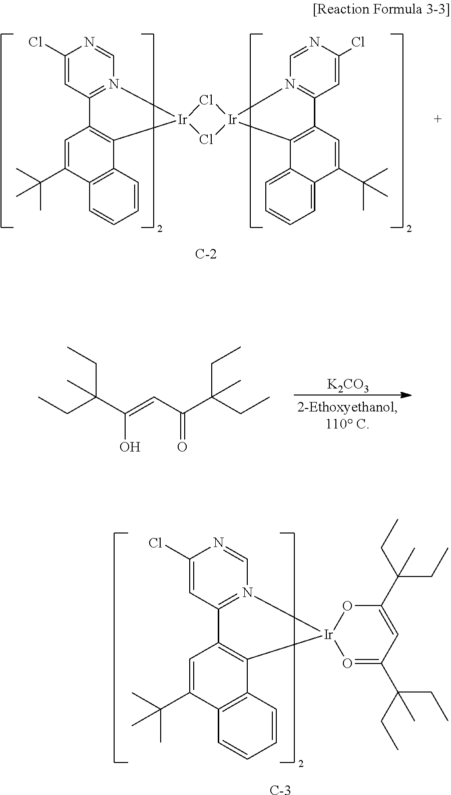

The Intermediate C-2 (4.1 g, 2.5 mmol), (Z)-3,7-diethyl-6-hydroxy-3,7-dimethylnon-5-en-4-one (6.0 g, 25.0 mmol), K₂CO₃ (6.9 g, 50.0 mmol) and 2-Ethoxyethanol (100 ml) were added into a reaction vessel under nitrogen atmosphere, and then the solution was stirred at 110° C. for 24 hours. After the reaction was complete, the solution was cooled to a room temperature. The organic layer was extracted with dichloromethane and washed sufficiently with H₂O. H₂O in the organic layer was removed with MgSO₄, and then the filtered solution was concentrated under reduced pressure. The obtained crude product was purified with a column chromatography (eluent: hexane and dichloromethane) to give Intermediate C-3 (3.1 g, yield: 61%).

### 4) Synthesis of Compound 90

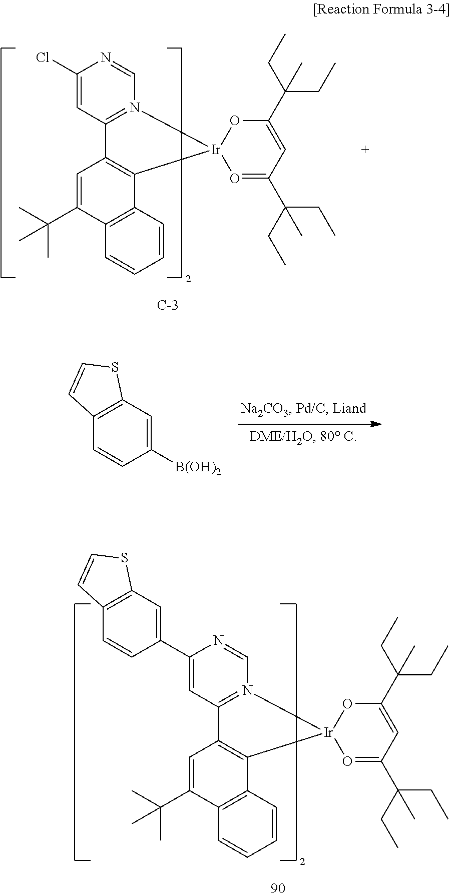

The Intermediate C-3 (2.6 g, 2.5 mmol), benzo[b]thiophen-6-ylboronic acid (1.0 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 90 (2.6 g, yield: 84%).

### Synthesis Example 4: Synthesis of Compound 93

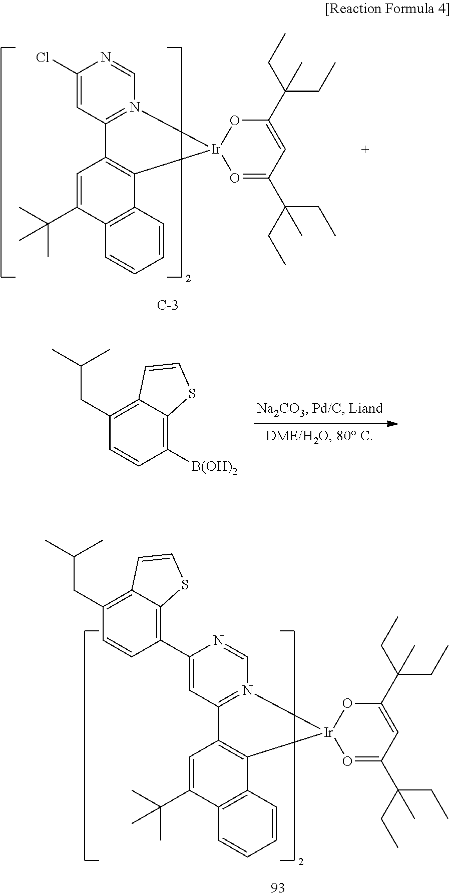

The Intermediate C-3 (2.6 g, 2.5 mmol), (4-isobutylbenzo[b]thiophen-7-yl)boronic acid (1.0 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 93 (2.3 g, yield: 70%).

### Synthesis Example 5: Synthesis of Compound 98

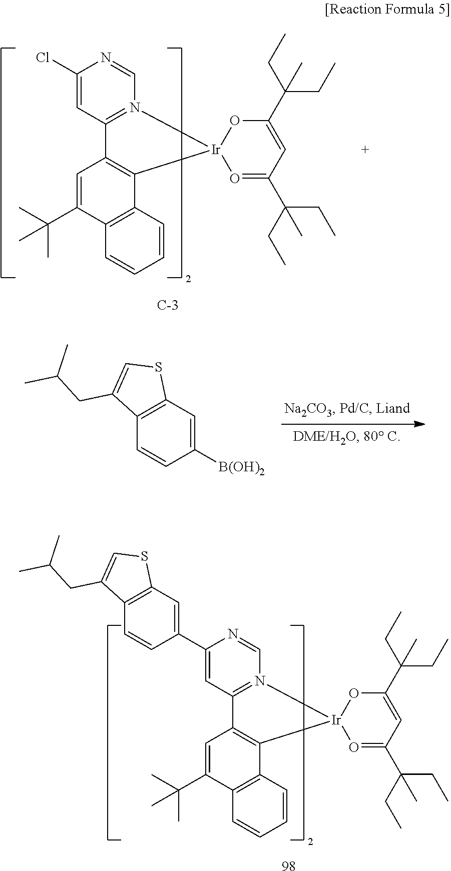

The Intermediate C-3 (2.6 g, 2.5 mmol), (3-isobutylbenzo[b]thiophen-6-yl)boronic acid (1.3 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 98 (2.6 g, yield: 79%).

### Synthesis Example 6: Synthesis of Compound 112

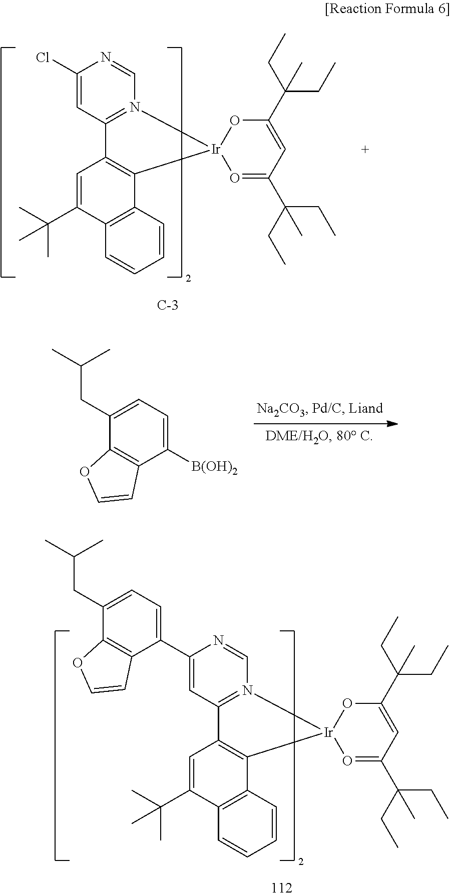

The Intermediate C-3 (2.6 g, 2.5 mmol), (7-isobutylbenzofuran-4-yl)boronic acid (1.2 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 112 (2.7 g, yield: 84%).

### Synthesis Example 7: Synthesis of Compound 119

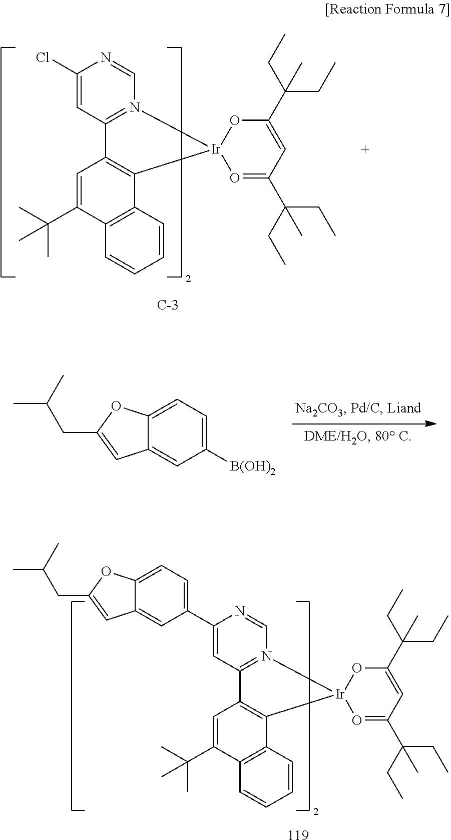

The Intermediate C-3 (2.6 g, 2.5 mmol), (2-isobutylbenzofuran-5-yl)boronic acid (1.2 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 119 (2.6 g, yield: 80%).

### Synthesis Example 8: Synthesis of Compound 196

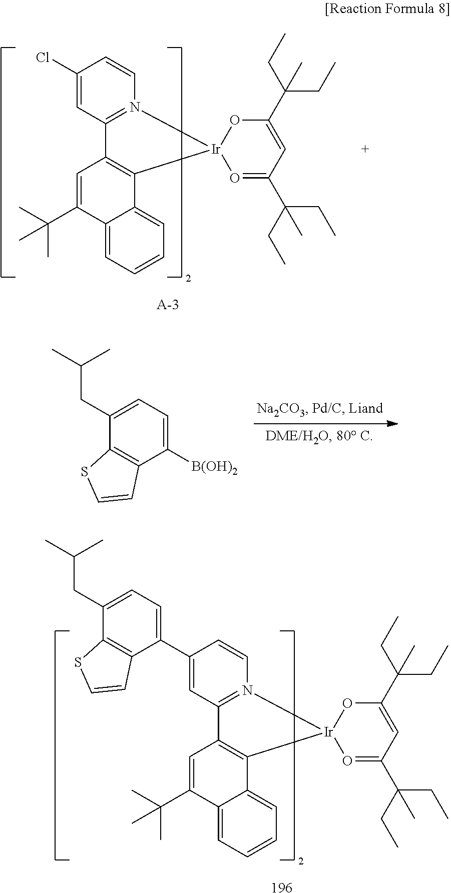

The Intermediate A-3 (2.6 g, 2.5 mmol), (7-isobutylthieno[3,2-c]pyridin-4-yl)boronic acid (1.3 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 196 (2.8 g, yield: 85%).

### Synthesis Example 9: Synthesis of Compound 240

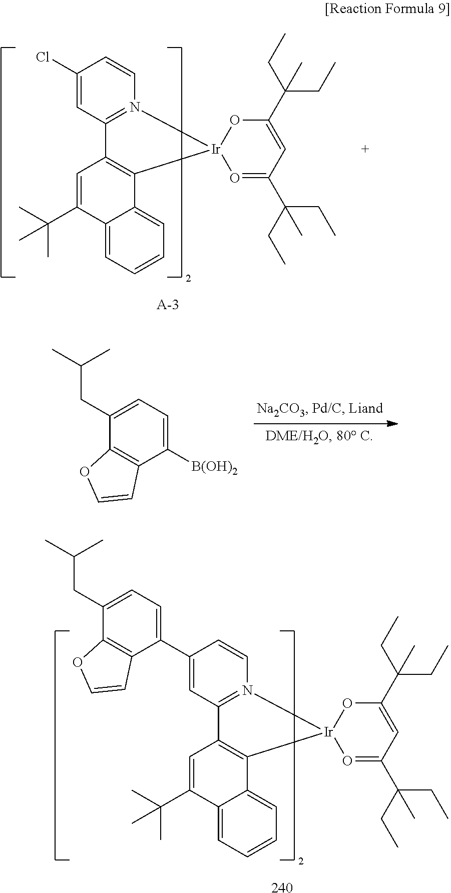

The Intermediate A-3 (2.6 g, 2.5 mmol), (7-isobutylfuro[3,2-c]pyridin-4-yl)boronic acid (1.2 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 240 (2.3 g, yield: 70%).

### Synthesis Example 10: Synthesis of Compound 255

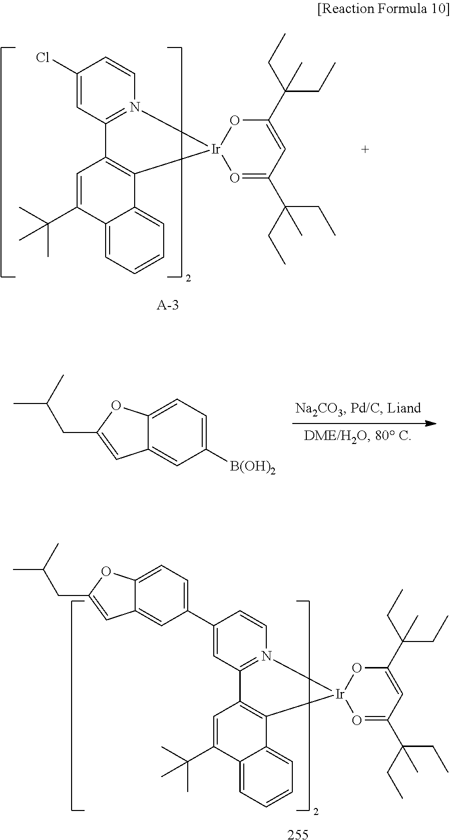

The Intermediate A-3 (2.6 g, 2.5 mmol), (2-isobutylfuro[2,3-b]pyridin-5-yl)boronic acid (1.2 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 255 (2.3 g, yield: 70%).

### Synthesis Example 11: Synthesis of Compound 362

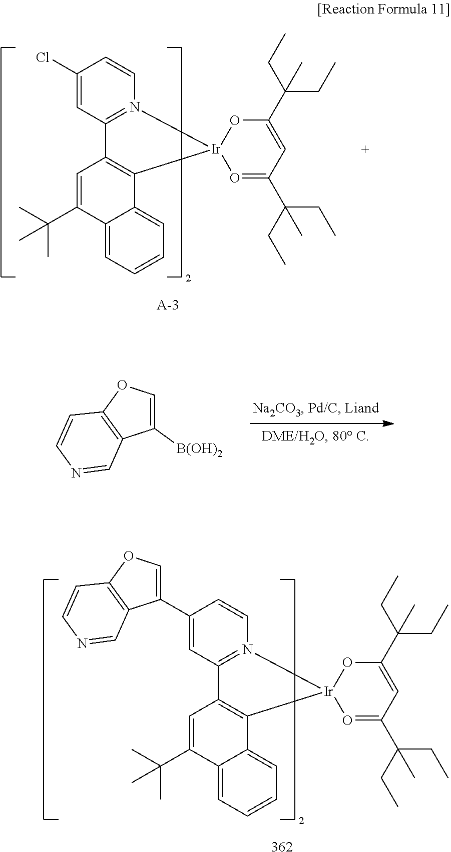

The Intermediate A-3 (2.6 g, 2.5 mmol), furo[3,2-c]pyridin-3-yl-boronic acid (0.9 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 362 (2.3 g, yield: 76%).

### Synthesis Example 12: Synthesis of Compound 373

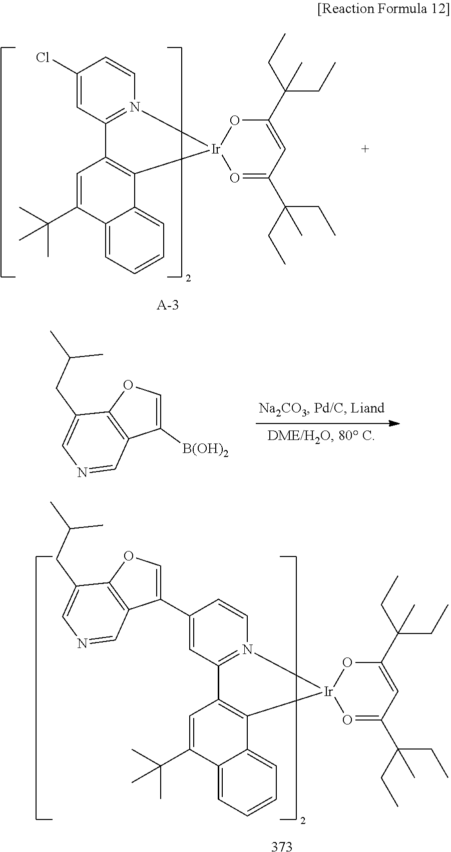

The Intermediate A-3 (2.6 g, 2.5 mmol), (7-isobutylthieno[3,2-c]pyridin-3-yl)boronic acid (1.3 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 373 (2.3 g, yield: 70%).

### Synthesis Example 13: Synthesis of Compound 374

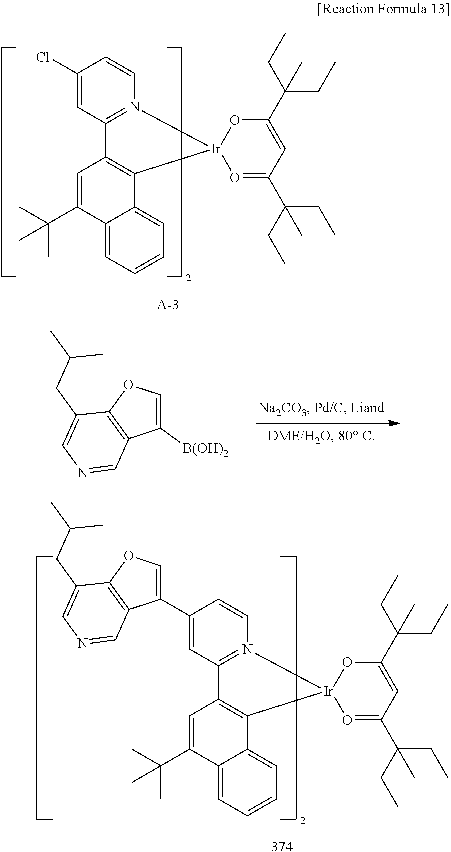

The Intermediate A-3 (2.6 g, 2.5 mmol), (7-isobutylfuro[3,2-c]pyridin-3-yl)boronic acid (1.2 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 374 (2.3 g, yield: 71%).

### Synthesis Example 14: Synthesis of Compound 511

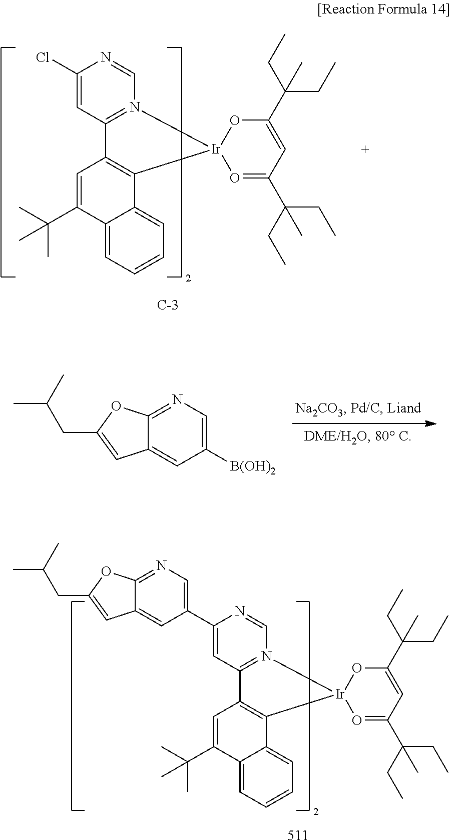

The Intermediate C-3 (2.6 g, 2.5 mmol), (2-isobutylfuro[2,3-b]pyridin-5-yl)boronic acid (1.2 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 511 (2.7 g, yield: 83%).

### Synthesis Example 15: Synthesis of Compound 555

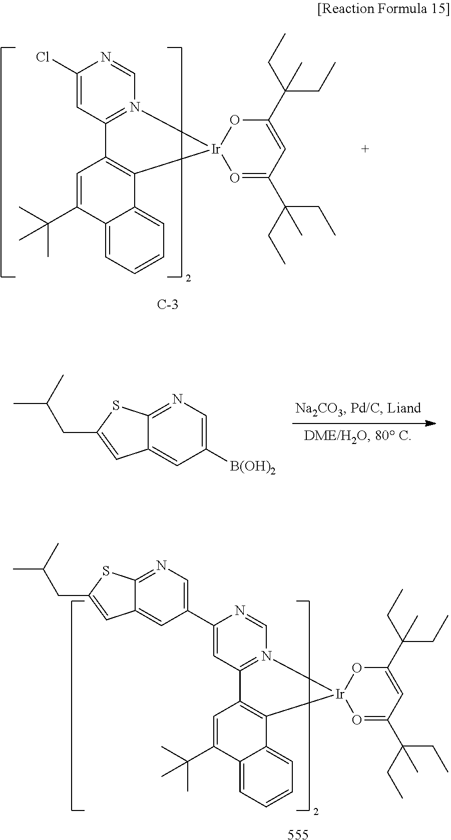

The Intermediate C-3 (2.6 g, 2.5 mmol), (2-isobutylthieno[2,3-b]pyridin-5-yl)boronic acid (1.3 g, 5.5 mmol), Na₂CO₃ (1.1 g, 10.0 mmol), Pd/C (10 wt %) (0.3 g, 0.3 mmol), Ligand (2-(Dicyclohexylphosphino)biphenyl) (0.2 g, 0.5 mmol) and a mixed solution (DME 100 ml, H₂O 50 ml) were added into a reaction vessel under nitrogen atmosphere, and then the solution was stirred at 80° C. for 24 hours. After the reaction was complete, the solution was cooled to a room temperature. The organic layer was extracted with dichloromethane and washed sufficiently with H₂O. The H₂O in the organic layer was removed with MgSO₄, and then the filtered solution was concentrated under reduced pressure. The obtained crude product was purified with a column chromatography (eleuent: hexane and dichloromethane) to give Compound 555 (2.5 g, yield: 70%).

### Example 1 (Ex. 1): Fabrication of OLED

An organic light emitting diode where Compound 5 was applied to an emitting material layer was fabricated. A glass substrate onto which ITO (50 nm) was coated as a thin film was washed and ultrasonically cleaned by solvent such as isopropyl alcohol, acetone and dried at 100° C. oven. The substrate was transferred to a vacuum chamber for depositing emissive layer. Subsequently, an emissive layer and a cathode were deposited by evaporation from a heating boat under about 5-7×10⁻⁷ Torr with setting a deposition rate 1 Å/s as the following order:

A hole injection layer (HIL, HAT-CN, 7 nm thickness); a hole transport layer (HTL, NPB, 78 nm thickness); an electron blocking layer (EBL, TAPC, 15 nm thickness); an emitting material layer (EML, Host (CBP, 95 wt %), Compound 5 (5 wt %), 30 nm thickness); a hole blocking layer (HBL, B3PYMPM, 10 nm thickness); an electrons transport layer (ETL, TPBi, 25 nm thickness); an electron injection layer (EIL) (EIL, LiF, 1 nm thickness); and a cathode (Al, 100 nm thickness).

The fabricated OLED was encapsulated with glass and then transferred from the deposition chamber to a dry box in order to form a film. And then, the OLED was encapsulated with UV-cured epoxy resin and wager getter. The structures of materials of hole injecting material, hole transporting material, electron blocking material, luminescent host, hole blocking material and electron transporting material are illustrated in the following:

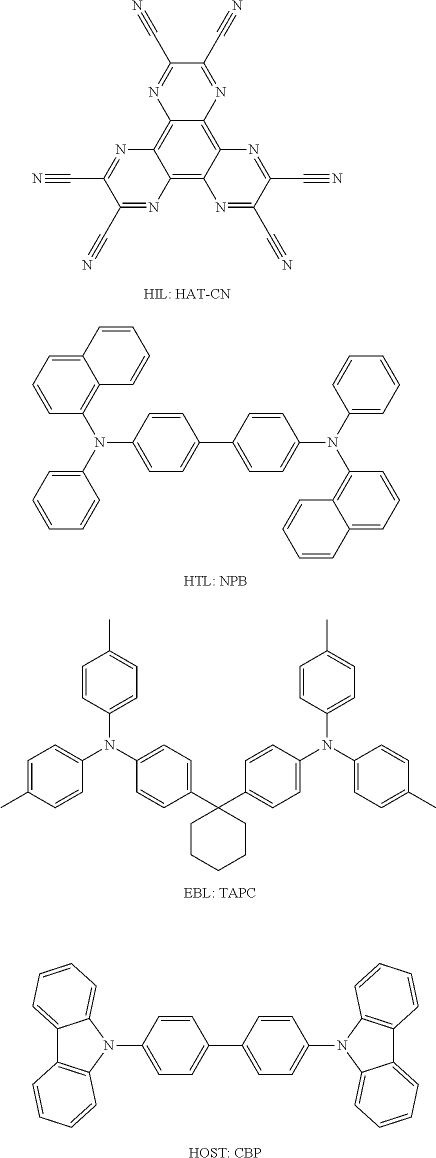

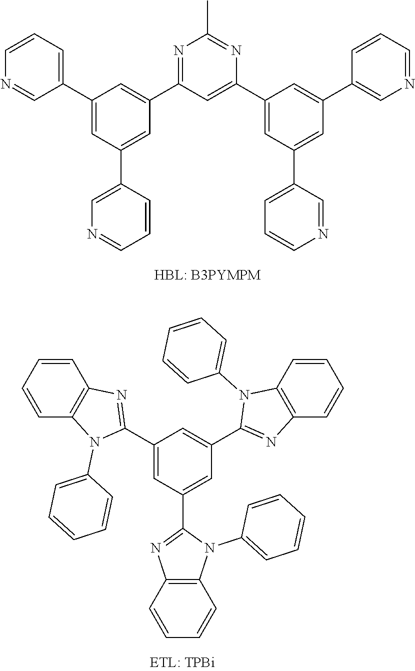 [SMILES: Cc1nc(-c2cc(-c3cccnc3)cc(-c3cccnc3)c2)cc(-c2cc(-c3cccnc3)cc(-c3cccnc3)c2)n1 ; c1ccc(-n2c(-c3cc(-c4nc5ccccc5n4-c4ccccc4)cc(-c4nc5ccccc5n4-c4ccccc4)c3)nc3ccccc32)cc1]

### Examples 2-15 (Ex. 2-15): Fabrication of OLEDs

An OLED was fabricated using the same procedure and the same material as Example 1, except that each of Compound 31 (Ex. 2), Compound 90 (Ex. 3), Compound 93 (Ex. 4), Compound 98 (Ex. 5), Compound 112 (Ex. 6), Compound 119 (Ex. 7), Compound 196 (Ex. 8), Compound 240 (Ex. 9), Compound 255 (Ex. 10), Compound 362 (Ex. 11), Compound 373 (Ex. 12), Compound 374 (Ex. 13), Compound 511 (Ex. 14) and Compound 555 (Ex. 15) instead of Compound 5 was used as the dopant in the EML, respectively.

### Comparative Examples 1-9 (Ref 1-9): Fabrication of OLEDs

An OLED was fabricated using the same procedure and the same material as Example 1, except that each of the following Compound Ref 1 (Ref 1), Compound Ref. 2 (Ref. 2), Compound Ref. 3 (Ref 3), Compound Ref 4 (Ref 4), Compound Ref 5 (Ref 5), Compound Ref 6 (Ref 6), Compound Ref. 7 (Ref. 7), Compound Ref. 8 (Ref. 8) and Compound Ref 9 (Ref. 9) instead of Compound 5 was used as the dopant in the EML, respectively.

### [Reference Compounds]

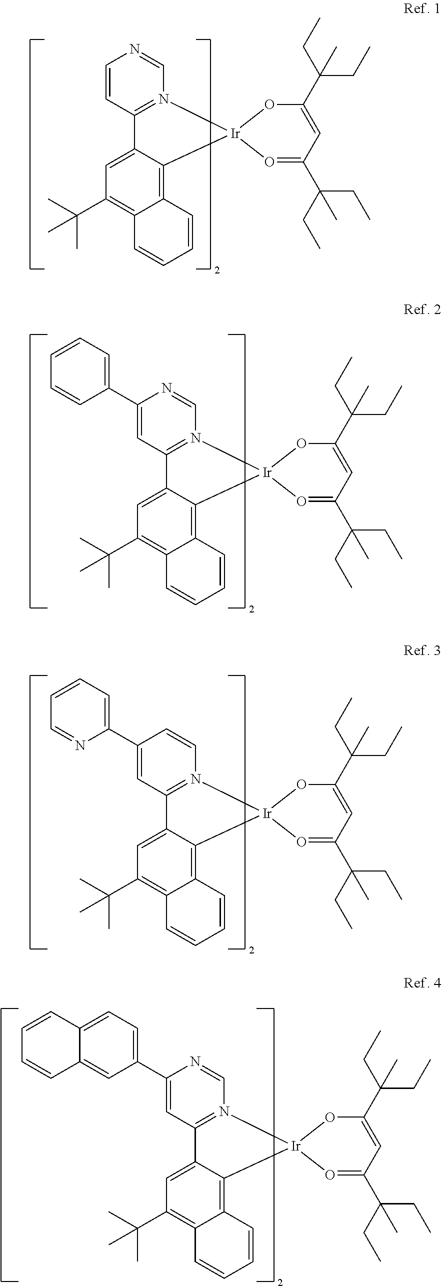

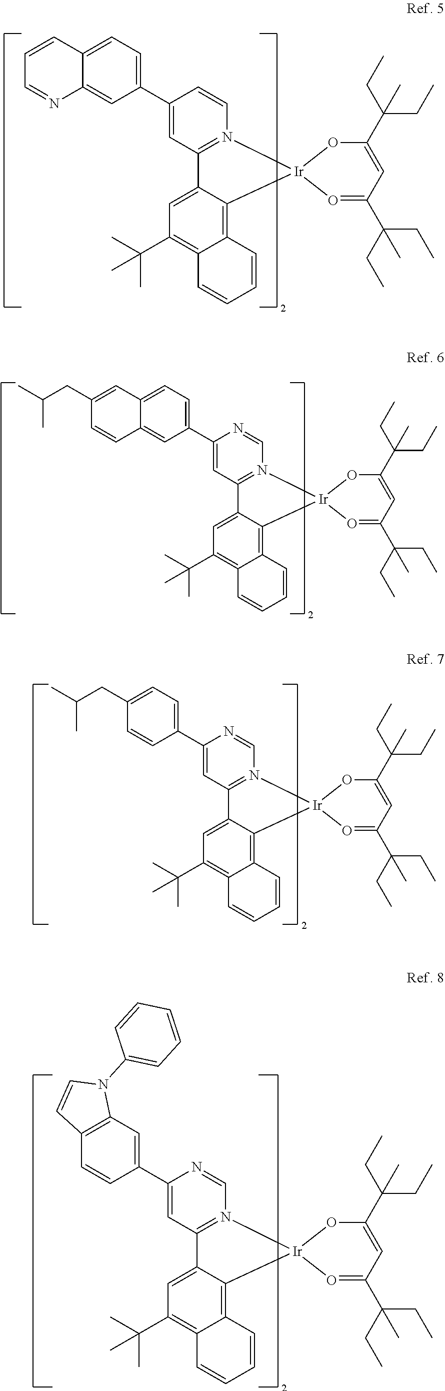

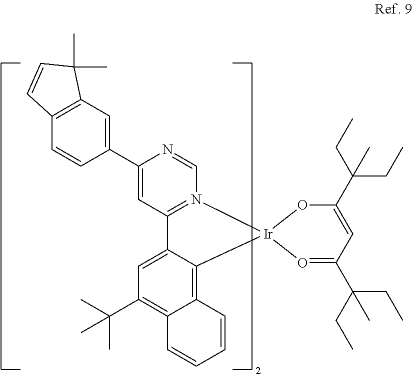

### Experimental Example 1: Measurement of Luminous Properties of OLEDs

Each of the OLEDs, having 9 mm² of emission area, fabricated in Examples 1 to 15 and Comparative Examples 1 to 9 was connected to an external power source and then luminous properties for all the OLEDs were evaluated using a constant current source (KEITHLEY) and a photometer PR650 at room temperature. In particular, driving voltage (V, relative value), External quantum efficiency (EQE, relative value) and time period (LT₉₅, relative value) at which the luminance was reduced to 95% from initial luminance was measured at a current density 10 mA/cm². The measurement results are indicated in the following Table 1.

TABLE 1
Luminous Properties of OLED

| Sample | Dopant | Driving voltage (V) | EQE (%) | LT₉₅ (%) |
|---|---|---|---|---|
| Ref. 1 | Ref. 1 | 100 | 100 | 100 |
| Ref. 2 | Ref. 2 | 95 | 105 | 105 |
| Ref. 3 | Ref. 3 | 96 | 106 | 106 |
| Ref. 4 | Ref. 4 | 96 | 106 | 107 |
| Ref. 5 | Ref. 5 | 97 | 105 | 106 |
| Ref. 6 | Ref. 6 | 96 | 107 | 105 |
| Ref. 7 | Ref. 7 | 96 | 106 | 109 |
| Ref. 8 | Ref. 8 | 95 | 85 | 62 |
| Ref. 9 | Ref. 9 | 95 | 79 | 59 |
| Ex. 1 | 5 | 95 | 123 | 110 |
| Ex. 2 | 31 | 94 | 129 | 124 |
| Ex. 3 | 90 | 94 | 119 | 111 |
| Ex. 4 | 93 | 94 | 129 | 116 |
| Ex. 5 | 98 | 95 | 128 | 114 |
| Ex. 6 | 112 | 94 | 130 | 117 |
| Ex. 7 | 119 | 93 | 135 | 129 |
| Ex. 8 | 196 | 94 | 124 | 116 |
| Ex. 9 | 240 | 95 | 128 | 118 |
| Ex. 10 | 255 | 93 | 133 | 127 |
| Ex. 11 | 362 | 94 | 121 | 115 |
| Ex. 12 | 373 | 94 | 128 | 117 |
| Ex. 13 | 374 | 95 | 129 | 113 |
| Ex. 14 | 511 | 93 | 129 | 116 |
| Ex. 15 | 555 | 93 | 125 | 114 |

As indicated in Table 1, as compared to the OLED fabricated in the Comparative Example 1, in the OLED where the organometallic compound was used as the dopant in the EML, the driving voltage was reduced by maximally 7%, EQE and LT₉₅ were improved by maximally 3500, 290%, respectively. The results above show that the organometallic compound introduced into the EML makes an OLED with reducing driving voltage and improving significantly luminous efficiency and luminous lifespan.

It will be apparent to those skilled in the art that various modifications and variations may be made in the present disclosure without departing from the scope of the disclosure. Thus, it is intended that the present disclosure cover the modifications and variations of the present disclosure provided they come within the scope of the appended claims.

What is claimed is:

1. An organometallic compound represented by a structure of Chemical Formula 1:
Ir(L_{A})ₘ(L_{B})ₙ [Chemical Formula 1]
wherein, in the Chemical Formula 1,
L_{A} has the following structure of Chemical Formula 2;
L_{B} is an auxiliary ligand;
m is 1, 2 or 3;
n is 0, 1 or 2; and
m+n is 3; 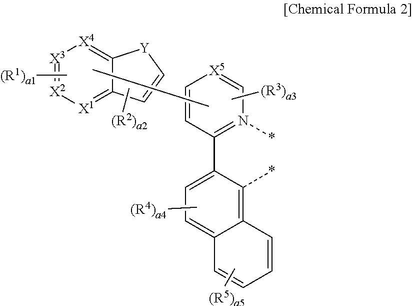
wherein, in the Chemical Formula 2,
each of X¹ to X⁴ is independently CR¹, N or a carbon atom linked to a hetero aromatic ring including X⁵, where at least one of X¹ to X⁴ is CR¹ or the carbon atom linked to the hetero aromatic ring including X⁵;
X⁵ is CR³, N or a carbon atom linked to a ring including X¹ to X⁴ and Y;
Y is CR⁶R⁷, NR⁶, O or S;
each of R¹ to R⁷ is independently hydrogen, halogen, a hydroxyl group, a cyano group, a nitro group, an amidino group, a hydrazine group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ alicyclic group, an unsubstituted or substituted C₃-C₃₀ hetero alicyclic group, an unsubstituted or substituted C₆-C₃₀ aromatic group or an unsubstituted or substituted C₃-C₃₀ hetero aromatic group, where each R¹ is identical to or different from each other when a1 is 2, 3 or 4, where each R² is identical to or different from each other when a2 is 2, where each R³ is identical to or different from each other when a3 is 2 or 3, where each R⁴ is identical to or different from each other when a4 is 2, and where each R⁵ is identical to or different from each other when a5 is 2, 3 or 4;
optionally,
two adjacent R¹ when a1 is 2, 3 or 4, and/or
two adjacent R² when a2 is 2, and/or
two adjacent R³ when a3 is 2 or 3, and/or
two adjacent R⁴ when a4 is 2, and/or
two adjacent R⁵ when a5 is 2, 3 or 4, and/or
R⁶ and R⁷
are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₃-C₂₀ hetero aromatic ring;
a1 is 1, 2, 3 or 4 when R¹ is hydrogen, and a1 is 0, 1, 2, 3 or 4 when R¹ is other than hydrogen;
a2 is 1 or 2 when R² is hydrogen, and a2 is 0, 1 or 2 when R² is other than hydrogen;
a3 is 2 or 3 when R³ is hydrogen, and a3 is 0, 1, 2 or 3 when R³ is other than hydrogen;
a4 is 2 when R⁴ is hydrogen, and a4 is 0, 1 or 2 when R⁴ is other than hydrogen; and
a5 is 4 when R⁵ is hydrogen, and a5 is 0, 1, 2, 3 or 4 when R⁵ is other than hydrogen.

2. The organometallic compound of claim 1, wherein the L_{A} has the following structure of Chemical Formula 3: 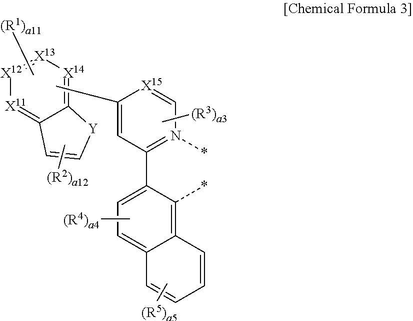
wherein, in the Chemical Formula 3,
each of Y, R¹ to R⁵ and a3 to a5 is a same as defined in Chemical Formula 2;
each of X¹¹ to X¹⁴ is independently CR¹, N or a carbon atom linked to a hetero aromatic ring including X¹⁵, where at least one of X¹¹ to X¹⁴ is CR¹ and another of X¹¹ to X¹⁴ is the carbon atom linked to the hetero aromatic ring including X¹⁵;
X¹⁵ is CR³ or N;
a11 is 1, 2 or 3 when R¹ is hydrogen, and a1 l is 0, 1, 2 or 3 when R¹ is other than hydrogen; and
a12 is 2 when R² is hydrogen, and a12 is 0, 1 or 2 when R² is other than hydrogen.

3. The organometallic compound of claim 1, wherein the L_{A} has the following structure of Chemical Formula 4: 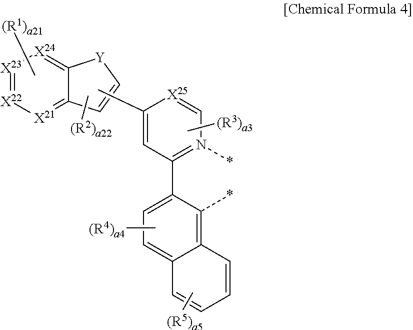
wherein, in the Chemical Formula 4,
each of Y, R¹ to R⁵ and a3 to a5 is a same as defined in Chemical Formula 2;
each of X²¹ to X²⁴ is independently CR¹ or N, where at least one of X²¹ to X²⁴ is CR¹;
X²⁵ is CR³ or N;
a21 is 1, 2, 3 or 4 when R¹ is hydrogen, and a21 is 0, 1, 2, 3 or 4 when R¹ is other than hydrogen; and
a22 is 1 when R² is hydrogen, and a22 is 0 or 1 when R² is other than hydrogen.

4. The organometallic compound of claim 1, wherein the L_{A} has the following structure of Chemical Formula 5: 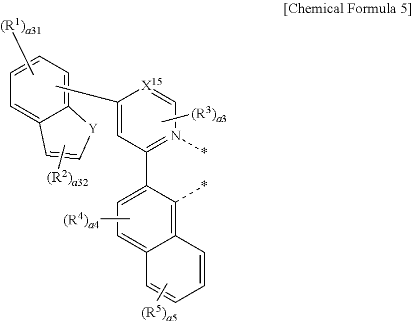
wherein, in the Chemical Formula 5,
each of Y, R¹ to R⁵ and a3 to a5 is a same as defined in Chemical Formula 2;
X¹⁵ is CR³ or N;
a31 is 3 when R¹ is hydrogen, and a31 is 0, 1, 2 or 3 when R¹ is other than hydrogen; and
a32 is 2 when R² is hydrogen, and a32 is 0, 1 or 2 when R² is other than hydrogen.

5. The organometallic compound of claim 1, wherein the L_{A} has the following structure of Chemical Formula 6: 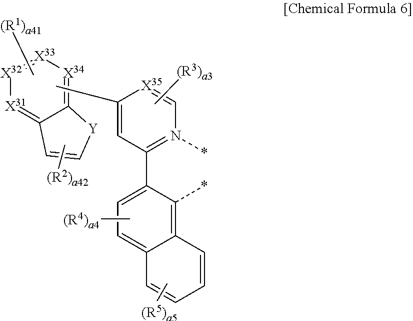
wherein, in the Chemical Formula 6,
each of Y, R³ to R⁵ and a3 to a5 is a same as defined in Chemical Formula 2;
each of X³¹ to X³⁴ is independently CR¹, N or a carbon atom linked to a hetero aromatic ring including X³⁵, where one of X³¹ to X³⁴ is N, the other of X³¹ to X³⁴ is the carbon atom linked to the hetero aromatic ring including X³⁵, and each of others of X³¹ to X³⁴ is independently CR¹;
X³⁵ is CR³ or N;
a41 is 2 when R³ is hydrogen, and a41 is 0, 1 or 2 when R³ is other than hydrogen; and
a42 is 1 when R² is hydrogen, and a42 is 0, 1 or 2 when R² is other than hydrogen.

6. The organometallic compound of claim 1, wherein the L_{A} has the following structure of Chemical Formula 7: 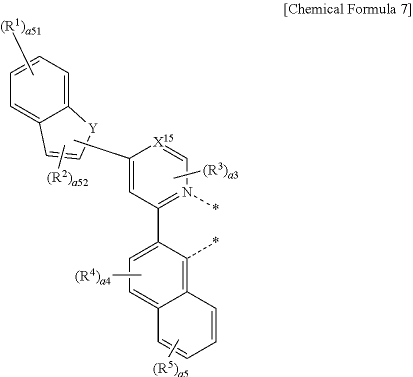
wherein, in the Chemical Formula 7,
each of Y, R¹ to R⁵ and a3 to a5 is a same as defined in Chemical Formula 2;
X¹⁵ is CR³ or N;
a51 is 4 when R¹ is hydrogen, and a51 is 0, 1, 2, 3 or 4 when R¹ is other than hydrogen; and
a52 is 1 when R² is hydrogen, and a52 is 0 or 1 when R² is other than hydrogen.

7. The organometallic compound of claim 1, wherein the L_{A} has the following structure of Chemical Formula 8: 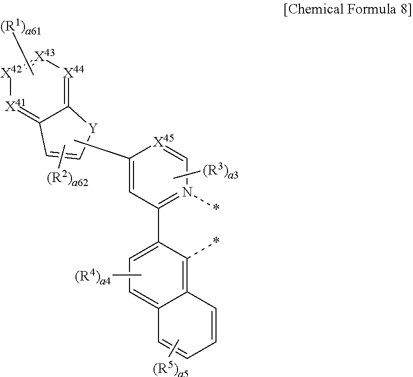
wherein, in the Chemical Formula 8,
each of Y, R¹ to R⁵ and a3 to a5 is a same as defined in Chemical Formula 2;
each of X⁴¹ to X⁴⁴ is independently CR¹ or N, where one of X⁴¹ to X⁴⁴ is N, and each of others of X⁴¹ to X⁴⁴ is independently CR¹;
X⁴⁵ is CR³ or N;
a61 is 3 when R¹ is hydrogen, and a61 is 0, 1, 2 or 3 when R¹ is other than hydrogen; and
a62 is 1 when R² is hydrogen, and a62 is 0 or 1 when R² is other than hydrogen.

8. The organometallic compound of claim 1, wherein the L_{B} has the following structure of Chemical Formula 9A or Chemical Formula 9B: 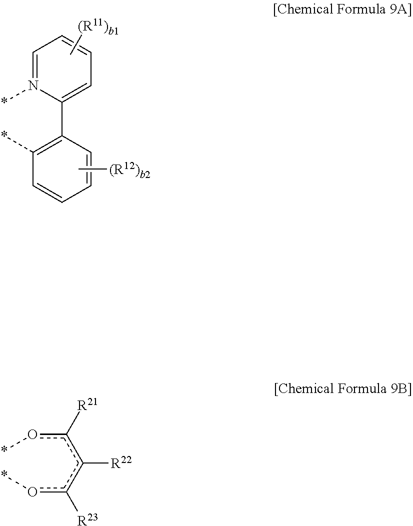
wherein, in the Chemical Formulae 9A and 9B,
each of R¹¹, R¹¹ and R²¹ to R²³ is independently hydrogen, halogen, a hydroxyl group, a cyano group, a nitro group, an amidino group, a hydrazine group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ alicyclic group, an unsubstituted or substituted C₃-C₃₀ hetero alicyclic group, an unsubstituted or substituted C₆-C₃₀ aromatic group or an unsubstituted or substituted C₃-C₃₀ hetero aromatic group, where each R¹¹ is identical to or different from each other when b1 is 2, 3 or 4, and where each R¹² is identical to or different from each other when b2 is 2, 3 or 4;
optionally,
two adjacent R¹¹ when b1 is 2, 3 or 4, and/or
two adjacent R¹² when b2 is 2, 3 or 4, and/or
R²¹ and R²² or R²² and R²³
are further linked together to form an unsubstituted or substituted C₄-C₂₀ alicyclic ring, an unsubstituted or substituted C₃-C₂₀ hetero alicyclic ring, an unsubstituted or substituted C₆-C₃₀ aromatic ring or an unsubstituted or substituted C₃-C₃₀ hetero aromatic ring; and
each of b1 and b2 is 4 when each of R¹¹ and R¹² is hydrogen and each of b1 and b2 is independently 0, 1, 2, 3 or 4 when each of R¹¹ and R¹² is other than hydrogen.

9. The organometallic compound of claim 1, wherein each of X¹ to X⁴ in Chemical Formula 2 is independently CR¹ or the carbon atom linked to the hetero aromatic ring including X⁵, Y in Chemical Formula 2 is O or S, and each of R¹ to R⁷ in Chemical Formula 2 is independently hydrogen or a C₁-C₂₀ alkyl group.

10. The organometallic compound of claim 1, wherein one of X¹ to X⁴ in Chemical Formula 2 is N and other three of X¹ to X⁴ is independently CR¹ or the carbon atom linked to the hetero aromatic ring including X⁵, Y in Chemical Formula 2 is O or S, and each R¹ to R⁵ in Chemical Formula 2 is independently hydrogen or a C₁-C₂₀ alkyl group.

11. The organometallic compound of claim 1, wherein the organometallic compound is at least one of:

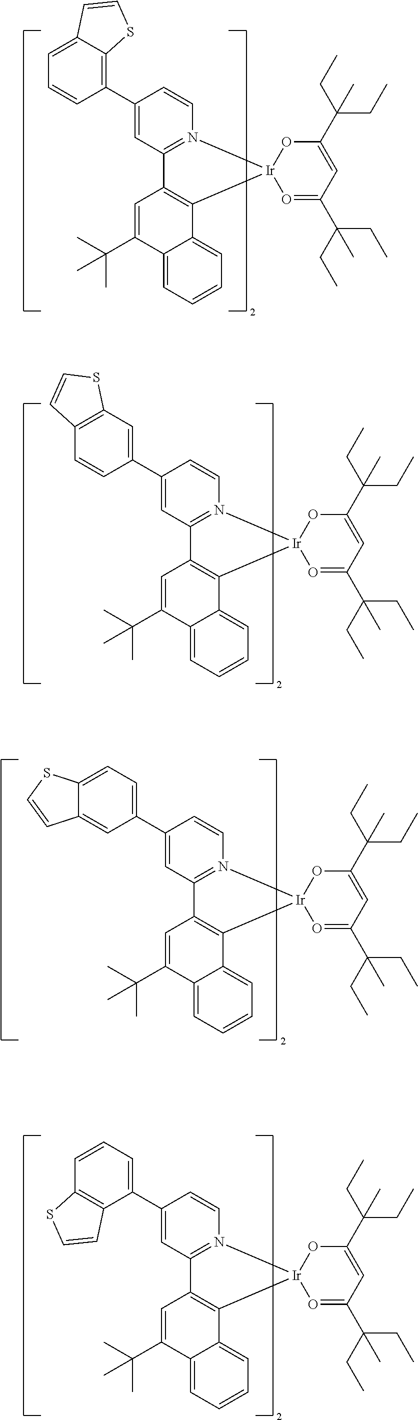

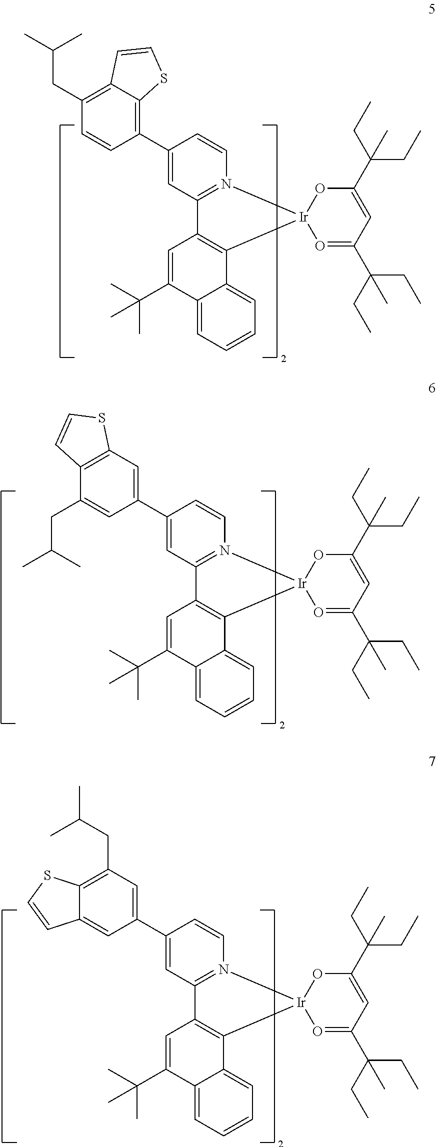

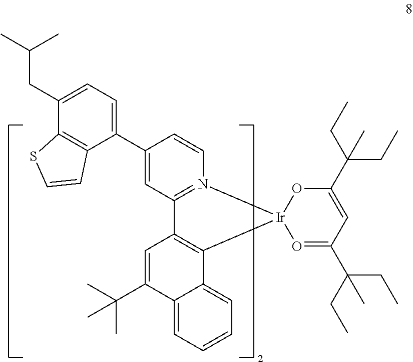

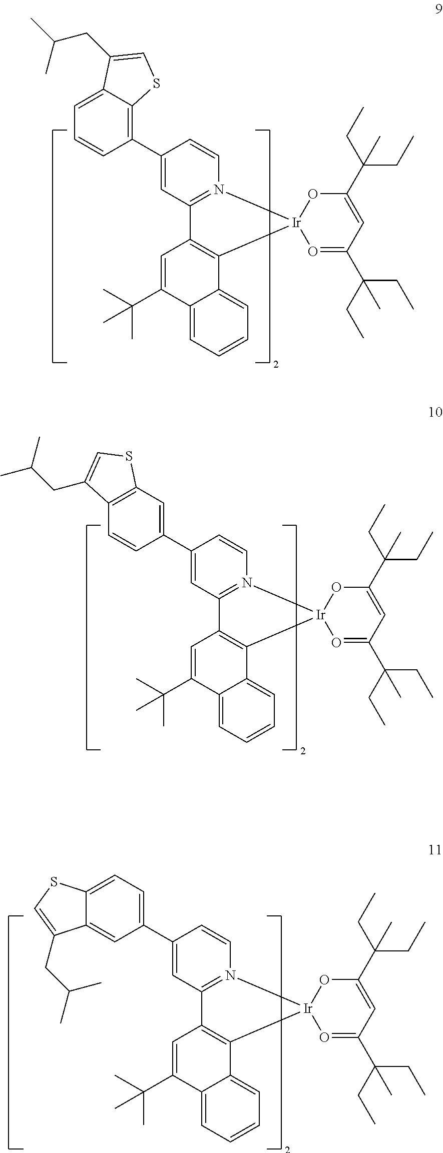

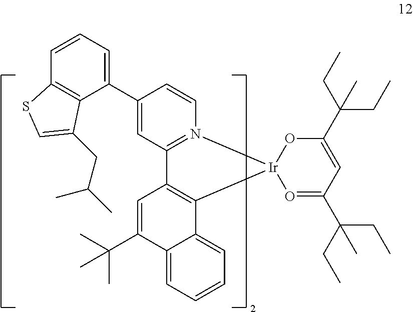

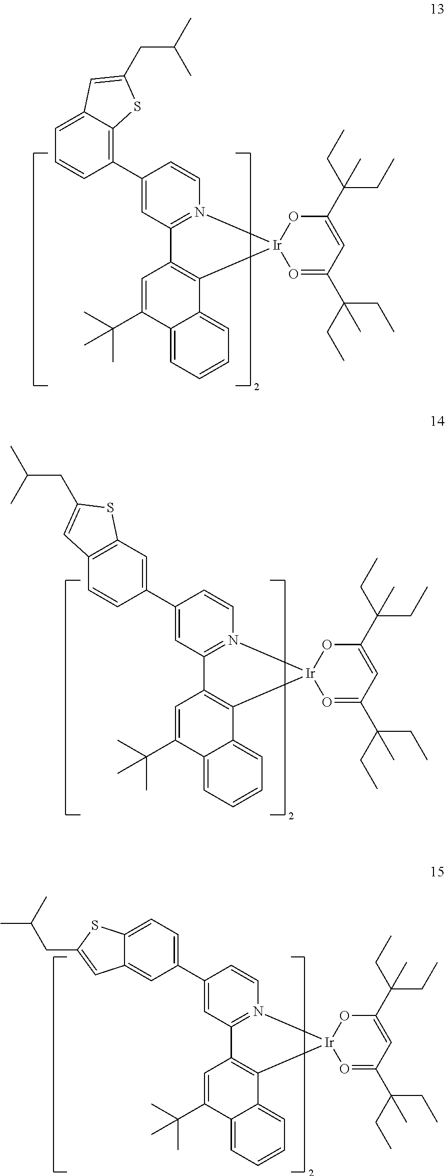

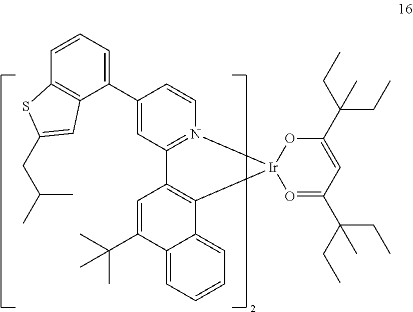

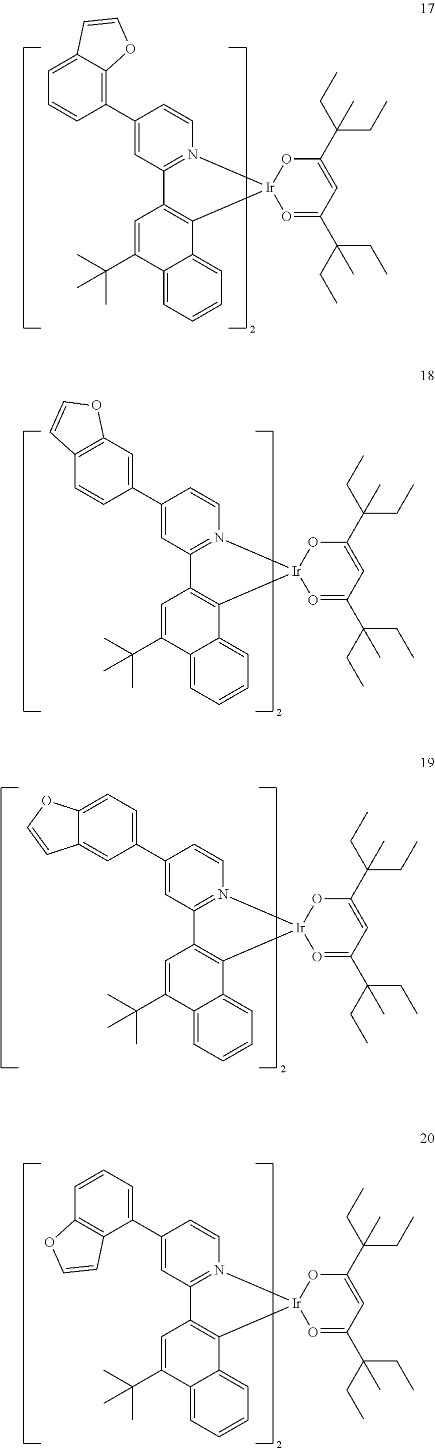

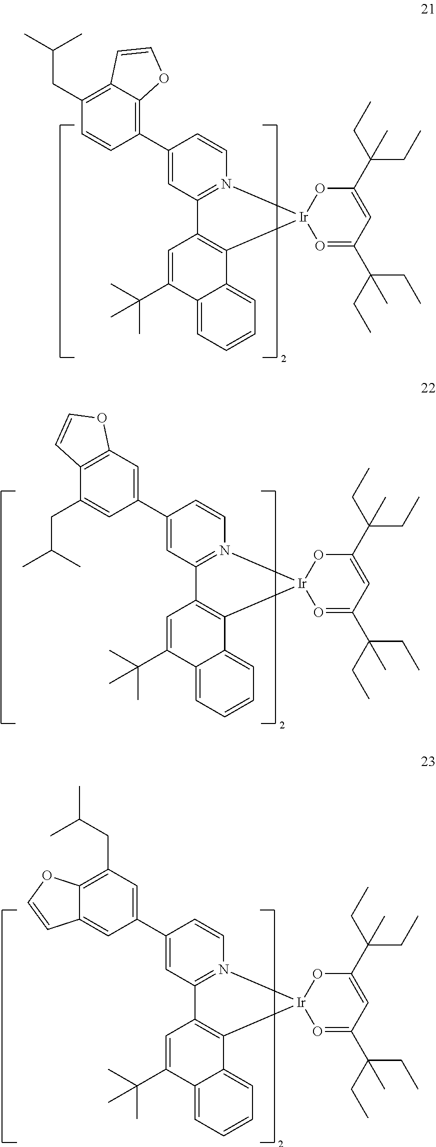

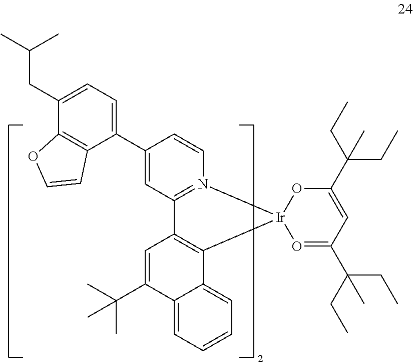

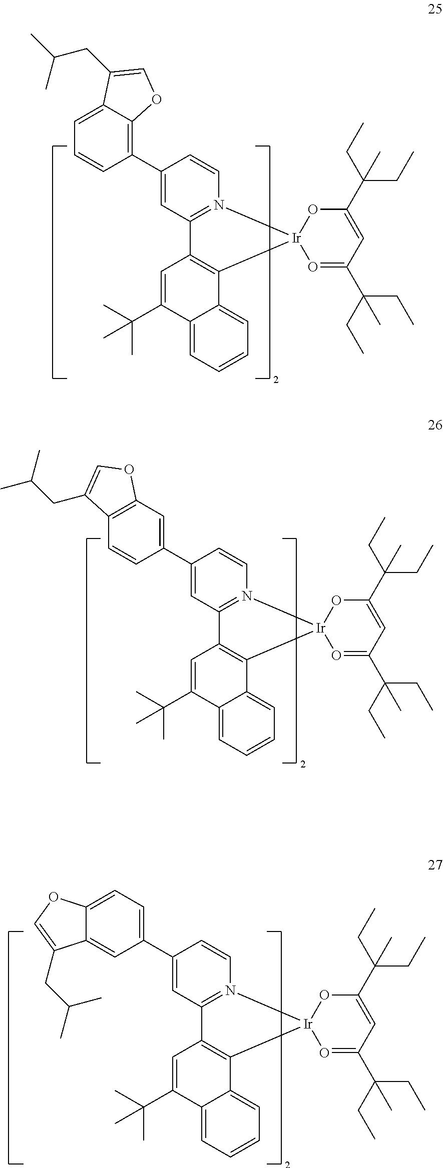

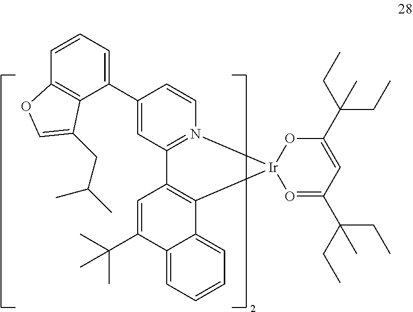

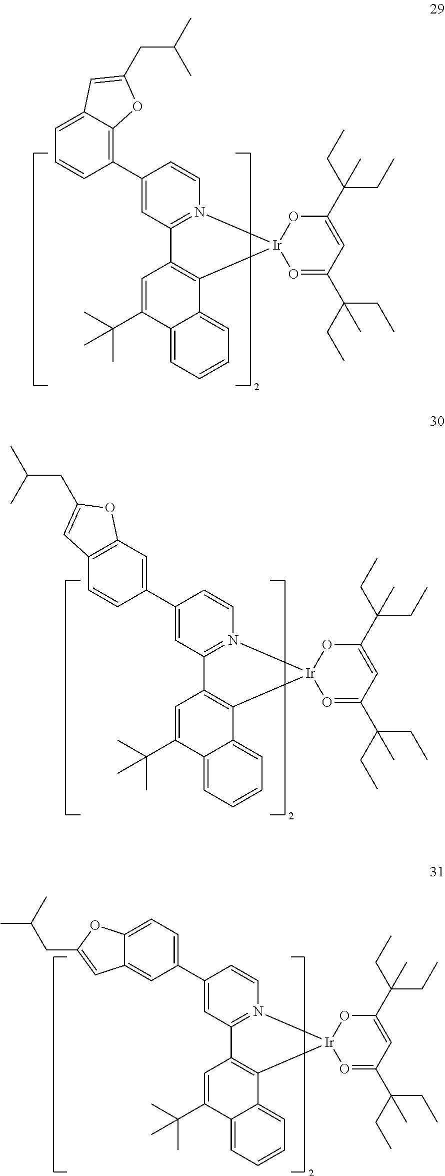

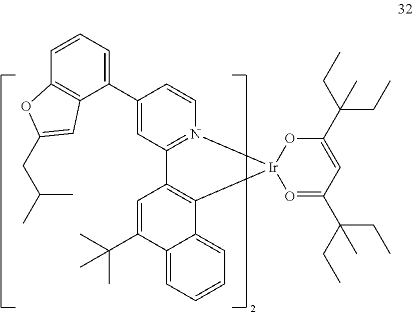

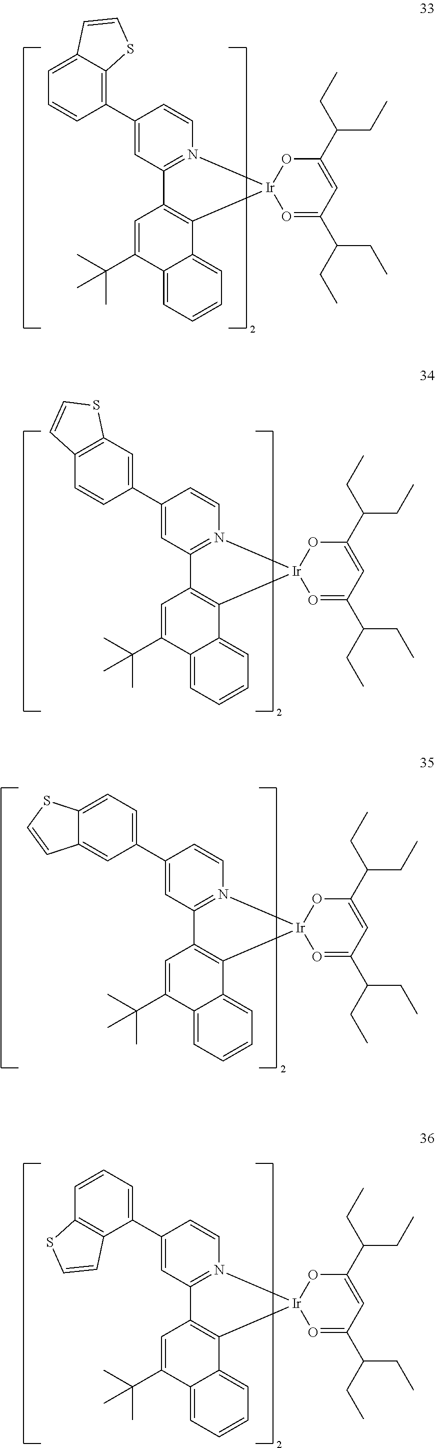

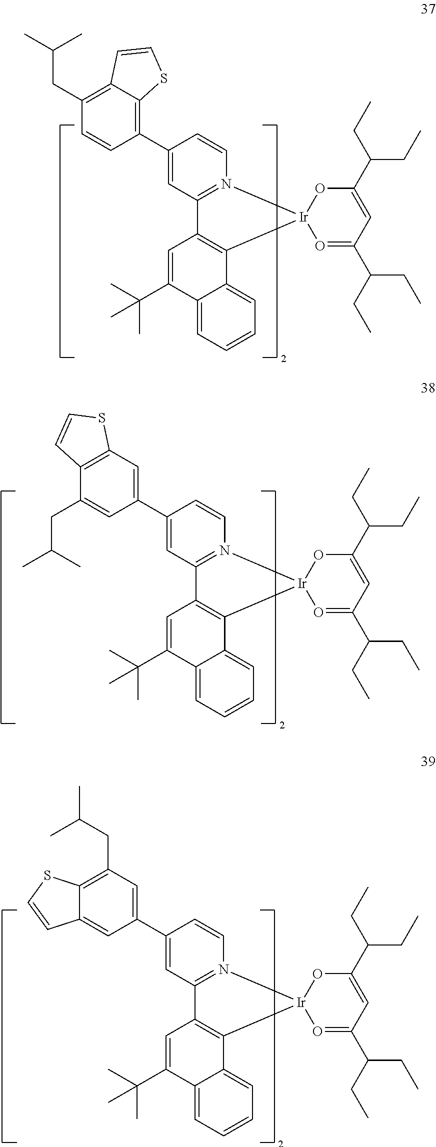

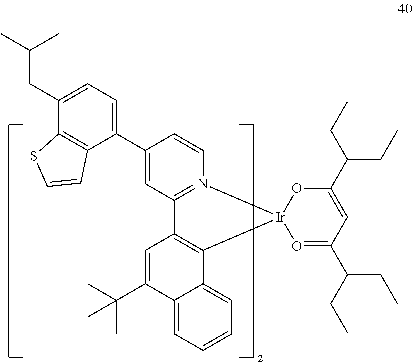

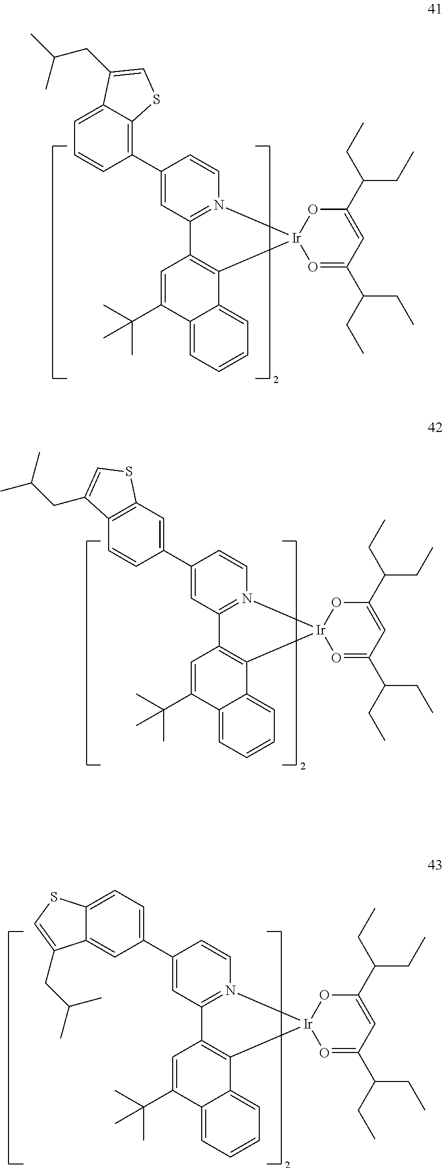

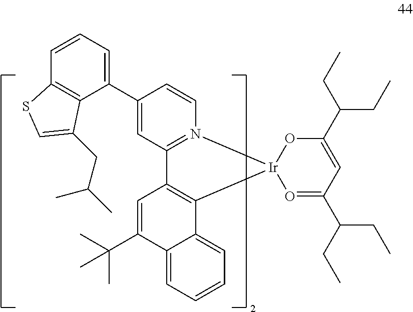

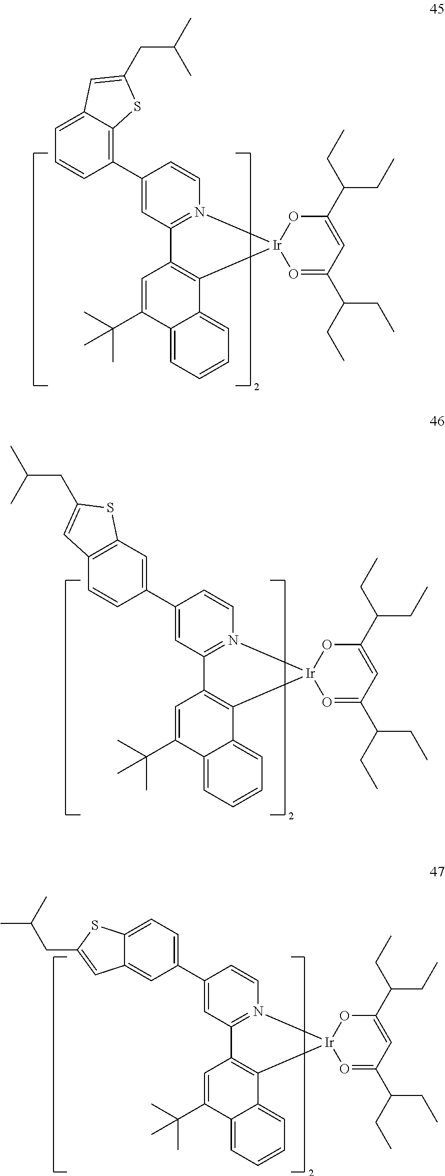

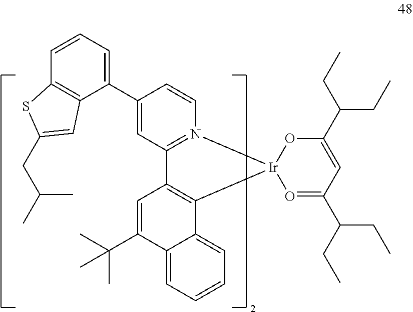

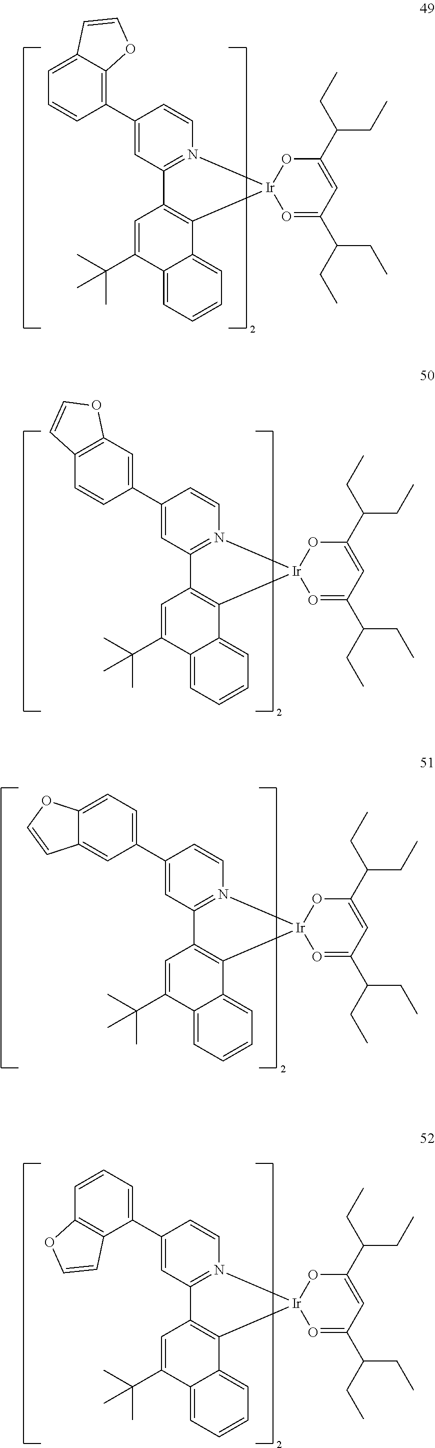

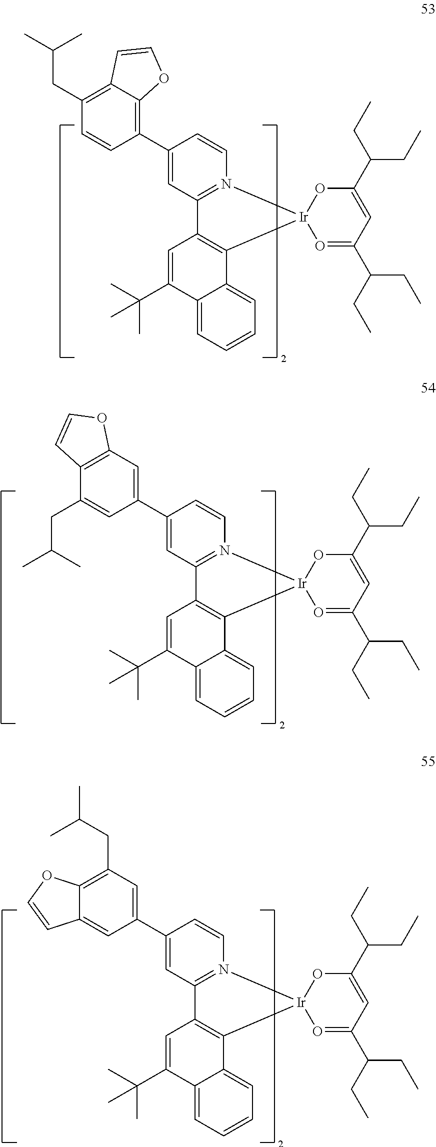

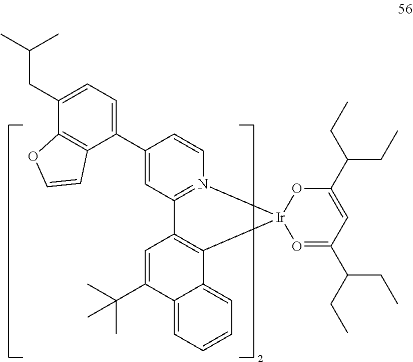

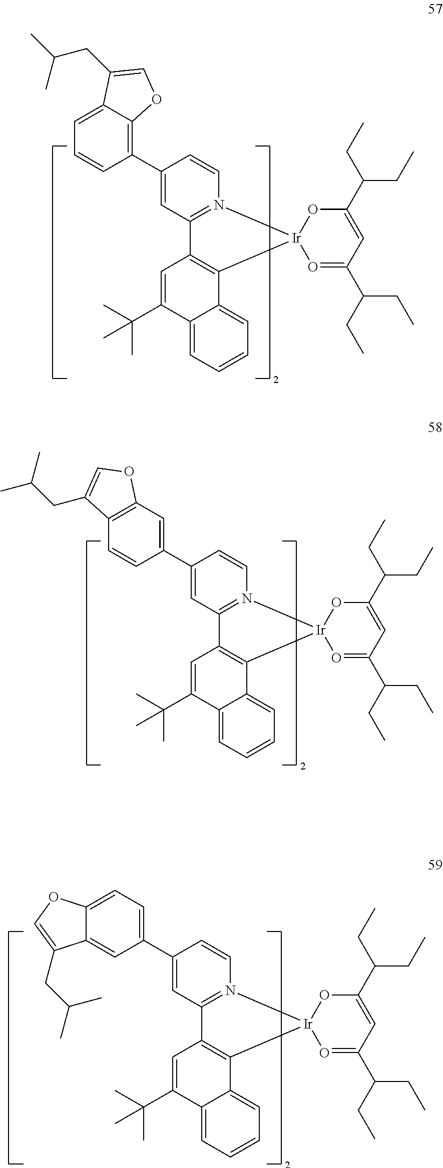

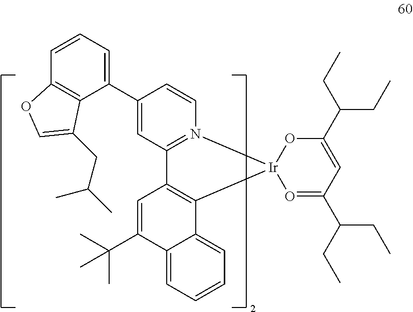

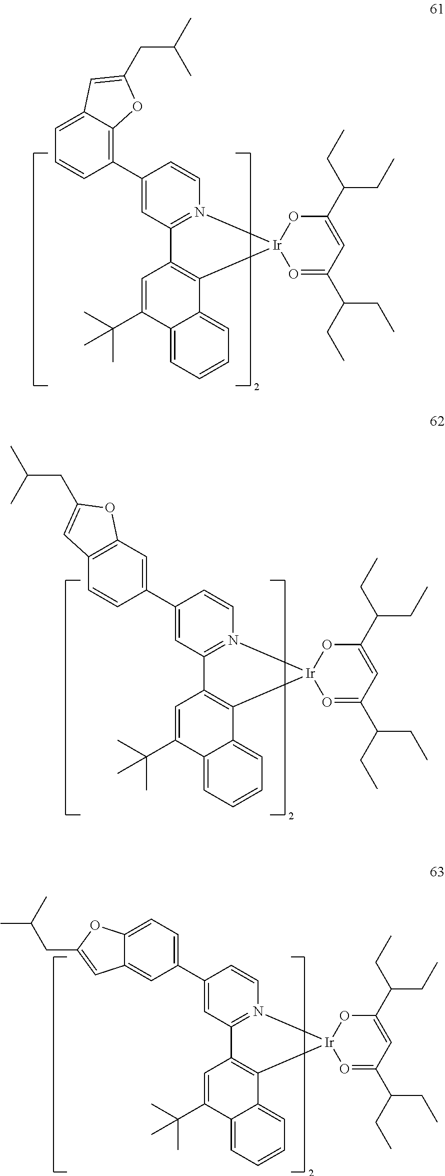

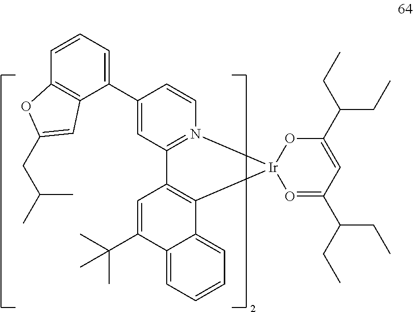

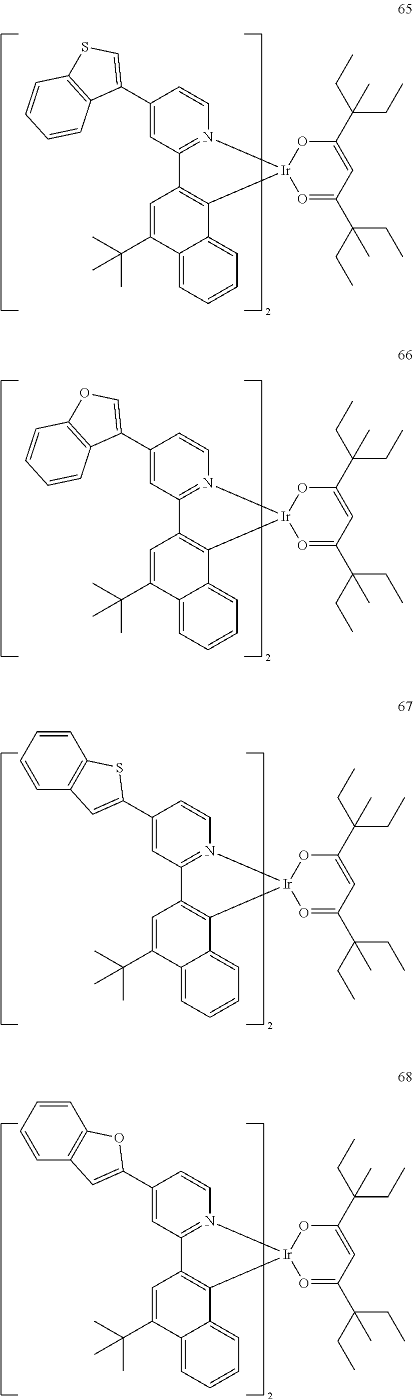

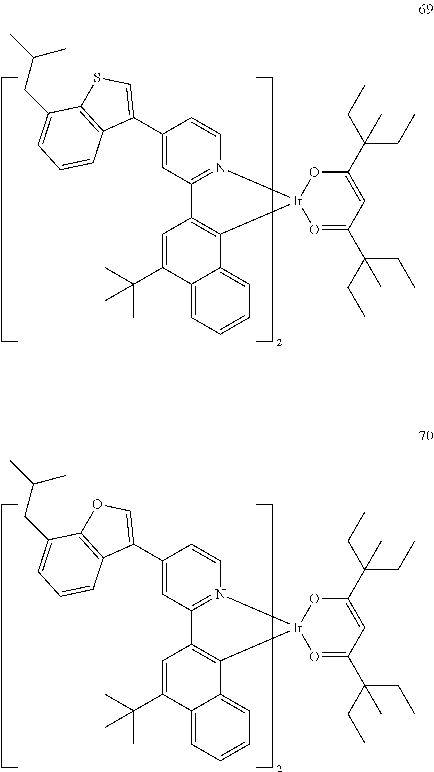

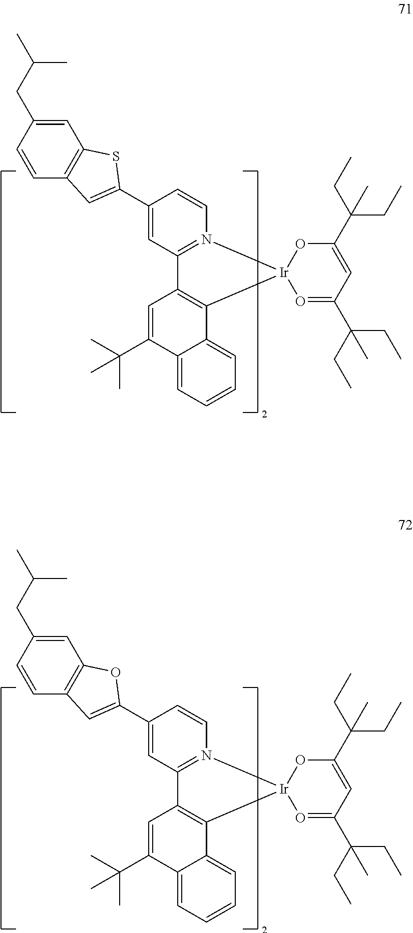

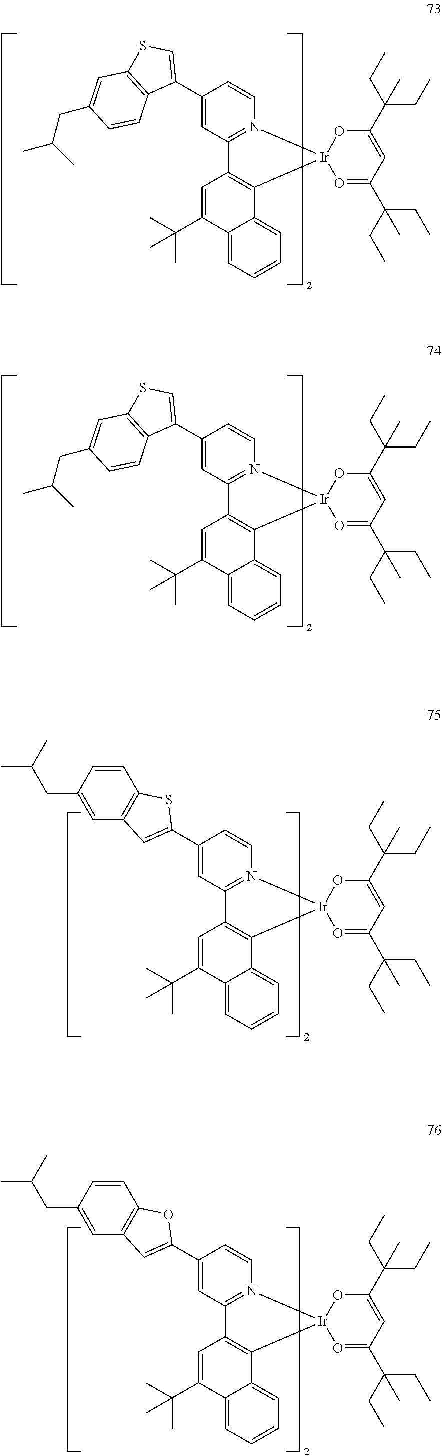

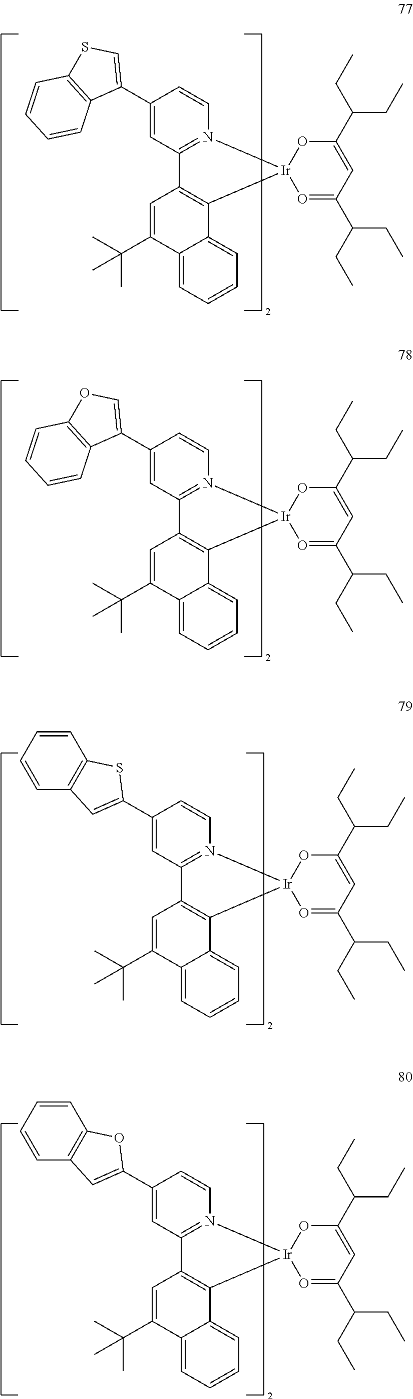

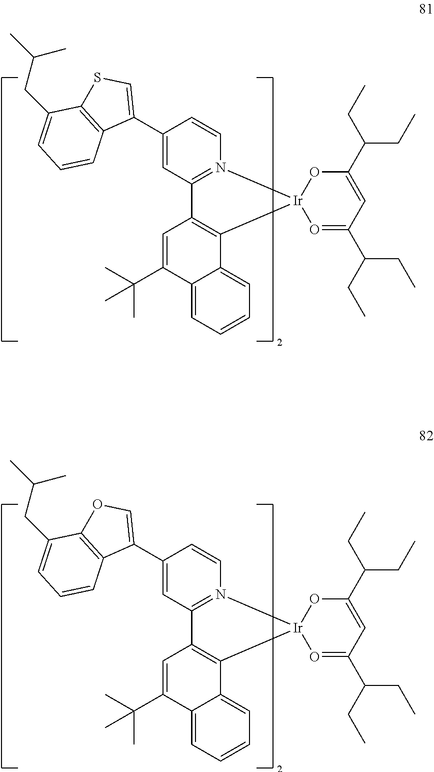

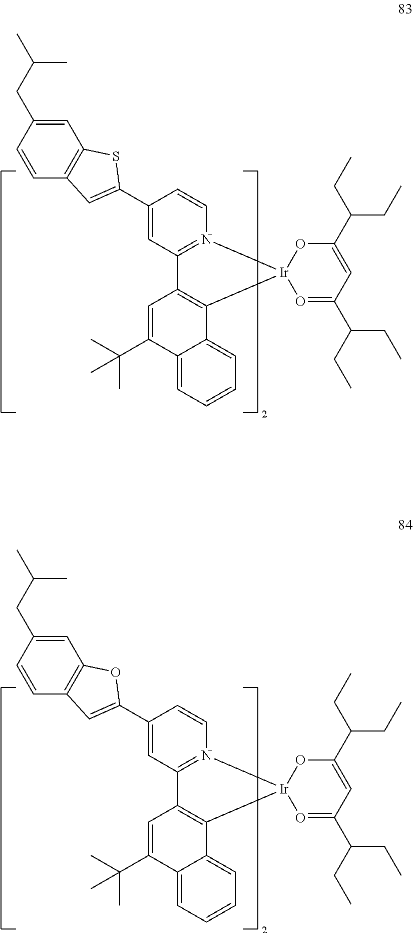

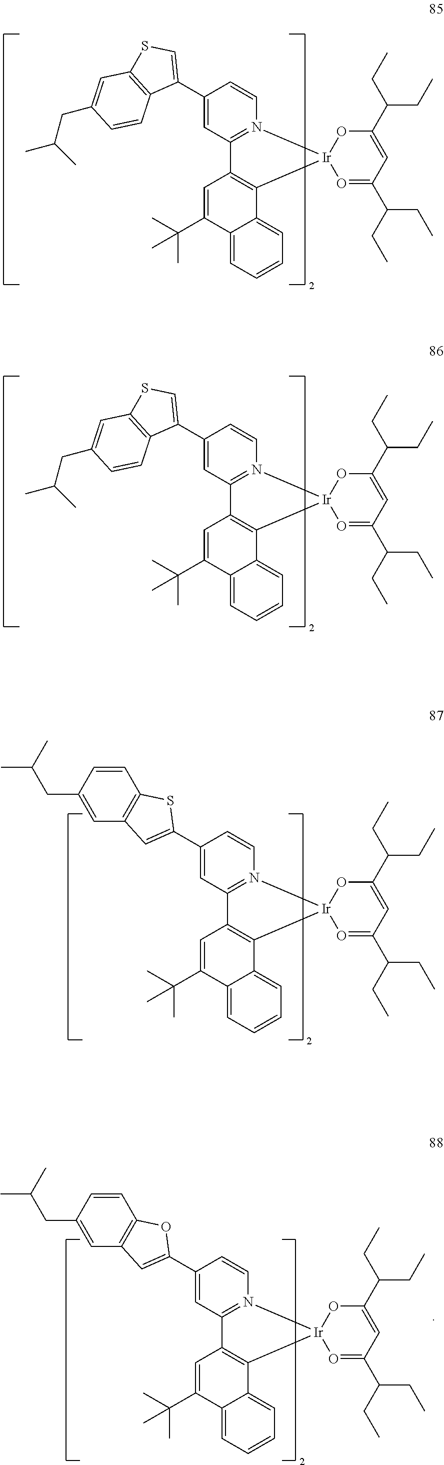

12. The organometallic compound of claim 1, wherein the organometallic compound is at least one of:

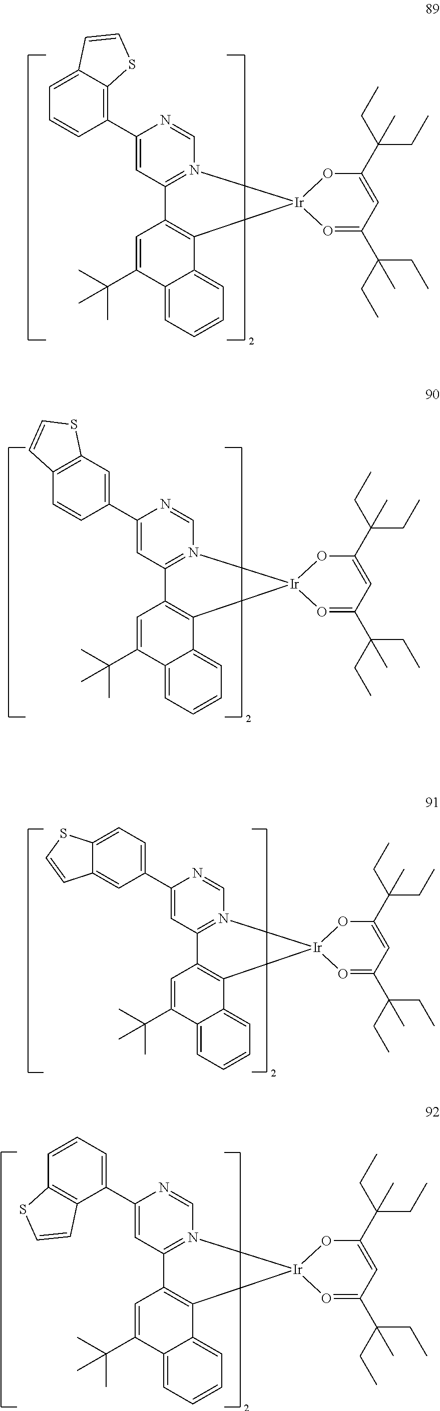

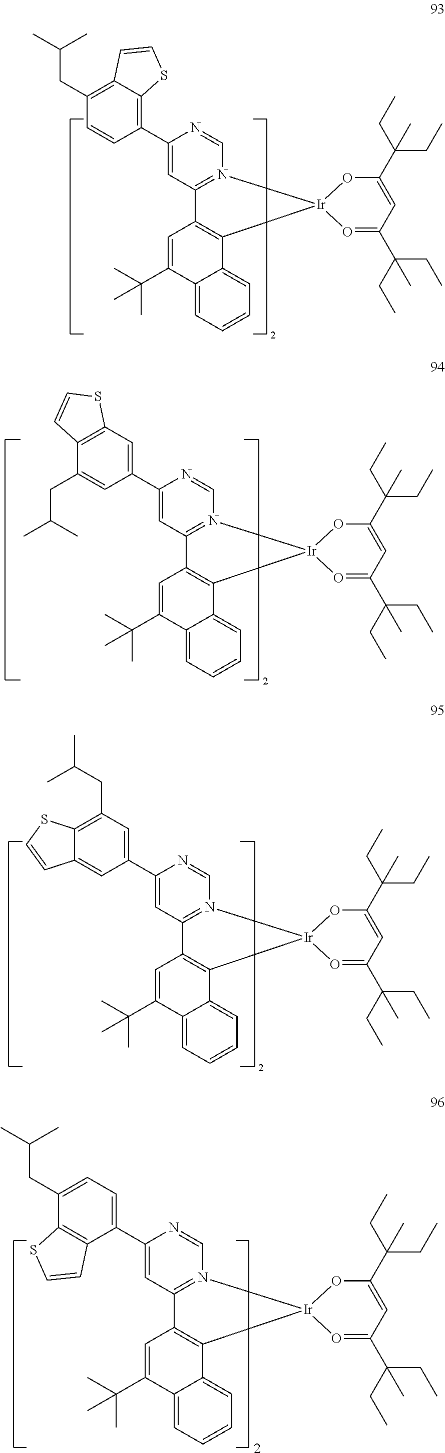

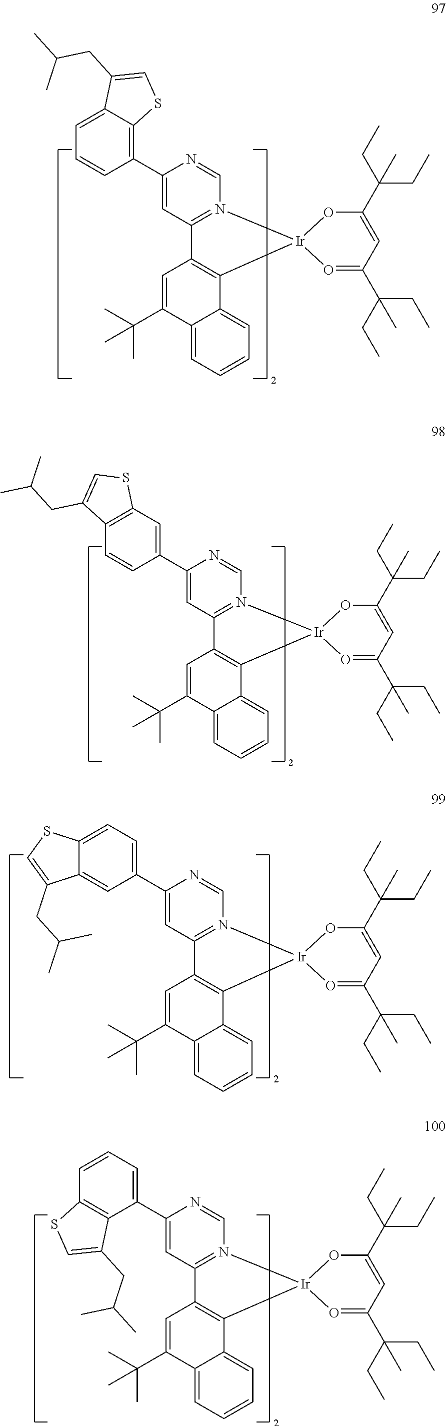

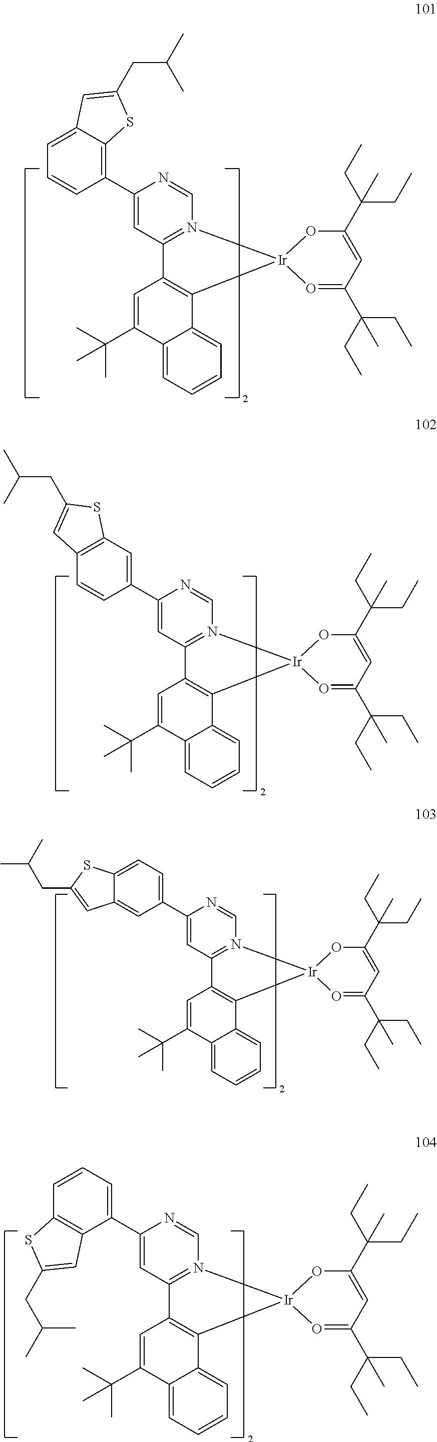

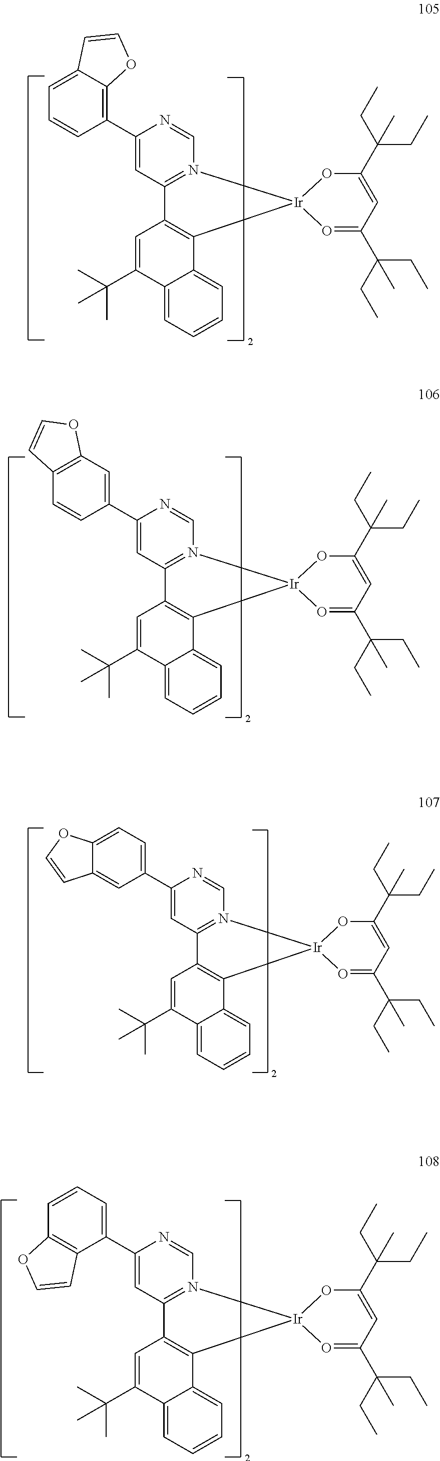

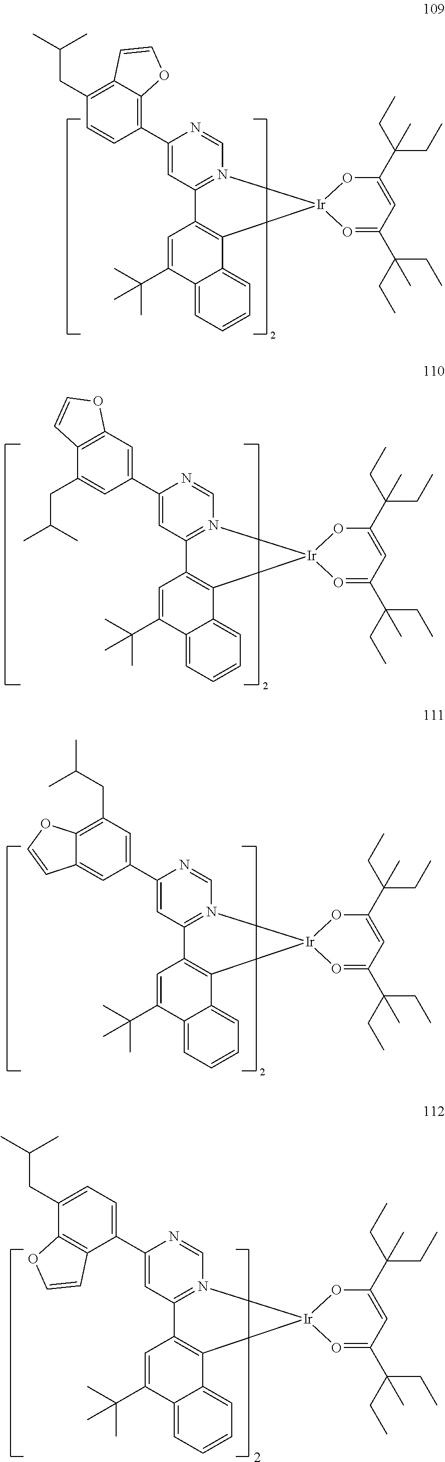

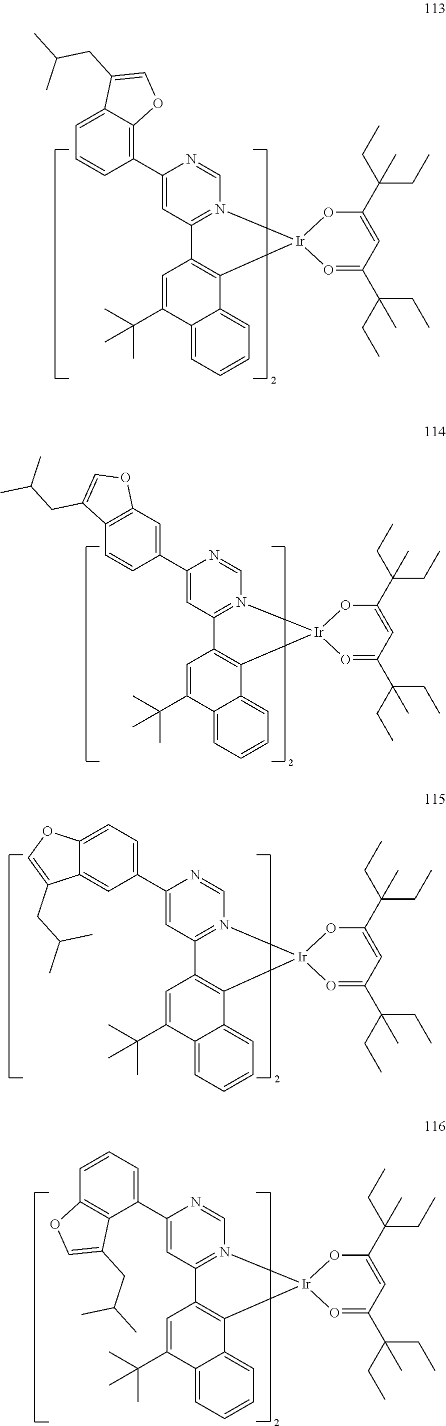

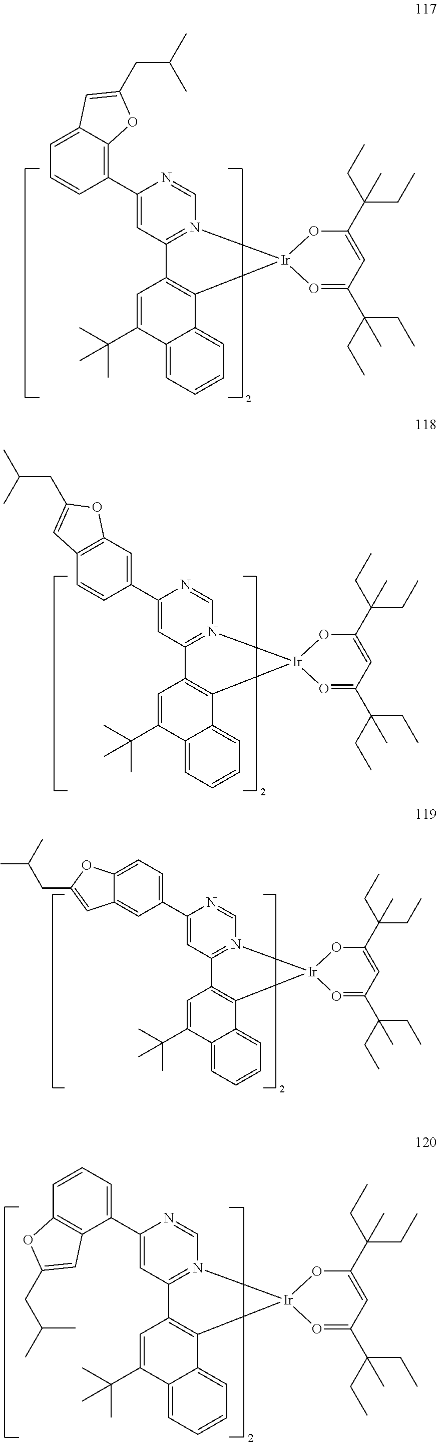

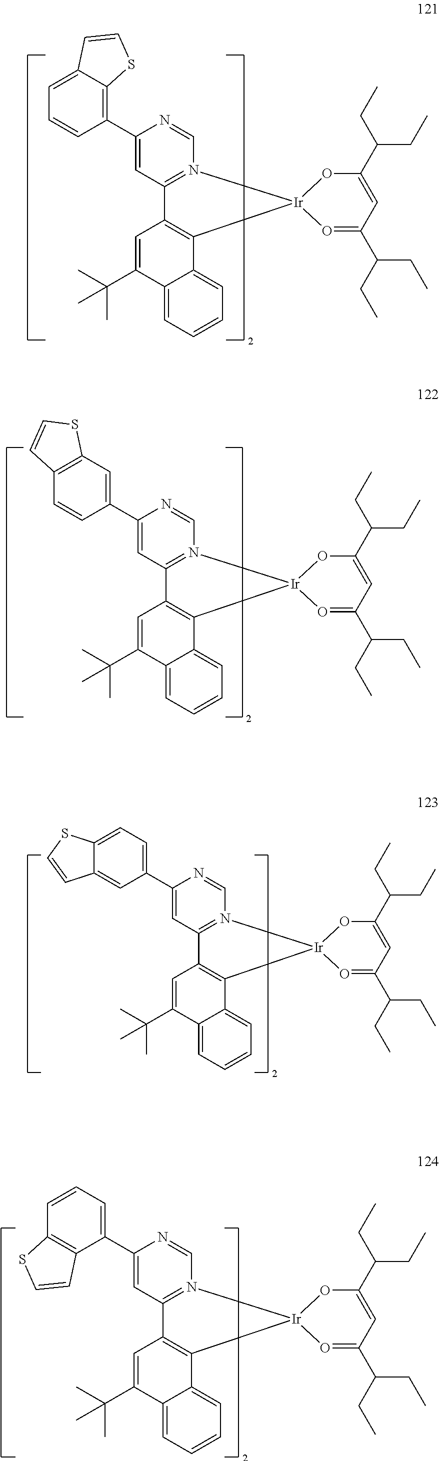

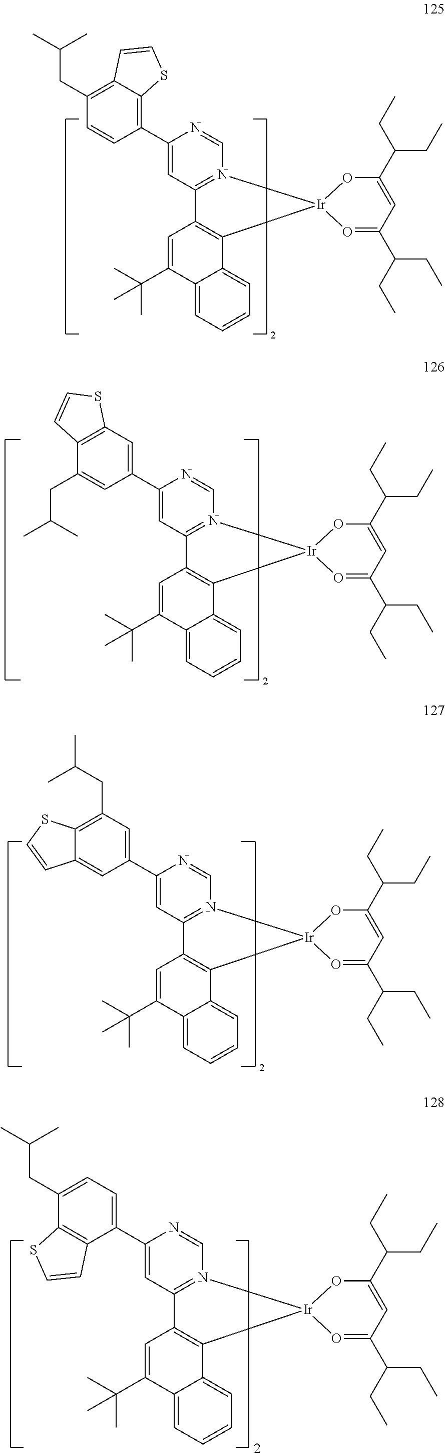

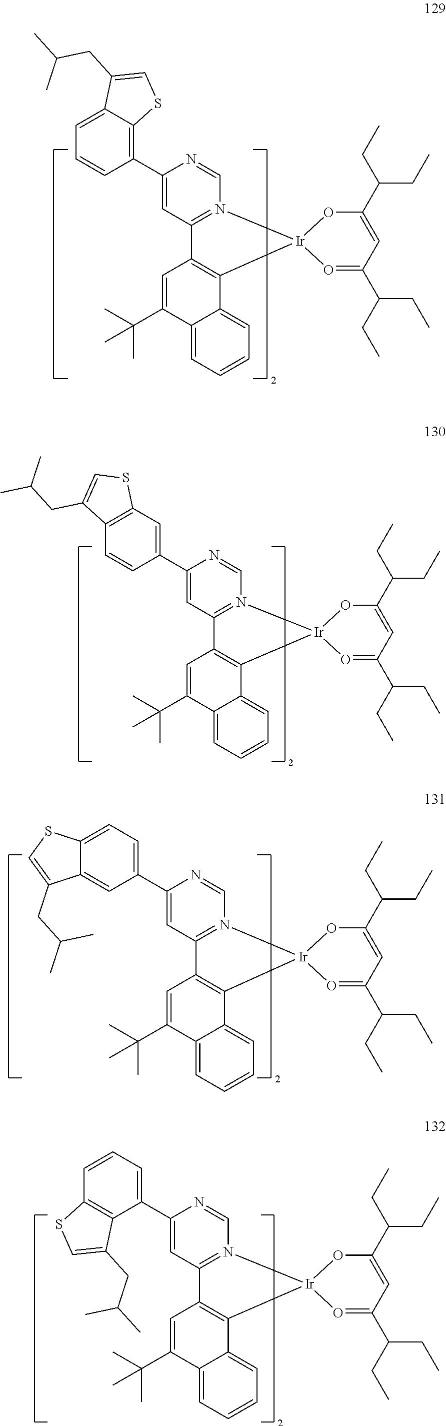

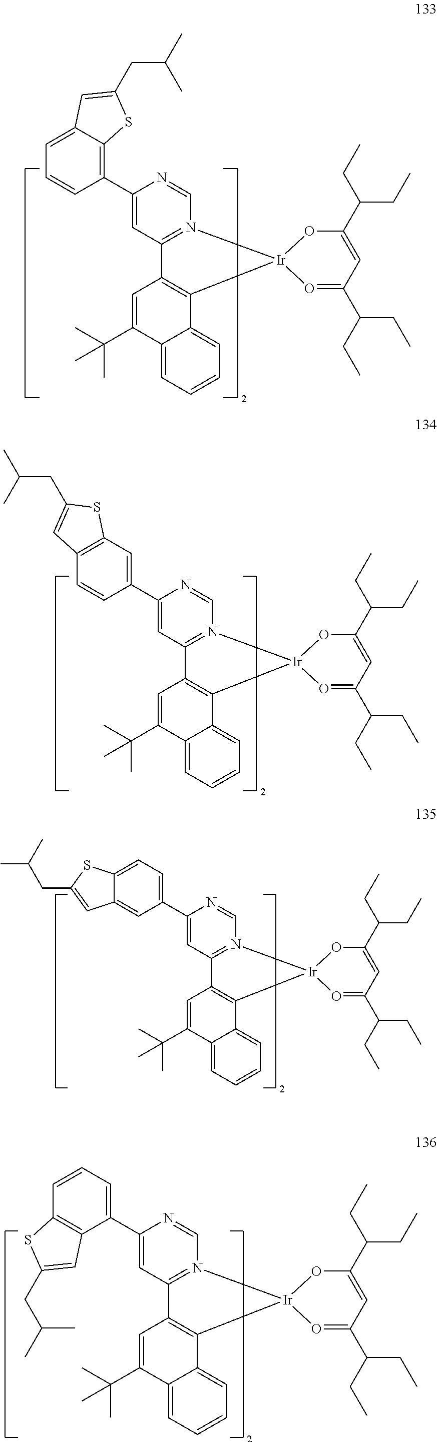

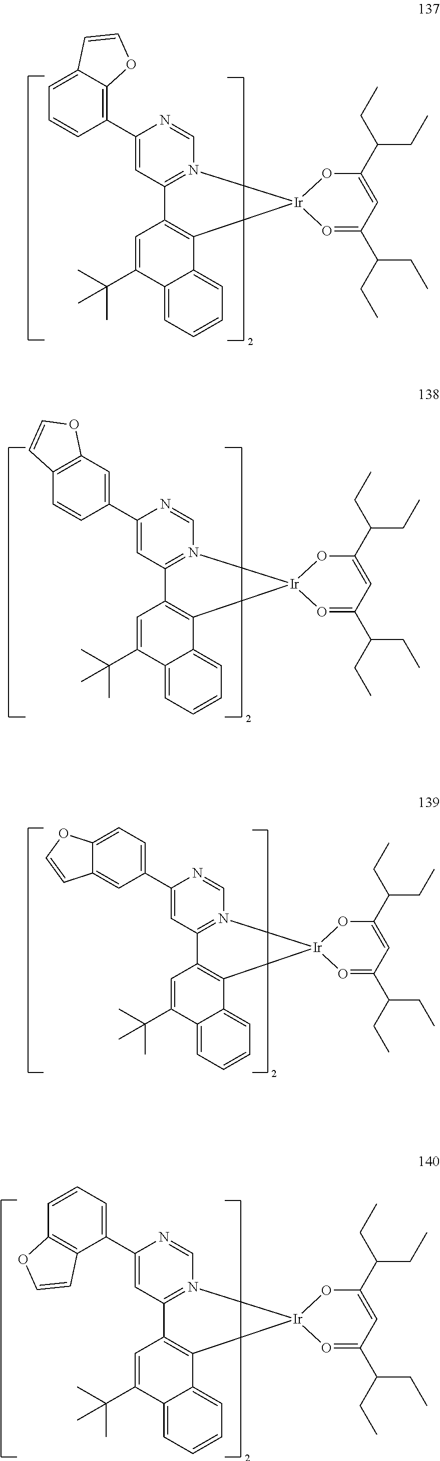

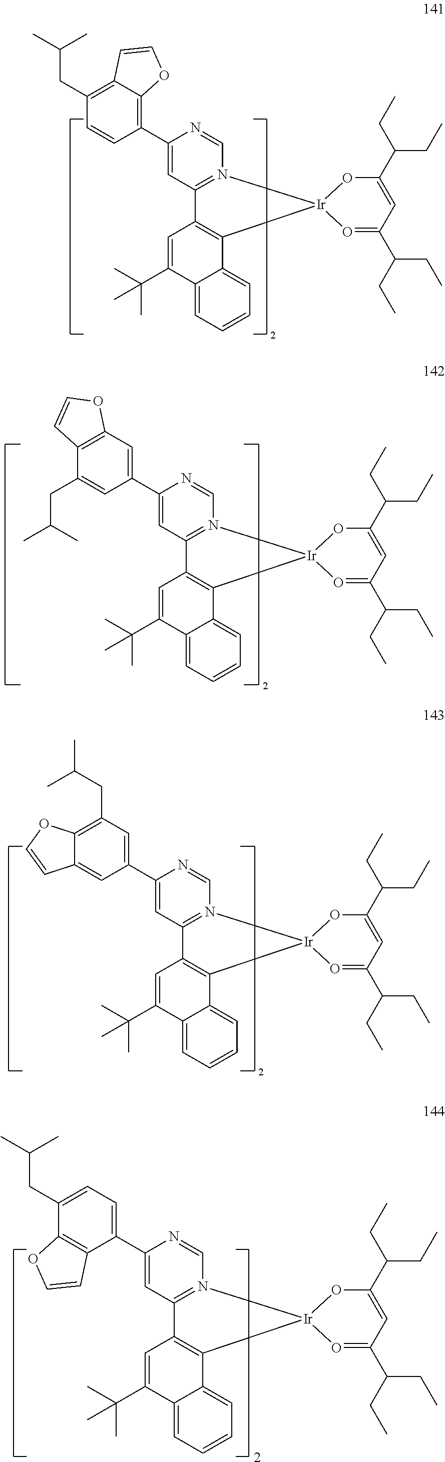

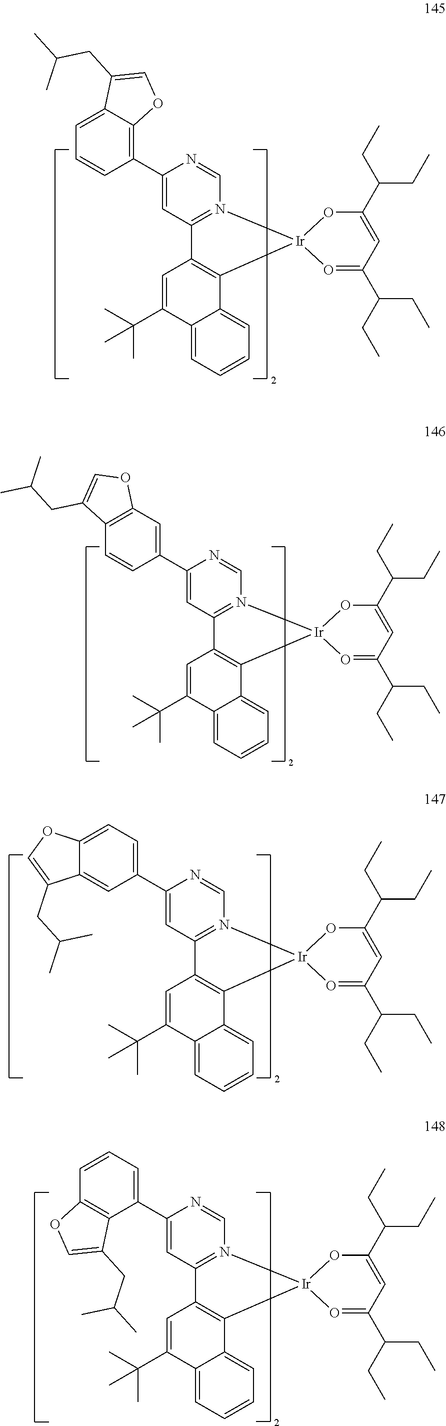

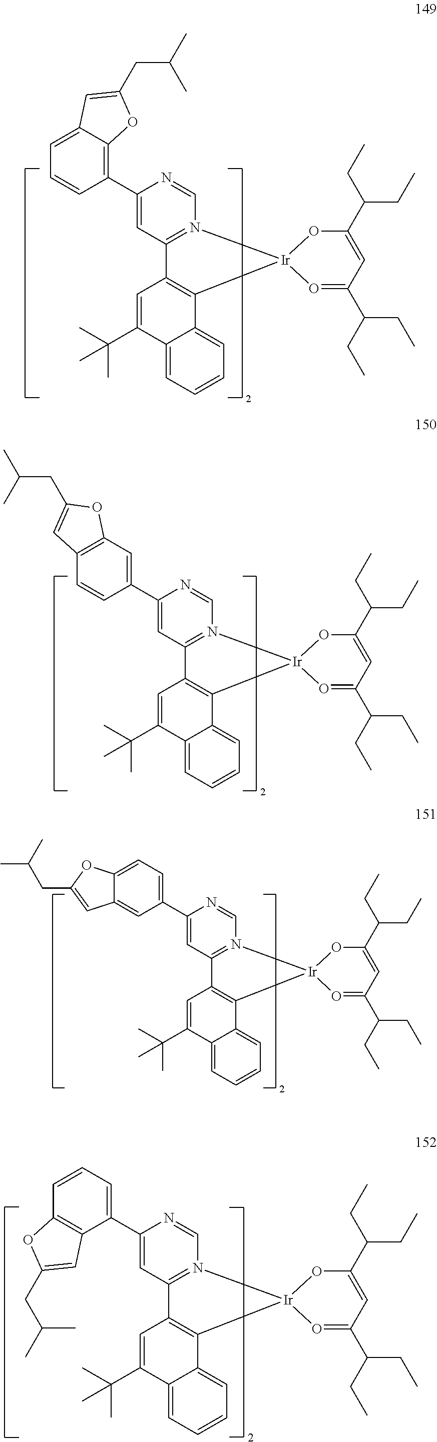

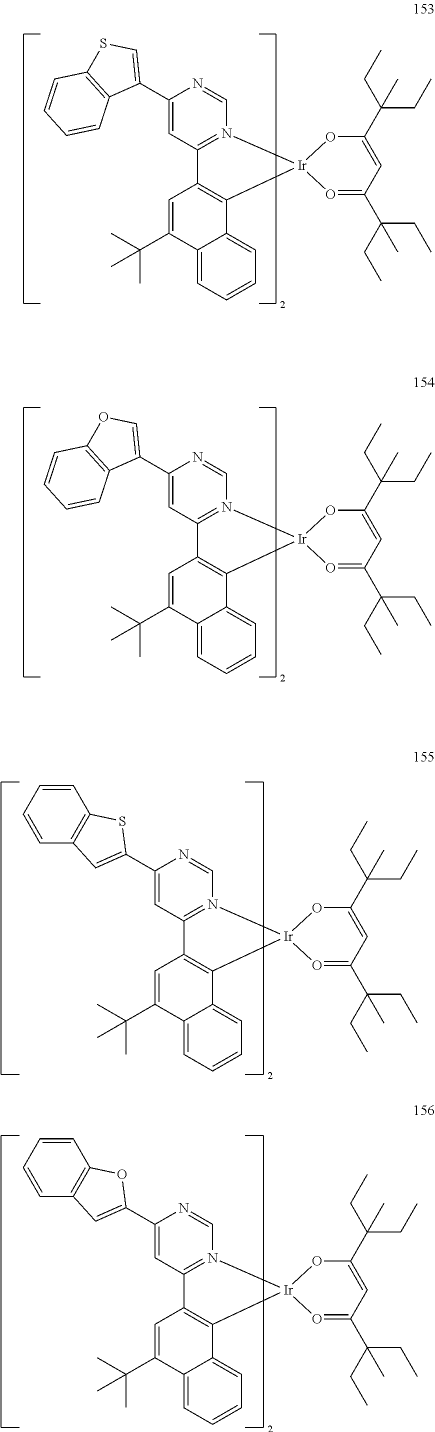

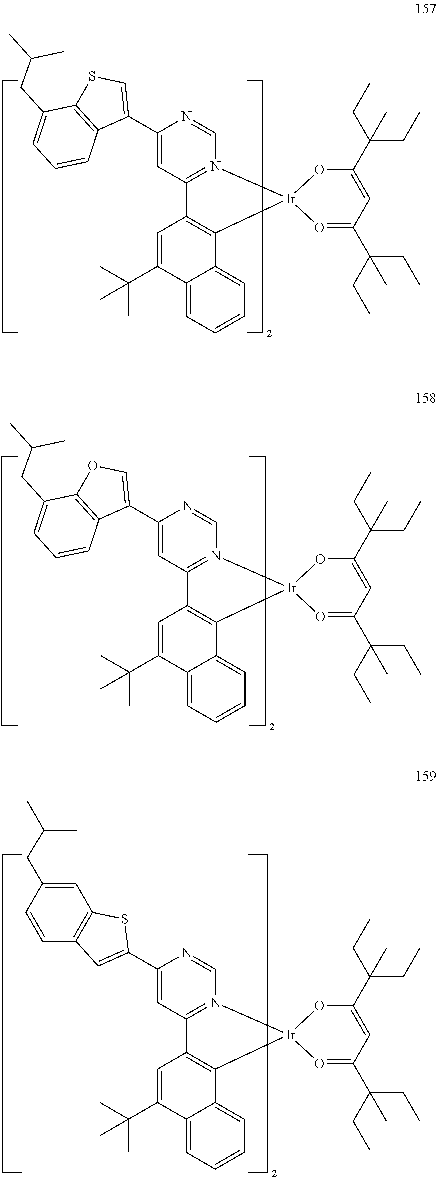

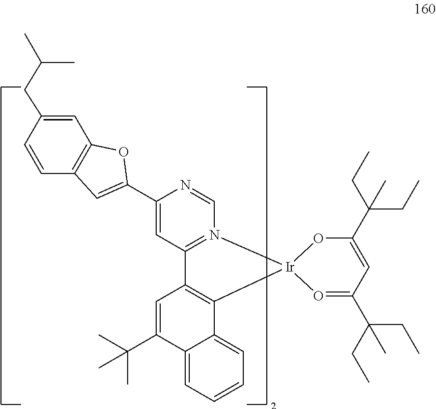

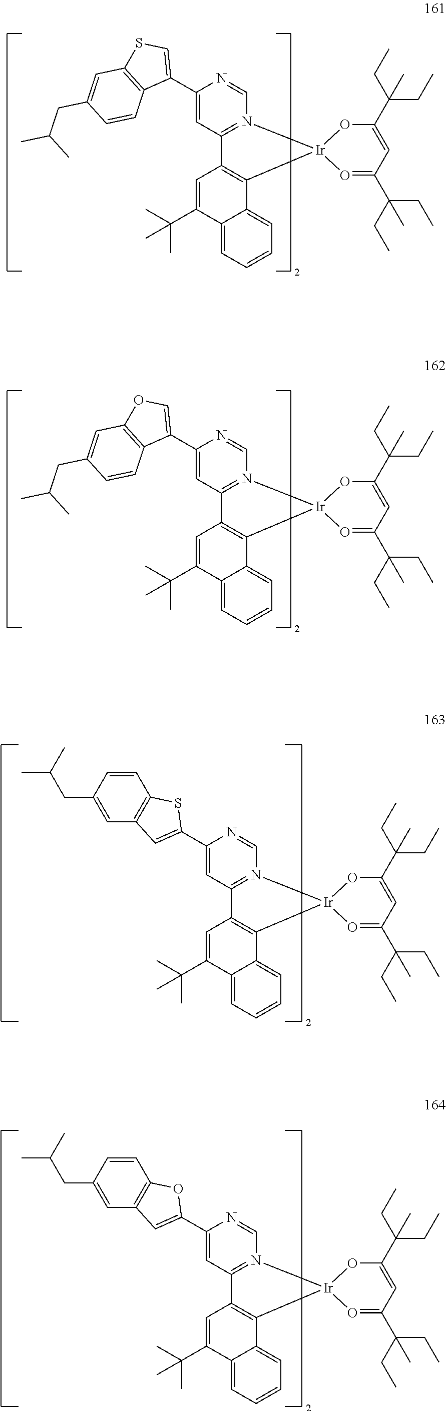

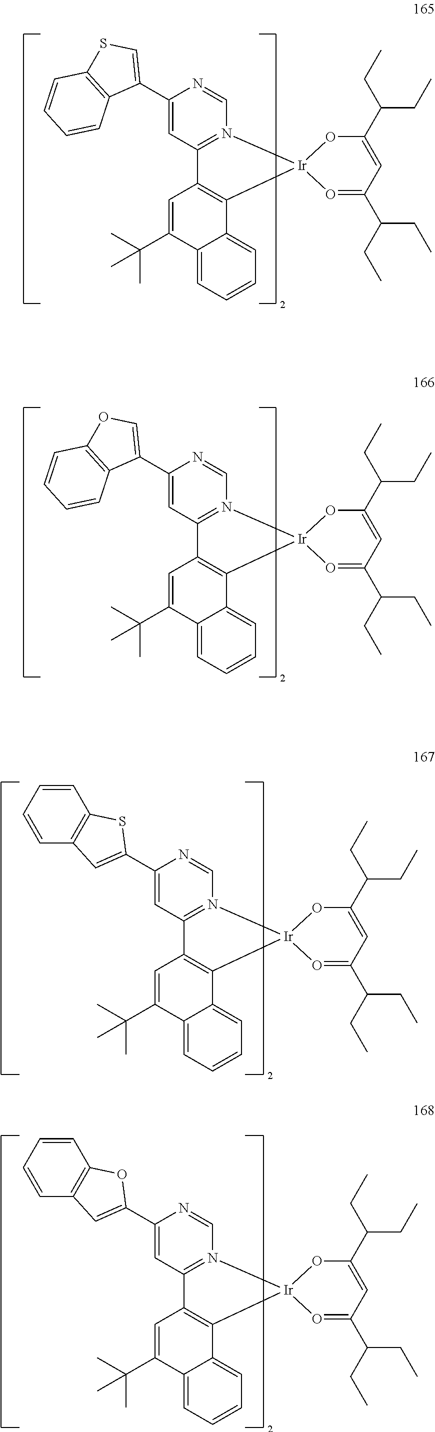

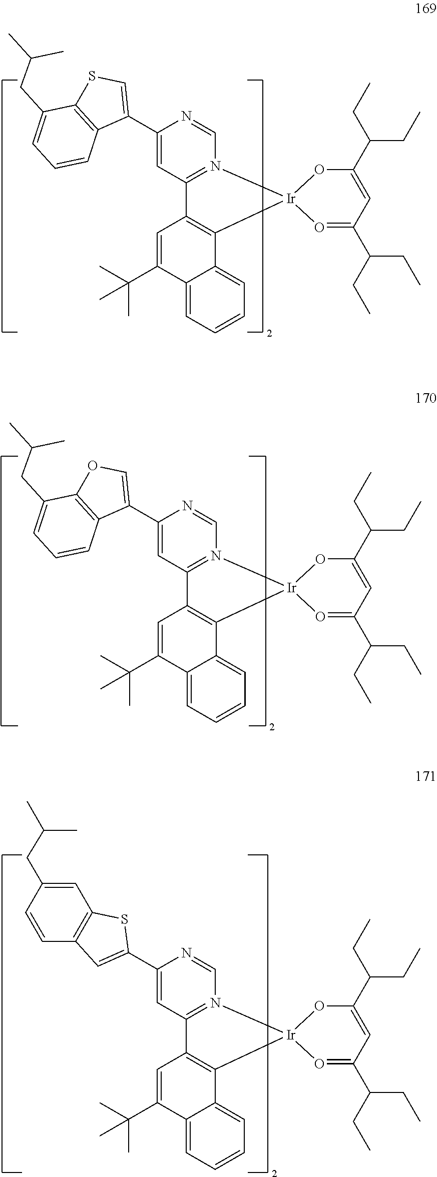

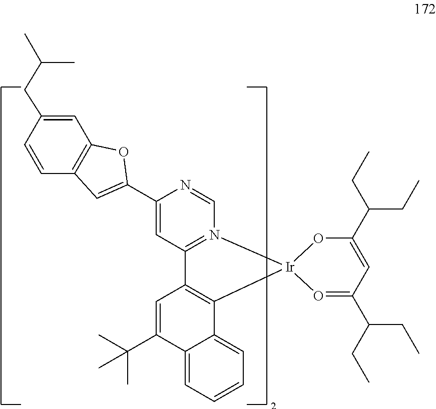

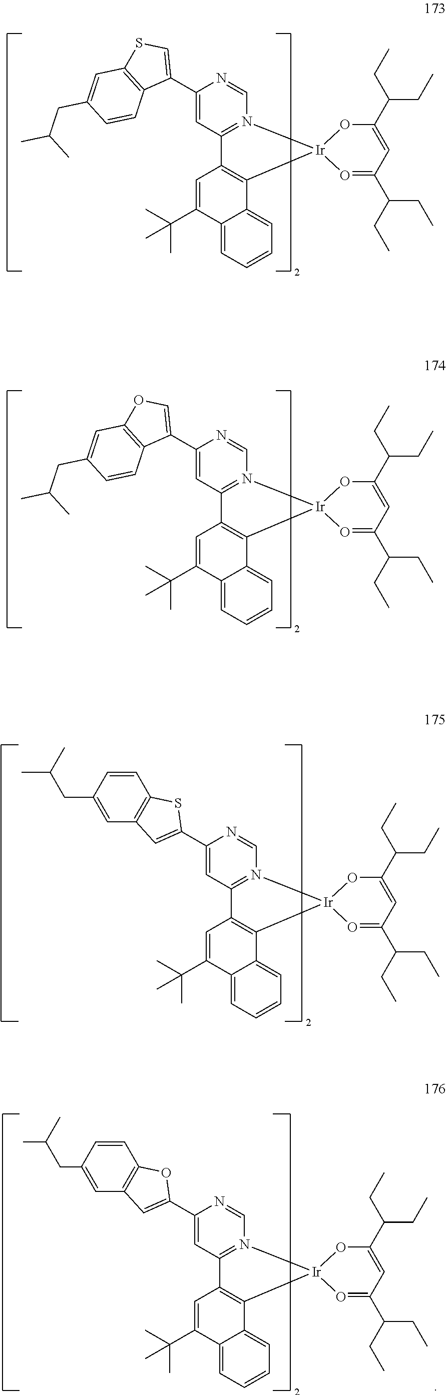

13. The organometallic compound of claim 1, wherein the organometallic compound is at least one of:

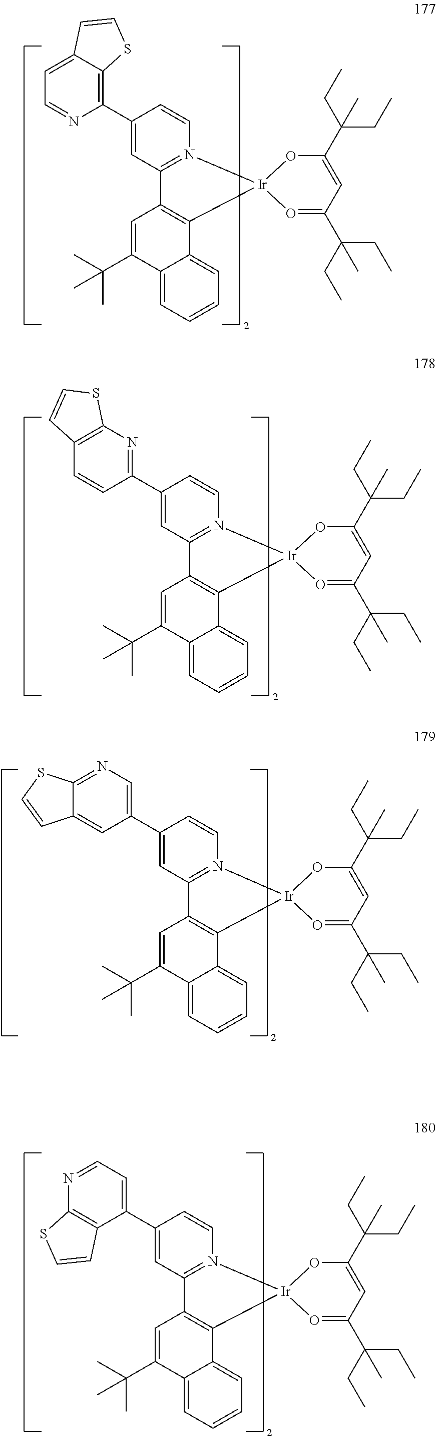

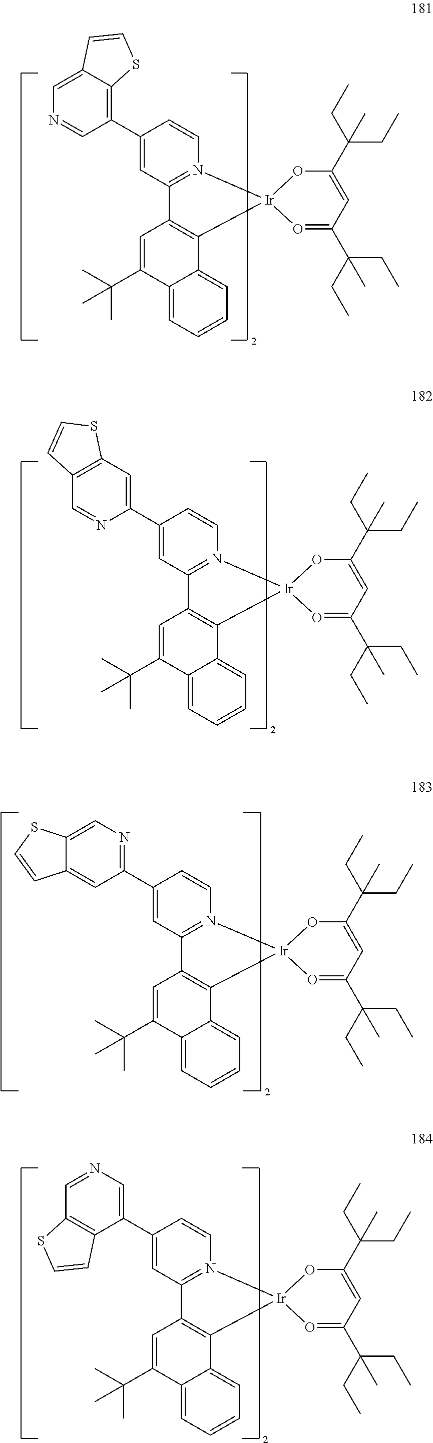

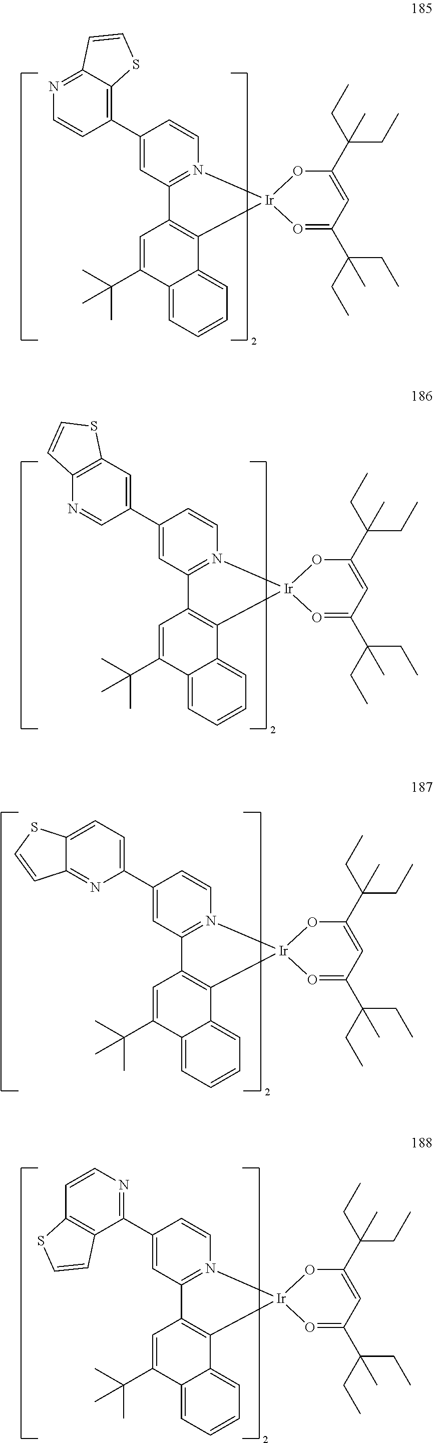

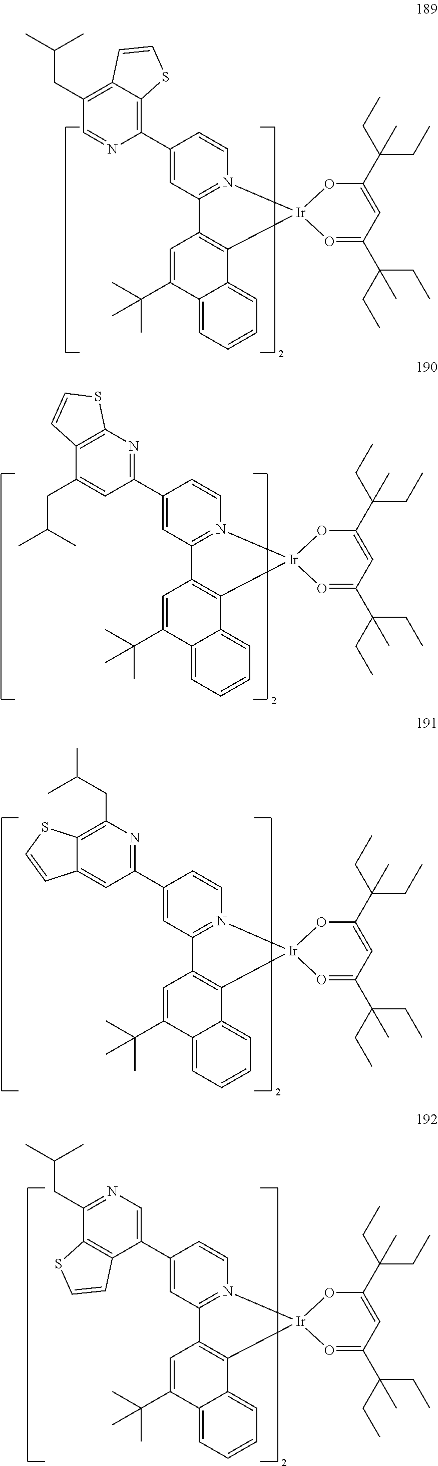

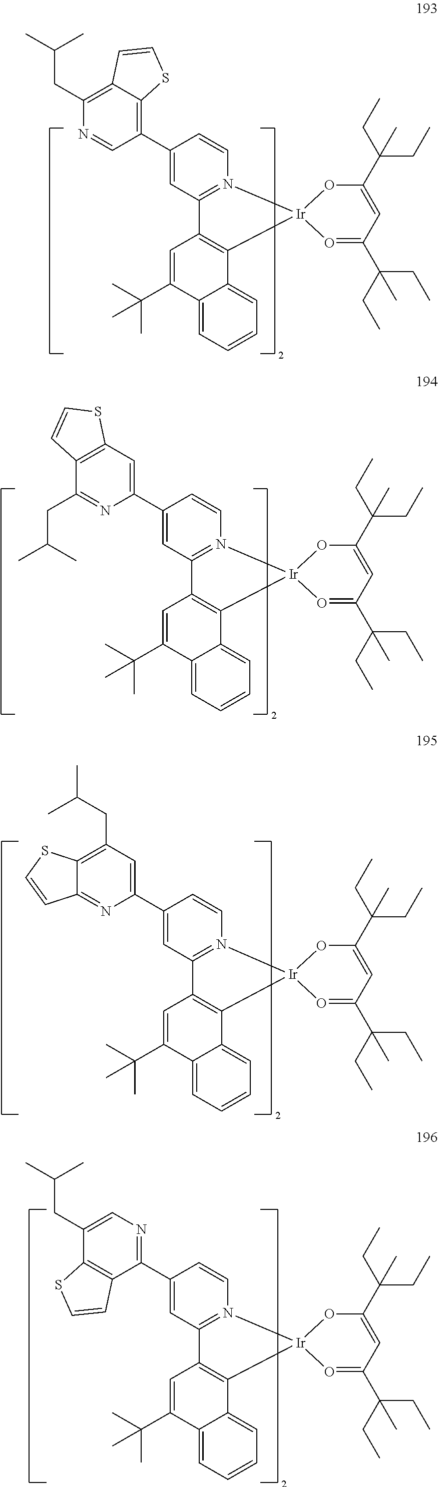

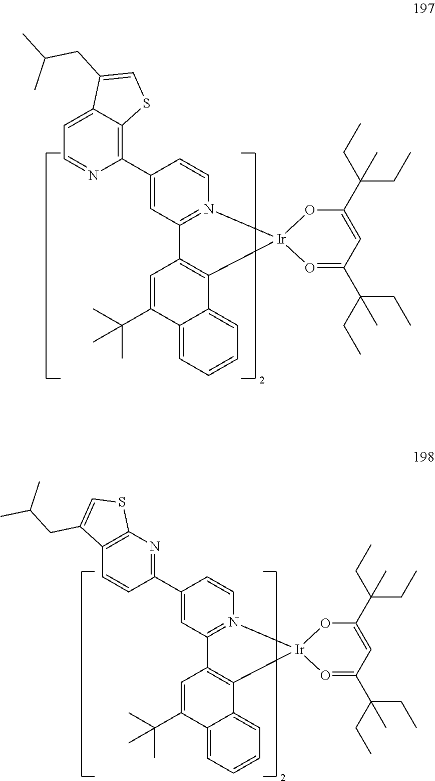

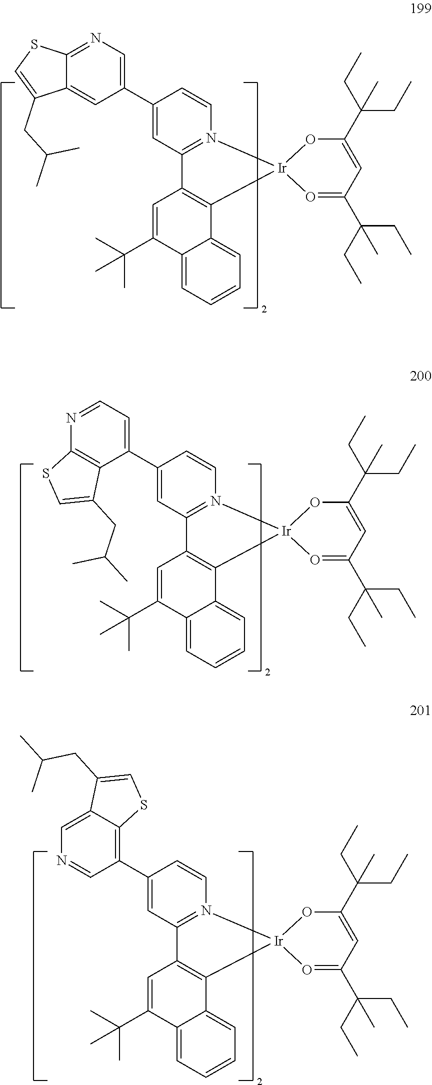

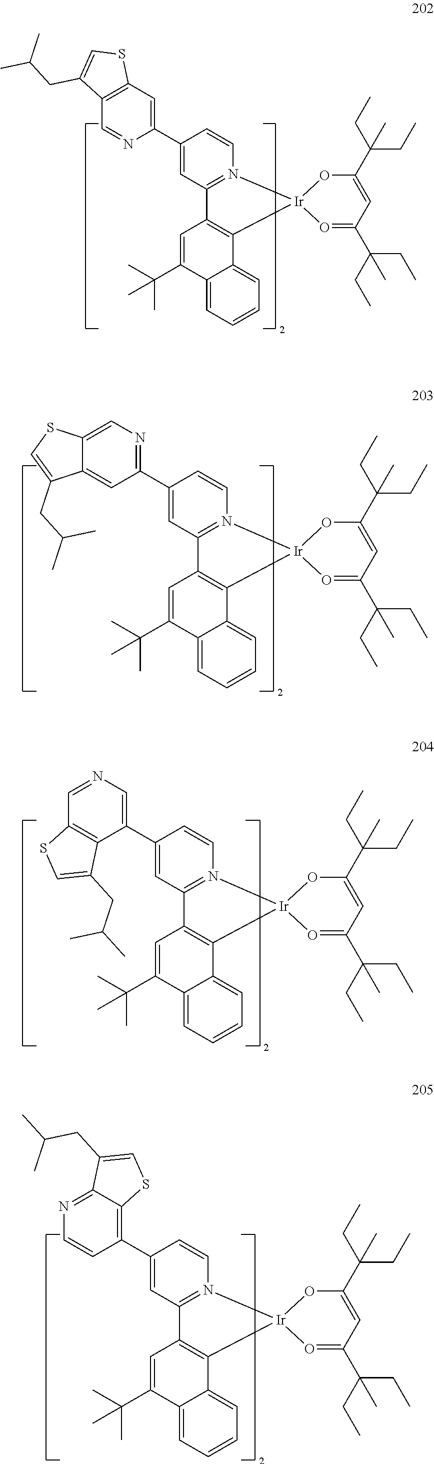

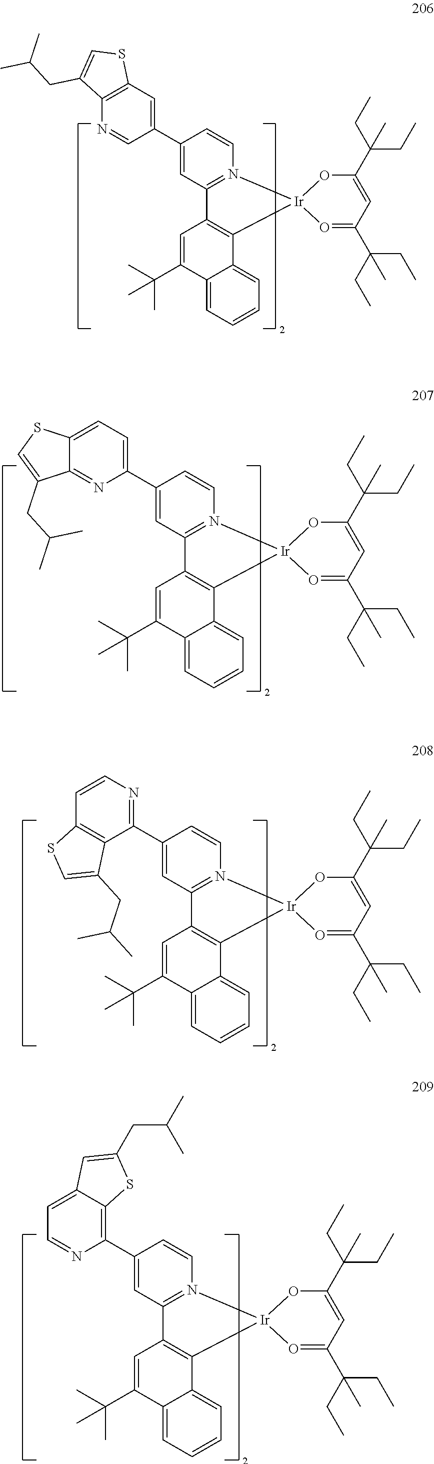

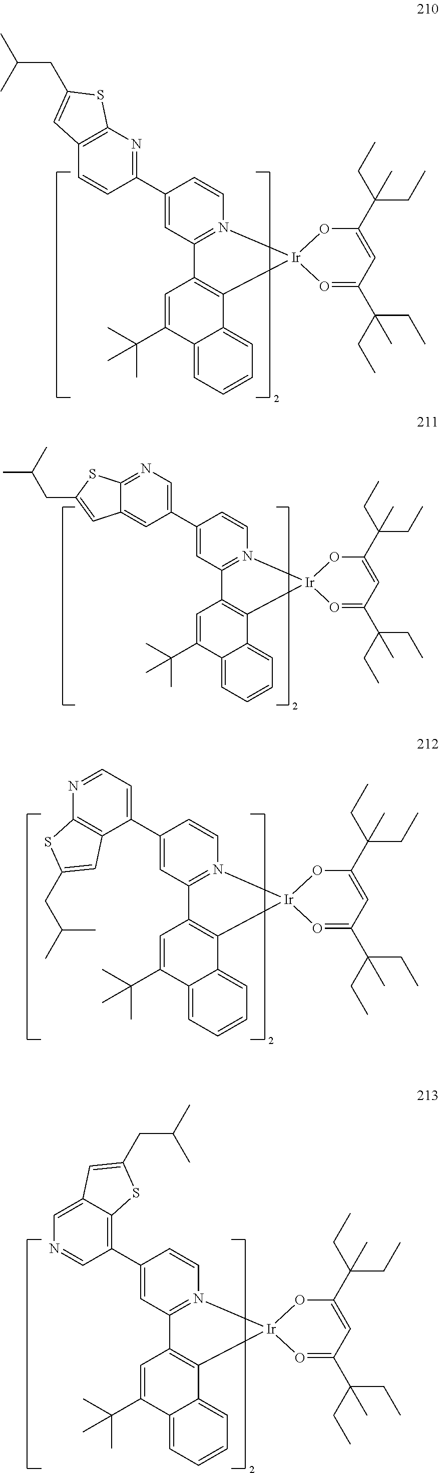

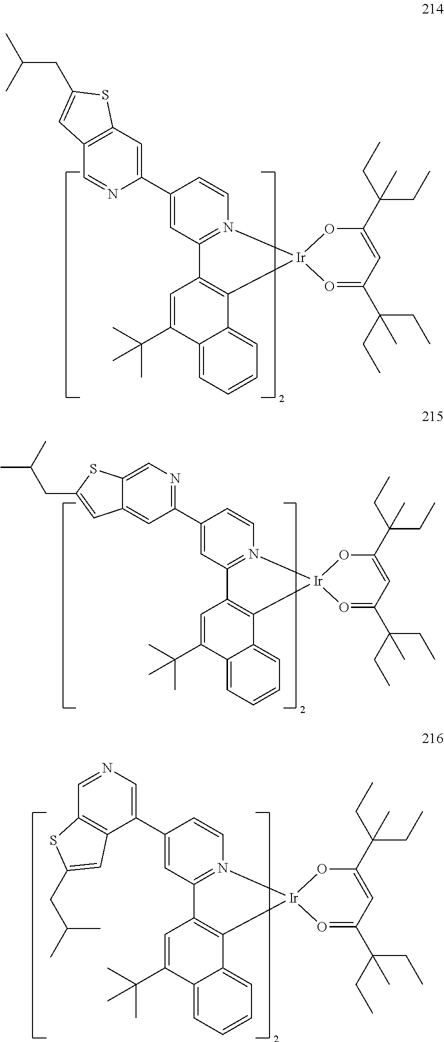

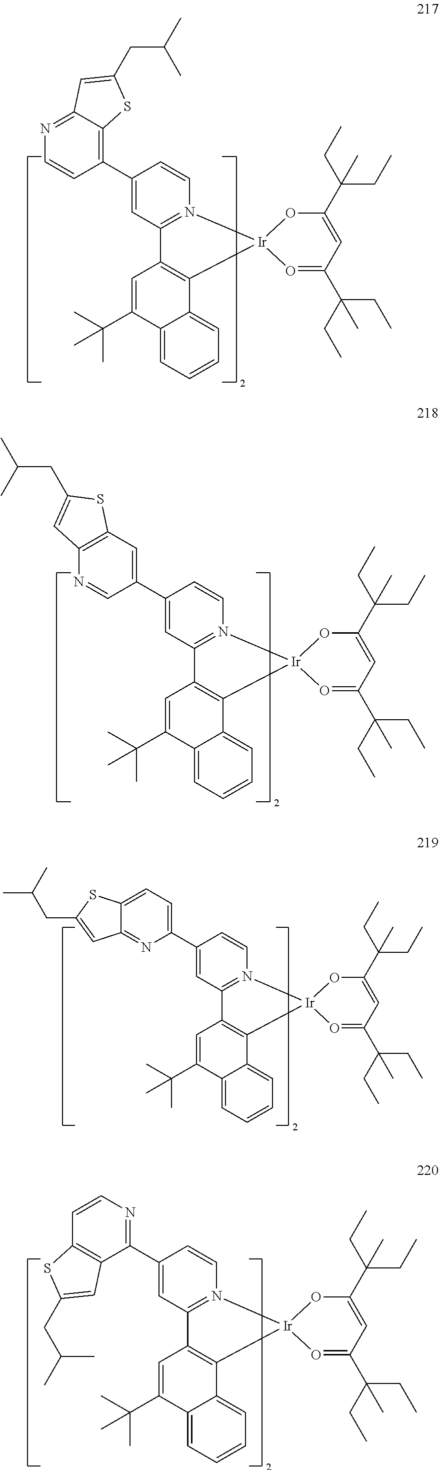

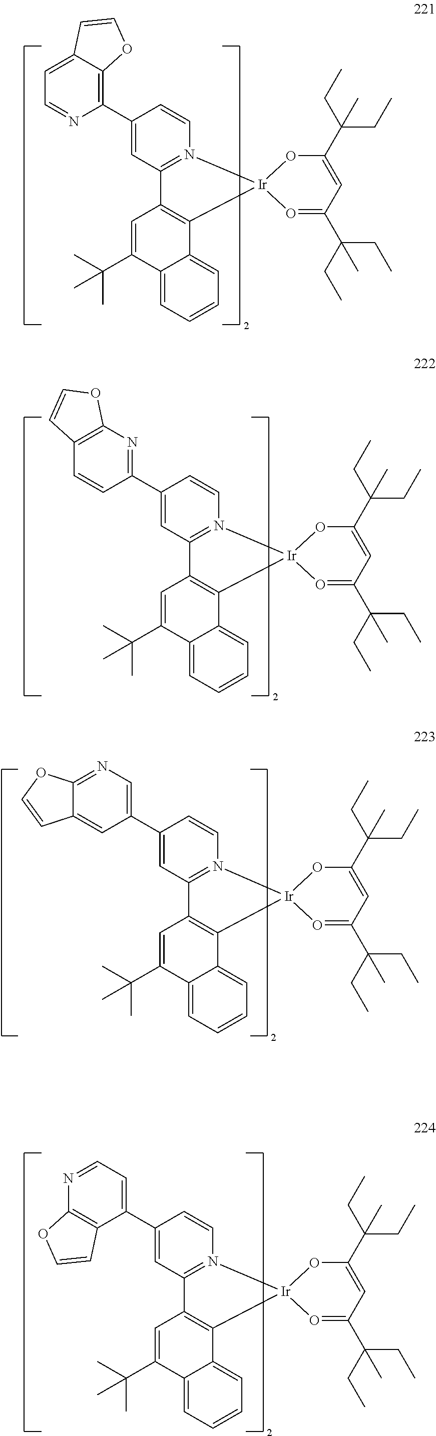

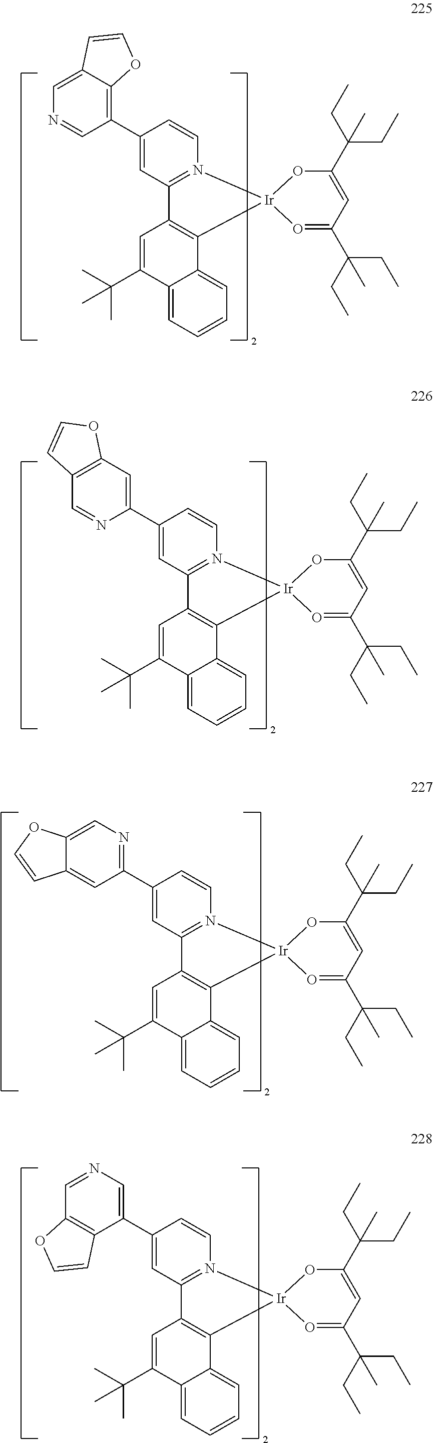

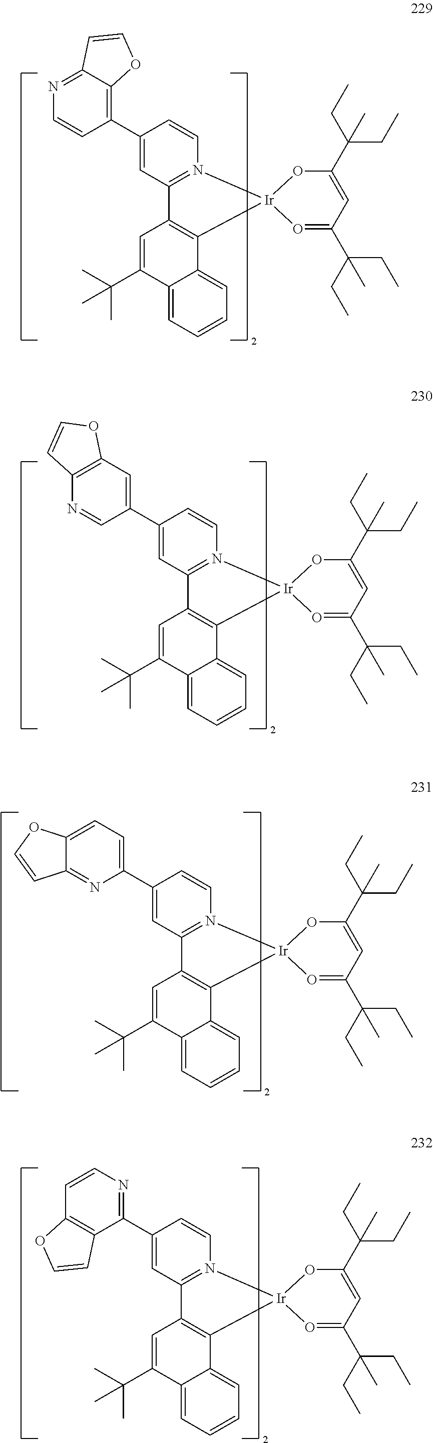

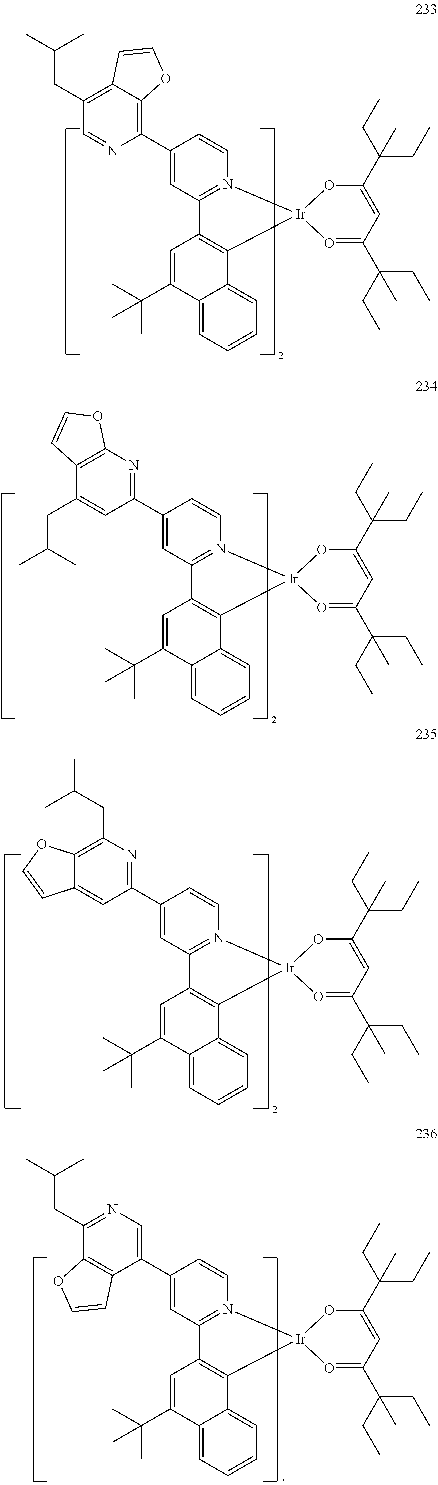

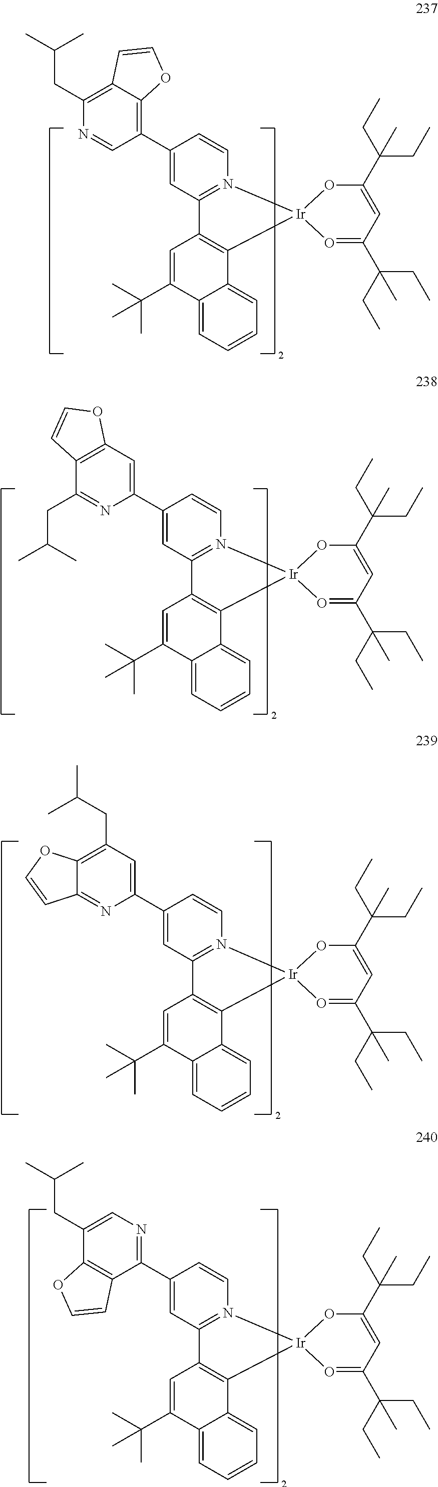

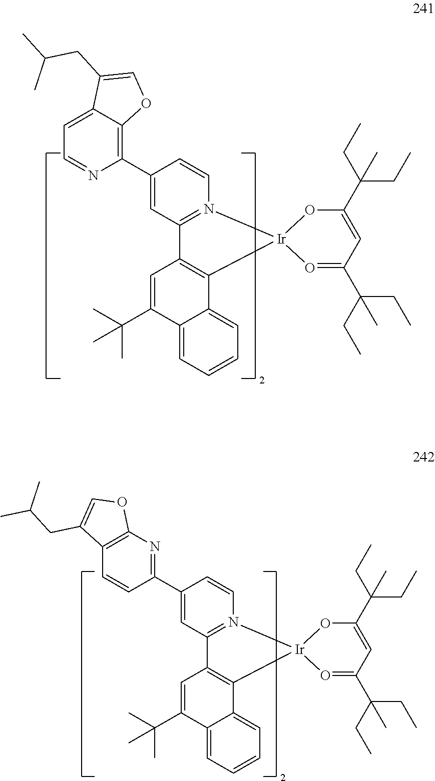

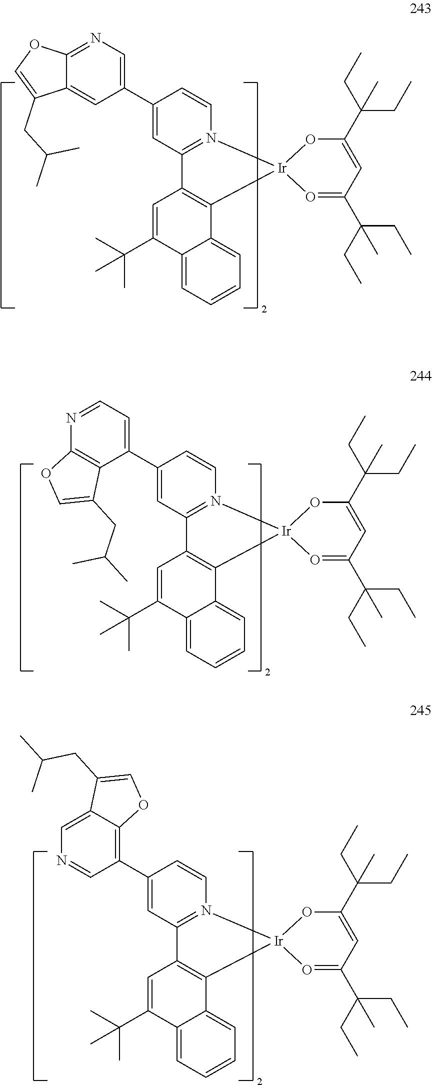

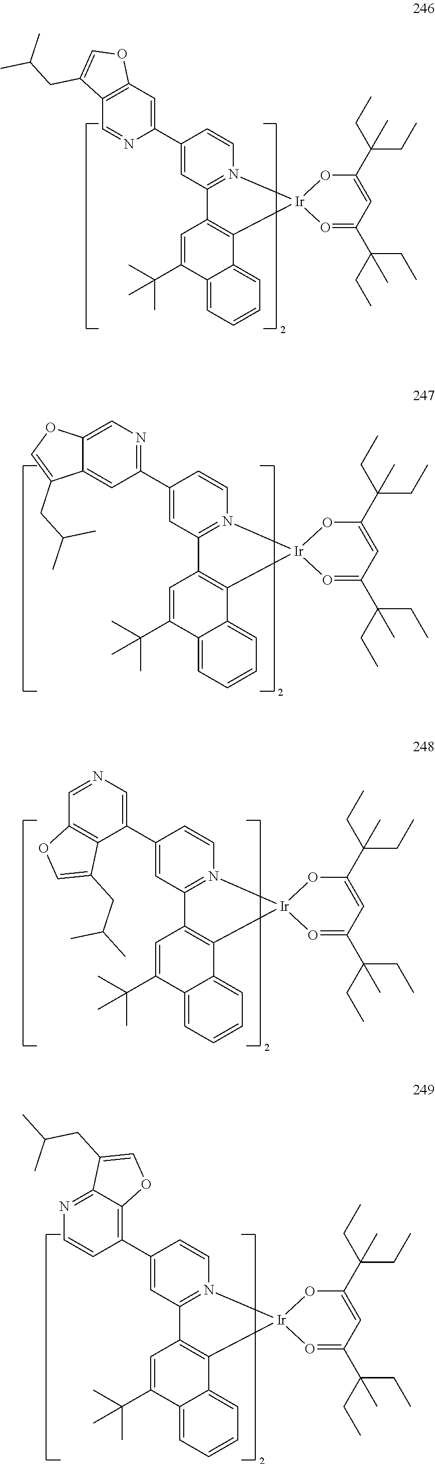

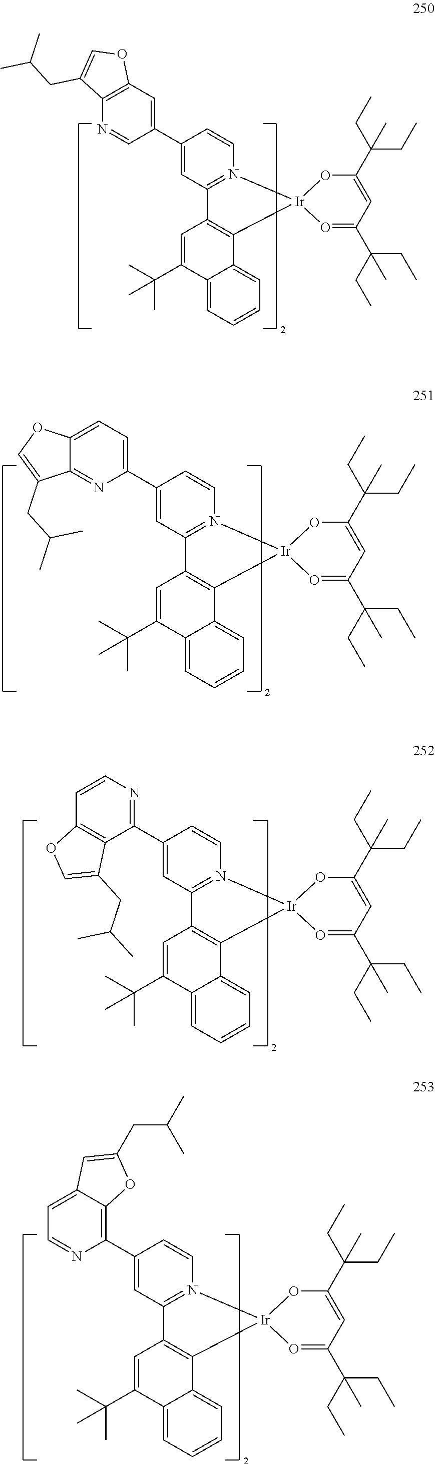

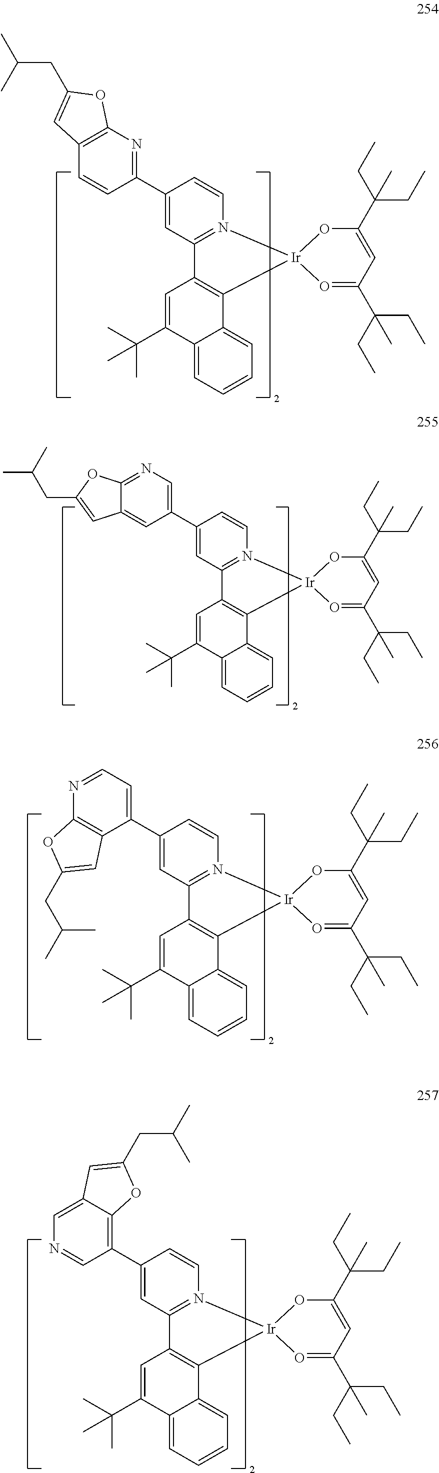

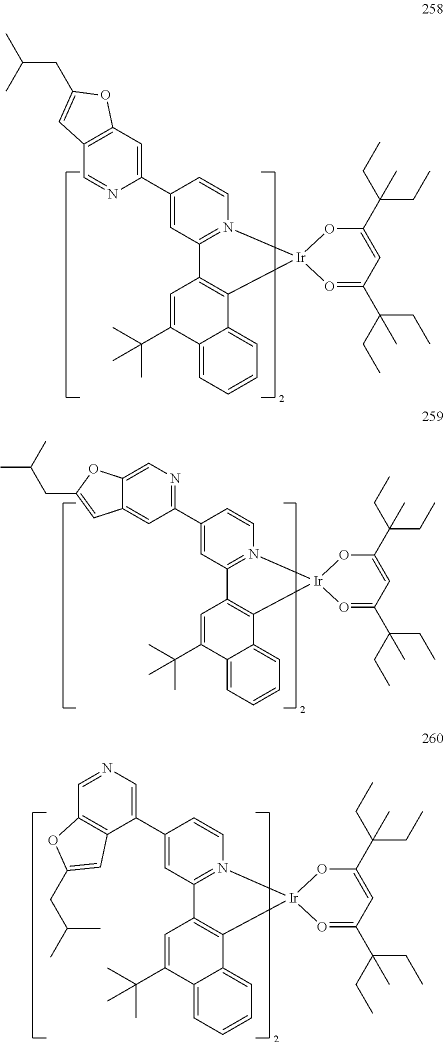

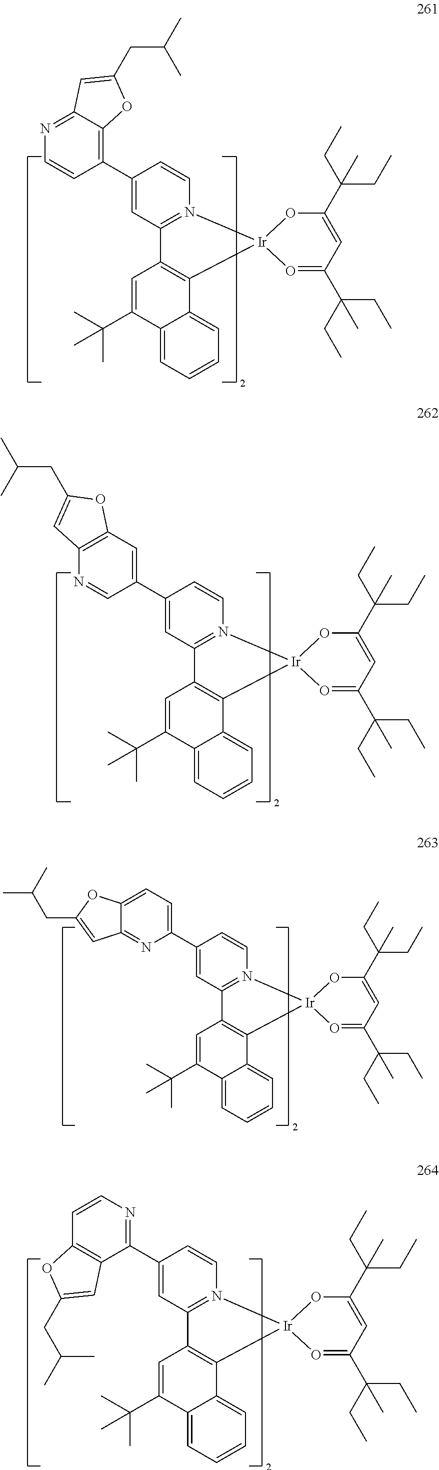

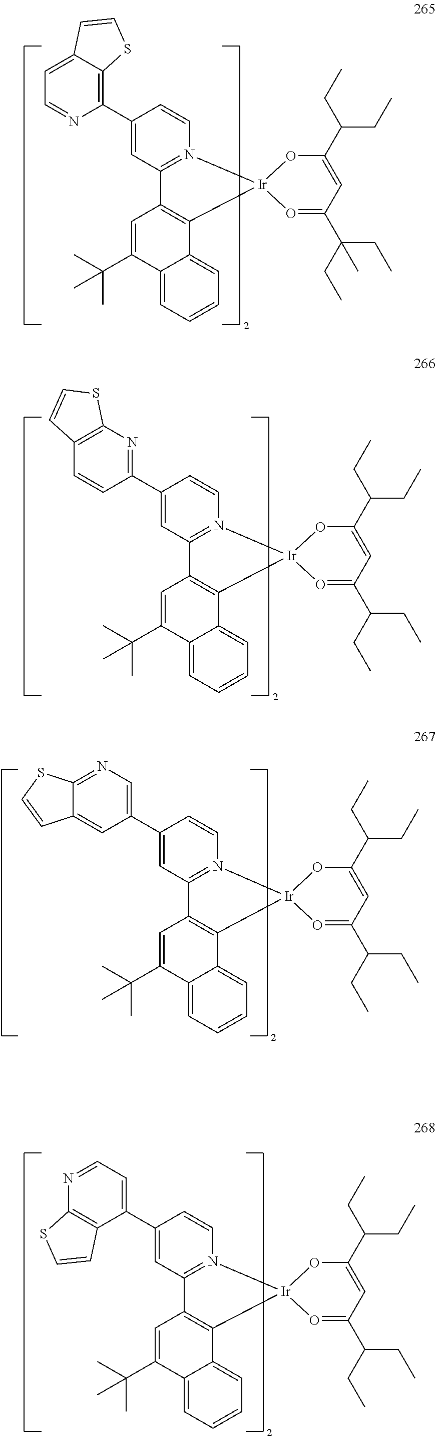

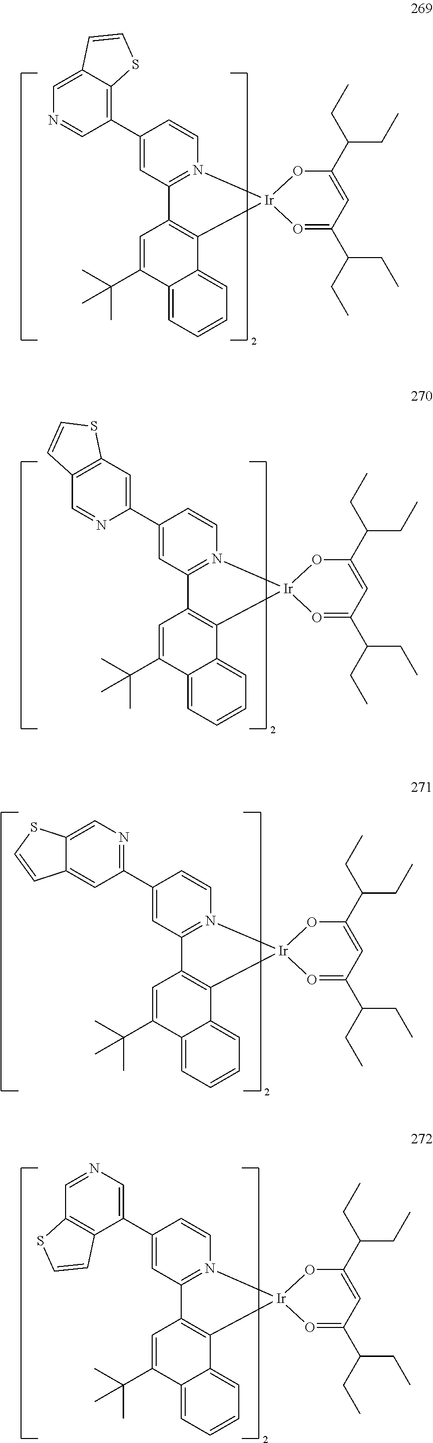

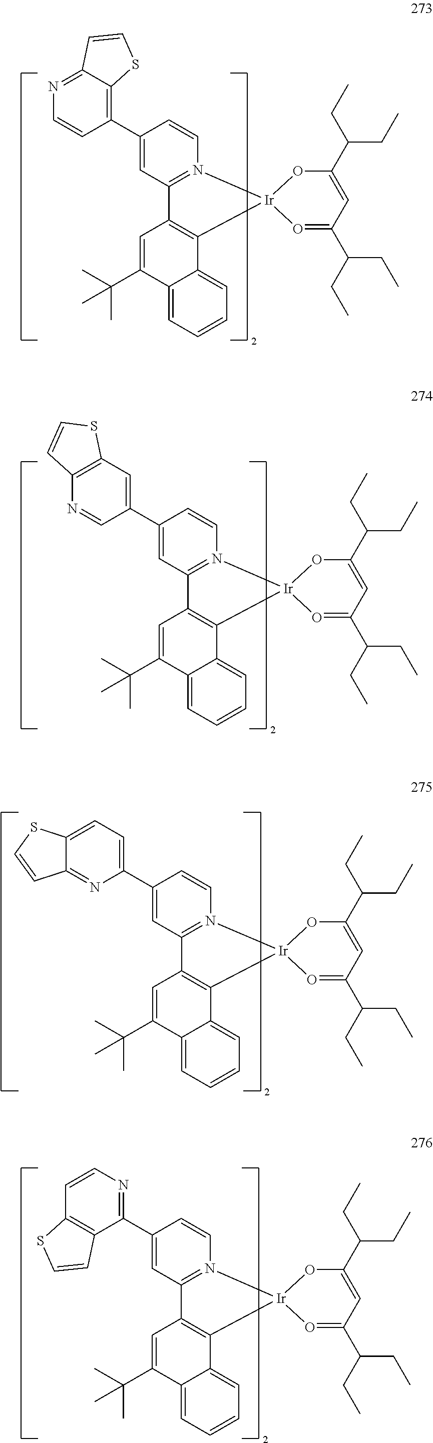

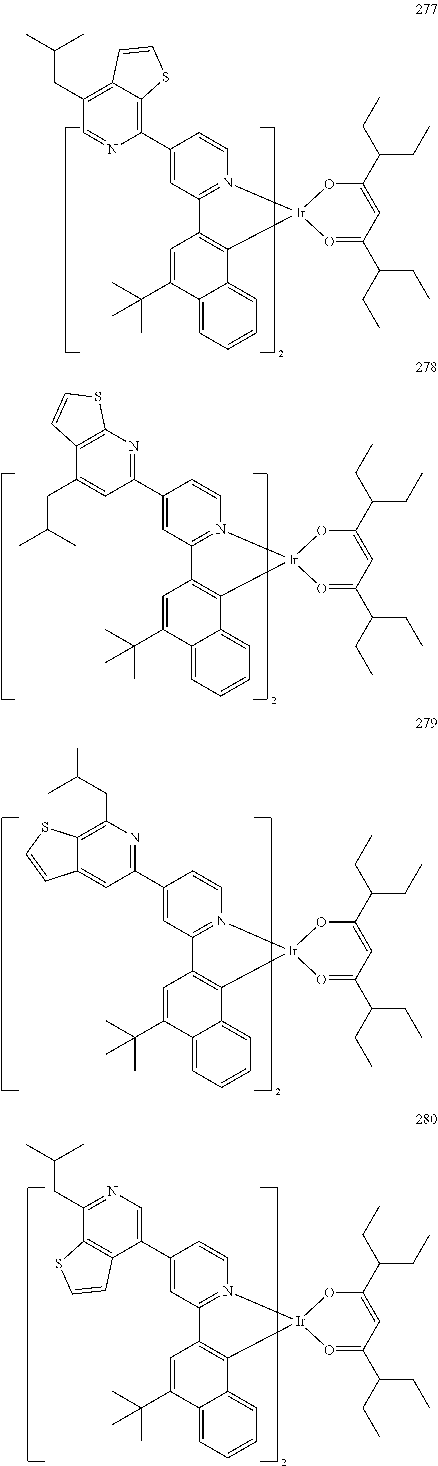

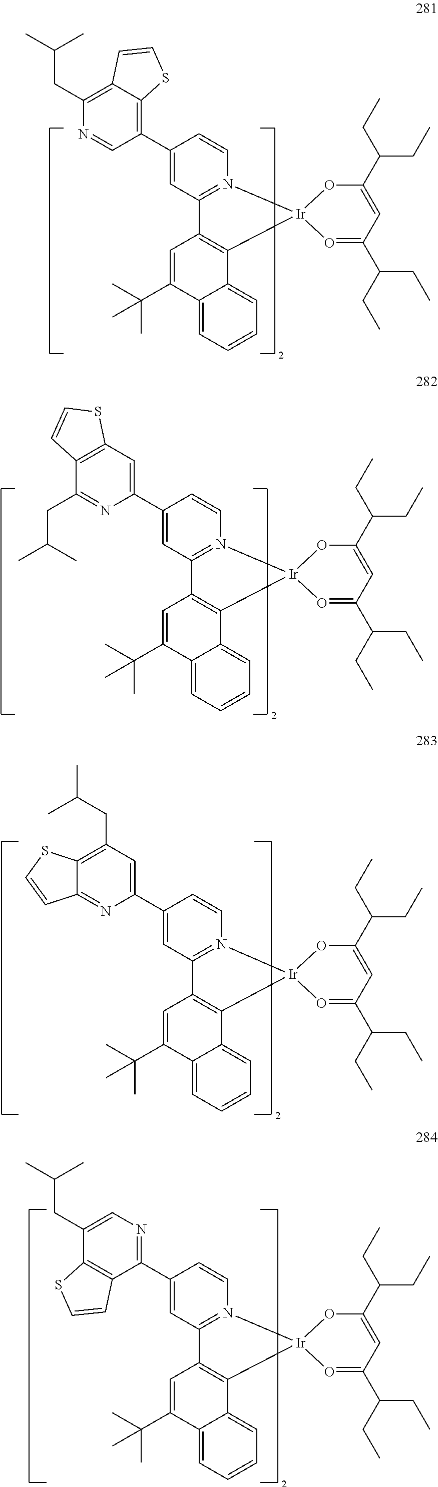

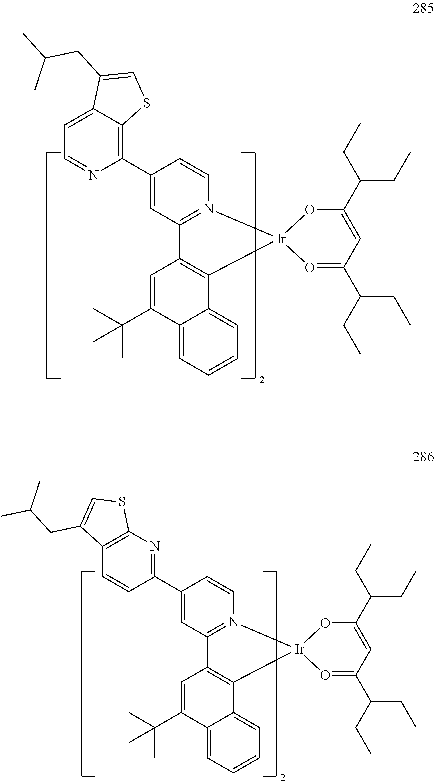

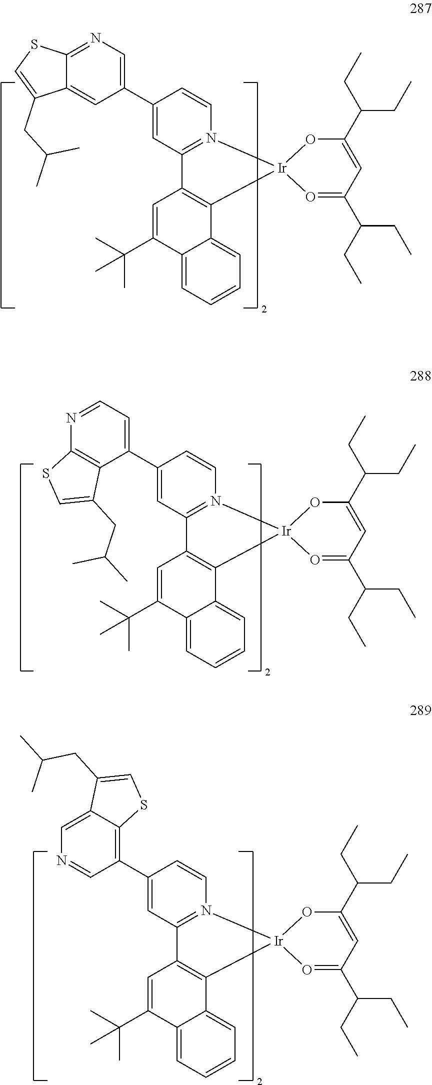

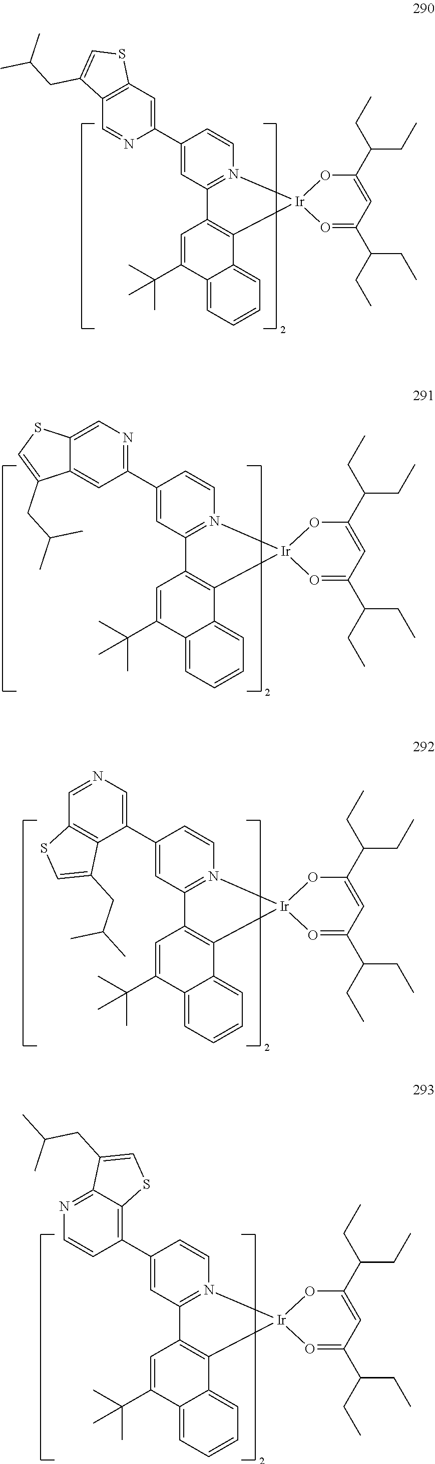

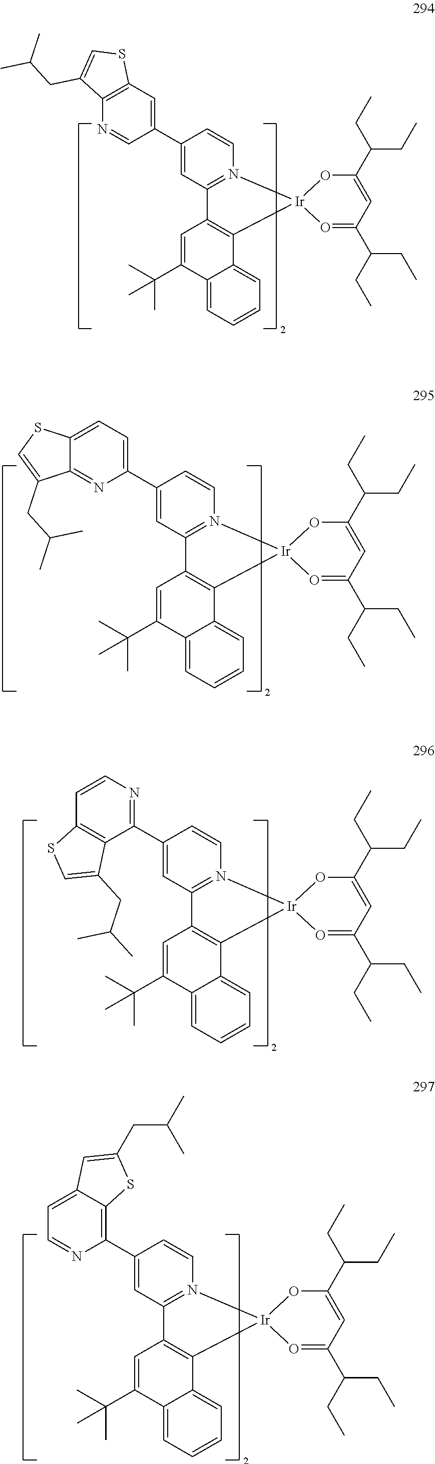

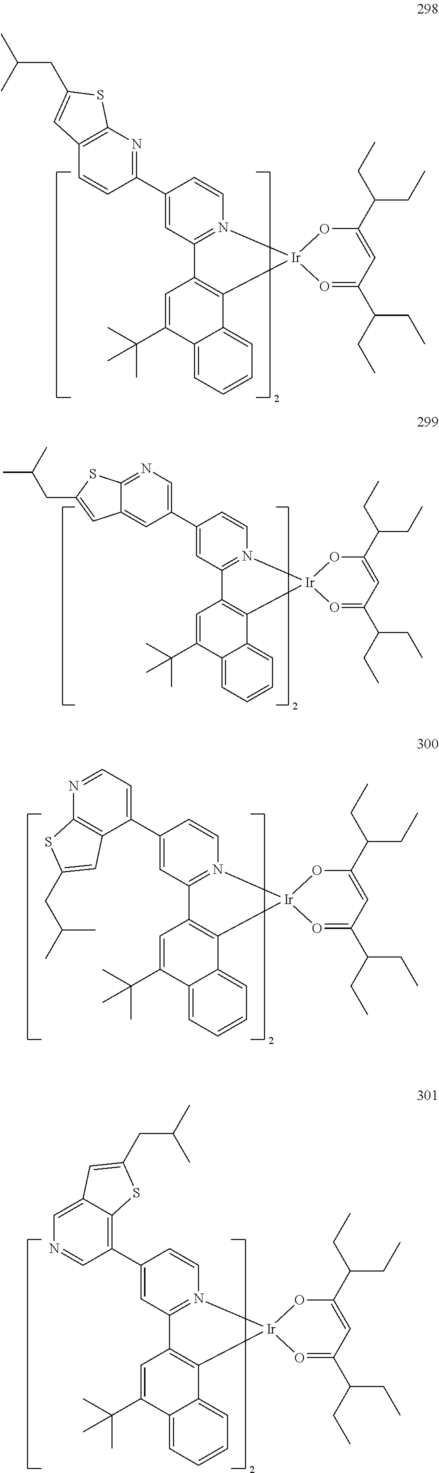

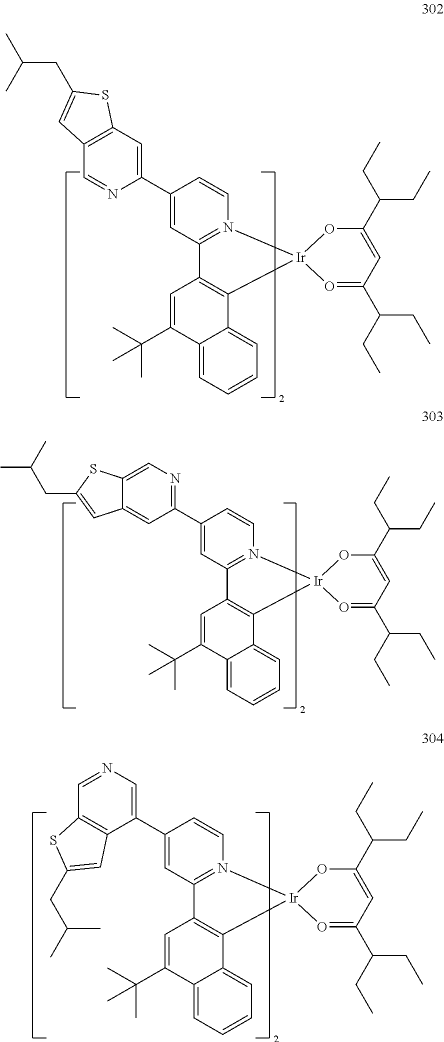

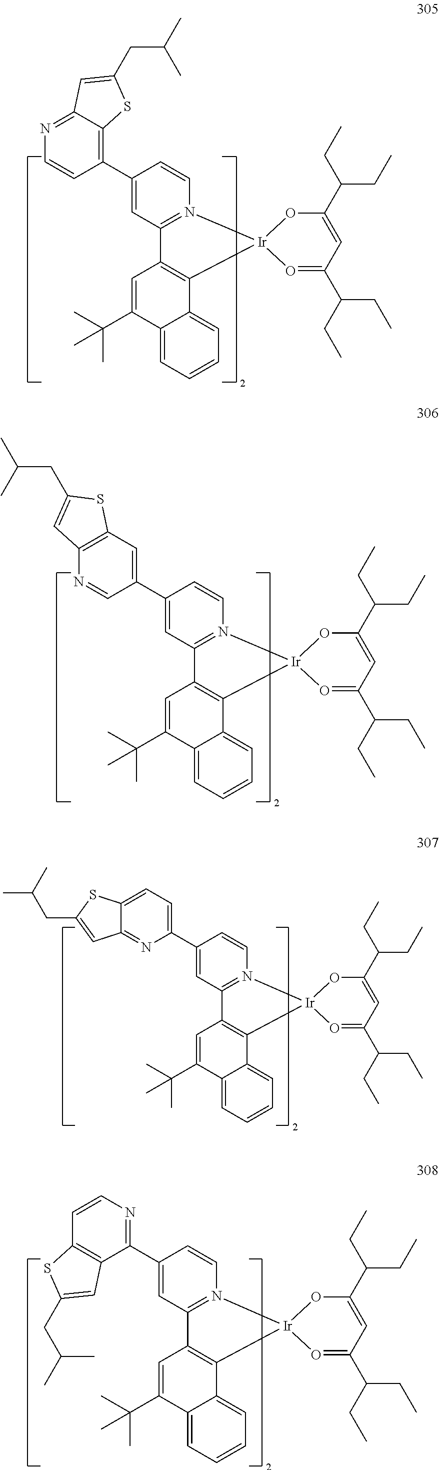

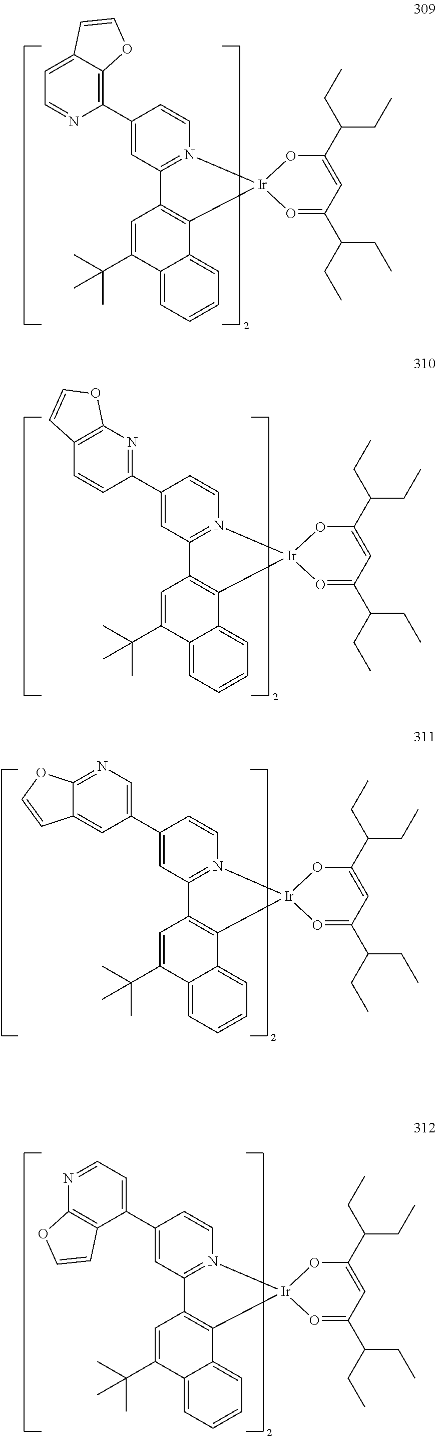

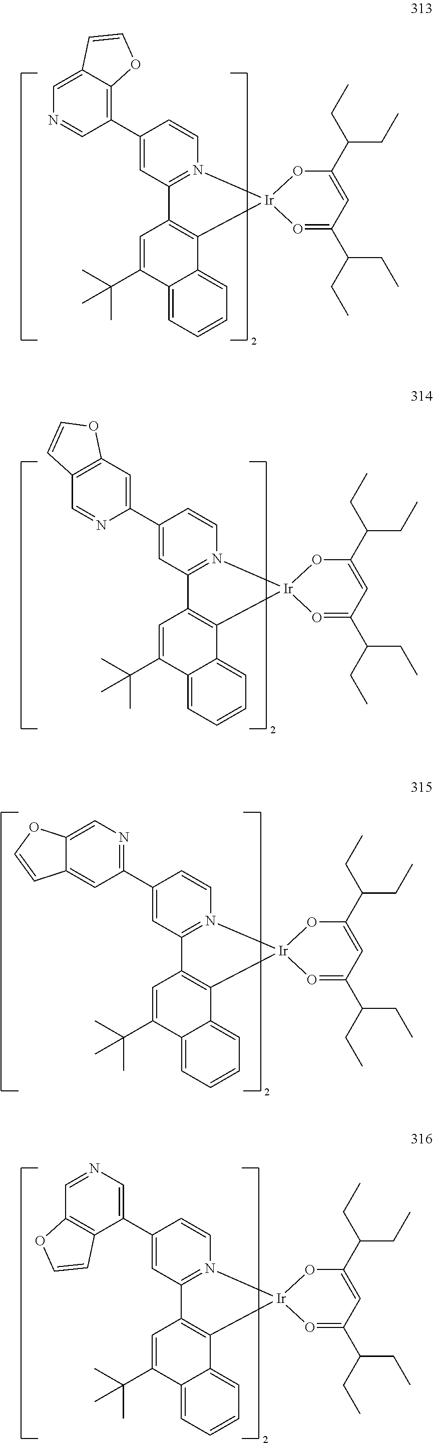

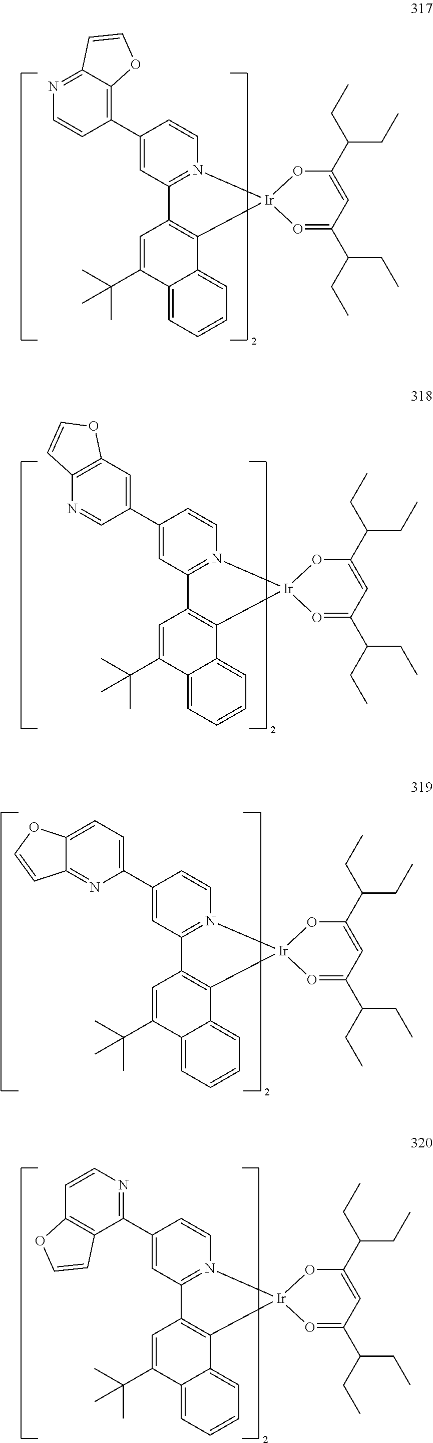

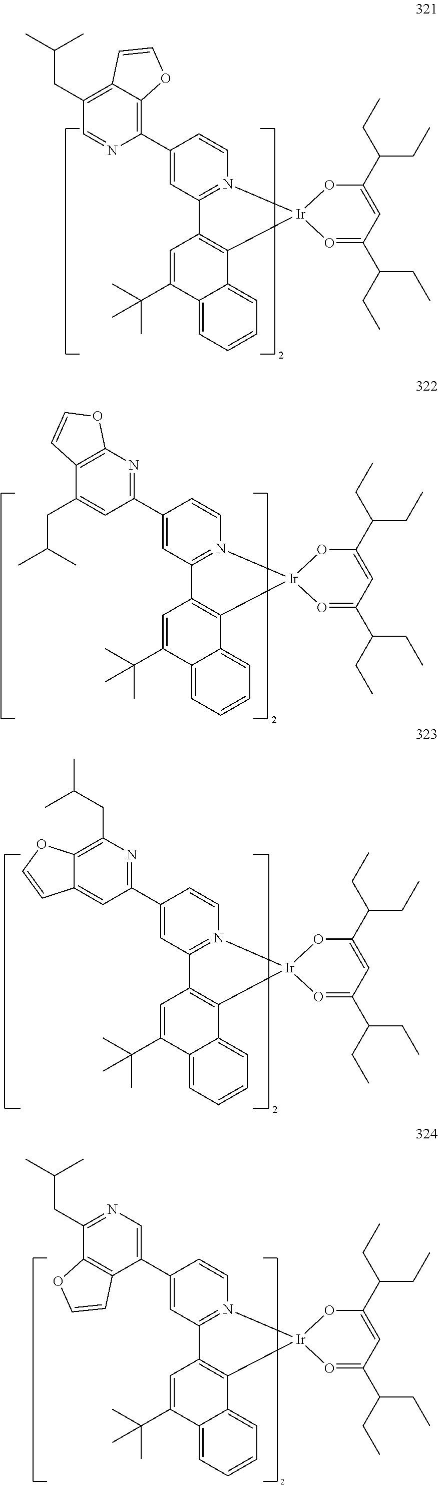

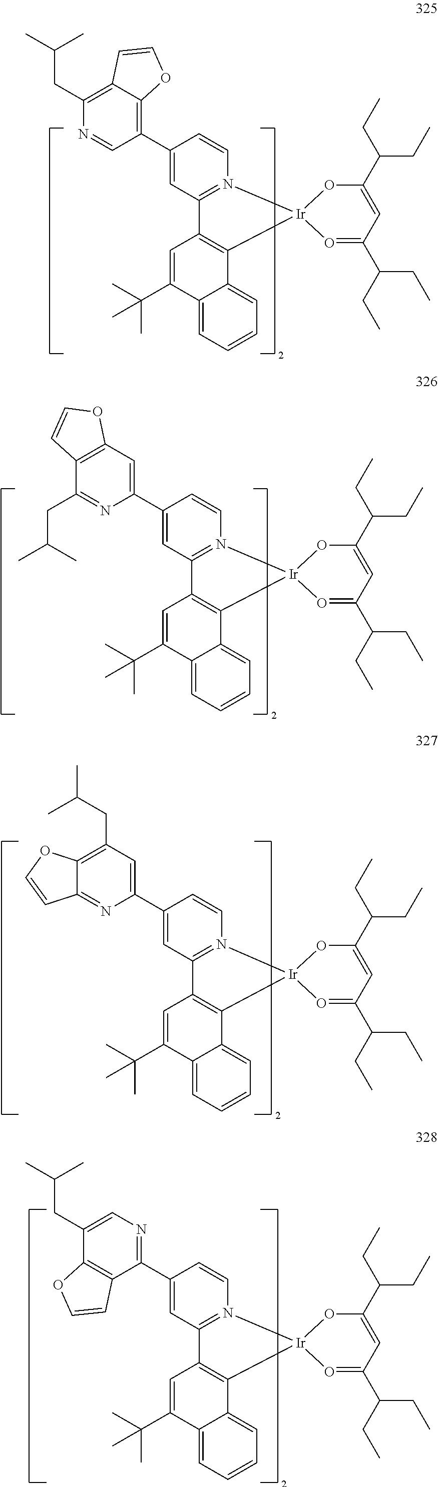

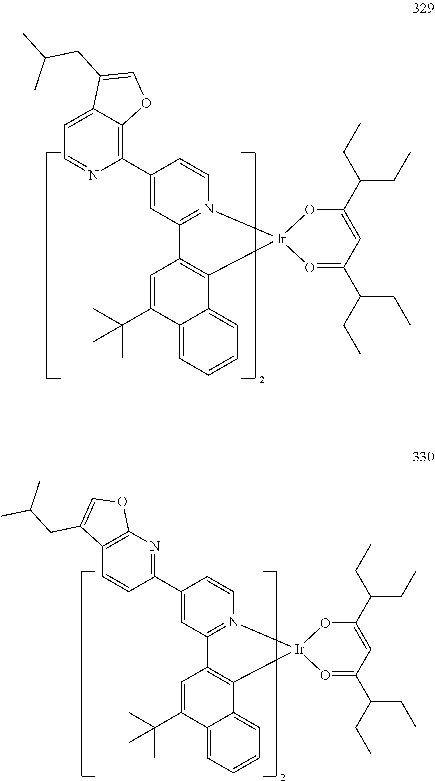

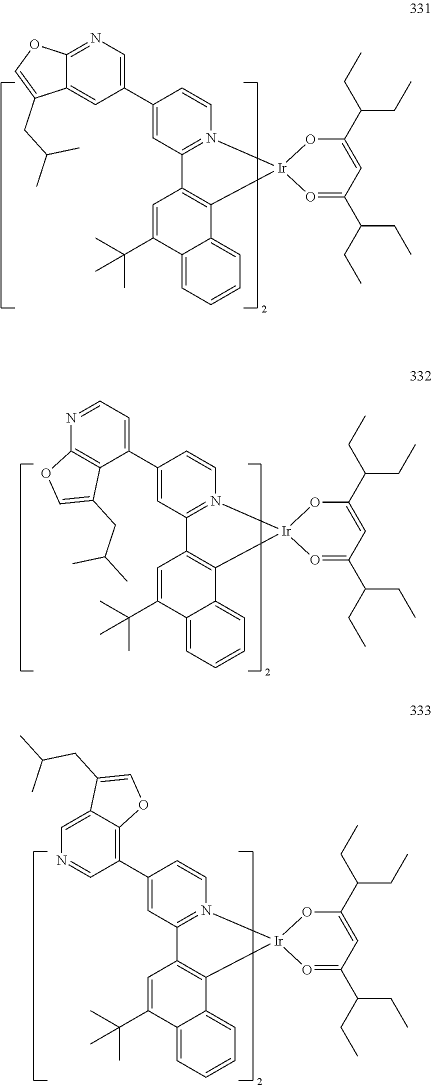

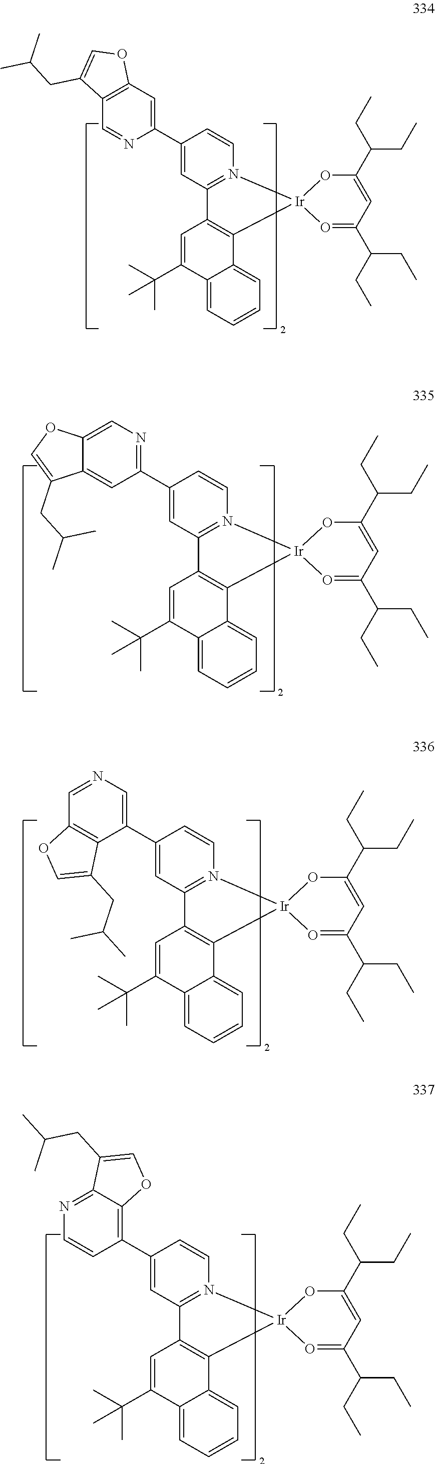

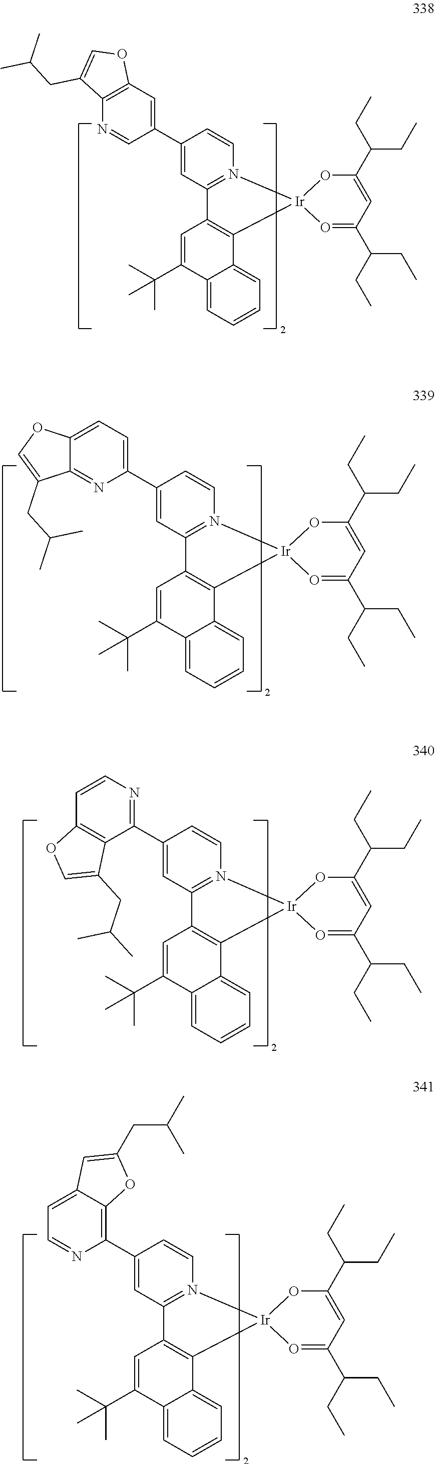

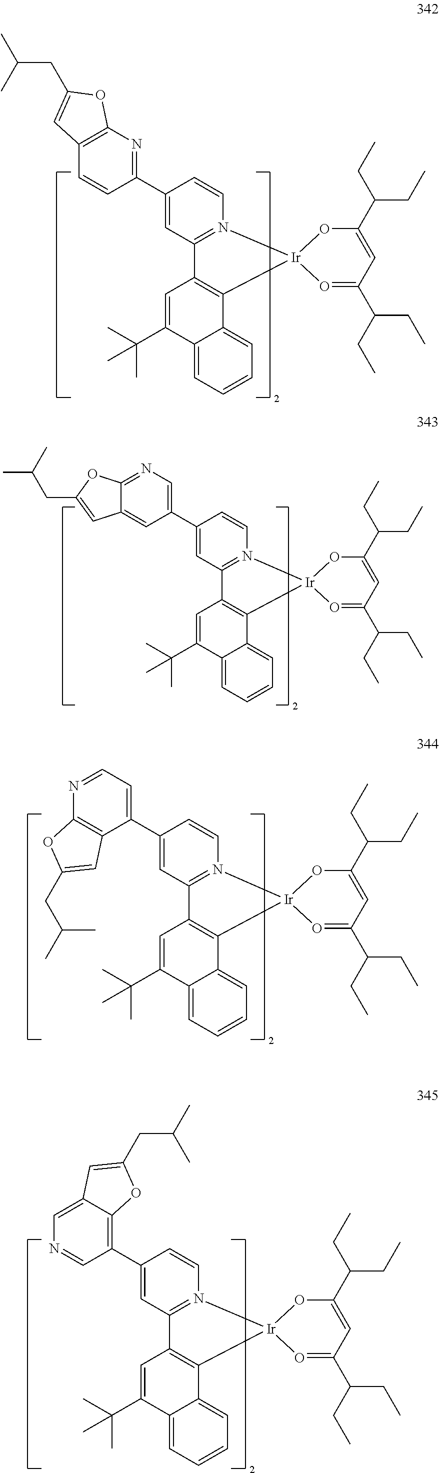

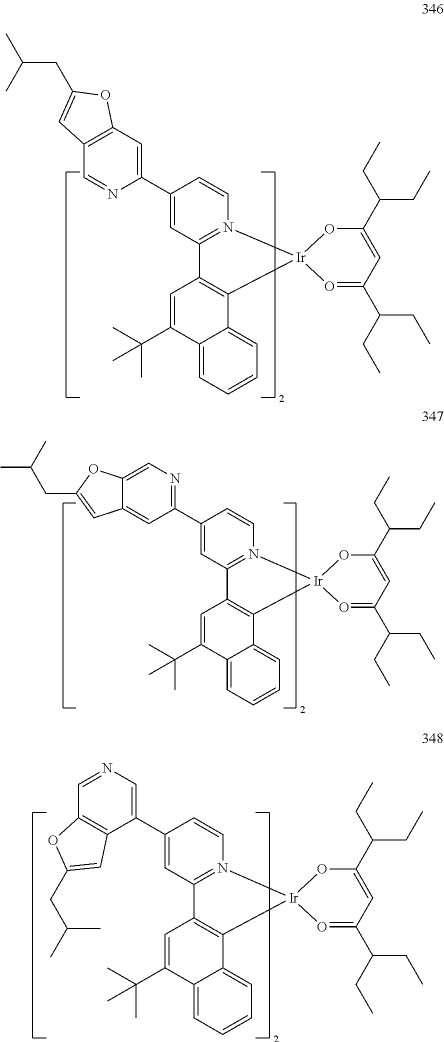

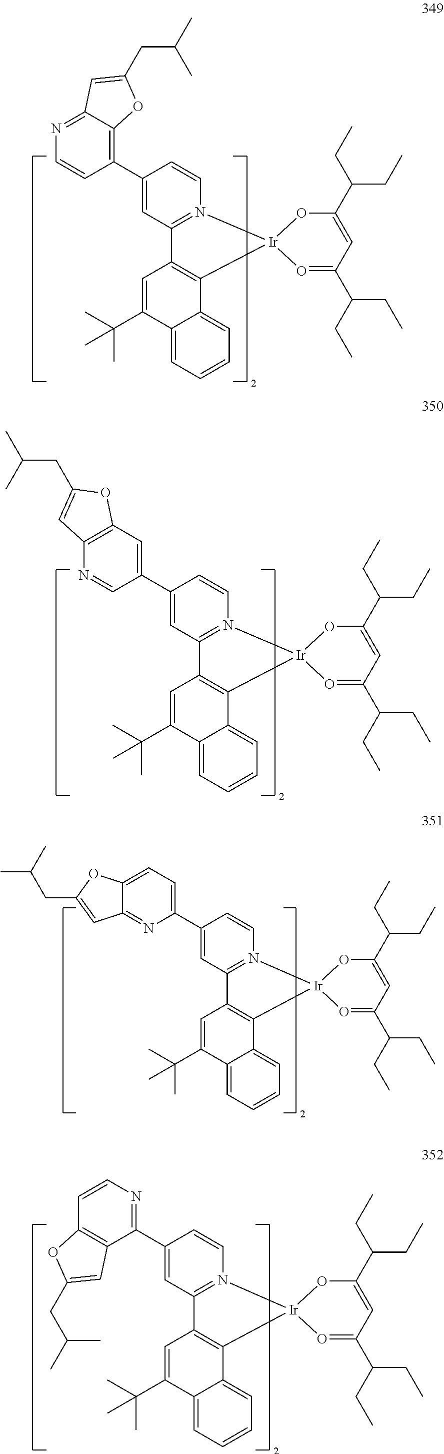

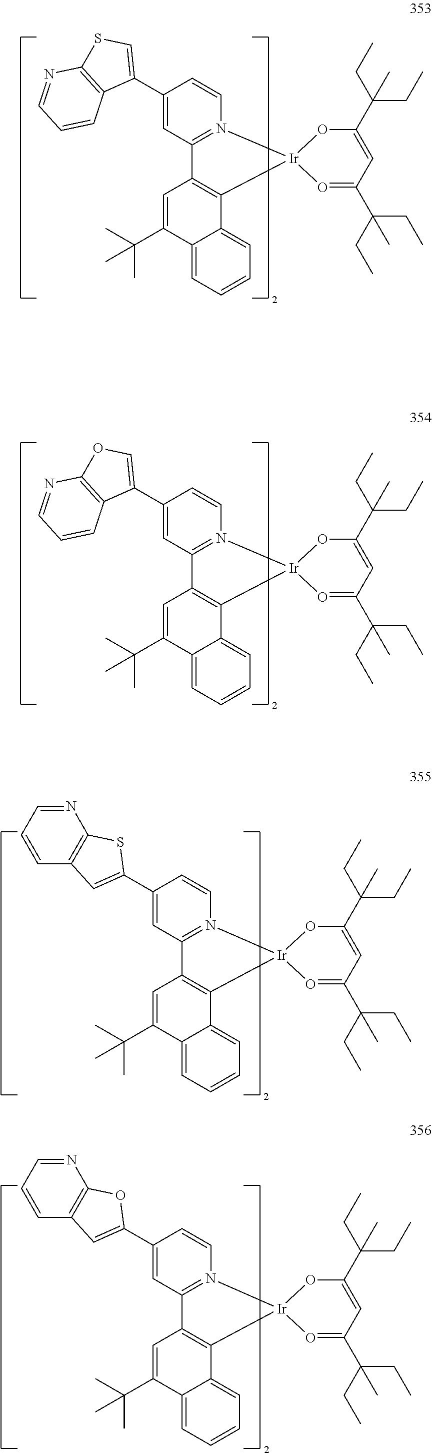

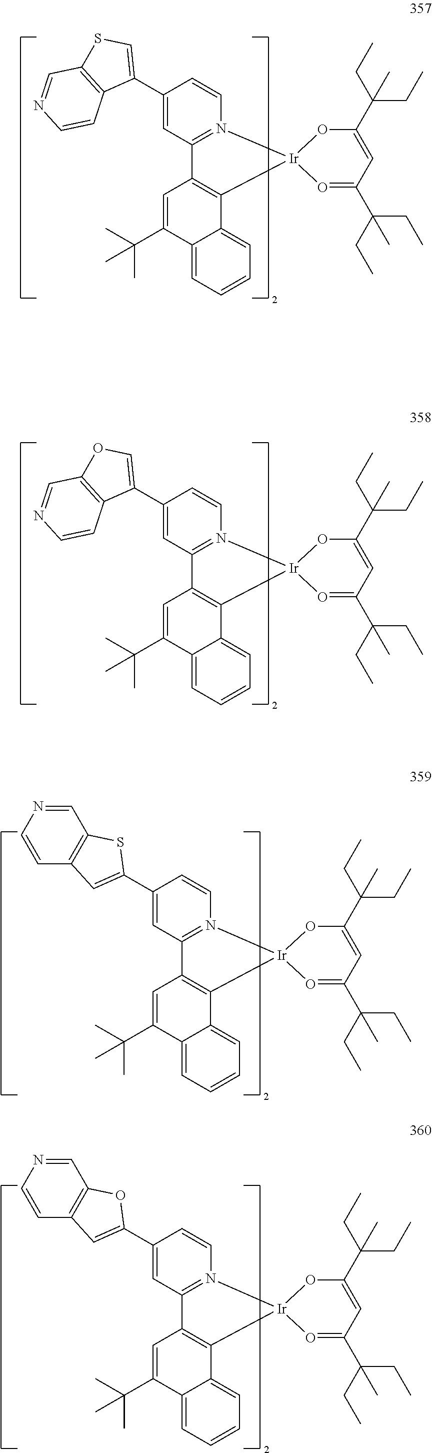

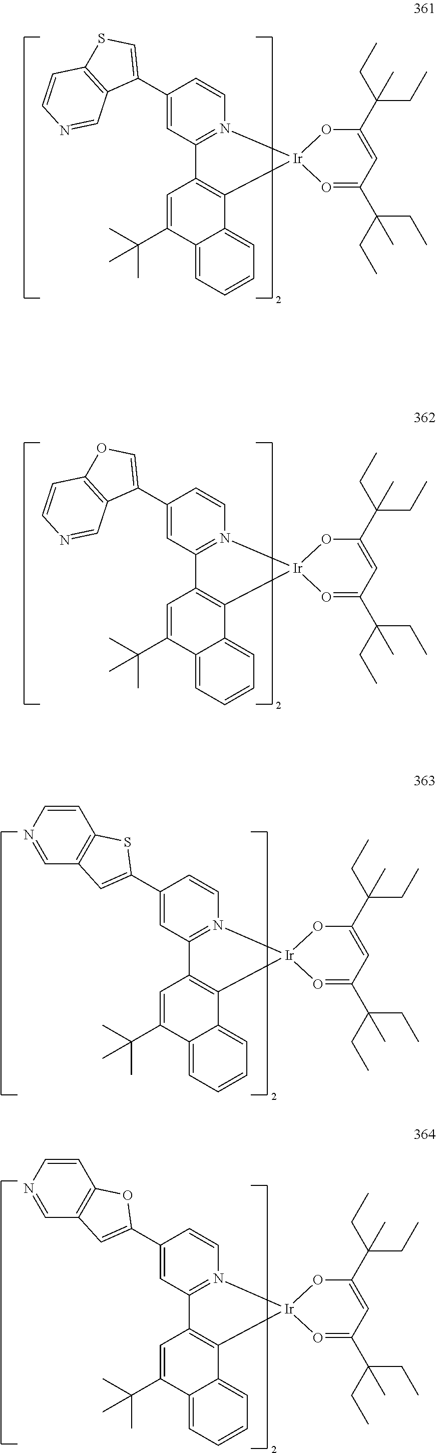

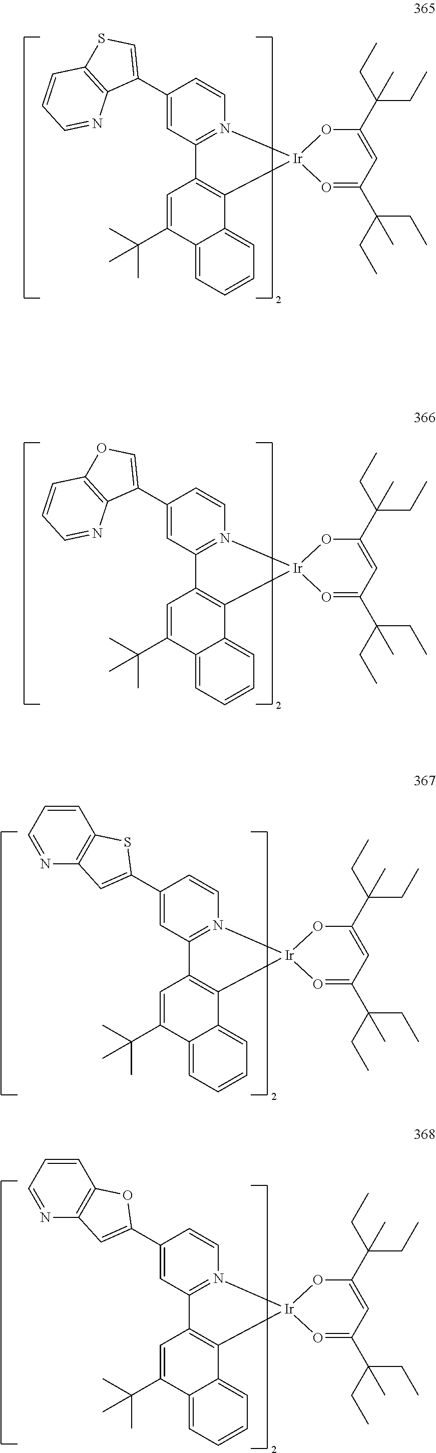

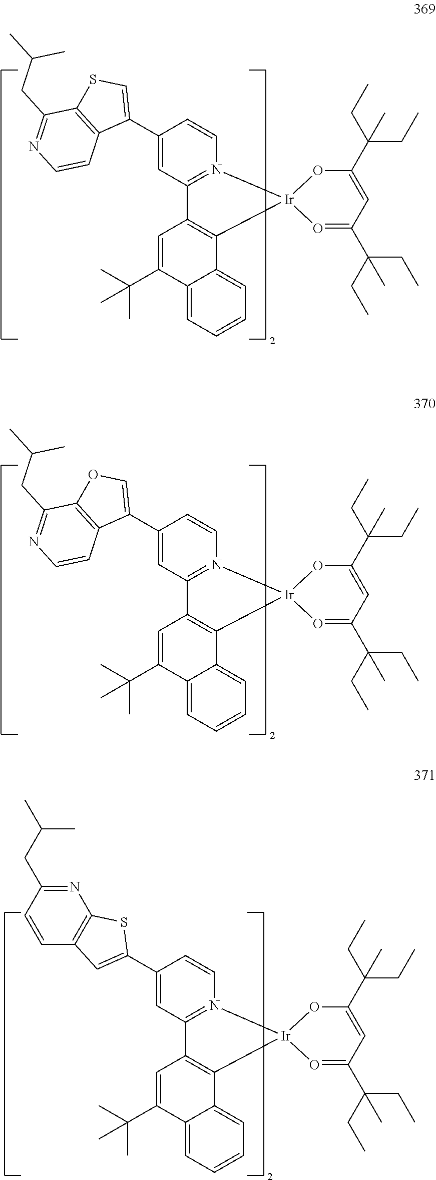

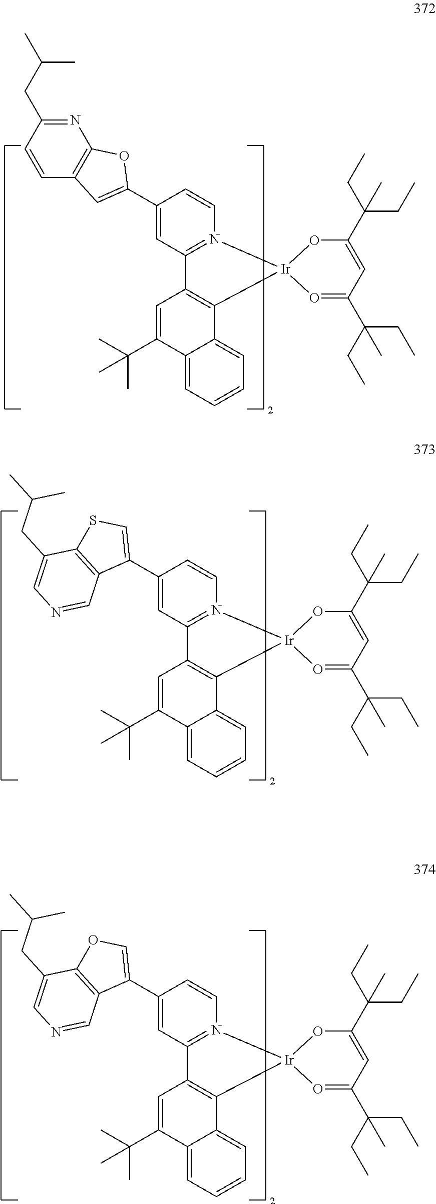

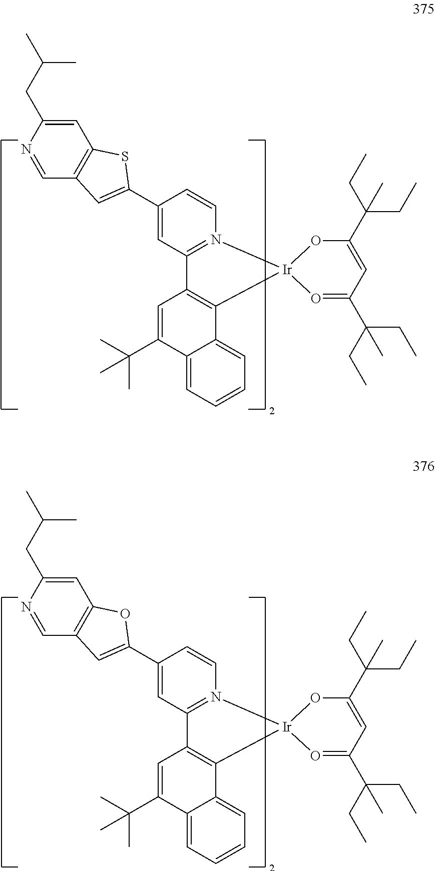

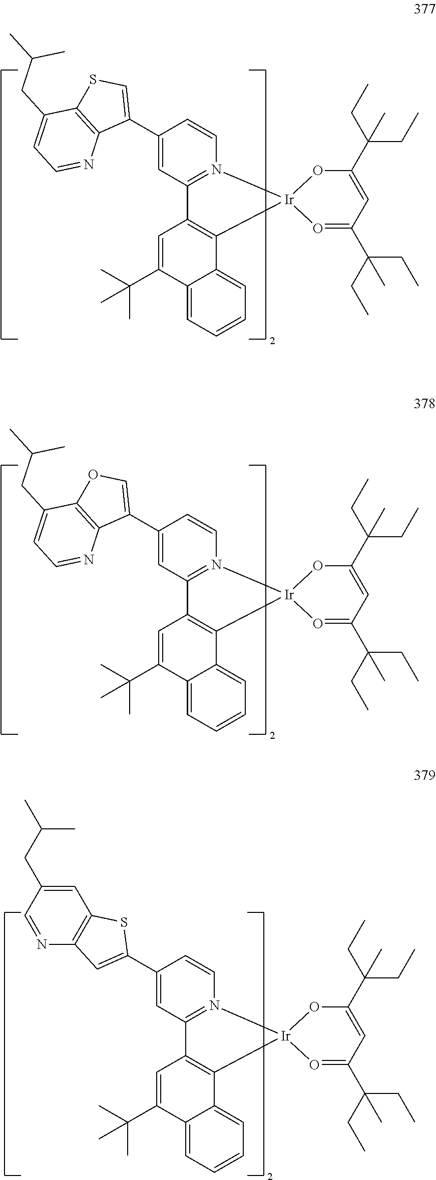

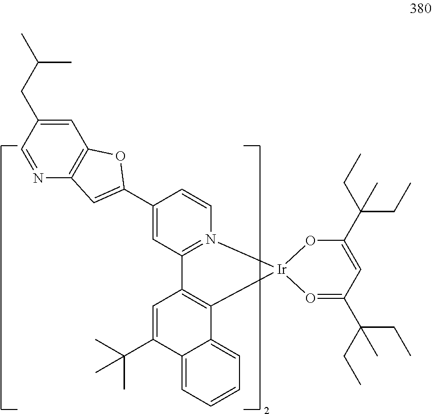

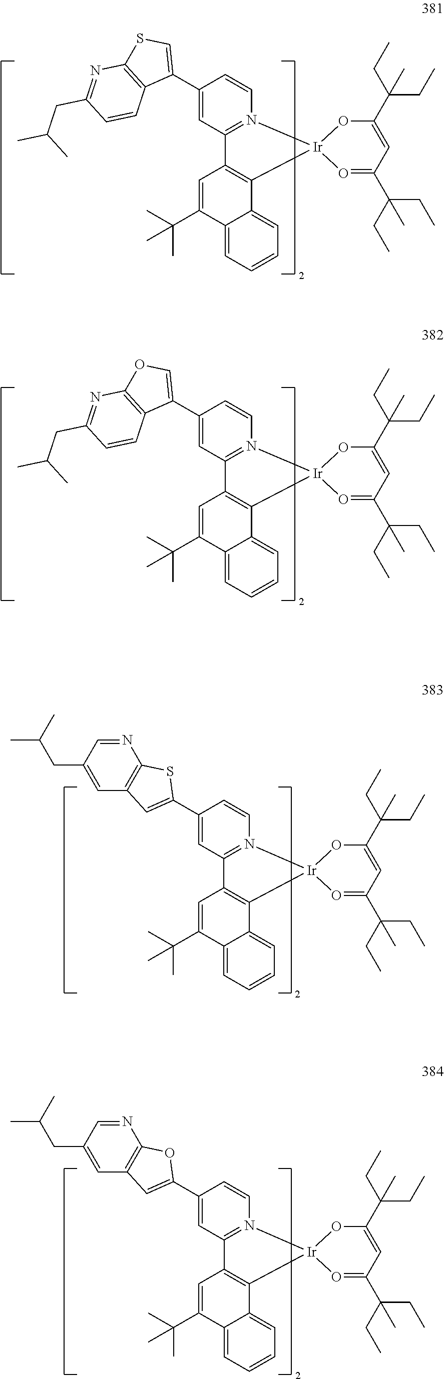

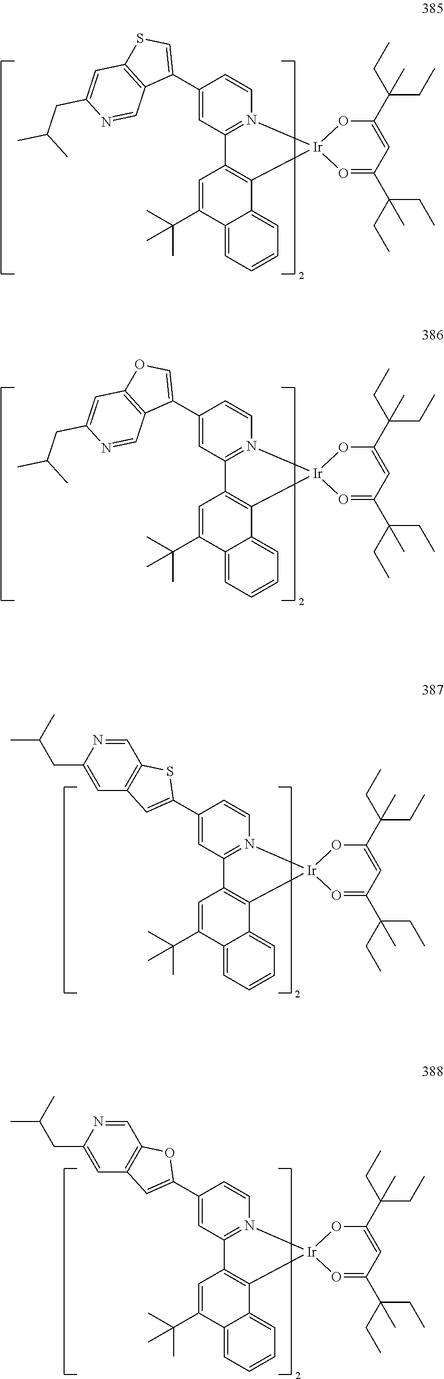

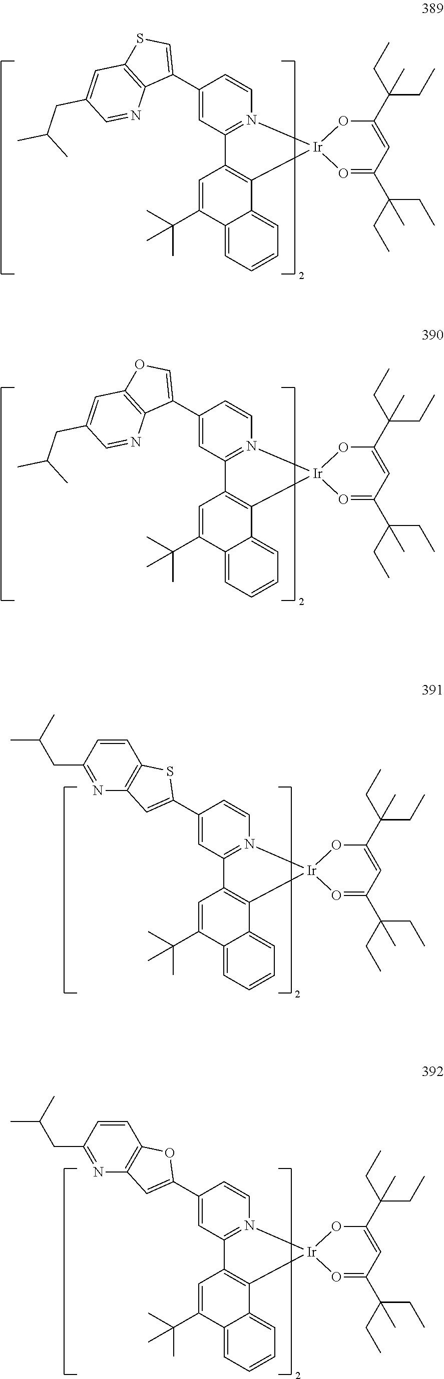

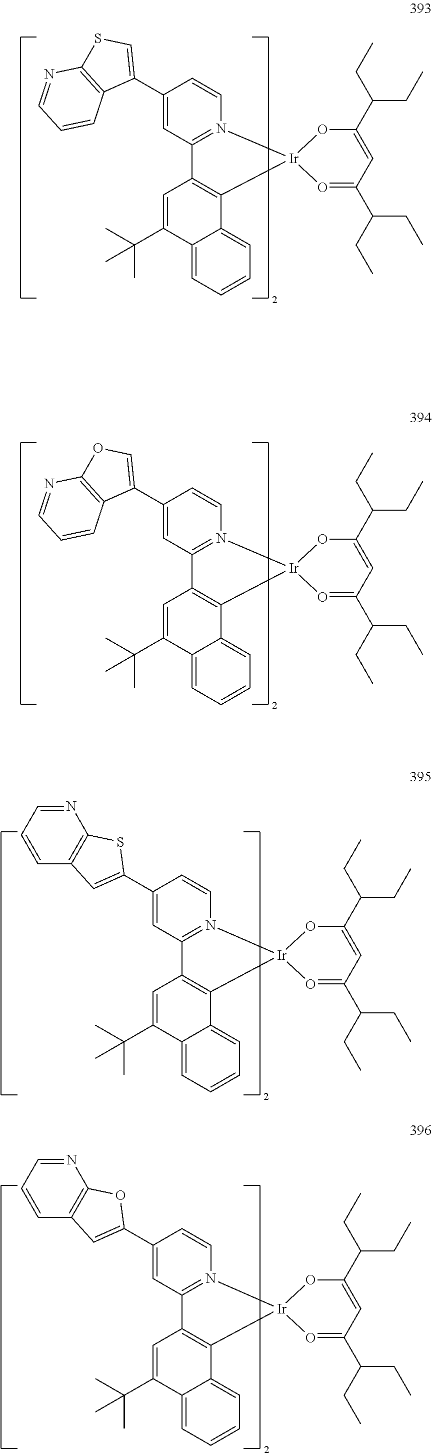

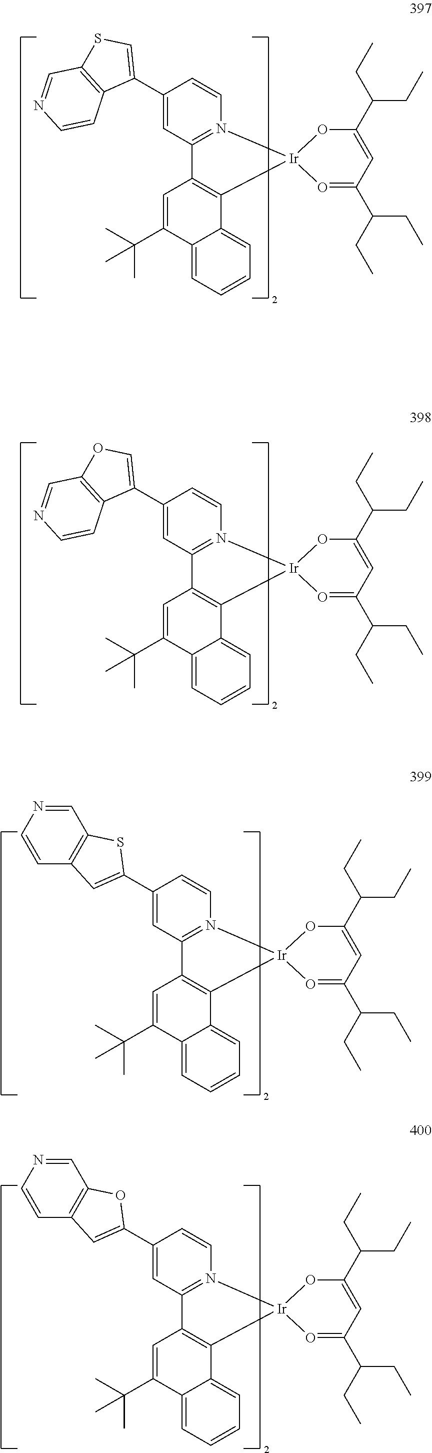

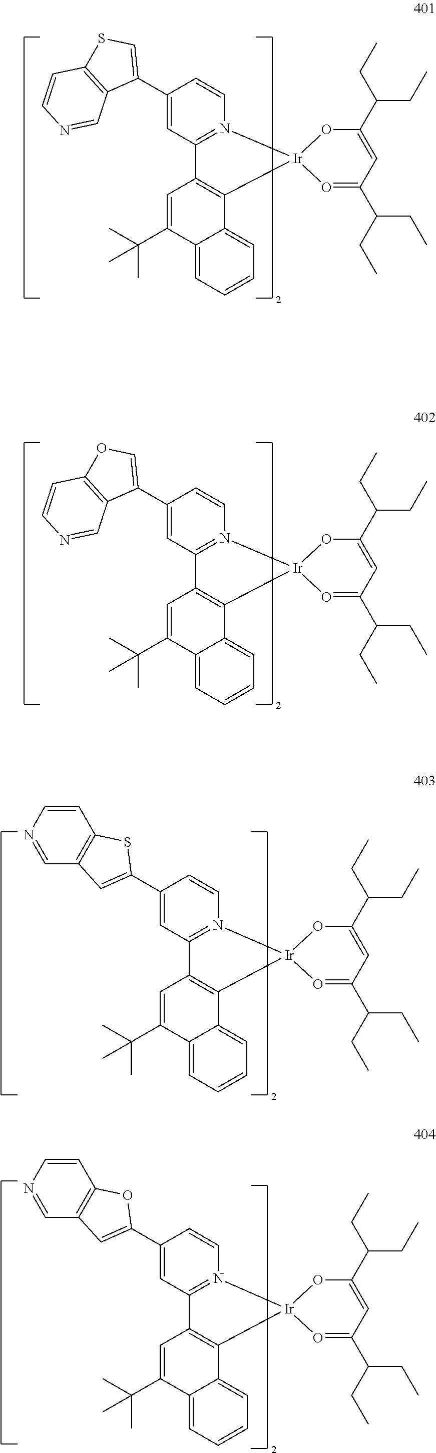

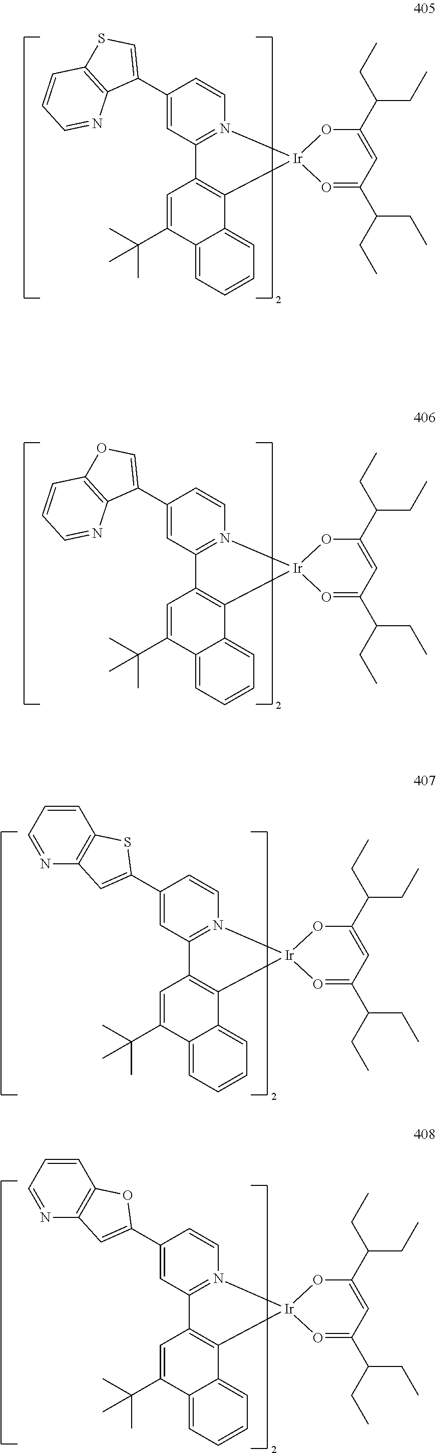

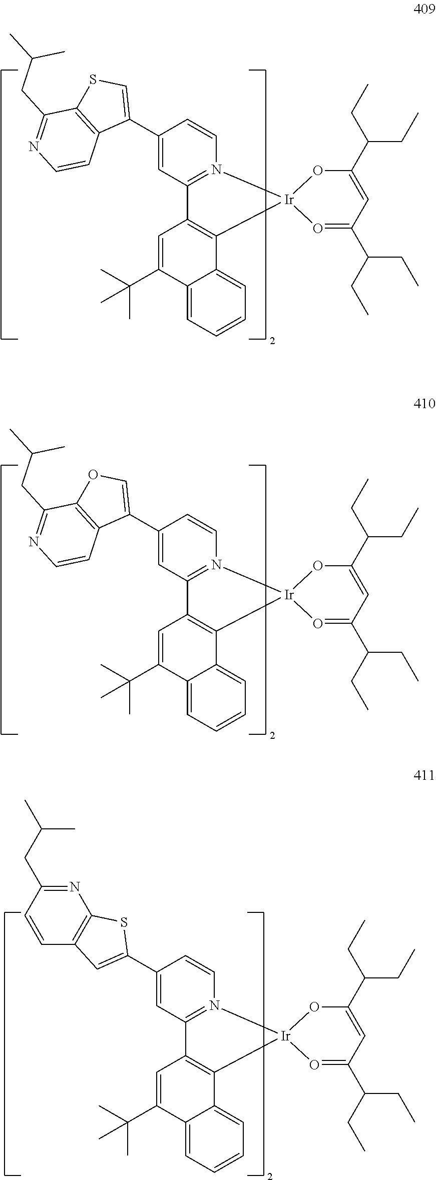

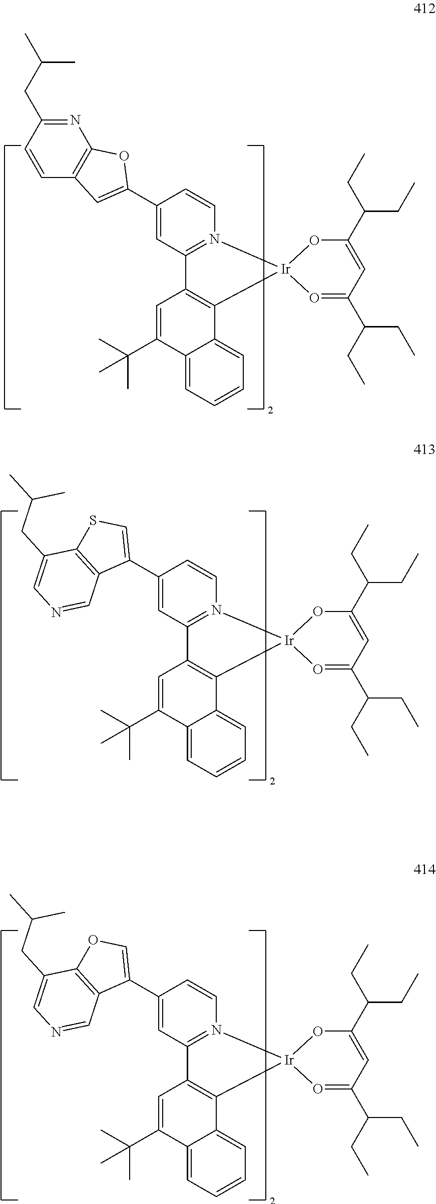

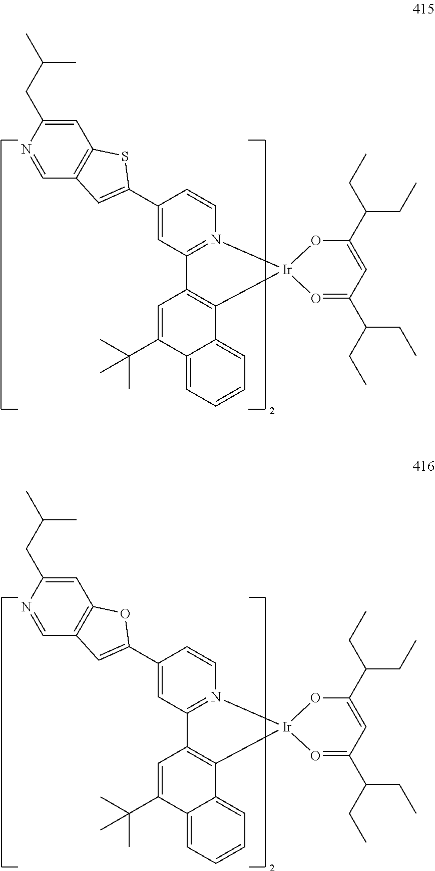

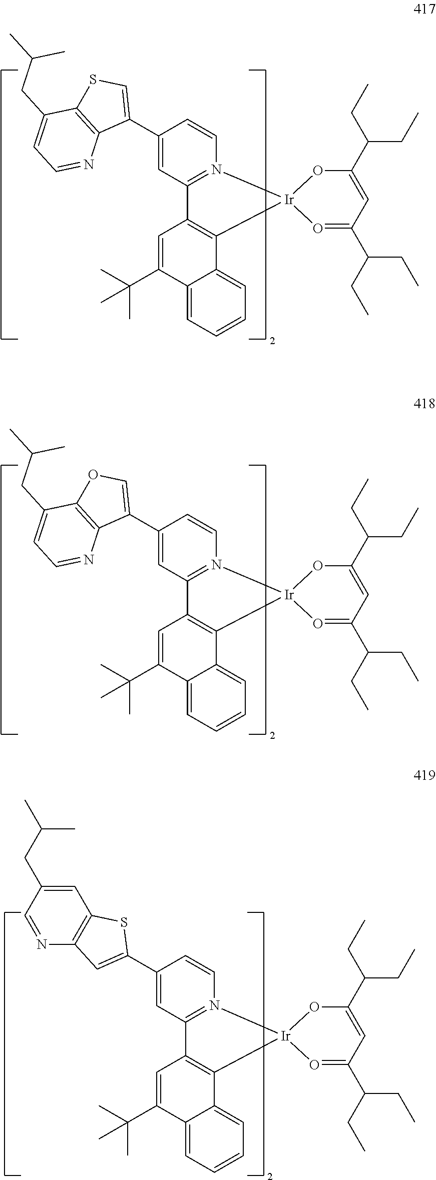

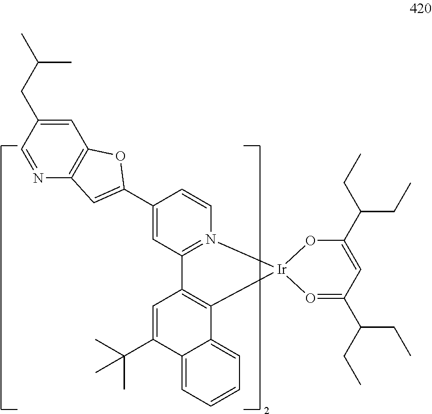

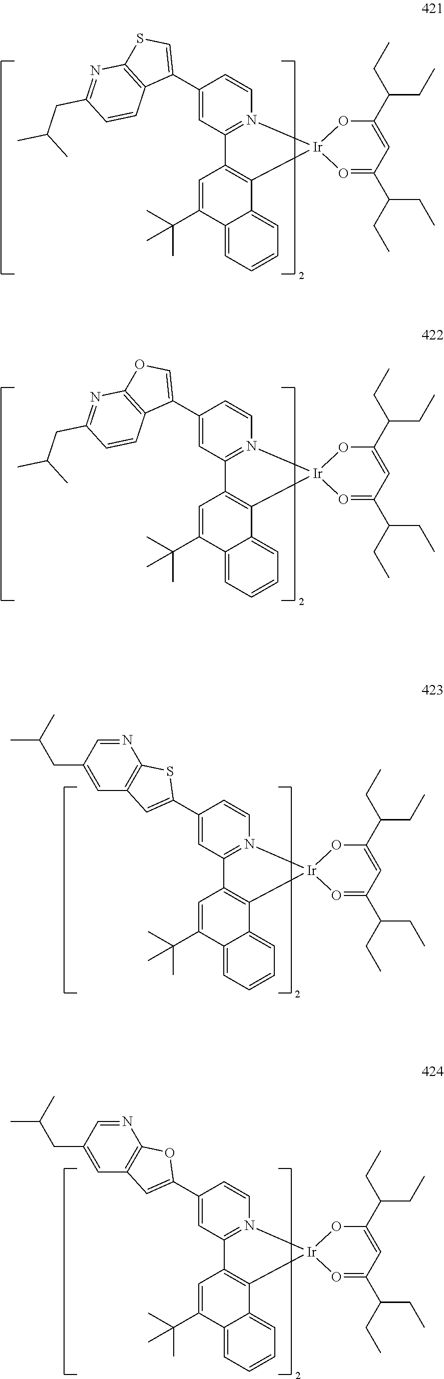

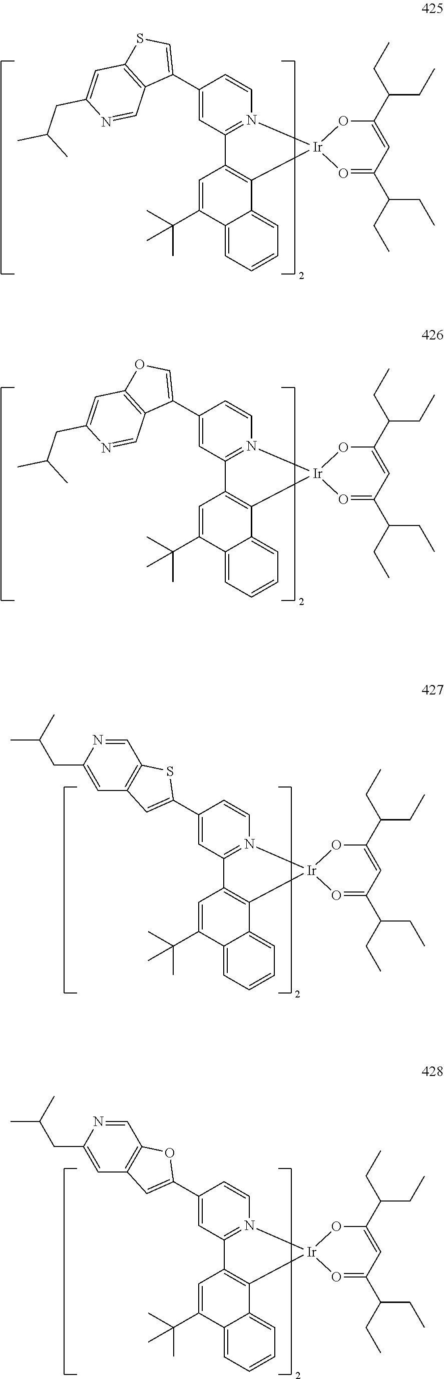

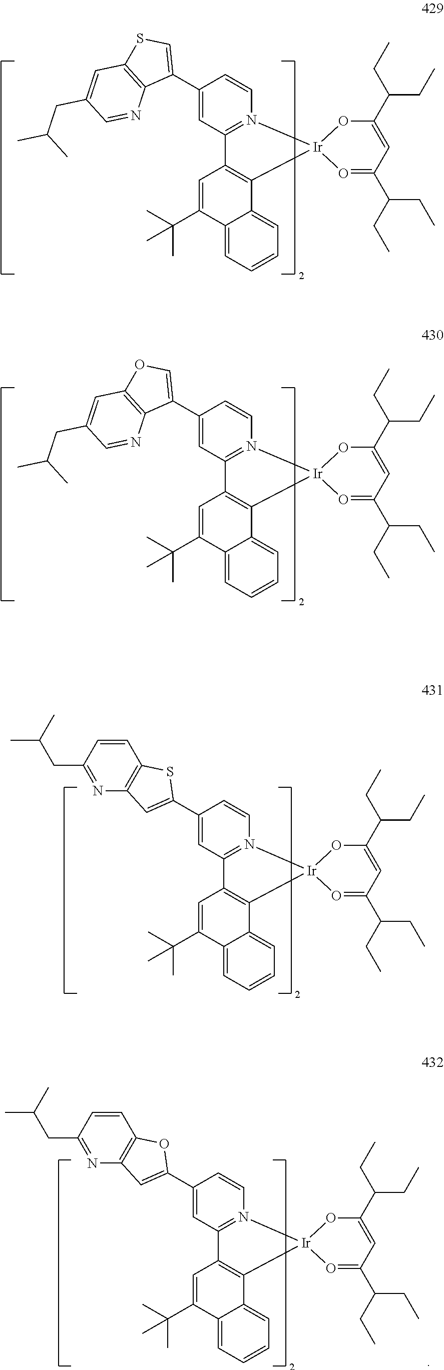

14. The organometallic compound of claim 1, wherein the organometallic compound is at least one of:

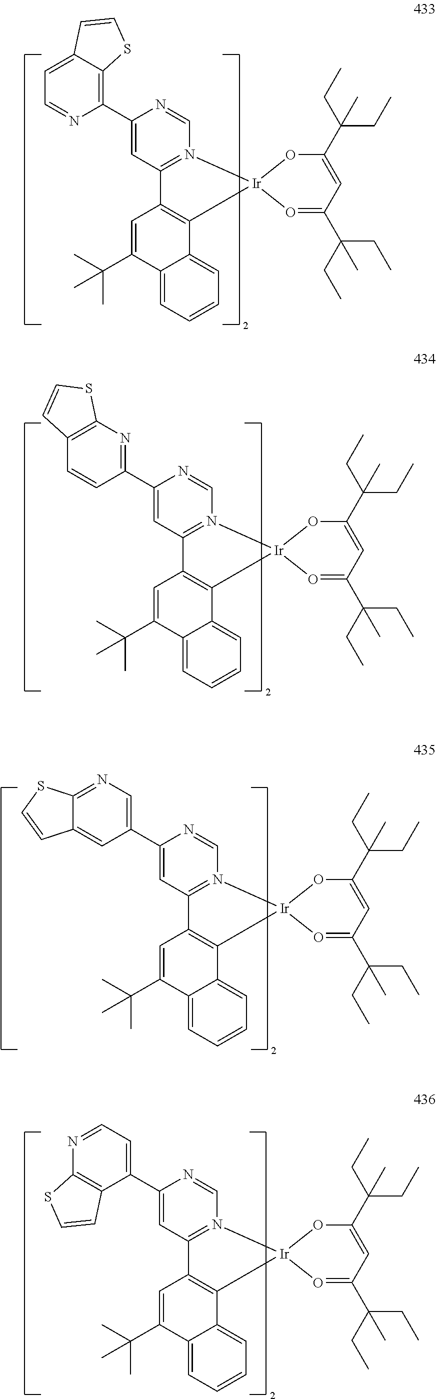

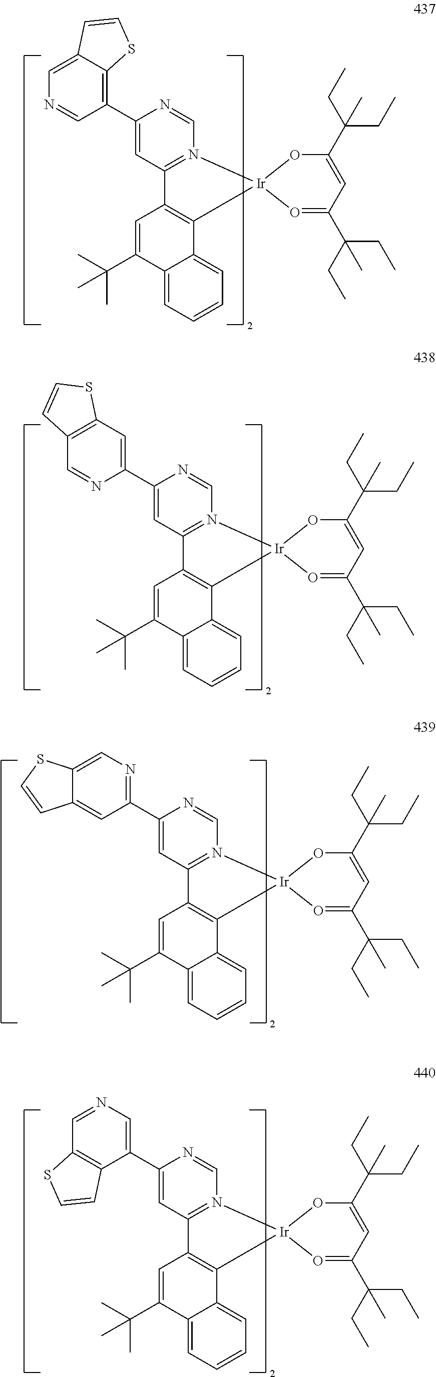

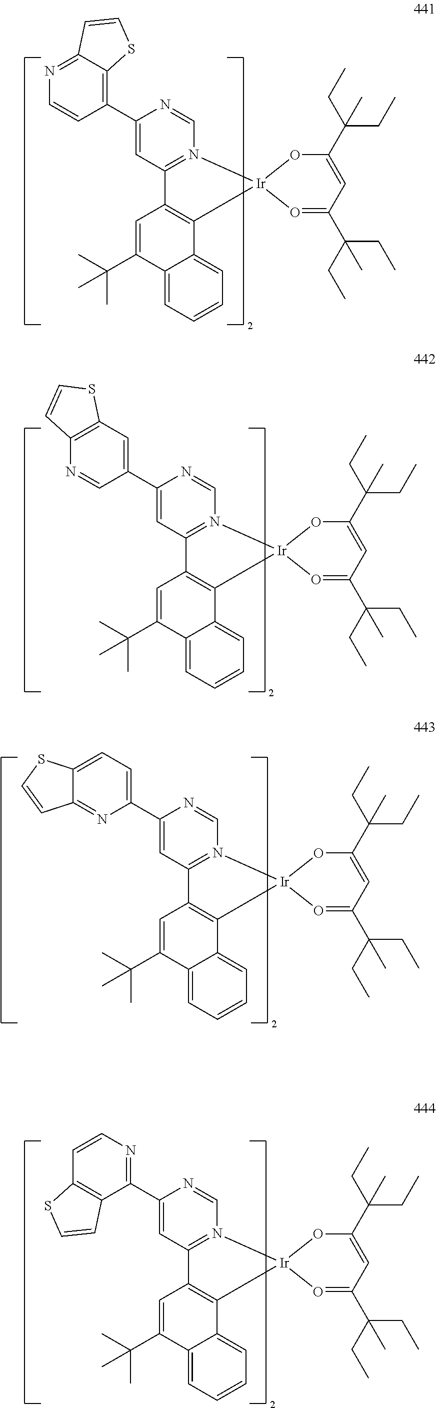

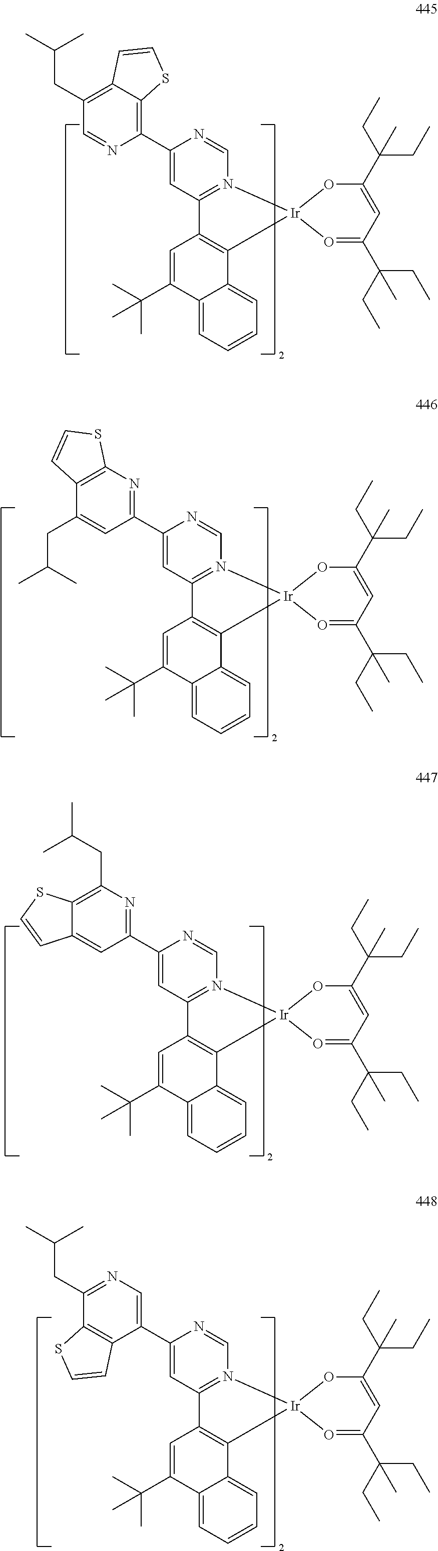

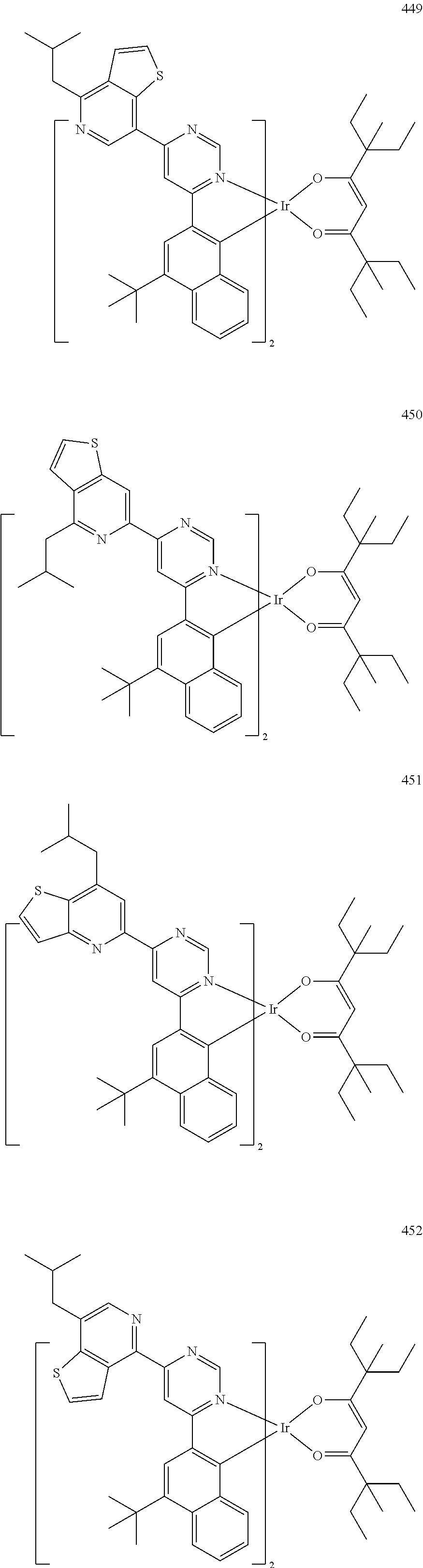

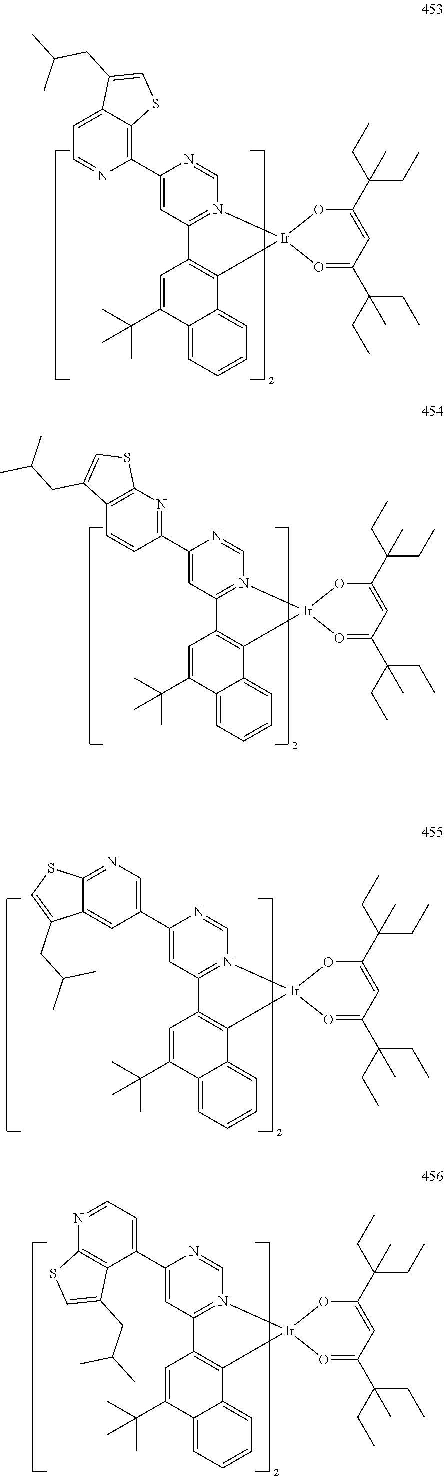

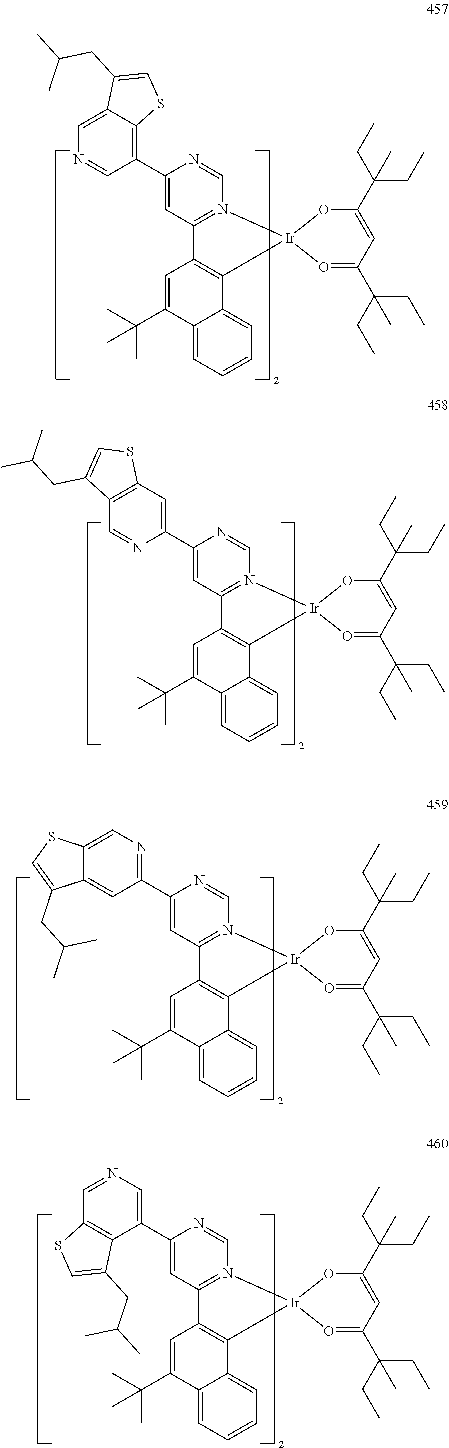

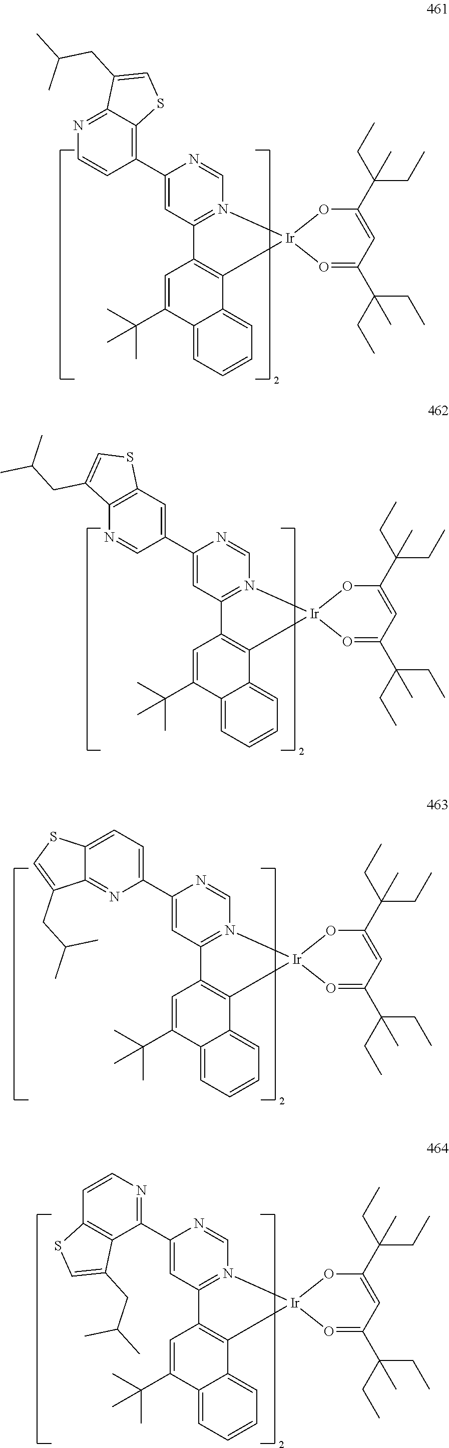

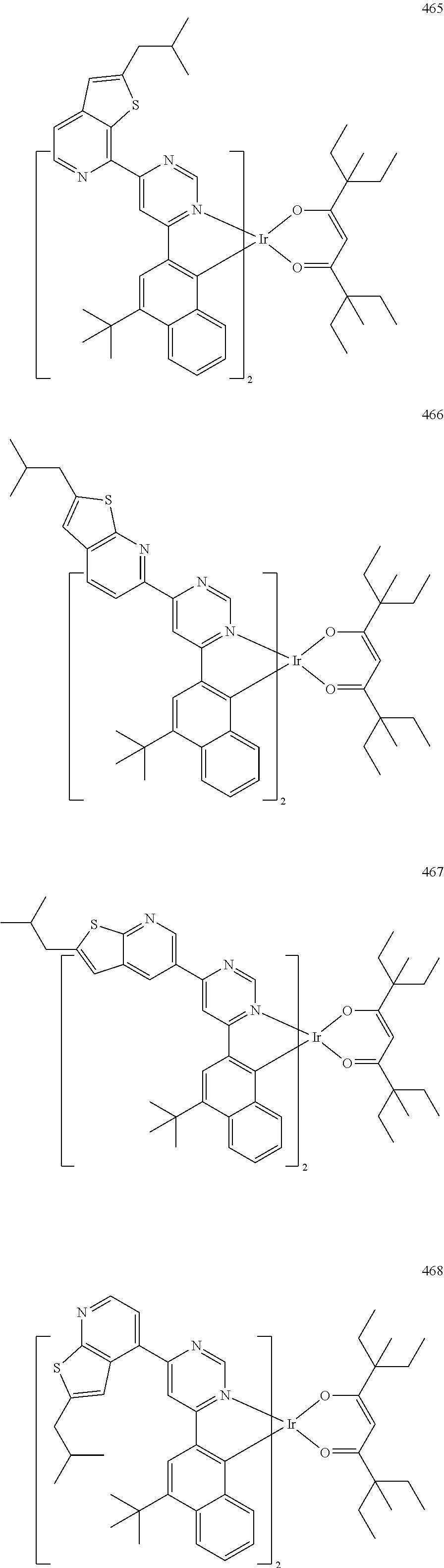

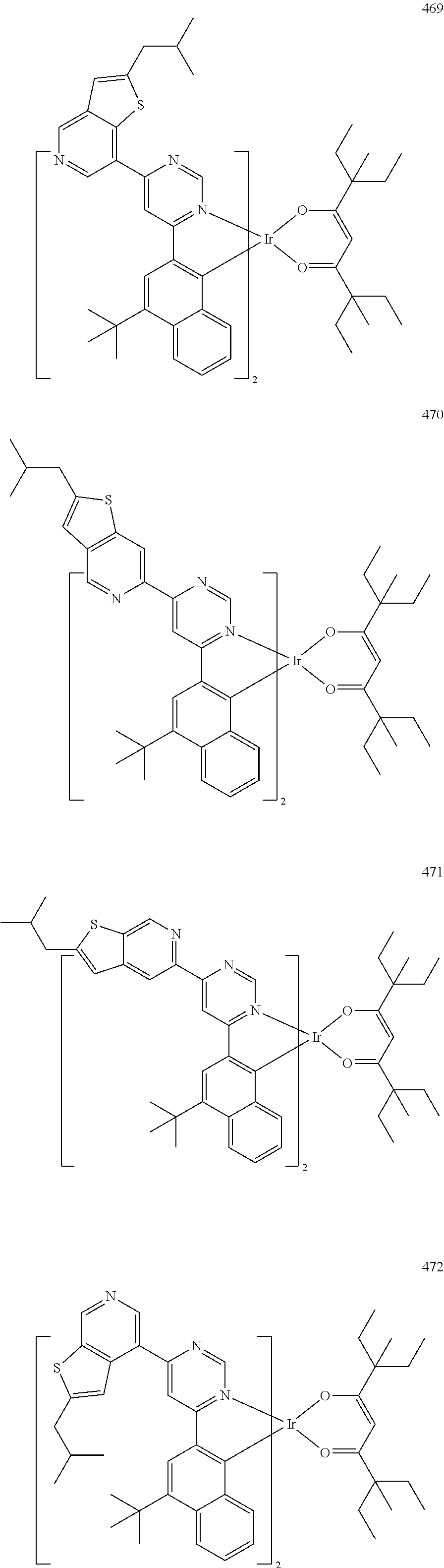

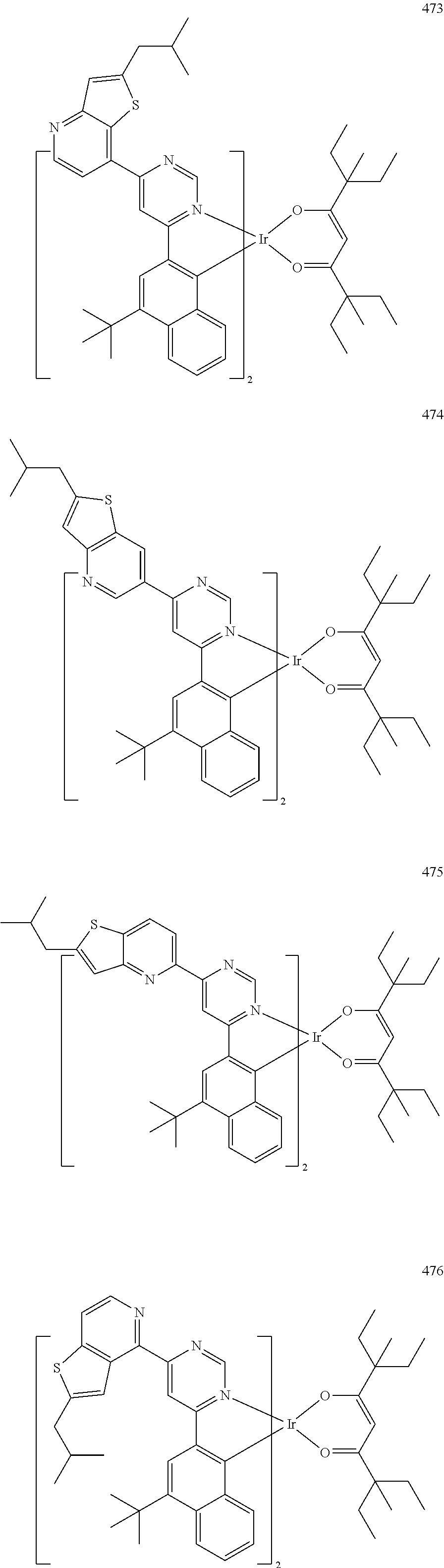

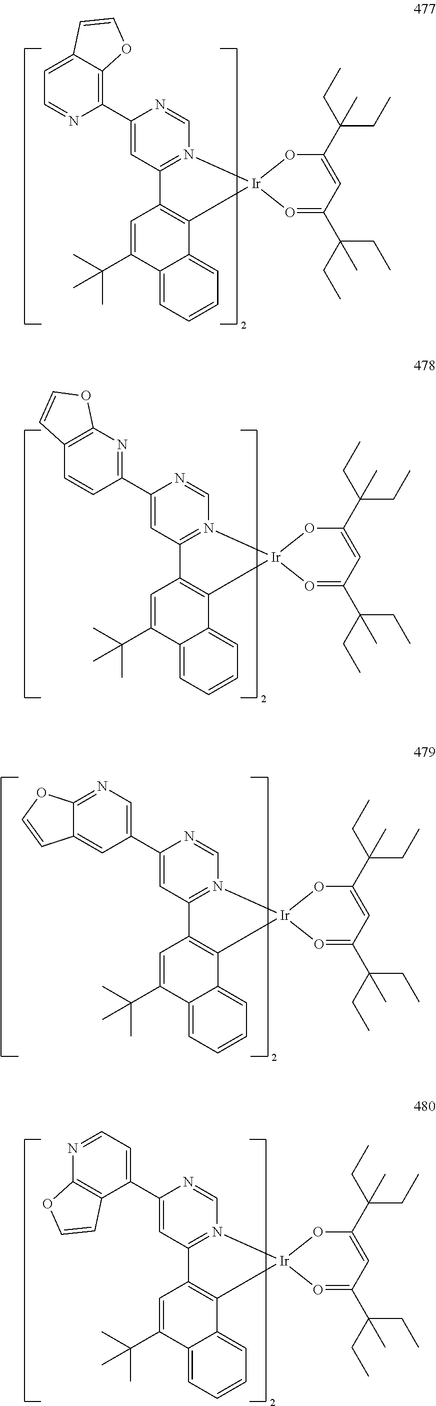

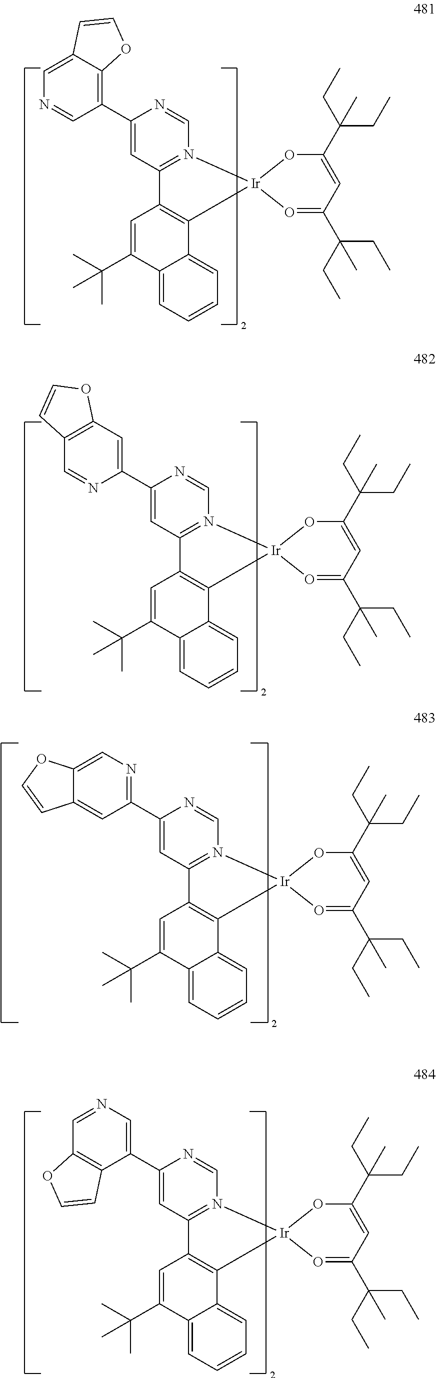

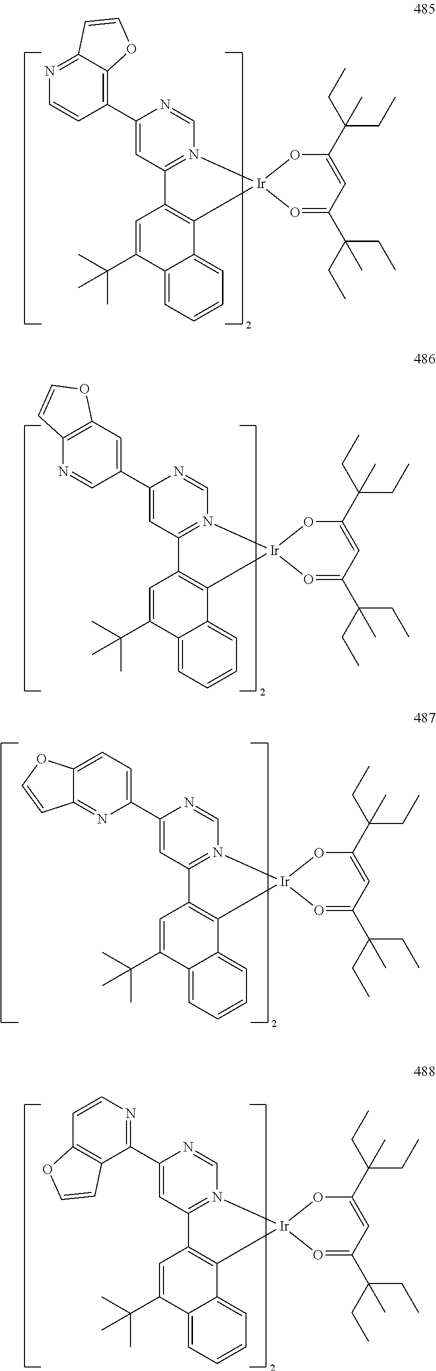

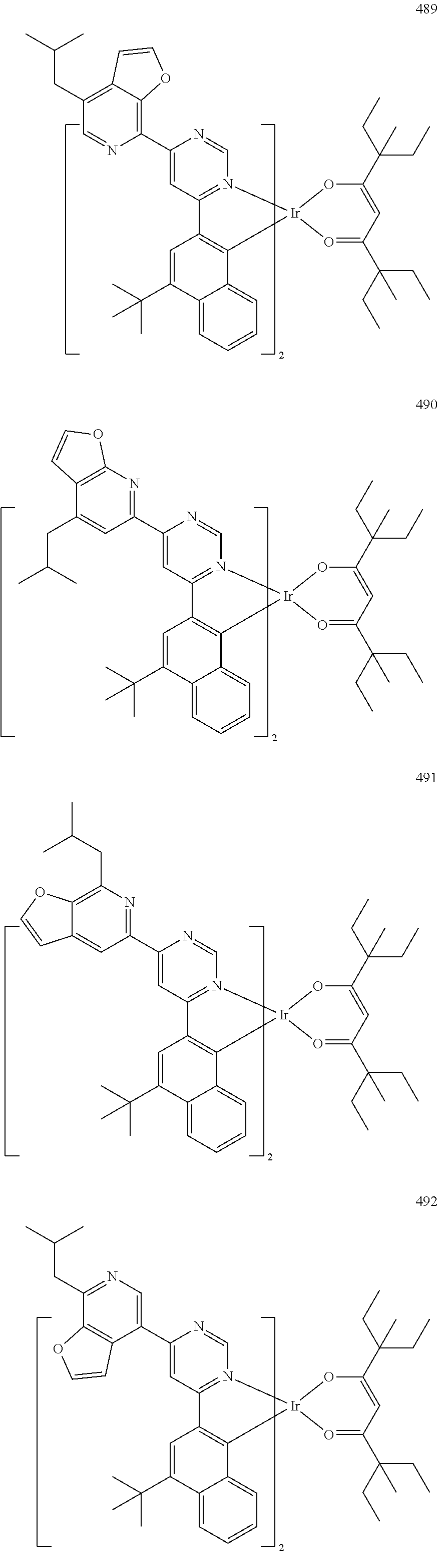

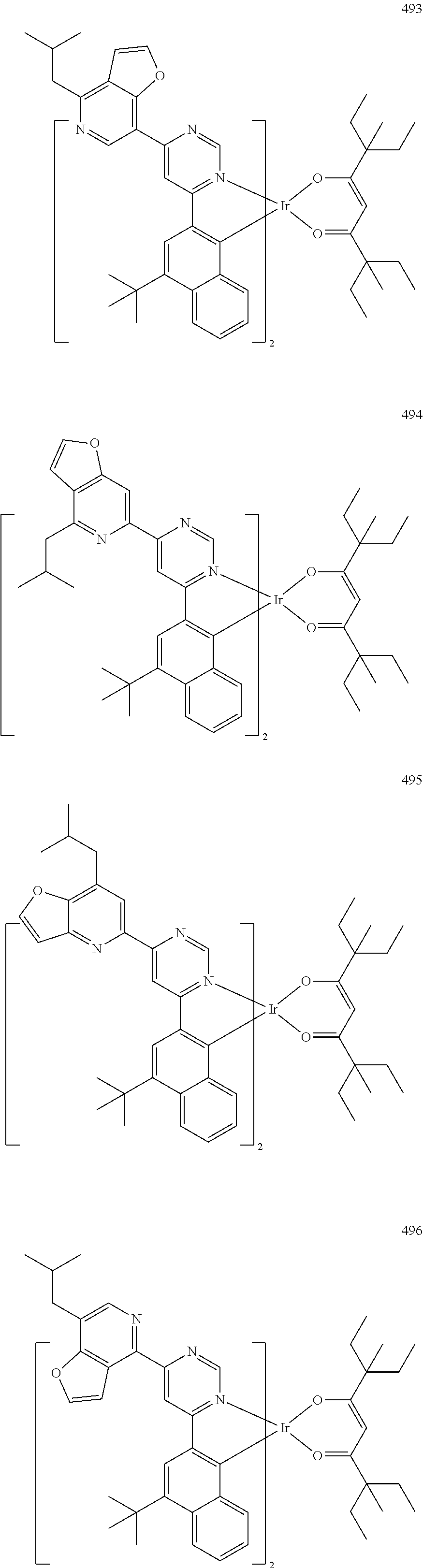

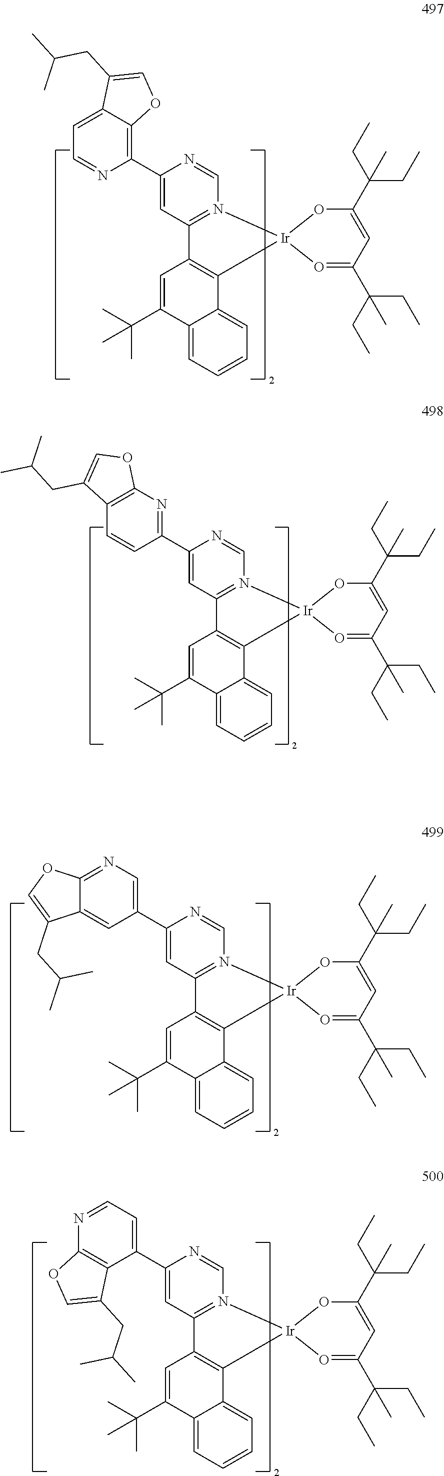

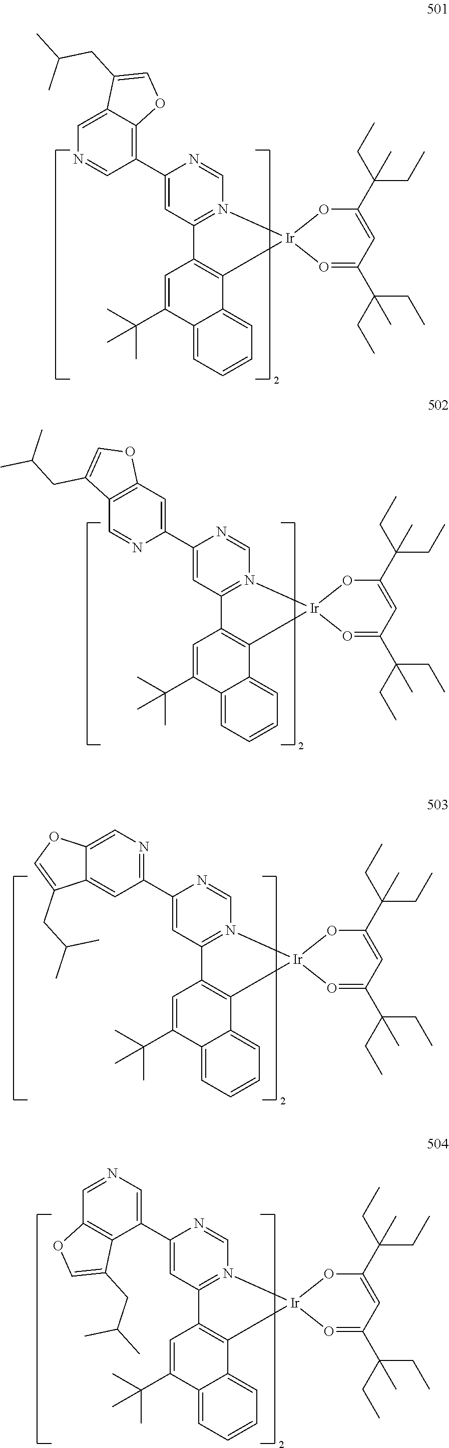

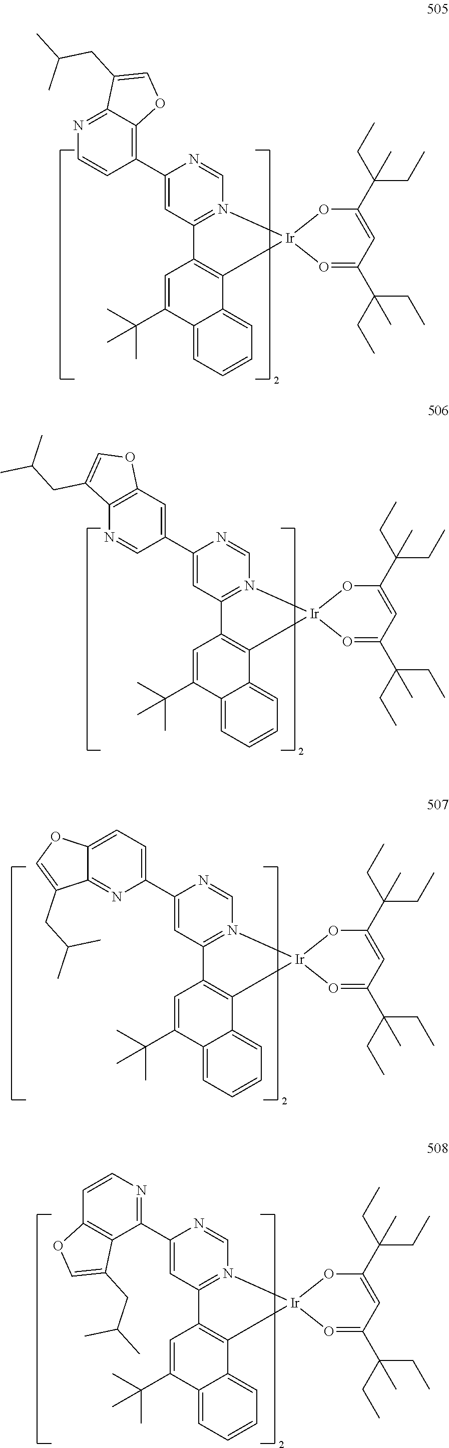

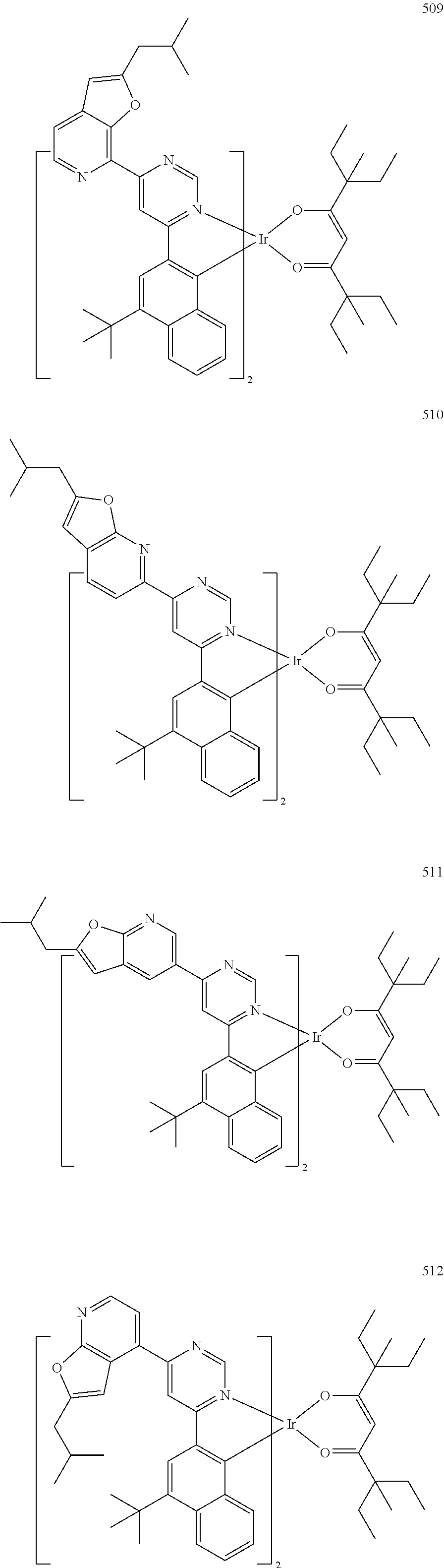

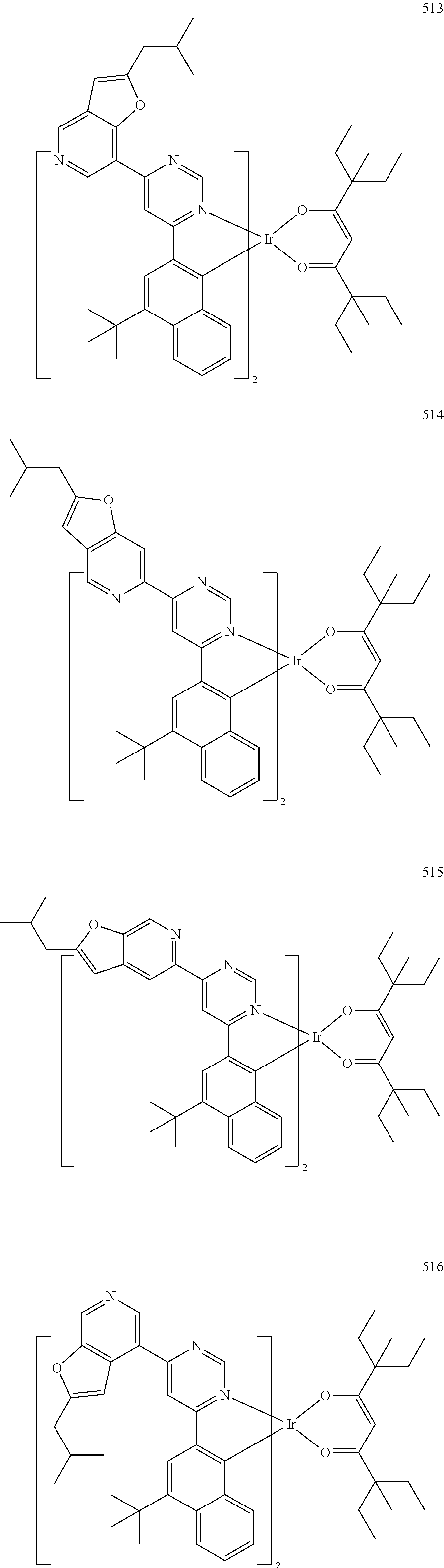

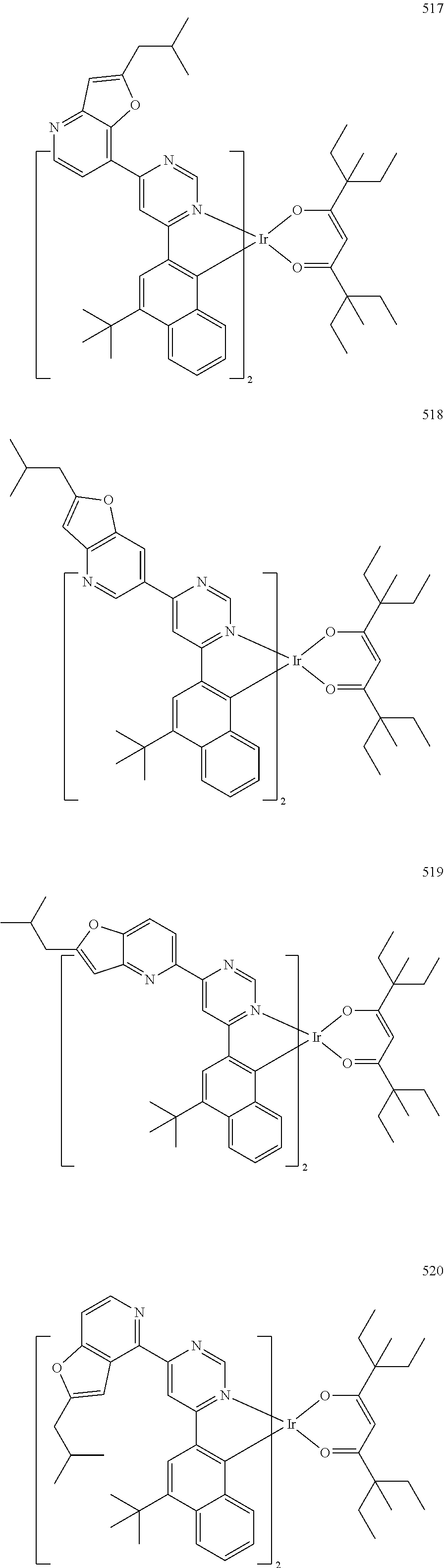

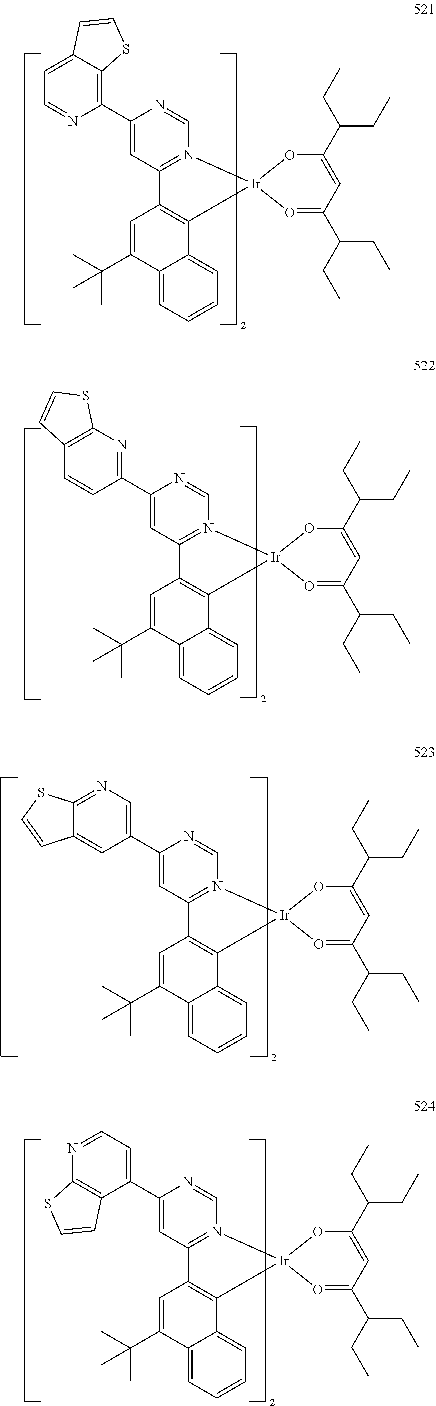

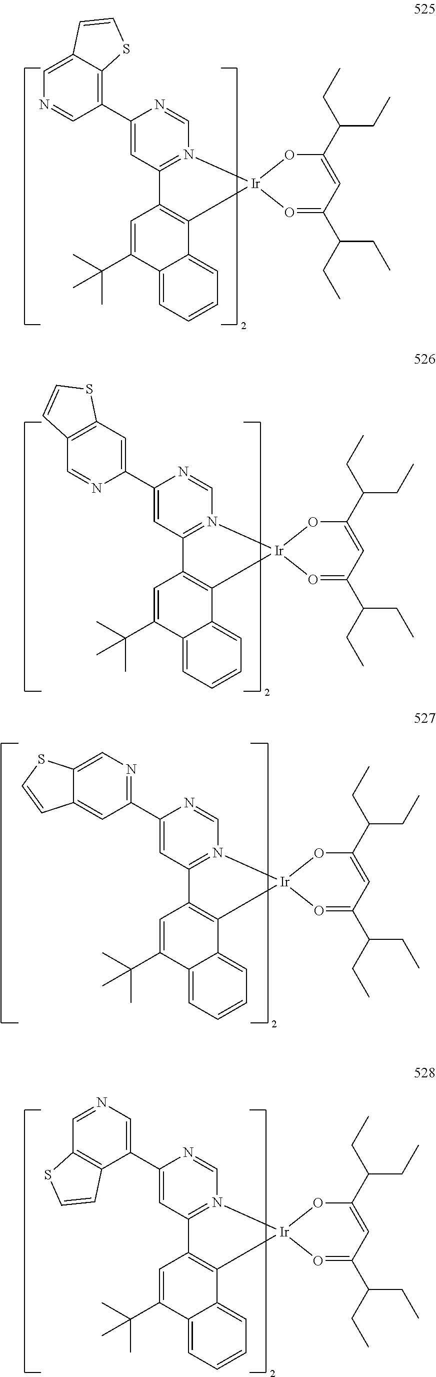

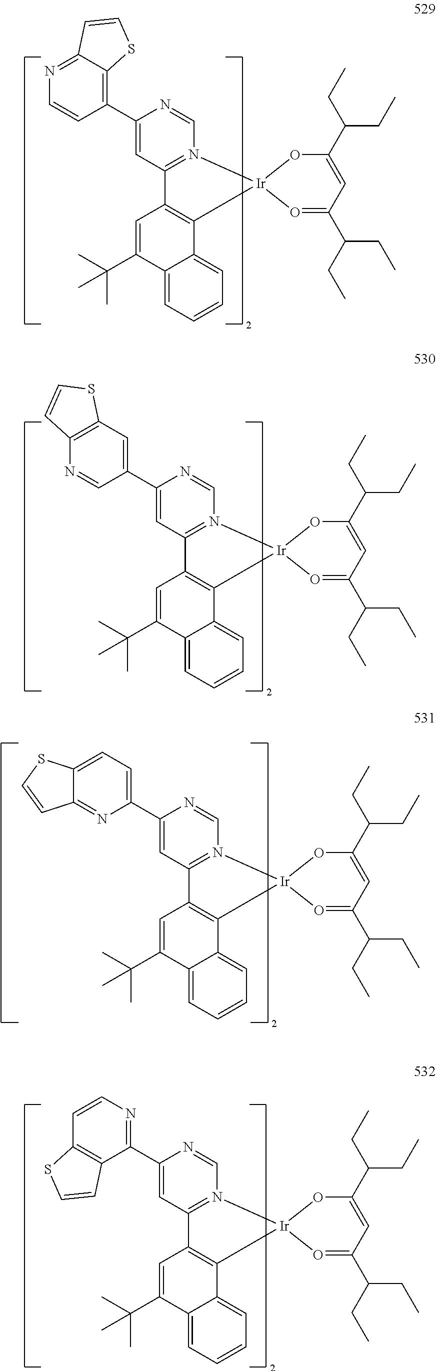

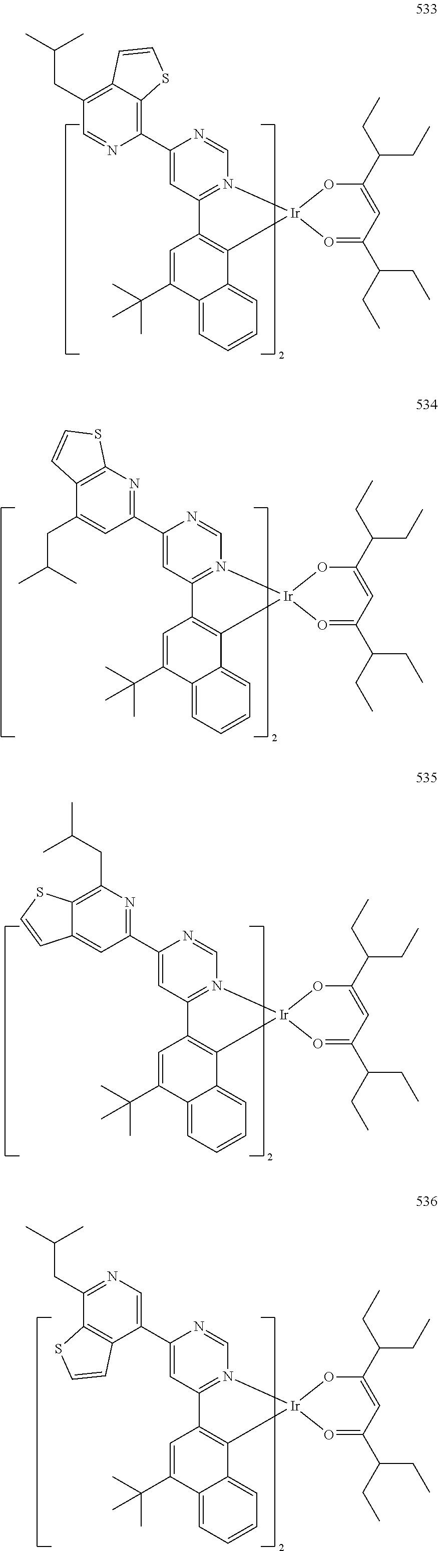

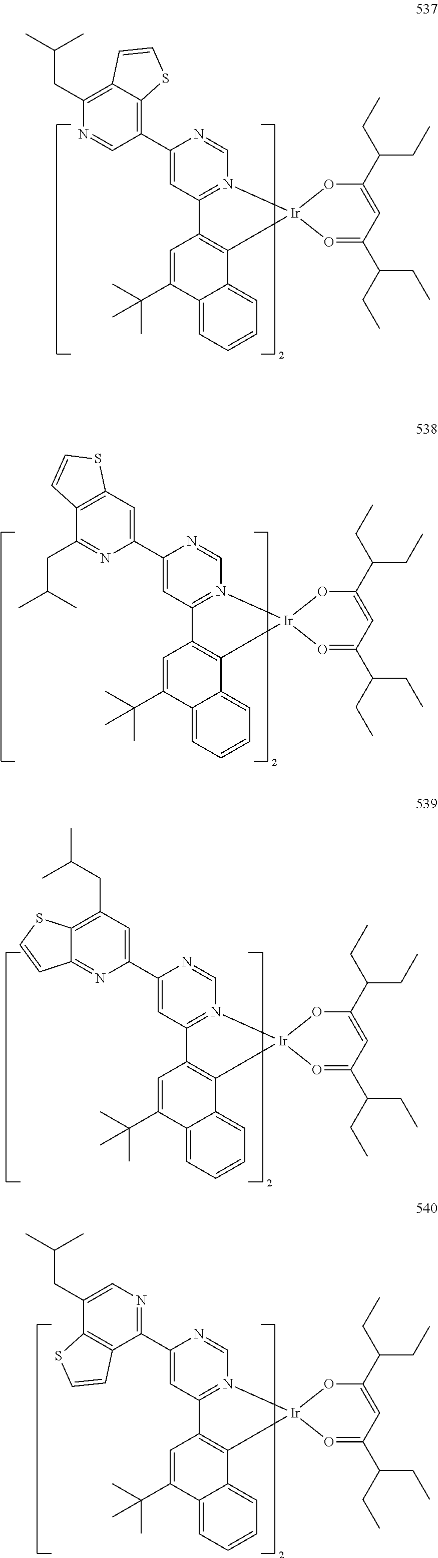

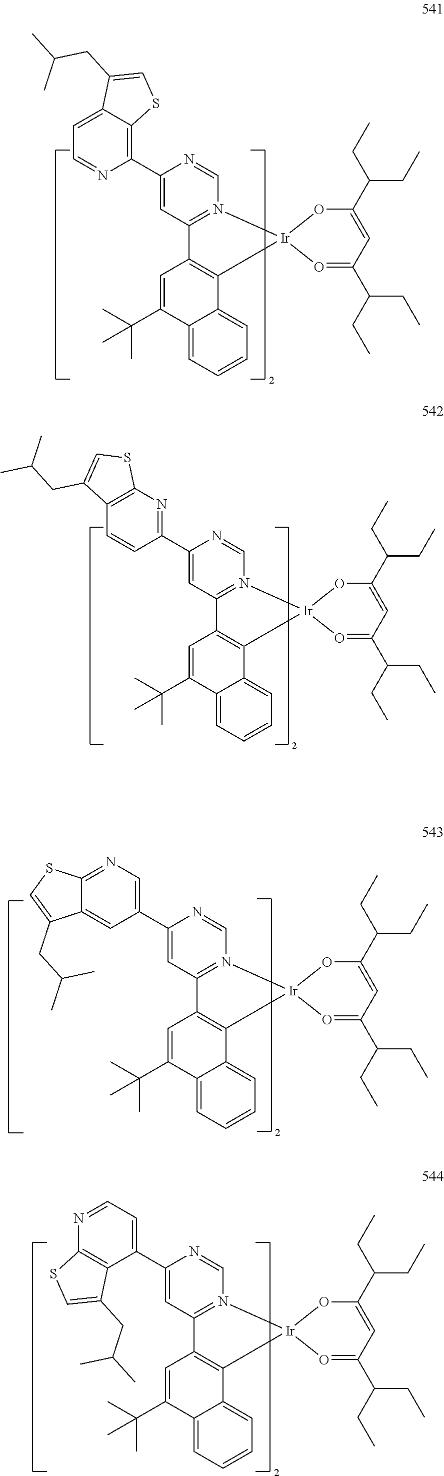

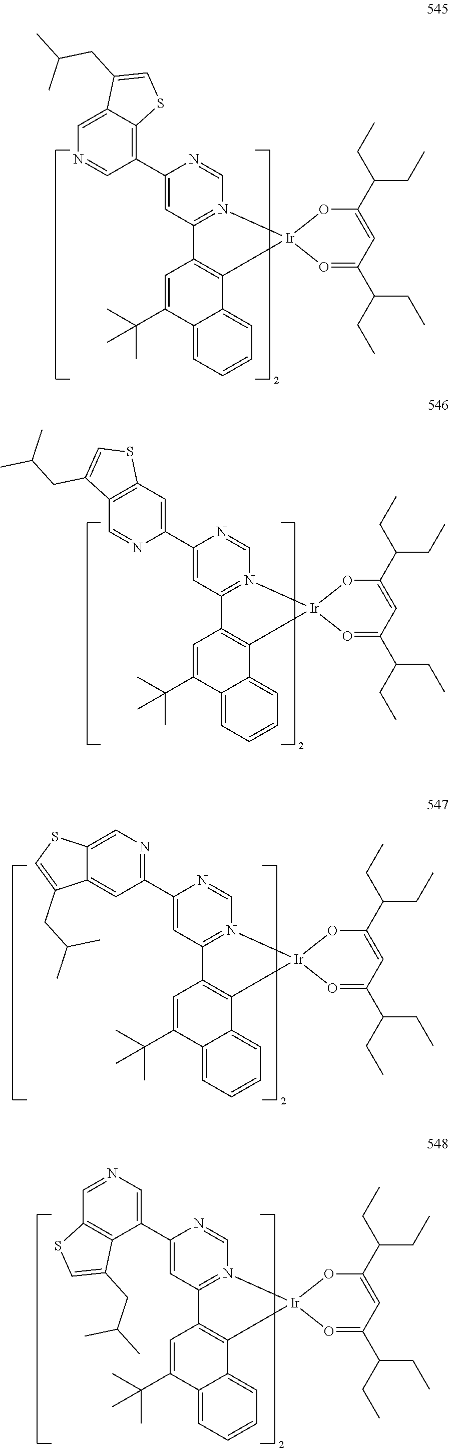

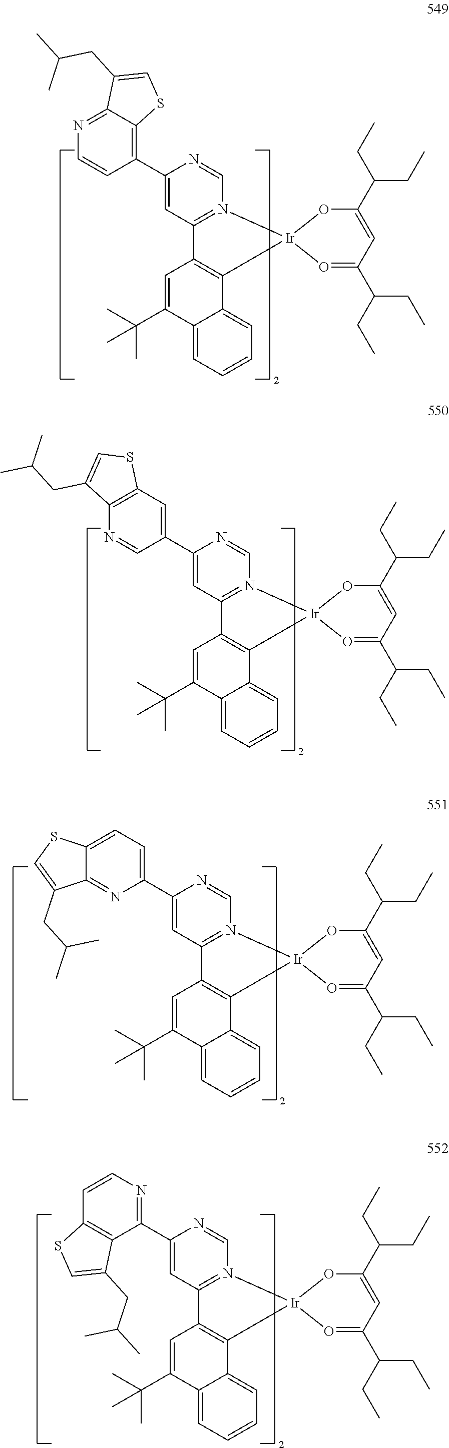

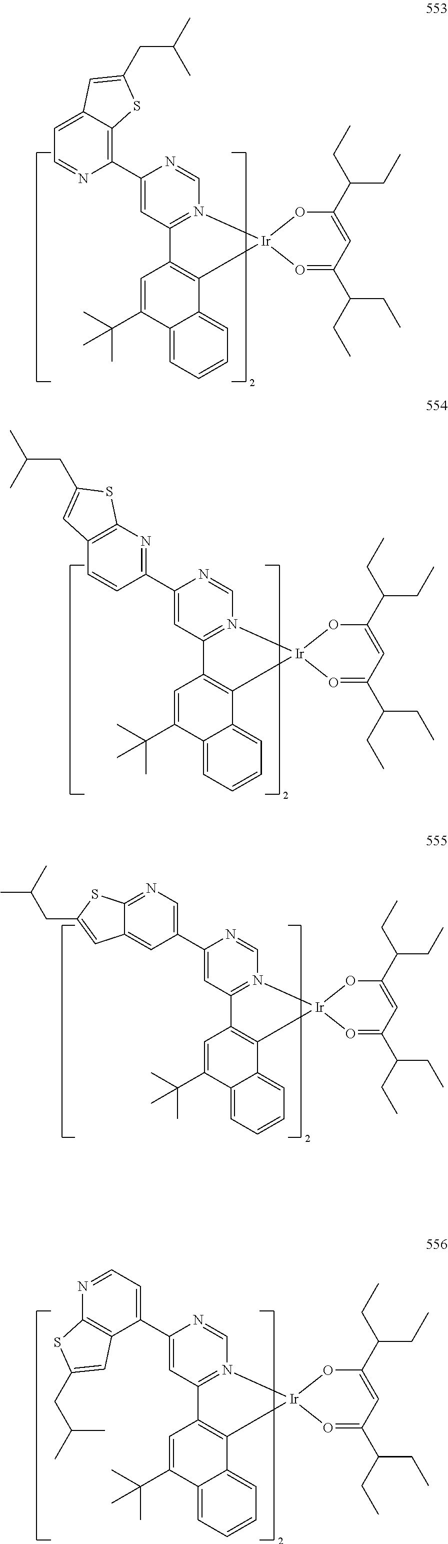

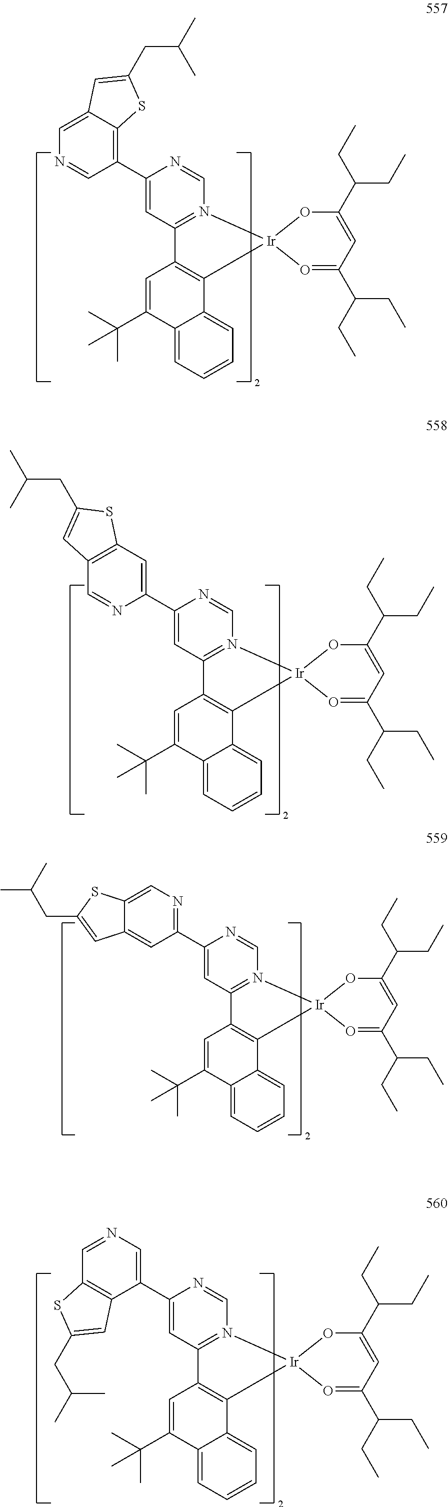

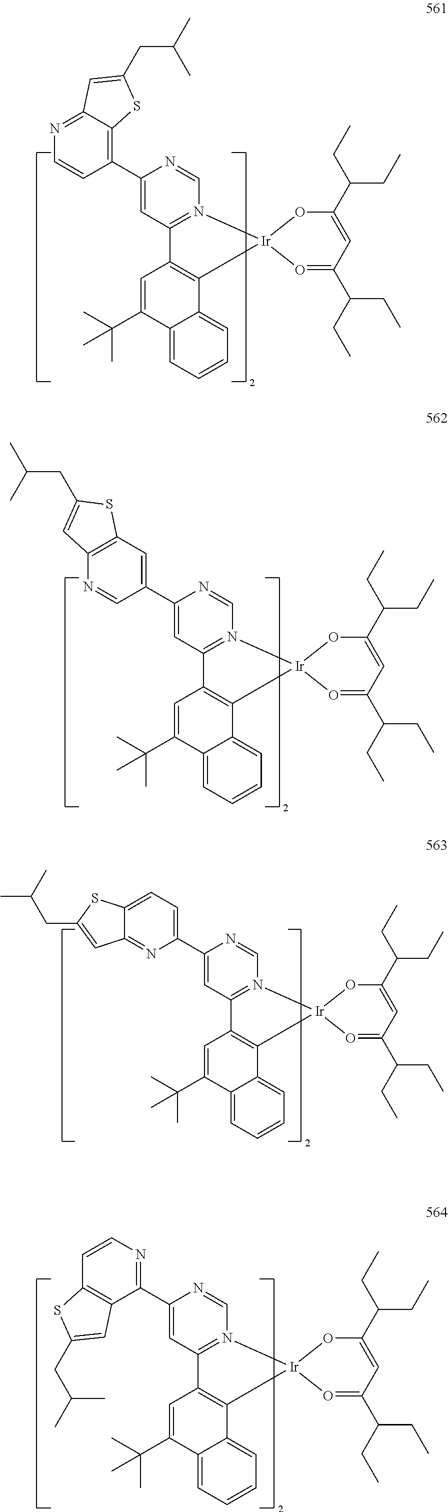

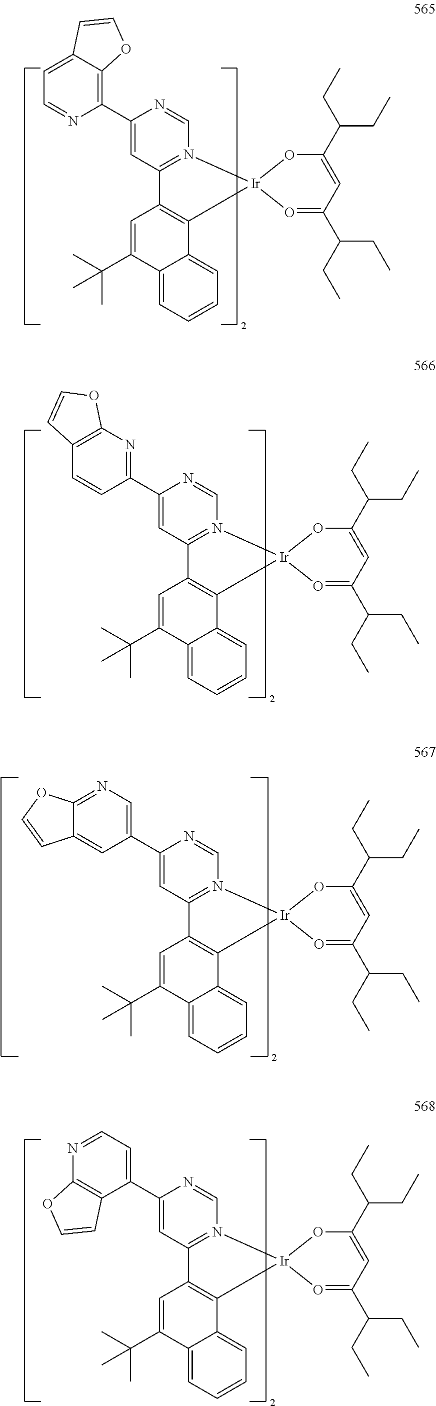

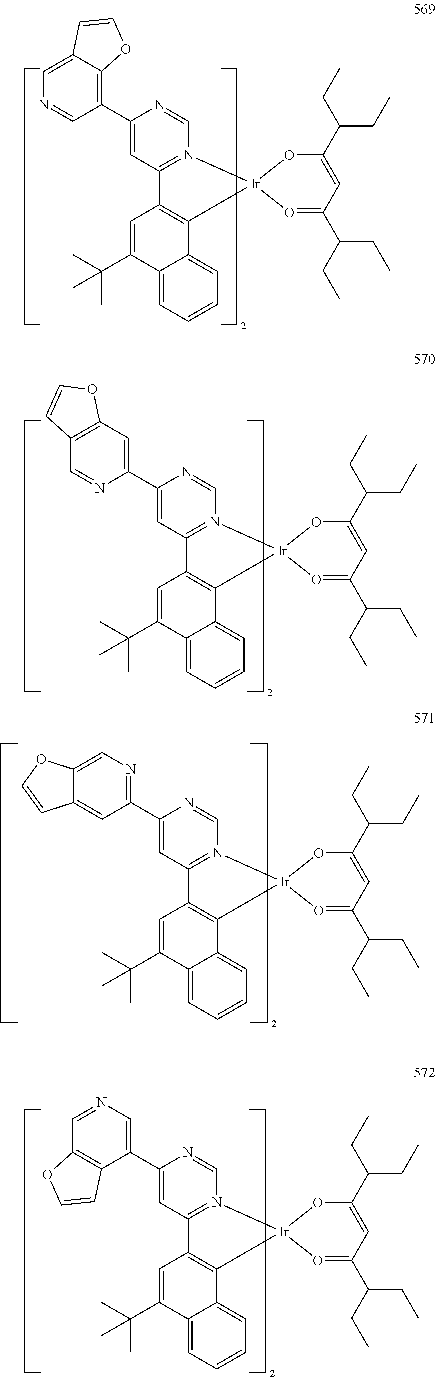

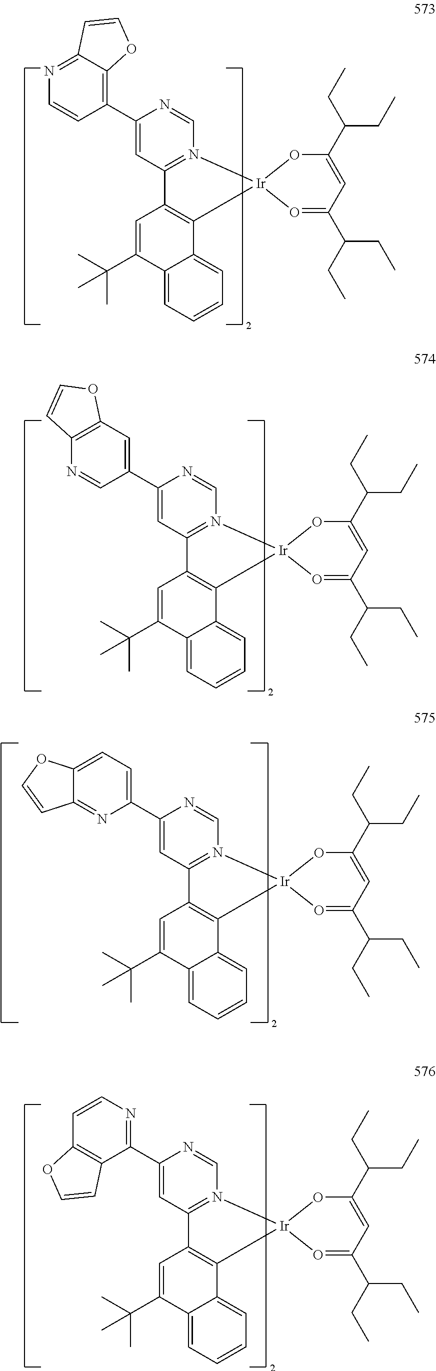

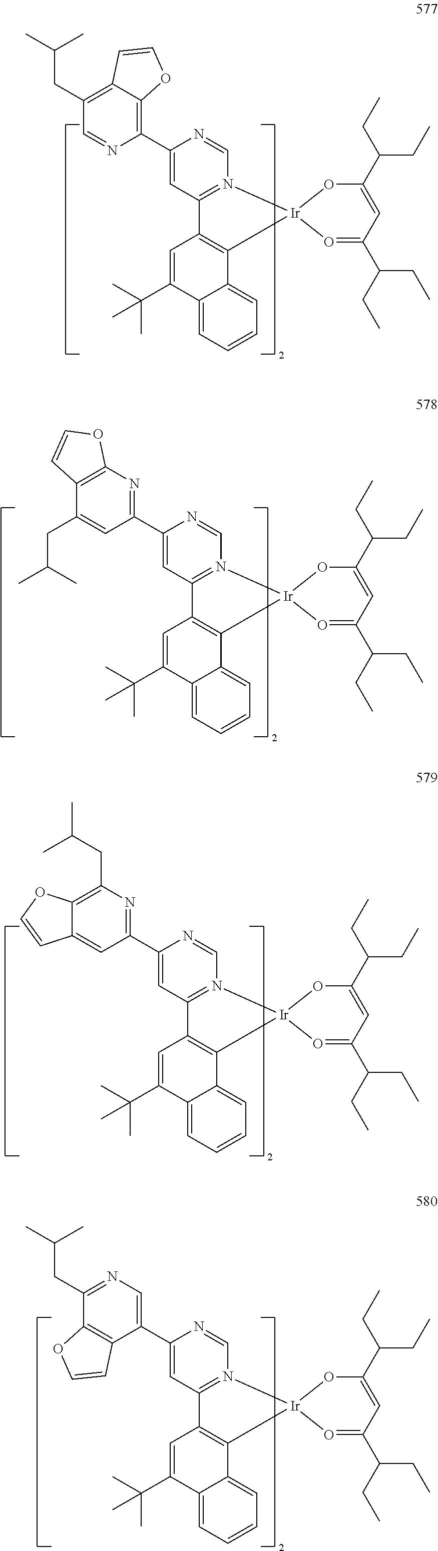

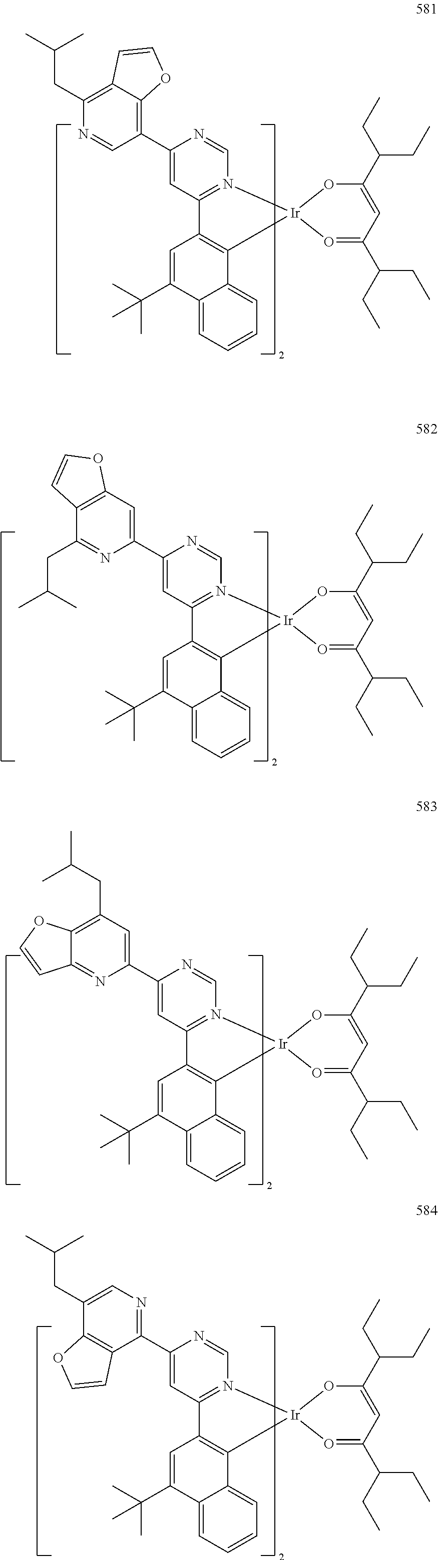

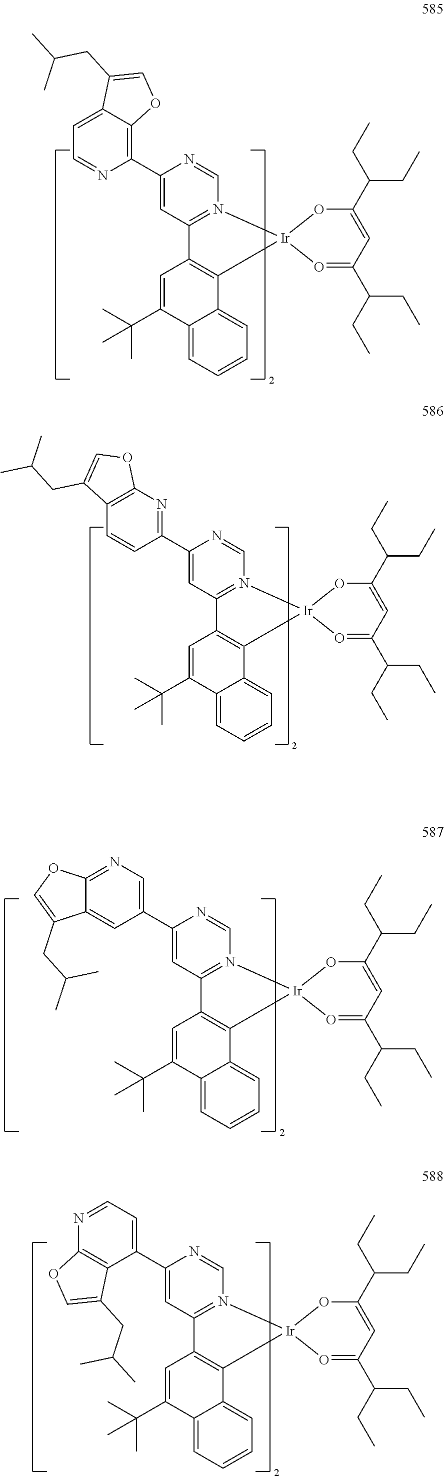

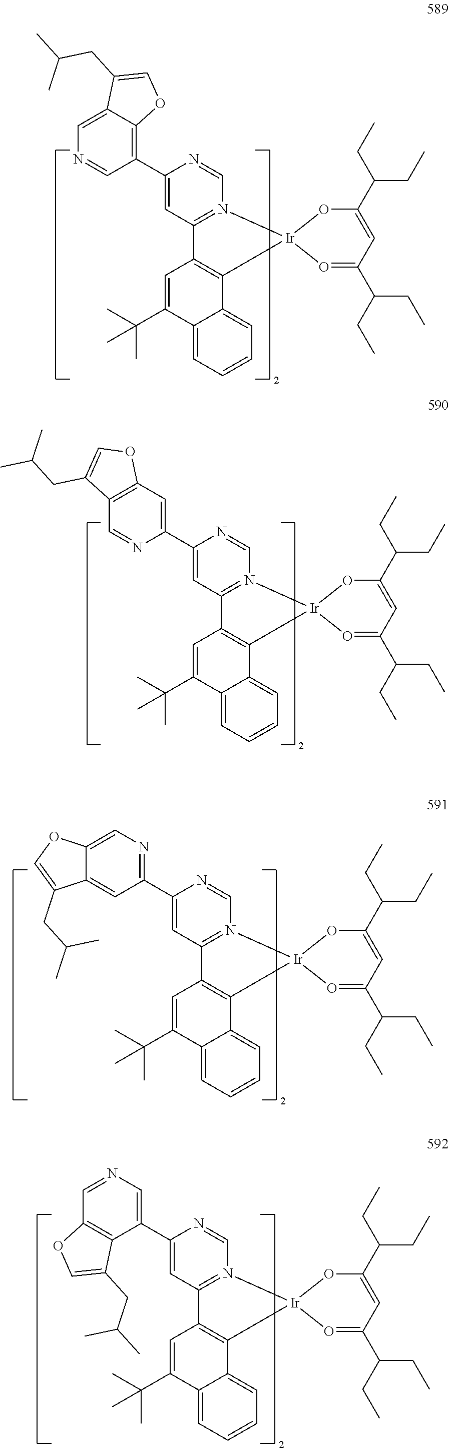

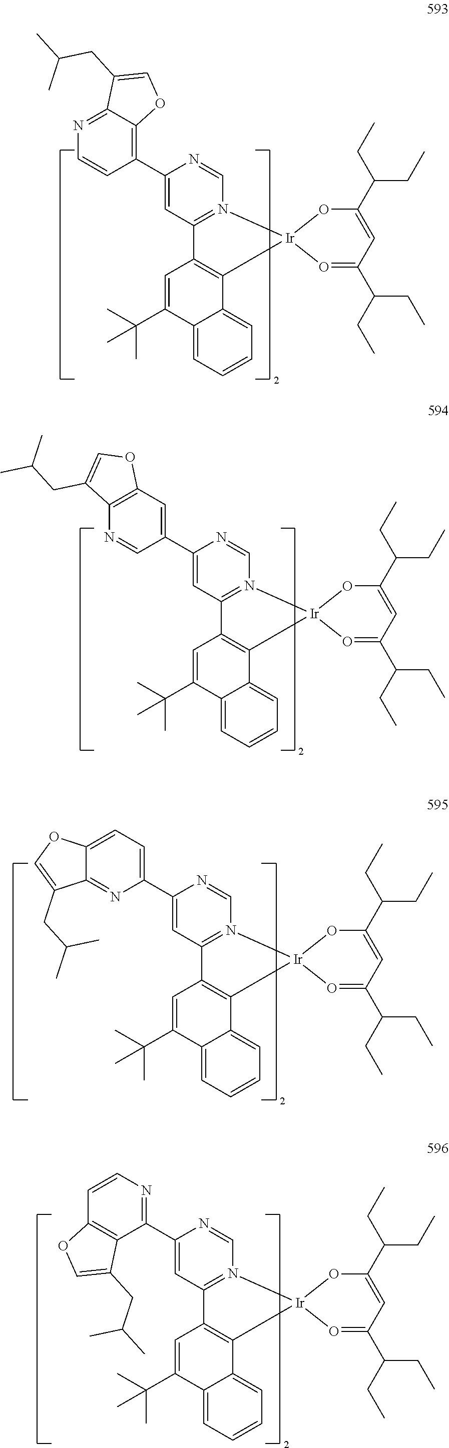

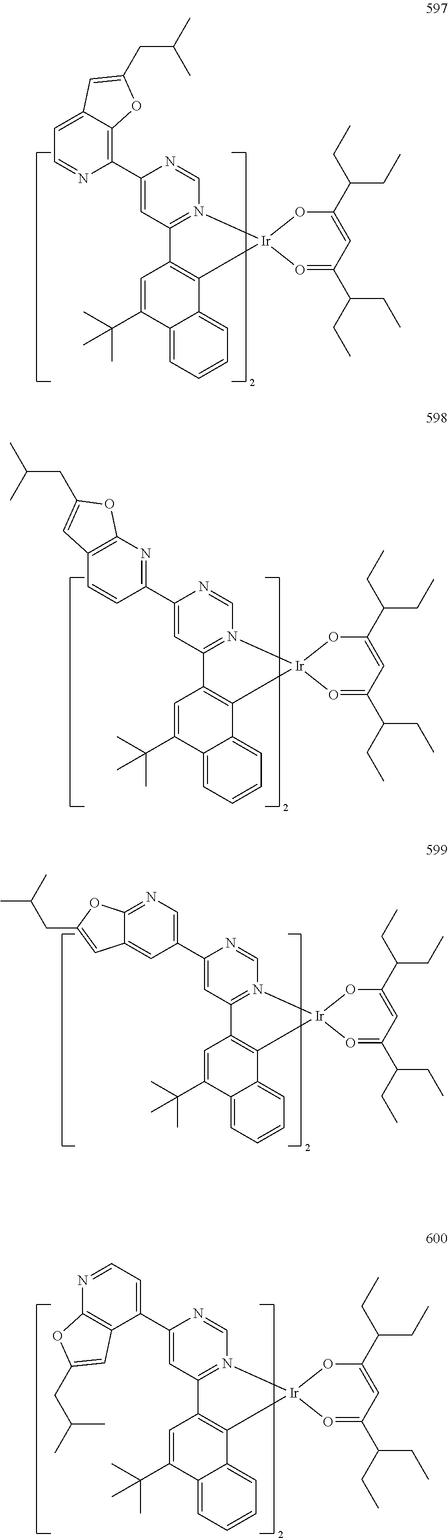

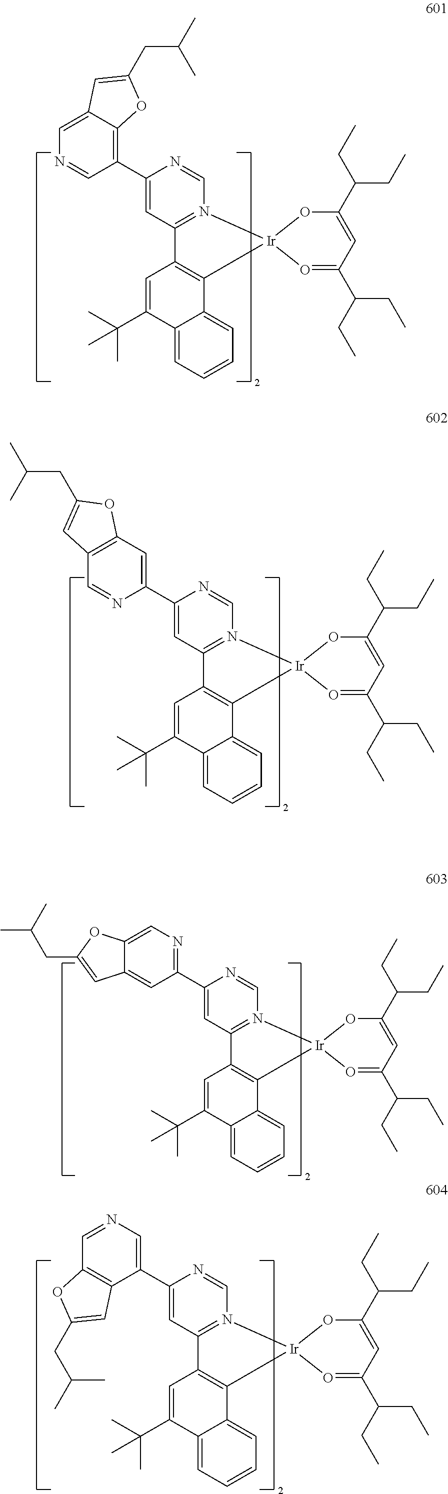

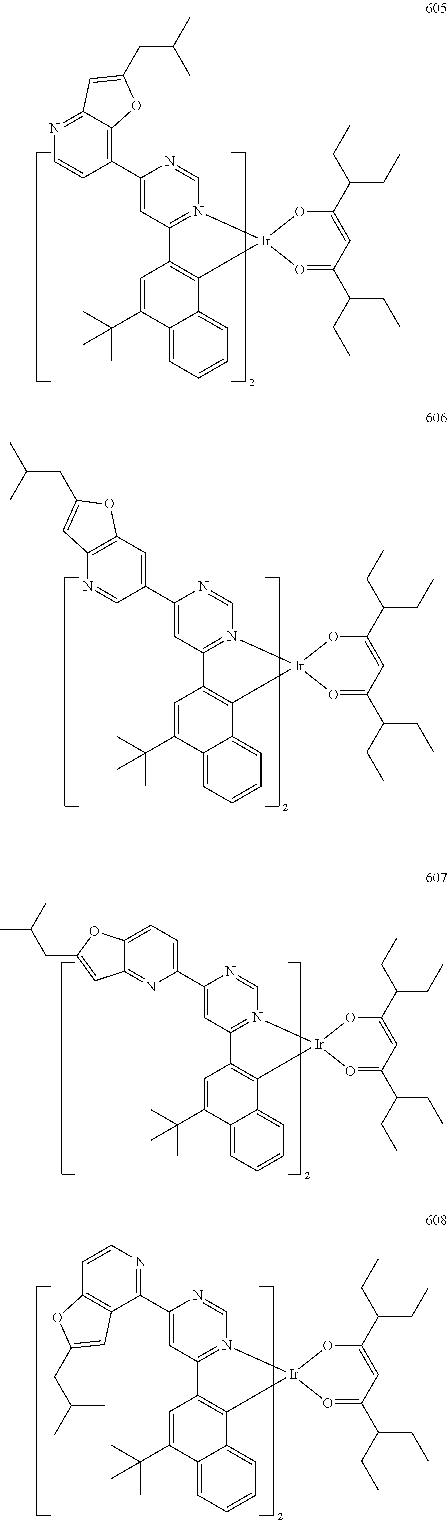

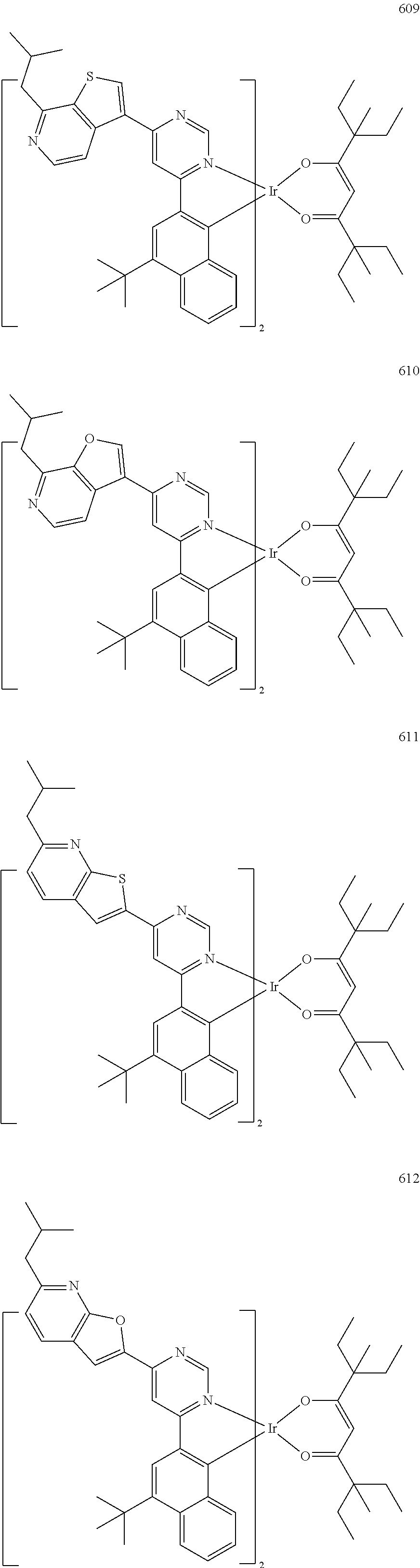

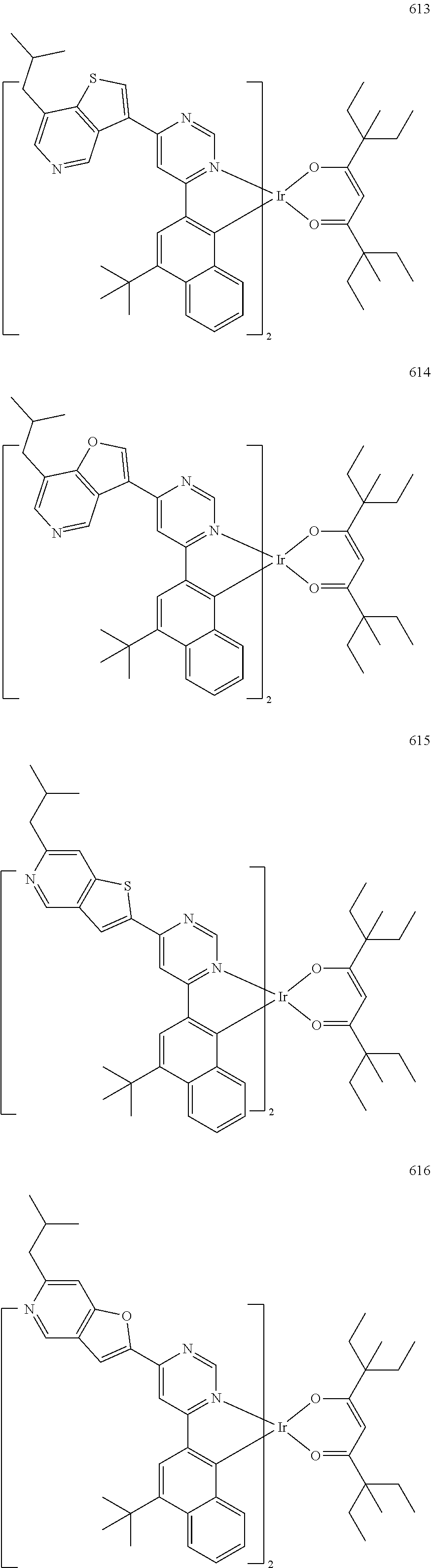

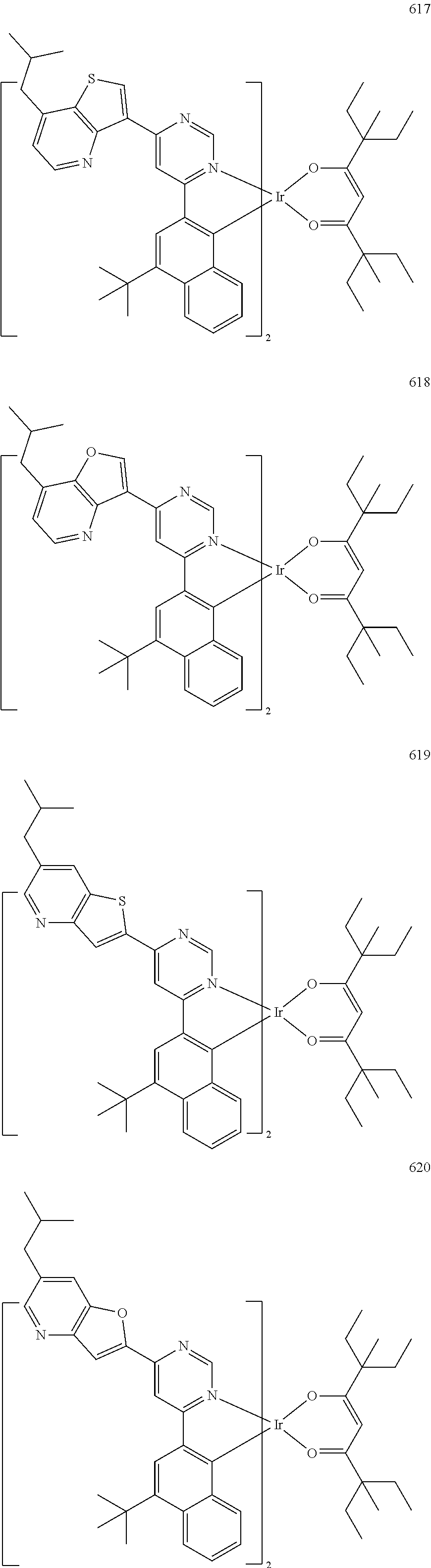

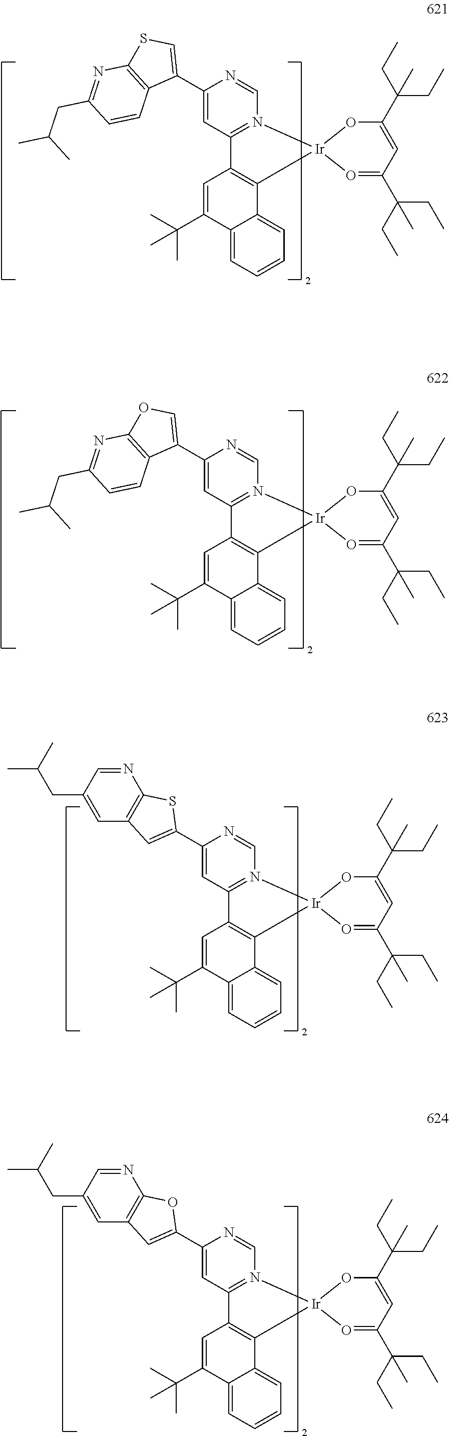

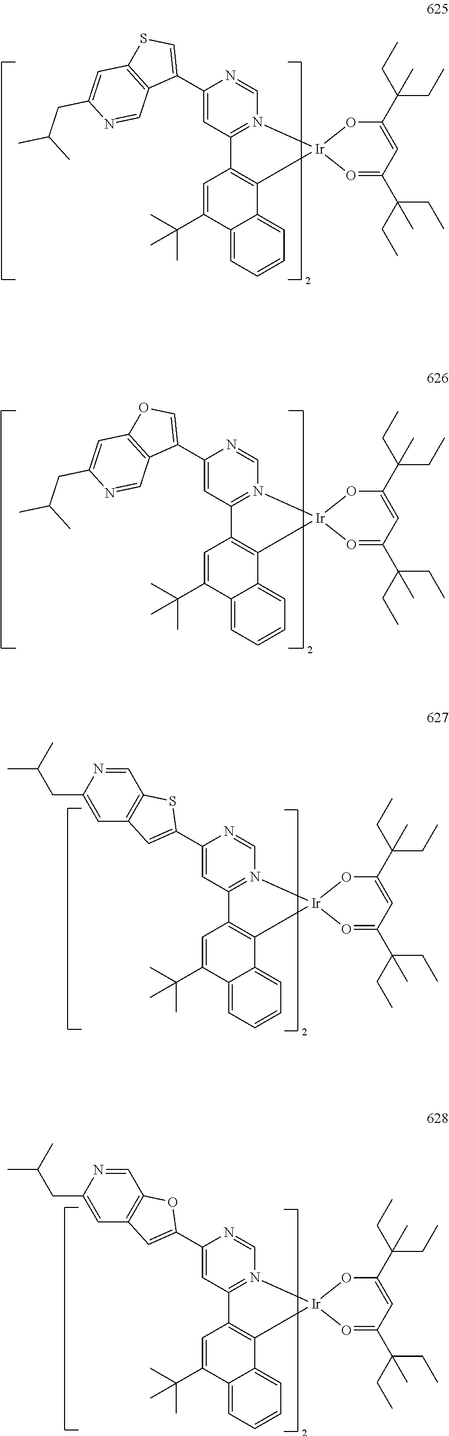

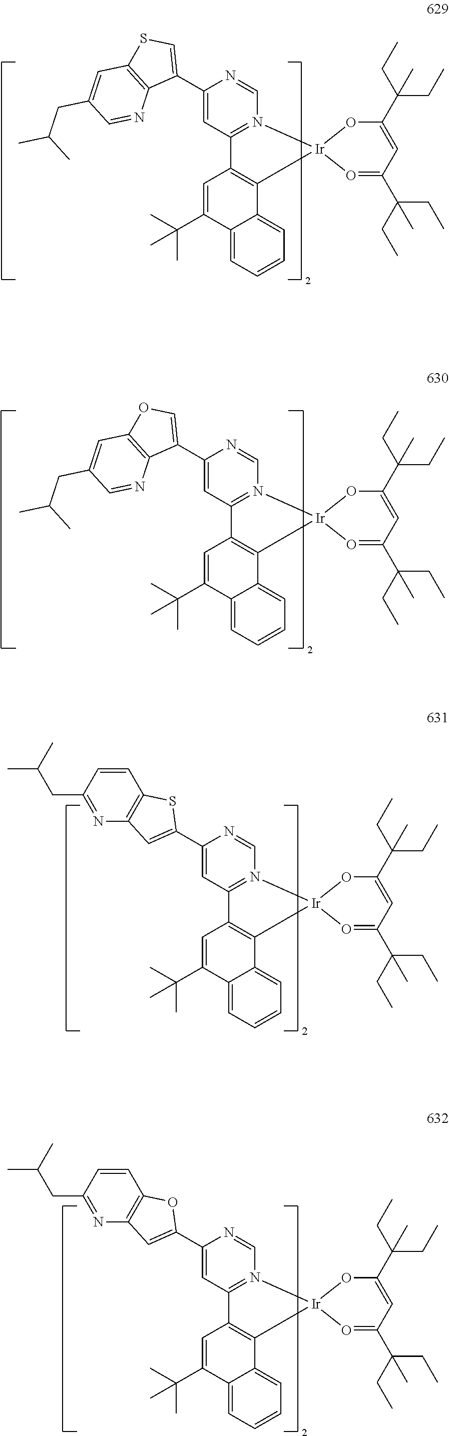

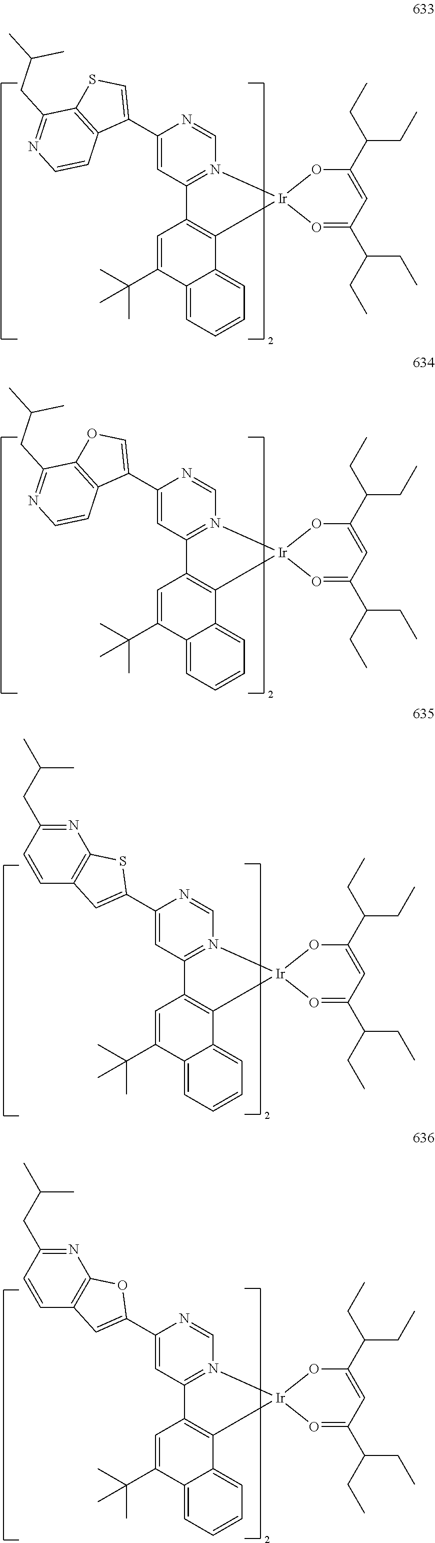

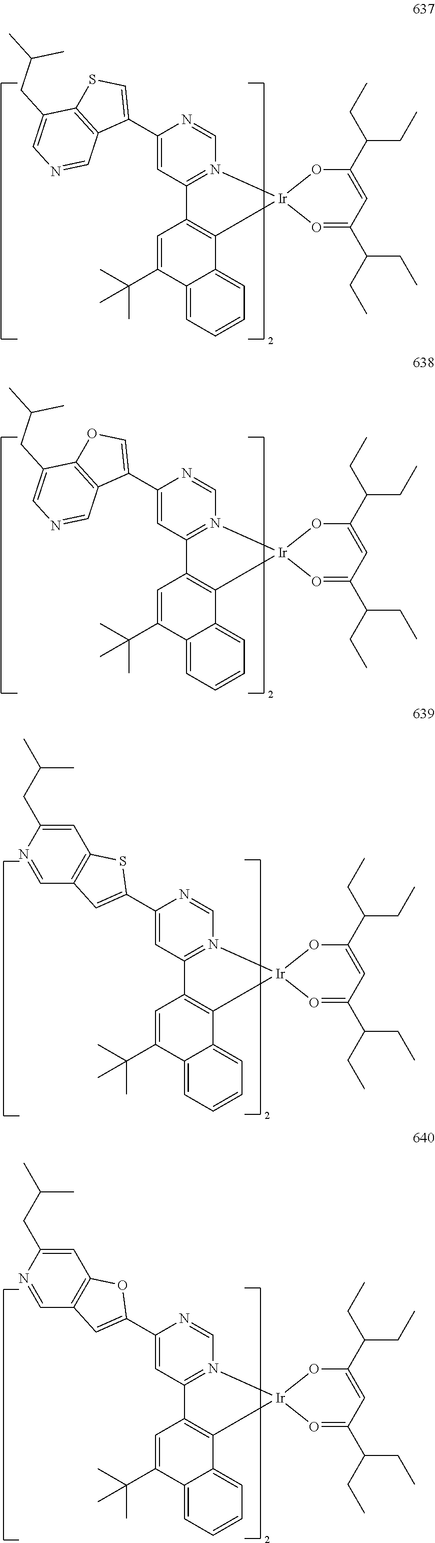

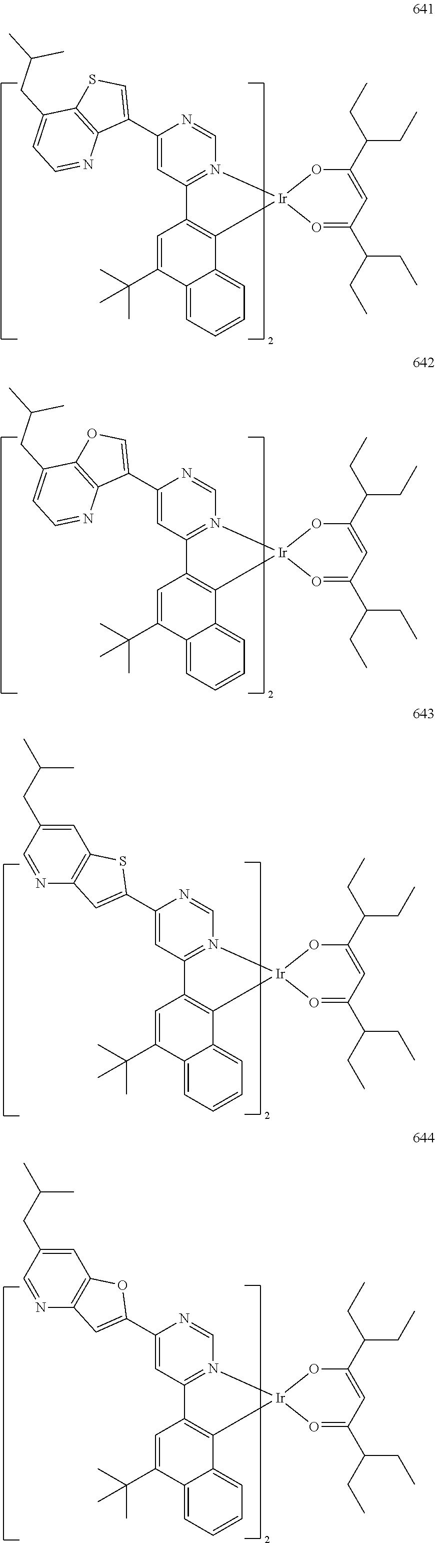

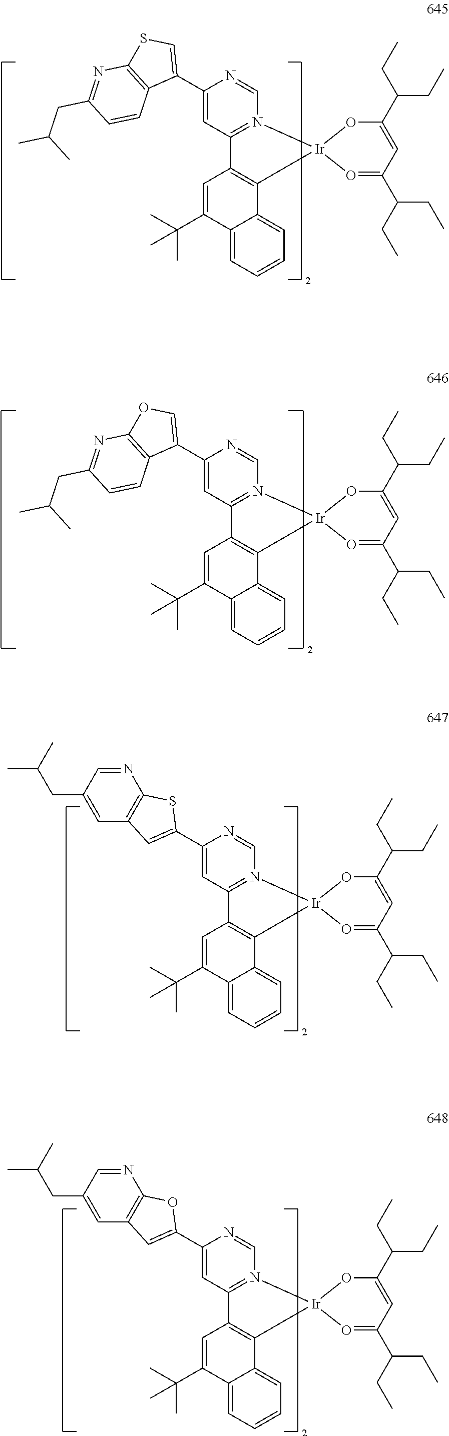

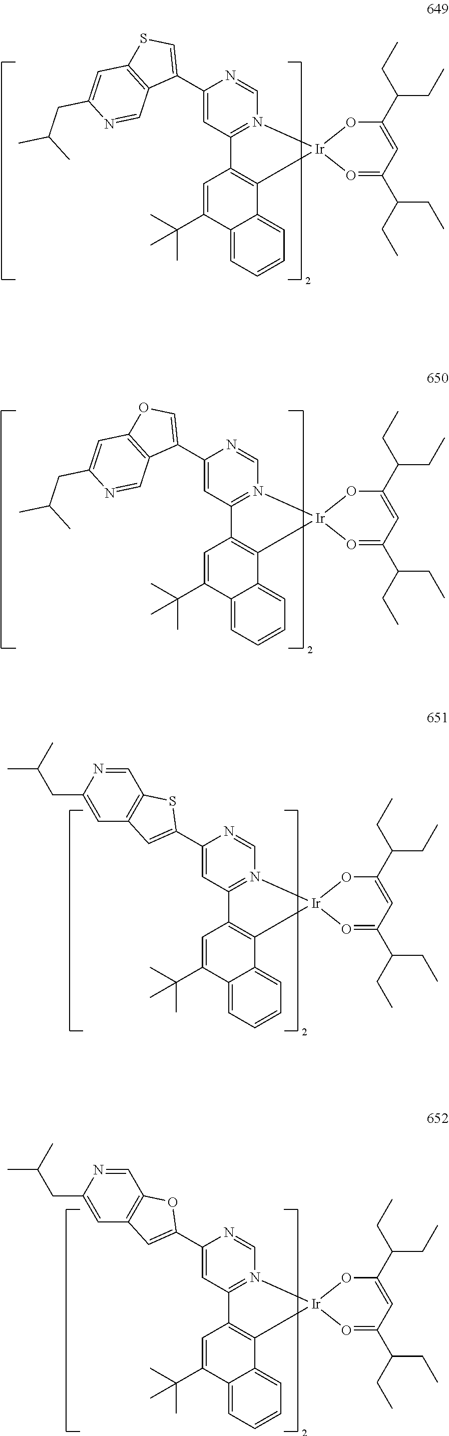

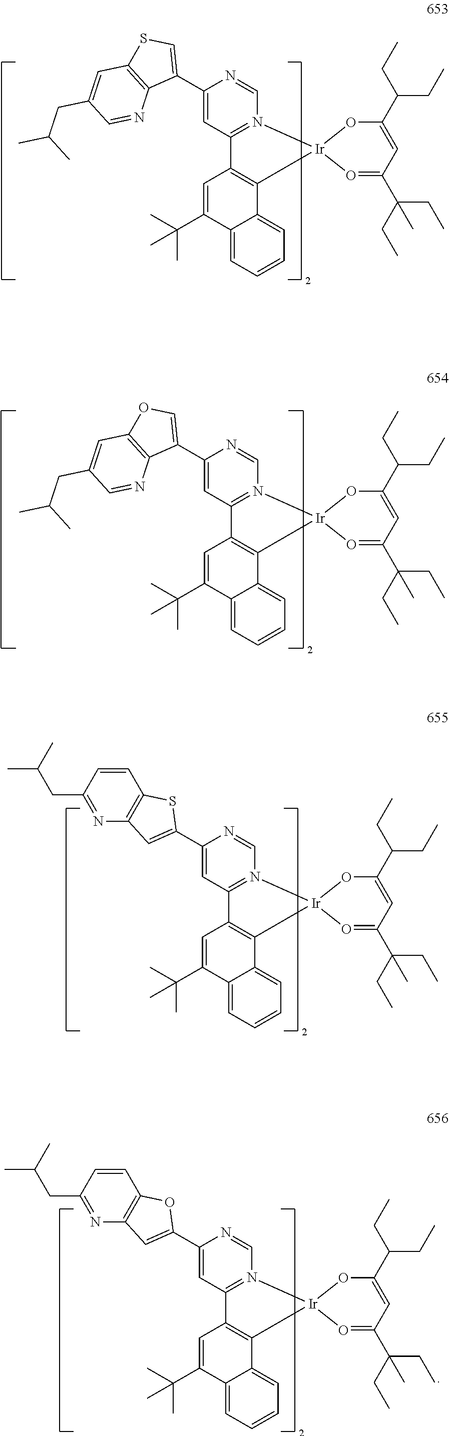

15. An organic light emitting diode including:
a first electrode;
a second electrode facing the first electrode; and
an emissive layer disposed between the first and second electrodes and including at least one emitting material layer,
wherein the at least emitting material layer includes an organometallic compound represented by a structure of Chemical Formula 1:
Ir(L_{A})ₘ(L_{B})ₙ [Chemical Formula 1]
wherein, in the Chemical Formula 1,
L_{A} has the following structure of Chemical Formula 2;
L_{B} is an auxiliary ligand;
m is 1, 2 or 3;
n is 0, 1 or 2; and
m+n is 3; 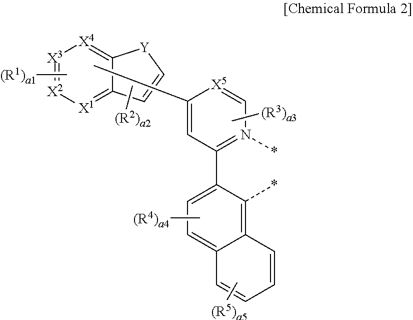
wherein, in the Chemical Formula 2,
each of X¹ to X⁴ is independently CR¹, N or a carbon atom linked to a hetero aromatic ring including X⁵, where at least one of X¹ to X⁴ is CR¹ or the carbon atom linked to the hetero aromatic ring including X⁵;
X⁵ is CR³, N or a carbon atom linked to a ring including X¹ to X⁴ and Y;
Y is CR⁶R⁷, NR⁶, O or S;
each of R¹ to R⁷ is independently hydrogen, halogen, a hydroxyl group, a cyano group, a nitro group, an amidino group, a hydrazine group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ alicyclic group, an unsubstituted or substituted C₃-C₃₀ hetero alicyclic group, an unsubstituted or substituted C₆-C₃₀ aromatic group or an unsubstituted or substituted C₃-C₃₀ hetero aromatic group, where each R¹ is identical to or different from each other when a1 is 2, 3 or 4, where each R² is identical to or different from each other when a2 is 2, where each R³ is identical to or different from each other when a3 is 2 or 3, where each R⁴ is identical to or different from each other when a4 is 2, and where each R⁵ is identical to or different from each other when a5 is 2, 3 or 4;
optionally,
two adjacent R¹ when a1 is 2, 3 or 4, and/or
two adjacent R² when a2 is 2, and/or
two adjacent R³ when a3 is 2 or 3, and/or
two adjacent R⁴ when a4 is 2, and/or
two adjacent R⁵ when a5 is 2, 3 or 4, and/or
R⁶ and R⁷
are further linked together to form an unsubstituted or substituted C₄-C₂₀ alicyclic ring, an unsubstituted or substituted C₃-C₂₀ hetero alicyclic ring, an unsubstituted or substituted C₆-C₂₀ aromatic ring or an unsubstituted or substituted C₃-C₂₀ hetero aromatic ring;
a1 is 1, 2, 3 or 4 when R¹ is hydrogen, and a1 is 0, 1, 2, 3 or 4 when R¹ is other than hydrogen;
a2 is 1 or 2 when R² is hydrogen, and a2 is 0, 1 or 2 when R² is other than hydrogen;
a3 is 2 or 3 when R³ is hydrogen, and a3 is 0, 1, 2 or 3 when R³ is other than hydrogen;
a4 is 2 when R⁴ is hydrogen, and a4 is 0, 1 or 2 when R⁴ is other than hydrogen; and
a5 is 4 when R⁵ is hydrogen, and a5 is 0, 1, 2, 3 or 4 when R⁵ is other than hydrogen.

16. The organic light emitting diode of claim 15, wherein the L_{A} has the following structure of Chemical Formula 3: 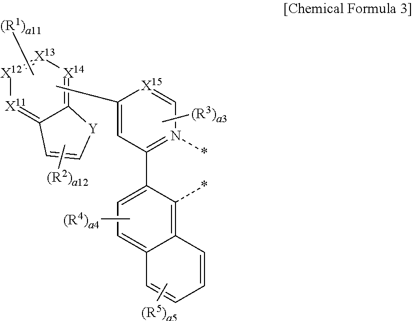
wherein, in the Chemical Formula 3,
each of Y, R¹ to R⁵ and a3 to a5 is a same as defined in Chemical Formula 2;
each of X¹¹ to X¹⁴ is independently CR¹, N or a carbon atom linked to a hetero aromatic ring including X¹⁵, where at least one of X¹¹ to X¹⁴ is CR¹ and another of X¹¹ to X¹⁴ is the carbon atom linked to the hetero aromatic ring including X¹⁵;
X¹⁵ is CR³ or N;
a11 is 1, 2 or 3 when R¹ is hydrogen, and a1 l is 0, 1, 2 or 3 when R¹ is other than hydrogen; and
a12 is 2 when R² is hydrogen, and a12 is 0, 1 or 2 when R² is other than hydrogen.

17. The organic light emitting diode of claim 15, wherein the L_{A} has the following structure of Chemical Formula 4: 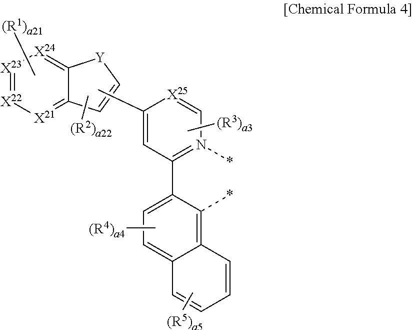
wherein, in the Chemical Formula 4,
each of Y, R¹ to R⁵ and a3 to a5 is a same as defined in Chemical Formula 2;
each of X²¹ to X²⁴ is independently CR¹ or N, where at least one of X²¹ to X²⁴ is CR¹;
X²⁵ is CR³ or N;
a21 is 1, 2, 3 or 4 when R¹ is hydrogen, and a21 is 0, 1, 2, 3 or 4 when R¹ is other than hydrogen; and
a22 is 1 when R² is hydrogen, and a22 is 0 or 1 when R² is other than hydrogen.

18. The organic light emitting diode of claim 15, wherein the L_{A} has the following structure of Chemical Formula 5: 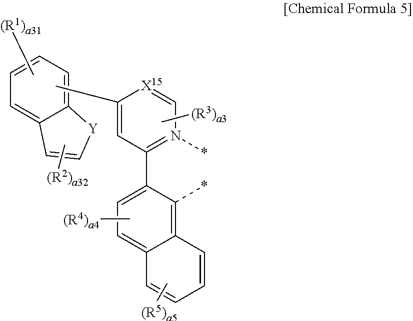
wherein, in the Chemical Formula 5,
each of Y, R¹ to R⁵ and a3 to a5 is a same as defined in Chemical Formula 2;
X¹⁵ is CR³ or N;
a31 is 3 when R¹ is hydrogen, and a31 is 0, 1, 2 or 3 when R¹ is other than hydrogen; and
a32 is 2 when R² is hydrogen, and a32 is 0, 1 or 2 when R² is other than hydrogen.

19. The organic light emitting diode of claim 15, wherein the L_{A} has the following structure of Chemical Formula 6: 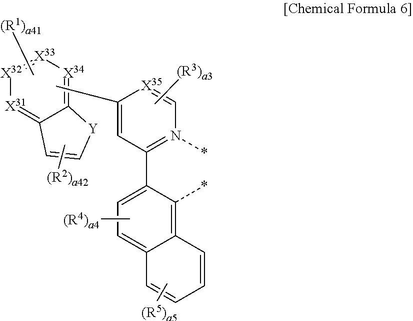
wherein, in the Chemical Formula 6,
each of Y, R³ to R⁵ and a3 to a5 is a same as defined in Chemical Formula 2;
each of X³¹ to X³⁴ is independently CR¹, N or a carbon atom linked to a hetero aromatic ring including X³⁵, where one of X³¹ to X³⁴ is N, the other of X³¹ to X³⁴ is the carbon atom linked to the hetero aromatic ring including X³⁵, and each of others of X³¹ to X³⁴ is independently CR¹;
X³⁵ is CR³ or N;
a41 is 2 when R³ is hydrogen, and a41 is 0, 1 or 2 when R³ is other than hydrogen; and
a42 is 1 when R² is hydrogen, and a42 is 0, 1 or 2 when R² is other than hydrogen.

20. The organic light emitting diode of claim 15, wherein the L_{A} has the following structure of Chemical Formula 7: 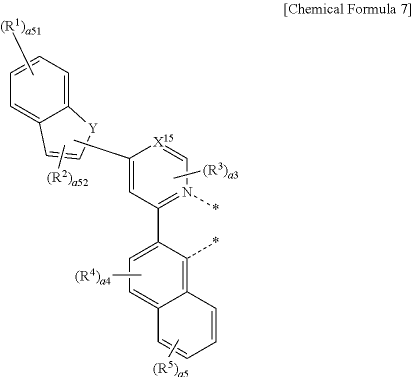
wherein, in the Chemical Formula 7,
each of Y, R¹ to R⁵ and a3 to a5 is a same as defined in Chemical Formula 2;
X¹⁵ is CR³ or N;
a51 is 4 when R¹ is hydrogen, and a51 is 0, 1, 2, 3 or 4 when R¹ is other than hydrogen; and
a52 is 1 when R² is hydrogen, and a52 is 0 or 1 when R² is other than hydrogen.

21. The organic light emitting diode of claim 15, wherein the L_{A} has the following structure of Chemical Formula 8: 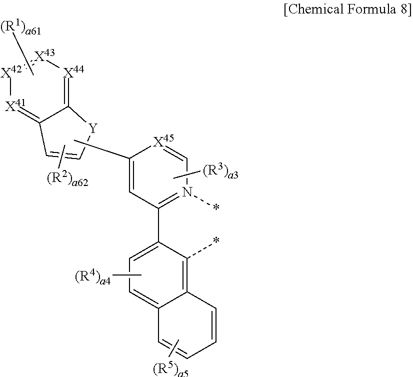
wherein, in the Chemical Formula 8,
each of Y, R¹ to R⁵ and a3 to a5 is a same as defined in Chemical Formula 2;
each of X⁴¹ to X⁴⁴ is independently CR¹ or N, where one of X⁴¹ to X⁴⁴ is N, and each of others of X⁴¹ to X⁴⁴ is independently CR¹;
X⁴⁵ is CR³ or N;
a61 is 3 when R¹ is hydrogen, and a61 is 0, 1, 2 or 3 when R¹ is other than hydrogen; and
a62 is 1 when R² is hydrogen, and a62 is 0 or 1 when R² is other than hydrogen.

22. The organic light emitting diode of claim 15, wherein the L_{B} has the following structure of Chemical Formula 9A or Chemical Formula 9B: 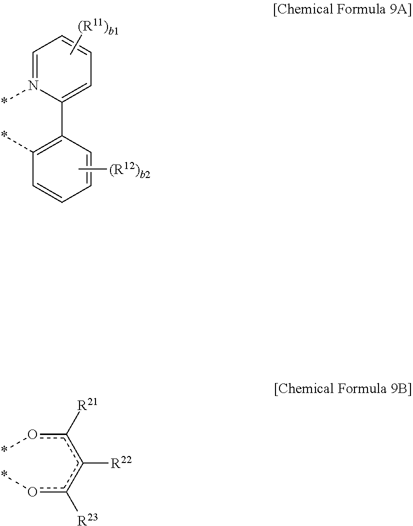
wherein, in the Chemical Formulae 9A and 9B,
each of R¹¹, R¹¹ and R²¹ to R²³ is independently hydrogen, halogen, a hydroxyl group, a cyano group, a nitro group, an amidino group, a hydrazine group, an unsubstituted or substituted C₁-C₂₀ alkyl group, an unsubstituted or substituted C₂-C₂₀ alkenyl group, an unsubstituted or substituted C₂-C₂₀ alkynyl group, an unsubstituted or substituted C₁-C₂₀ alkoxy group, an unsubstituted or substituted C₁-C₂₀ alkyl amino group, an unsubstituted or substituted C₁-C₂₀ alkyl silyl group, an unsubstituted or substituted C₄-C₃₀ alicyclic group, an unsubstituted or substituted C₃-C₃₀ hetero alicyclic group, an unsubstituted or substituted C₆-C₃₀ aromatic group or an unsubstituted or substituted C₃-C₃₀ hetero aromatic group, where each R¹¹ is identical to or different from each other when b1 is 2, 3 or 4, and where each R¹² is identical to or different from each other when b2 is 2, 3 or 4;
optionally,
two adjacent R¹¹ when b1 is 2, 3 or 4, and/or
two adjacent R¹² when b2 is 2, 3 or 4, and/or
R²¹ and R²² or R²² and R²³
are further linked together to form an unsubstituted or substituted C₄-C₂₀ alicyclic ring, an unsubstituted or substituted C₃-C₂₀ hetero alicyclic ring, an unsubstituted or substituted C₆-C₃₀ aromatic ring or an unsubstituted or substituted C₃-C₃₀ hetero aromatic ring; and
each of b1 and b2 is 4 when each of R¹¹ and R¹² is hydrogen and each of b1 and b2 is independently 0, 1, 2, 3 or 4 when each of R¹¹ and R¹² is other than hydrogen.

23. The organic light emitting diode claim 15, wherein each of X¹ to X⁴ in Chemical Formula 2 is independently CR¹ or the carbon atom linked to the hetero aromatic ring including X⁵, Y in Chemical Formula 2 is O or S, and each of R¹ to R⁷ in Chemical Formula 2 is independently hydrogen or a C₁-C₂₀ alkyl group.

24. The organic light emitting diode of claim 15, wherein one of X¹ to X⁴ in Chemical Formula 2 is N and other three of X¹ to X⁴ is independently CR¹ or the carbon atom linked to the hetero aromatic ring including X⁵, Y in Chemical Formula 2 is O or S, and each R¹ to R⁵ in Chemical Formula 2 is independently hydrogen or a C₁-C₂₀ alkyl group.

25. The organic light emitting diode of claim 15, wherein the at least one emitting material layer includes a host and a dopant, and wherein the dopant includes the organometallic compound.

26. The organic light emitting diode of claim 15, wherein the emissive layer includes:
a first emitting part disposed between the first and second electrodes and including a first emitting material layer;
a second emitting part disposed between the first emitting part and the second electrode and including second emitting material layer; and
a first charge generation layer disposed between the first emitting part and the second emitting part, and
wherein at least one of the first emitting material layer and the second emitting material layer includes the organometallic compound.

27. The organic light emitting diode of claim 26, wherein the second emitting material layer includes:
a first layer disposed between the first charge generation layer and the second electrode; and
a second layer disposed between the first layer and the second electrode, and
wherein one of the first layer and the second layer includes the organometallic compound.

28. The organic light emitting diode of claim 26, wherein the emissive layer further includes:
a third emitting part disposed between the second emitting part and the second electrode and including a third emitting material layer; and
a second charge generation layer disposed between the second emitting part and the third emitting part.

29. An organic light emitting device including:
a substrate; and
the organic light emitting diode of claim 15 disposed over the substrate.
